(19) United States
(12) Patent Application Publication
(10) Pub. No.: US 2025/0386499 A1
(43) Pub. Date: Dec. 18, 2025

(54) THREE-DIMENSIONAL MEMORY DEVICE WITH THROUGH-STACK CONTACT VIA STRUCTURES AND METHODS FOR FORMING THE SAME

(71) Applicant: Sandisk Technologies LLC, Addison, TX (US)

(72) Inventors: Masato NOGUCHI, Yokkaichi (JP); Masanori TSUTSUMI, Yokkaichi (JP)

(21) Appl. No.: 18/887,781

(22) Filed: Sep. 17, 2024

Related U.S. Application Data
(63) Continuation-in-part of application No. 18/805,051, filed on Aug. 14, 2024.
(60) Provisional application No. 63/660,154, filed on Jun. 14, 2024.

(51) Int. Cl. H10B 43/27; G11C 5/06; G11C 16/04; H10B 41/10; H10B 41/27; H10B 41/35; H10B 43/10; H10B 43/35

(52) U.S. Cl. CPC H10B 43/27; G11C 5/06; G11C 16/0483; H10B 41/10; H10B 41/27; H10B 41/35; H10B 43/10; H10B 43/35

(57) ABSTRACT

A device structure includes at least one alternating stack of respective insulating layers and respective electrically conductive layers, at least one retro-stepped dielectric material portion overlying portions of the at least one alternating stack, a memory stack structure vertically extending through each layer within the at least one alternating stack, and a contact via structure including a laterally bulging portion in contact with a first electrically conductive layer of the electrically conductive layers within the at least one alternating stack, an upper portion that vertically extends upward from the laterally bulging portion and through the at least one retro-stepped dielectric material portion, and a lower portion that vertically extends through second electrically conductive layers of the electrically conductive layers that underlie the first electrically conductive layer.

### RELATED APPLICATIONS

This application is a continuation-in-part of U.S. Non-Provisional application Ser. No. 18/805,051 filed on Aug. 14, 2024, which claims the benefit of priority from U.S. Provisional Application Ser. No. 64/660,154 filed on Jun. 14, 2024, the entire contents of which are incorporated herein by reference.

### FIELD

The present disclosure relates generally to the field of semiconductor devices, and particularly to a three-dimensional memory device including through-stack contact via structures and methods for forming the same.

### BACKGROUND

A three-dimensional memory device including three-dimensional vertical NAND strings having one bit per cell is disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a device structure is provided, which comprises: at least one alternating stack of respective insulating layers and respective electrically conductive layers, wherein each of the at least one alternating stack comprises respective stepped surfaces located in a staircase region; at least one retro-stepped dielectric material portion overlying portions of the at least one alternating stack located in the staircase region; a memory opening vertically extending through each layer within the at least one alternating stack; a memory opening fill structure located in the memory opening and comprising a vertical stack of memory elements and a vertical semiconductor channel; and a contact via structure comprising a laterally bulging portion in contact with a first electrically conductive layer of the electrically conductive layers within the at least one alternating stack, an upper portion that vertically extends upward from the laterally bulging portion and through the at least one retro-stepped dielectric material portion, and a lower portion that vertically extends through second electrically conductive layers of the electrically conductive layers that underlie the first electrically conductive layer; and a vertical stack of annular dielectric spacers laterally surrounding the lower portion of the contact via structure, and laterally surrounded by the second electrically conductive layers.

According to another aspect of the present disclosure, a method of forming a device structure is provided, which comprises: forming an alternating stack of insulating layers and sacrificial material layers over a substrate; forming stepped surfaces by patterning the alternating stack in a staircase region; forming a retro-stepped dielectric material portion over the stepped surfaces; forming a contact via cavity through the retro-stepped dielectric material portion and a subset of the sacrificial material layers within the alternating stack, wherein the subset of the sacrificial material layers comprises a first sacrificial material layer which is a topmost sacrificial material layer of the subset of the sacrificial material layers and further comprises second sacrificial material layers that underlie the first sacrificial material layer; locally expanding the contact via cavity by laterally recessing the first sacrificial material layer around the contact via cavity to form a rectangular-vertical-profiled toroidal void in a volume from which a portion of the first sacrificial material layer is removed; forming a dual-inward-flanged tube comprising a sacrificial material in the rectangular-vertical-profiled toroidal void; forming a sacrificial contact via structure in the contact via cavity; replacing the sacrificial material layers and the dual-inward-flanged tube at least with electrically conductive layers; and replacing the sacrificial contact via structure with a contact via structure, wherein the contact via structure contacts a cylindrical sidewall of the first electrically conductive layer.

According an aspect of the present disclosure, a device structure comprises: at least one alternating stack of respective insulating layers and respective electrically conductive layers, wherein each of the at least one alternating stack comprises respective stepped surfaces located in a staircase region; at least one retro-stepped dielectric material portion overlying portions of the at least one alternating stack located in the staircase region; a memory opening vertically extending through each layer within the at least one alternating stack; a memory opening fill structure located in the memory opening and comprising a vertical stack of memory elements and a vertical semiconductor channel; and a contact via structure comprising a laterally bulging portion in contact with a first electrically conductive layer of the electrically conductive layers within the at least one alternating stack, an upper portion that vertically extends upward from the laterally bulging portion and through the at least one retro-stepped dielectric material portion, and a lower portion that vertically extends through second electrically conductive layers of the electrically conductive layers that underlie the first electrically conductive layer. The second electrically conductive layers are laterally offset from a first cylindrical vertical plane including an outer sidewall of the lower portion of the contact via structure by a first lateral offset distance; and the first electrically conductive layers are laterally offset from the first cylindrical vertical plane by a second lateral offset distance that is less than the first lateral offset distance.

According to another aspect of the present disclosure, a method of forming a device structure comprises: forming an alternating stack of insulating layers and sacrificial material layers over a substrate; forming stepped surfaces by patterning the alternating stack in a staircase region; forming a retro-stepped dielectric material portion over the stepped surfaces; forming a contact via cavity through the retro-stepped dielectric material portion and a subset of the sacrificial material layers within the alternating stack, wherein the subset of the sacrificial material layers comprises a first sacrificial material layer which is a topmost sacrificial material layer of the subset of the sacrificial material layers and further comprises second sacrificial material layers that underlie the first sacrificial material layer; replacing an annular portion of the first sacrificial material layer that is proximal to the contact via cavity with a sacrificial fill material spacer; forming a sacrificial contact via structure having a straight sidewall that vertically extends at least from a horizontal plane including a top surface of the retro-stepped dielectric material portion to a horizontal plane including a bottommost surface of the retro-stepped dielectric material portion; replacing the sacrificial material layers with electrically conductive layers such that a first electrically conductive layer of the electrically conductive layers occupies a volume of the sacrificial fill material spacer and a volume of the first sacrificial material layer; and replacing the sacrificial contact via structure with a contact via structure, wherein the contact via structure contacts a cylindrical sidewall of the first electrically conductive layer.

According to an aspect of the present disclosure, a device structure comprises: at least one alternating stack of respective insulating layers and respective electrically conductive layers, wherein each of the at least one alternating stack comprises respective stepped surfaces located in a staircase region, and wherein each of the insulating layers comprises a respective carbon-doped silicate glass layer; at least one retro-stepped dielectric material portion overlying portions of the at least one alternating stack located in the staircase region; a memory opening vertically extending through each layer within the at least one alternating stack; a memory opening fill structure located in the memory opening and comprising a vertical stack of memory elements and a vertical semiconductor channel; and a contact via structure comprising a laterally bulging portion in contact with a first electrically conductive layer of the electrically conductive layers within the at least one alternating stack, an upper portion that vertically extends upward from the laterally bulging portion and through the at least one retro-stepped dielectric material portion, and a lower portion that vertically extends through a subset of the electrically conductive layers that underlies the first electrically conductive layer.

According to another aspect of the present disclosure, a method of forming a device structure comprises: forming an alternating stack of insulating layers and sacrificial material layers over a substrate, wherein each of the insulating layers comprises a respective carbon-doped silicate glass layer; forming stepped surfaces by patterning the alternating stack in a staircase region; forming a retro-stepped dielectric material portion overlying the stepped surfaces; forming a contact via cavity through the retro-stepped dielectric material portion and a subset of the sacrificial material layers within the alternating stack, wherein the subset of the sacrificial material layers comprises a first sacrificial material layer which is a topmost sacrificial material layer of the subset of the sacrificial material layers and further comprises second sacrificial material layers that underlie the first sacrificial material layer; forming first annular recess regions by performing a first isotropic etch process that isotropically etches proximal portions of the second sacrificial material layers selectively to the insulating layers; depositing a recess-fill dielectric material layer in the first annular recess regions and over a sidewall of the contact via cavity; isotropically recessing the recess-fill dielectric material layer by performing a second isotropic etch process that etches the recess-fill dielectric material layer at a higher etch rate than the carbon-doped silicate glass layers; replacing the sacrificial material layers with electrically conductive layers; and filling the contact via cavity with a contact via structure, wherein the contact via structure contacts a cylindrical sidewall of a first electrically conductive layer of the electrically conductive layers which is formed within a volume of the first sacrificial material layer.

### BRIEF DESCRIPTION OF THE DRAWINGS

FIG. 1A is a plan view of a configuration of an exemplary semiconductor die including multiple three-dimensional memory array regions according to an embodiment of the present disclosure. FIG. 1B is a schematic see-through top-down view of region M1 of FIG. 1A. FIG. 1C is a schematic vertical cross-sectional view of a region of the exemplary semiconductor die along the vertical plane C-C′ of FIG. 1B. The vertical plane E-E′ is the cut plane of the schematic vertical cross-sectional view of FIG. 1E. FIG. 1D is a schematic vertical cross-sectional view of a region of the exemplary semiconductor die along the vertical plane D-D′ of FIG. 1B. FIG. 1E is a schematic vertical cross-sectional view of a region of the exemplary semiconductor die along the vertical plane E-E′ of FIG. 1B. The vertical plane C-C′ is the cut plane of the schematic vertical cross-sectional view of FIG. 1C. FIG. 1F is a vertical cross-sectional view of a region of the exemplary semiconductor die around a memory opening fill structure.

FIG. 2A is a schematic vertical cross-sectional view of a first exemplary structure for forming a semiconductor die after formation of a vertically alternating sequence of first-tier continuous insulating layers and first-tier continuous sacrificial material layers, and a first-tier stepped cavity according to an embodiment of the present disclosure. FIG. 2B is a schematic vertical cross-sectional view of the first exemplary structure along the vertical plane B-B′ of FIG. 2A. The vertical plane A-A′ is the cut plane of the vertical cross-sectional view of FIG. 2A. FIG. 2C is a magnified view of a region of the first exemplary structure around a portion of a first-tier stepped cavity in FIG. 2B.

FIGS. 3A and 3B are sequential vertical cross-sectional views of a region of the first exemplary structure during thickening of physically-exposed portions of the first-tier sacrificial material layers according to an embodiment of the present disclosure. FIG. 3C is a top-down view a region of the first exemplary structure after the processing steps of FIG. 3B according to an embodiment of the present disclosure.

FIG. 4A is a schematic vertical cross-sectional view of the first exemplary structure after formation of a first-tier retro-stepped dielectric material portion according to an embodiment of the present disclosure. FIG. 4B is a schematic vertical cross-sectional view of the first exemplary structure along the vertical plane B-B′ of FIG. 4A. The vertical plane A-A′ is the cut plane of the vertical cross-sectional view of FIG. 4A. FIG. 4C is a magnified view of a region of the first exemplary structure around a thickened portion of a first-tier sacrificial material layer in FIG. 4B.

FIG. 5A is a schematic vertical cross-sectional view of the first exemplary structure after formation of various first-tier openings and various first-tier sacrificial opening fill structures according to an embodiment of the present disclosure. FIG. 5B is a schematic vertical cross-sectional view of the first exemplary structure along the vertical plane B-B′ of FIG. 5A. The vertical plane A-A′ is the cut plane of the vertical cross-sectional view of FIG. 5A.

FIG. 6A is a schematic vertical cross-sectional view of the first exemplary structure after formation of a vertically alternating sequence of second-tier continuous insulating layers and second-tier continuous sacrificial material layers, a second-tier stepped cavity, and a second-tier retro-stepped dielectric material portion according to an embodiment of the present disclosure. FIG. 6B is a schematic vertical cross-sectional view of the first exemplary structure along the vertical plane B-B′ of FIG. 6A. The vertical plane A-A′ is the cut plane of the vertical cross-sectional view of FIG. 6A. FIG. 6C is a see-through top-down view a region of the first exemplary structure of FIGS. 6A and 6B.

FIG. 7A is a schematic vertical cross-sectional view of the first exemplary structure after formation of various second-tier openings and various second-tier sacrificial opening fill structures according to an embodiment of the present disclosure. FIG. 7B is a schematic vertical cross-sectional view of the first exemplary structure along the vertical plane B-B′ of FIG. 7A. The vertical plane A-A′ is the cut plane of the vertical cross-sectional view of FIG. 7A.

FIG. 8A is a schematic vertical cross-sectional view of the first exemplary structure after formation of a vertically alternating sequence of third-tier continuous insulating layers and third-tier continuous sacrificial material layers, a third-tier stepped cavity, and a third-tier retro-stepped dielectric material portion according to an embodiment of the present disclosure. FIG. 8B is a schematic vertical cross-sectional view of the first exemplary structure along the vertical plane B-B′ of FIG. 8A. The vertical plane A-A′ is the cut plane of the vertical cross-sectional view of FIG. 8A.

FIG. 9A is a schematic vertical cross-sectional view of the first exemplary structure after formation of various third-tier openings and various third-tier sacrificial opening fill structures according to an embodiment of the present disclosure. FIG. 9B is a schematic vertical cross-sectional view of the first exemplary structure along the vertical plane B-B′ of FIG. 9A. The vertical plane A-A′ is the cut plane of the vertical cross-sectional view of FIG. 9A.

FIG. 10 is a schematic vertical cross-sectional view of the first exemplary structure after removal of sacrificial support opening fill structures according to an embodiment of the present disclosure.

FIG. 11 is a schematic vertical cross-sectional view of the first exemplary structure after formation of support pillar structures according to an embodiment of the present disclosure.

FIG. 12 is a schematic vertical cross-sectional view of the first exemplary structure after formation of memory opening according to an embodiment of the present disclosure.

FIGS. 13A-13F illustrate sequential vertical cross-sectional views of a memory opening during formation of a memory opening fill structure according to an embodiment of the present disclosure.

FIG. 14A is a schematic vertical cross-sectional view of the first exemplary structure after formation of memory opening fill structures according to an embodiment of the present disclosure. FIG. 14B is a schematic vertical cross-sectional view of the first exemplary structure along the vertical plane B-B′ of FIG. 14A. The vertical plane A-A′ is the cut plane of the vertical cross-sectional view of FIG. 14A. FIG. 14C is a magnified view of a region of the first exemplary structure around a thickened portion of a first-tier sacrificial material layer in FIG. 14B.

FIG. 15A is a schematic vertical cross-sectional view of the first exemplary structure after formation of a contact-level dielectric layer and contact via cavities according to an embodiment of the present disclosure. FIG. 15B is a schematic vertical cross-sectional view of the first exemplary structure along the vertical plane B-B′ of FIG. 15A. The vertical plane A-A′ is the cut plane of the vertical cross-sectional view of FIG. 15A. FIG. 15C is a magnified view of a region of the first exemplary structure around a bottom corner of a first-tier stepped cavity in FIG. 15B.

FIG. 16A is a schematic vertical cross-sectional view of the first exemplary structure after formation of semiconductor oxide spacer liners according to an embodiment of the present disclosure. FIG. 16B is a schematic vertical cross-sectional view of the first exemplary structure along the vertical plane B-B′ of FIG. 16A. The vertical plane A-A′ is the cut plane of the vertical cross-sectional view of FIG. 16A.

FIGS. 17A and 17B are sequential vertical cross-sectional views of a region of the first exemplary structure during formation of annular recess regions and a recess-fill dielectric material layer according to an embodiment of the present disclosure.

FIG. 18A is a schematic vertical cross-sectional view of the first exemplary structure after formation of annular dielectric spacers according to an embodiment of the present disclosure. FIG. 18B is a schematic vertical cross-sectional view of the first exemplary structure along the vertical plane B-B′ of FIG. 18A. The vertical plane A-A′ is the cut plane of the vertical cross-sectional view of FIG. 18A. FIG. 18C is a magnified view of a region of a first configuration of the first exemplary structure around a contact via cavity in FIG. 18B. FIG. 18D is a magnified view of a region of a second configuration of the first exemplary structure around a contact via cavity in FIG. 18B.

FIG. 19A is a schematic vertical cross-sectional view of the first exemplary structure after formation of sacrificial contact via structures according to an embodiment of the present disclosure. FIG. 19B is a schematic vertical cross-sectional view of the first exemplary structure along the vertical plane B-B′ of FIG. 19A. The vertical plane A-A′ is the cut plane of the vertical cross-sectional view of FIG. 19A. FIG. 19C is a magnified view of a region of a first configuration of the first exemplary structure around a contact via cavity in FIG. 19B. FIG. 19D is a magnified view of a region of a second configuration of the first exemplary structure around a contact via cavity in FIG. 19B.

FIG. 20A is a schematic vertical cross-sectional view of the first exemplary structure after formation of lateral isolation trenches according to an embodiment of the present disclosure. FIG. 20B is a schematic vertical cross-sectional view of the first exemplary structure along the vertical plane B-B′ of FIG. 20A. The vertical plane A-A′ is the cut plane of the vertical cross-sectional view of FIG. 20A.

FIG. 21A is a schematic vertical cross-sectional view of the first exemplary structure after formation of lateral recesses according to an embodiment of the present disclosure. FIG. 21B is a schematic vertical cross-sectional view of the first exemplary structure along the vertical plane B-B′ of FIG. 21A. The vertical plane A-A′ is the cut plane of the vertical cross-sectional view of FIG. 21A. FIG. 21C is a magnified view of a region of a first configuration of the first exemplary structure around a contact via cavity in FIG. 21B. FIG. 21D is a magnified view of a region of a second configuration of the first exemplary structure around a contact via cavity in FIG. 21B.

FIG. 22 is a vertical cross-sectional view of a region of the first configuration of the first exemplary structure after formation of an outer blocking dielectric layer according to an embodiment of the present disclosure.

FIG. 23A is a schematic vertical cross-sectional view of the first exemplary structure after formation of electrically conductive layers according to an embodiment of the present disclosure. FIG. 23B is a schematic vertical cross-sectional view of the first exemplary structure along the vertical plane B-B′ of FIG. 23A. The vertical plane A-A′ is the cut plane of the vertical cross-sectional view of FIG. 23A. FIG. 23C is a magnified view of a region of a first configuration of the first exemplary structure around a contact via cavity in FIG. 23B. FIG. 23D is a magnified view of a region of a second configuration of the first exemplary structure around a contact via cavity in FIG. 23B. FIG. 23E is a vertical cross-sectional view of the first exemplary structure of FIGS. 23A-23D around a memory opening fill structure.

FIG. 24A is a schematic vertical cross-sectional view of the first exemplary structure after formation of lateral isolation trench fill structures according to an embodiment of the present disclosure. FIG. 24B is a schematic vertical cross-sectional view of the first exemplary structure along the vertical plane B-B′ of FIG. 24A. The vertical plane A-A′ is the cut plane of the vertical cross-sectional view of FIG. 24A.

FIG. 25A is a schematic vertical cross-sectional view of the first exemplary structure after removal of the sacrificial contact via structures according to an embodiment of the present disclosure. FIG. 25B is a schematic vertical cross-sectional view of the first exemplary structure along the vertical plane B-B′ of FIG. 25A. The vertical plane A-A′ is the cut plane of the vertical cross-sectional view of FIG. 25A. FIG. 25C is a magnified view of a region of a first configuration of the first exemplary structure around a contact via cavity in FIG. 25B.

FIG. 26A is a vertical cross-sectional view of a region of the first configuration of the first exemplary structure after removal of proximal portions of the outer blocking dielectric layers that are exposed to the contact via cavities according to an embodiment of the present disclosure. FIG. 26B is a vertical cross-sectional view of a region of the second configuration of the first exemplary structure after removal of proximal portions of the outer blocking dielectric layers that are exposed to the contact via cavities according to an embodiment of the present disclosure.

FIG. 27A is a schematic vertical cross-sectional view of the first exemplary structure after formation of contact via structures according to an embodiment of the present disclosure.

FIG. 27B is a schematic vertical cross-sectional view of the first exemplary structure along the vertical plane B-B′ of FIG. 27A. The vertical plane A-A′ is the cut plane of the vertical cross-sectional view of FIG. 27A. FIG. 27C is a magnified view of a region of a first configuration of the first exemplary structure around a contact via cavity in FIG. 27B. FIG. 27D is a magnified view of a region of a second configuration of the first exemplary structure around a contact via cavity in FIG. 27B.

FIG. 28 is a schematic vertical cross-sectional view of the first exemplary structure after formation of drain contact via structures according to an embodiment of the present disclosure.

FIG. 29 is a schematic vertical cross-sectional view of the first exemplary structure after formation of a memory die, bonding of the memory die to a logic die, removal of the carrier substrate, and formation of source-side structures according to an embodiment of the present disclosure.

FIG. 30A is a schematic vertical cross-sectional view of a second exemplary structure after formation of memory opening fill structures according to an embodiment of the present disclosure. FIG. 30B is a schematic vertical cross-sectional view of the second exemplary structure along the vertical plane B-B′ of FIG. 30A. The vertical plane A-A′ is the cut plane of the vertical cross-sectional view of FIG. 30A. FIG. 30C is a magnified view of a region of the second exemplary structure around a thickened portion of a first-tier sacrificial material layer in FIG. 30B.

FIG. 31A is a schematic vertical cross-sectional view of the second exemplary structure after formation of a contact-level dielectric layer and contact via cavities according to an embodiment of the present disclosure. FIG. 31B is a schematic vertical cross-sectional view of the second exemplary structure along the vertical plane B-B′ of FIG. 31A. The vertical plane A-A′ is the cut plane of the vertical cross-sectional view of FIG. 31A. FIG. 31C is a magnified view of a region of the second exemplary structure around a bottom corner of a first-tier stepped cavity in FIG. 31B.

FIGS. 32A-32H are vertical cross-sectional views of a region of the second exemplary structure around a contact via cavity during formation of annular dielectric spacers, a sacrificial fill material spacer, a sacrificial permeable liner, and an annular void according to an embodiment of the present disclosure.

FIG. 33A is a schematic vertical cross-sectional view of the second exemplary structure after formation of sacrificial contact via structures according to an embodiment of the present disclosure. FIG. 33B is a schematic vertical cross-sectional view of the second exemplary structure along the vertical plane B-B′ of FIG. 33A. The vertical plane A-A′ is the cut plane of the vertical cross-sectional view of FIG. 33A. FIG. 33C is a magnified view of a region of the second exemplary structure around a thickened portion of a first-tier sacrificial material layer in FIG. 33B.

FIG. 34A is a schematic vertical cross-sectional view of the second exemplary structure after formation of lateral isolation trenches and lateral recesses according to an embodiment of the present disclosure. FIG. 34B is a schematic vertical cross-sectional view of the second exemplary structure along the vertical plane B-B′ of FIG. 34A. The vertical plane A-A′ is the cut plane of the vertical cross-sectional view of FIG. 34A. FIG. 34C is a magnified view of a region of the second exemplary structure around a thickened portion of a first-tier sacrificial material layer in FIG. 34B.

FIG. 35 is a magnified view of a region around a contact via cavity after formation of electrically conductive layers according to an embodiment of the present disclosure.

FIG. 36A is a schematic vertical cross-sectional view of the second exemplary structure after formation of lateral isolation trench fill structures and removal of the sacrificial contact via structures according to an embodiment of the present disclosure. FIG. 36B is a schematic vertical cross-sectional view of the second exemplary structure along the vertical plane B-B′ of FIG. 36A. The vertical plane A-A′ is the cut plane of the vertical cross-sectional view of FIG. 36A. FIG. 36C is a magnified view of a region of the second exemplary structure around a thickened portion of a first-tier sacrificial material layer in FIG. 36B.

FIG. 37 is a magnified view of a region around a contact via cavity after removal of the sacrificial contact via structures according to an embodiment of the present disclosure.

FIG. 38 is a magnified view of a region around a contact via cavity after removal of portions of an outer blocking dielectric layer around the contact via cavity according to an embodiment of the present disclosure.

FIG. 39A is a schematic vertical cross-sectional view of the second exemplary structure after formation of contact via structures according to an embodiment of the present disclosure. FIG. 39B is a schematic vertical cross-sectional view of the second exemplary structure along the vertical plane B-B′ of FIG. 39A. The vertical plane A-A′ is the cut plane of the vertical cross-sectional view of FIG. 39A. FIG. 39C is a magnified view of a region of the second exemplary structure around a contact via cavity in FIG. 39B.

FIG. 40 is a schematic vertical cross-sectional view of the second exemplary structure after formation of a memory die, bonding of the memory die to a logic die, removal of the carrier substrate, and formation of source-side structures according to an embodiment of the present disclosure.

FIGS. 41A-41J are sequential vertical cross-sectional views of a region of a third exemplary structure during formation of a sacrificial contact via structure around a contact via cavity according to a third embodiment of the present disclosure.

FIGS. 42A-42C are sequential vertical cross-sectional views of a region of the third exemplary structure during replacement of the sacrificial material layers with outer blocking dielectric layers and electrically conductive layers according to the third embodiment of the present disclosure.

FIGS. 43A-43D are sequential vertical cross-sectional views of a region of the third exemplary structure during replacement of a sacrificial contact via structure with a contact via structure according to the third embodiment of the present disclosure.

FIGS. 44A-44I are sequential vertical cross-sectional views of a region of a fourth exemplary structure during formation of a sacrificial contact via structure around a contact via cavity according to a fourth embodiment of the present disclosure.

FIGS. 45A-45C are sequential vertical cross-sectional views of a region of the fourth exemplary structure during replacement of the sacrificial material layers with outer blocking dielectric layers and electrically conductive layers according to the fourth embodiment of the present disclosure.

FIGS. 46A-46D are sequential vertical cross-sectional views of a region of the fourth exemplary structure during replacement of a sacrificial contact via structure with a contact via structure according to the fourth embodiment of the present disclosure.

### DETAILED DESCRIPTION

As discussed above, embodiments of the present disclosure are directed to a three-dimensional memory device including through-stack contact via structures and methods for forming the same, the various aspects of which are now described in detail.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements. The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or from each other, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the first continuous structure. For example, a layer may be located between any pair of horizontal planes between, or at, a top surface and a bottom surface of the first continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

As used herein, a “memory level” or a “memory array level” refers to the level corresponding to a general region between a first horizontal plane (i.e., a plane parallel to the top surface of the substrate) including topmost surfaces of an array of memory elements and a second horizontal plane including bottommost surfaces of the array of memory elements. As used herein, a “through-stack” element refers to an element that vertically extends through a memory level.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded throughout, for example, by flip-chip bonding or another chip-to-chip bonding. A package or a chip may include a single semiconductor die (or a “die”) or a plurality of semiconductor dies. A die is the smallest unit that may independently execute external commands or report status. Typically, a package or a chip with multiple dies is capable of simultaneously executing as many number of external commands as the total number of dies therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

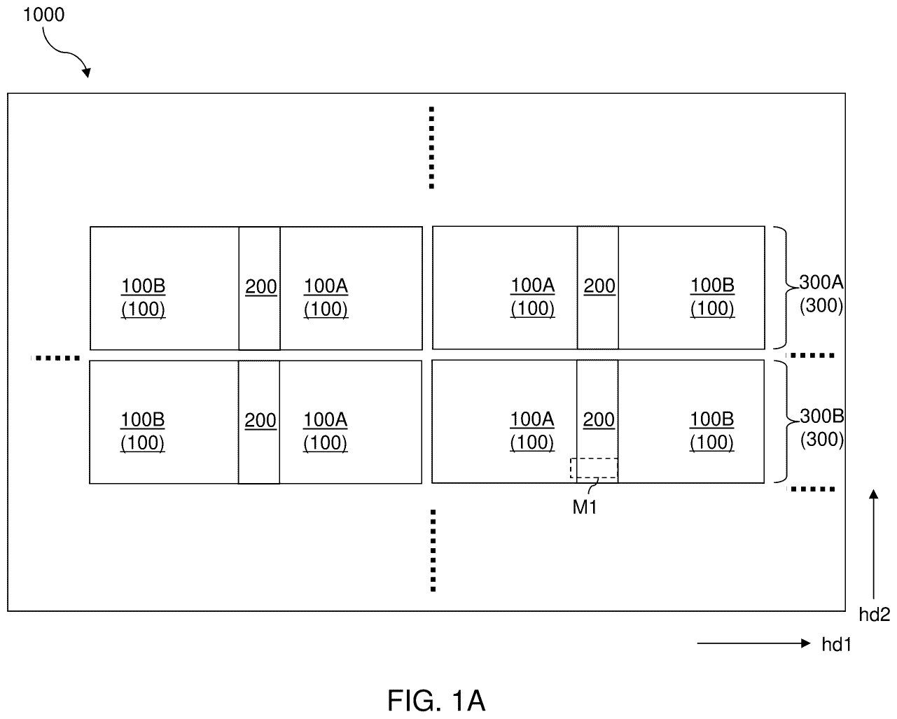

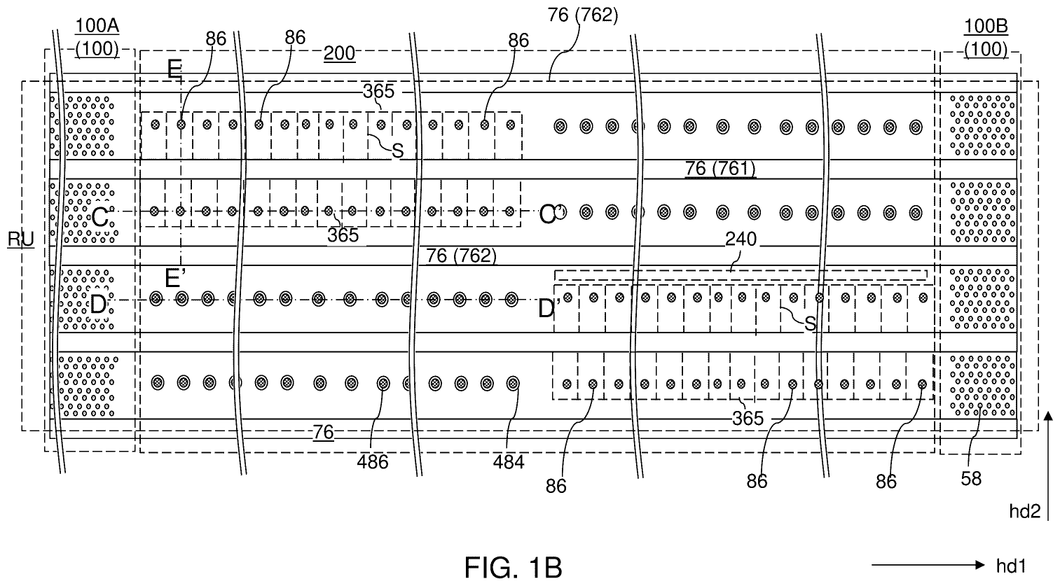

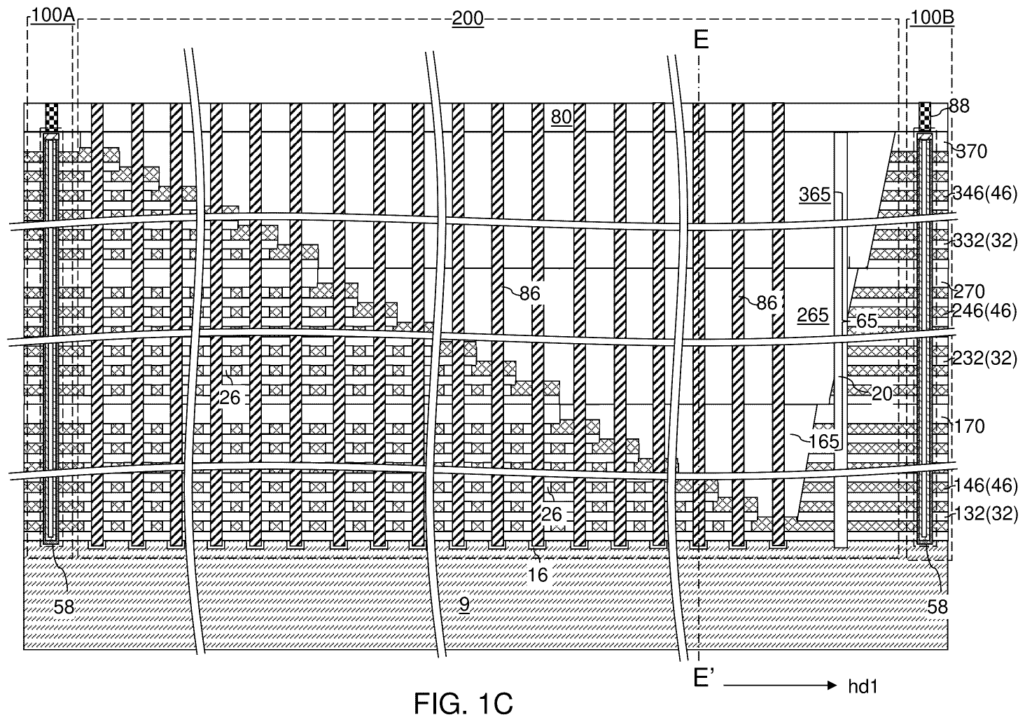

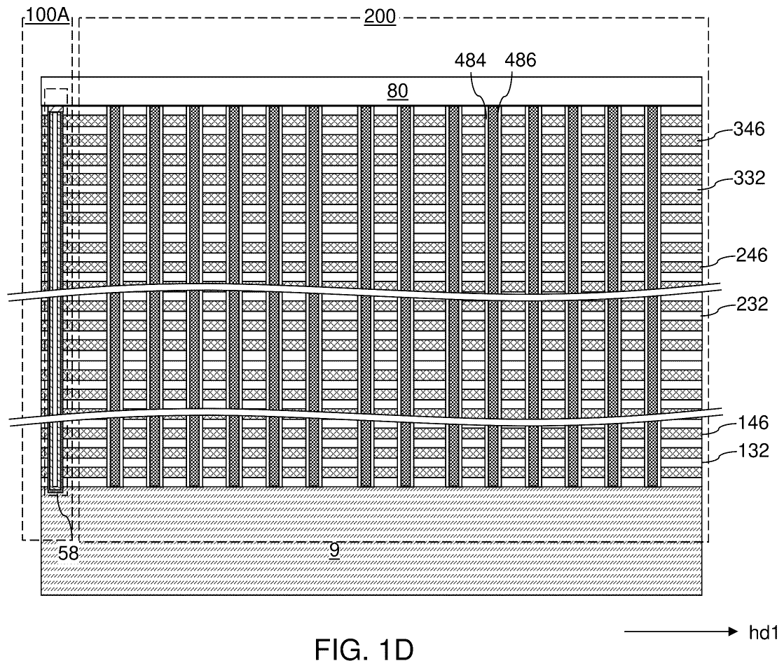

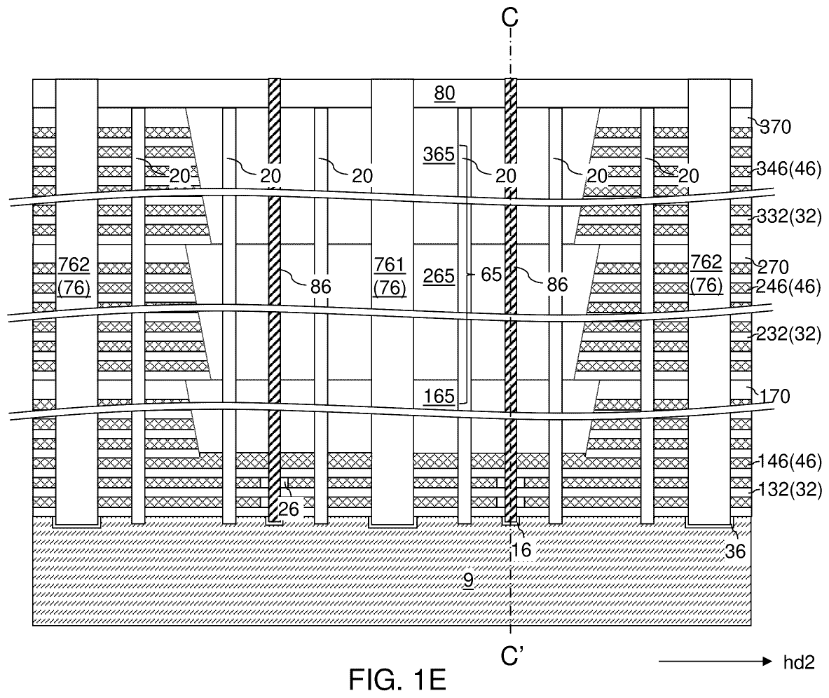

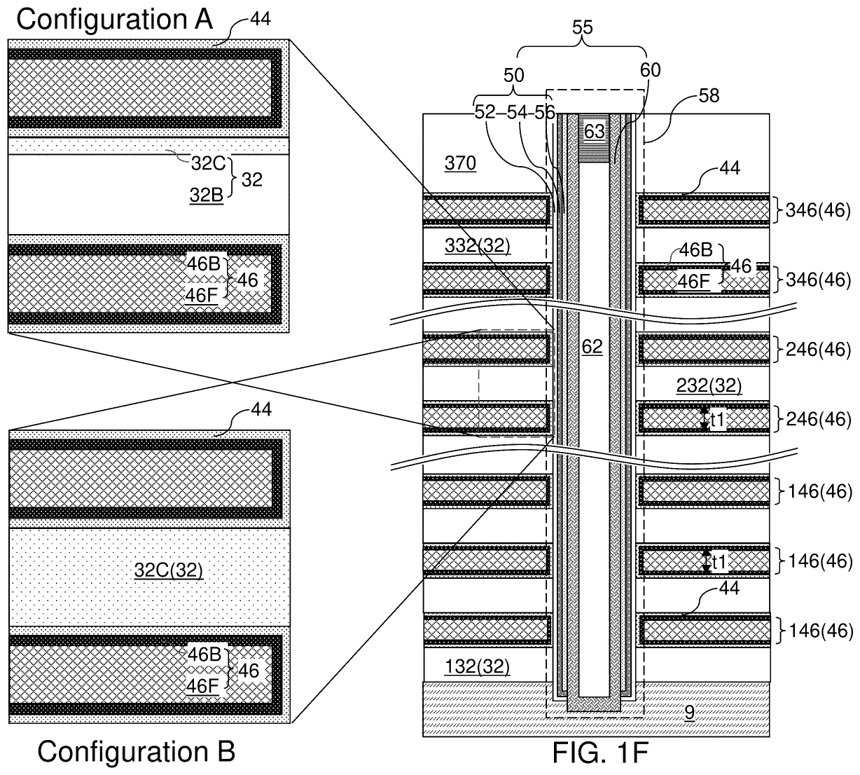

Referring to FIGS. 1A-1F, an exemplary semiconductor die 1000 according to an embodiment of the present disclosure is illustrated. The exemplary semiconductor die 1000 comprises a substrate 9, which may be a semiconductor substrate and/or a carrier substrate. For example, the substrate 9 may comprise a commercially available silicon wafer. If the substrate 9 comprises a carrier substrate, the substrate 9 may comprise any material that may be removed selectively to the materials of overlying materials which are subsequently formed. The exemplary semiconductor die 1000 is illustrated after a set of processing steps that forms various contact via structures (86, 88), which include layer contact via structures 86 and drain contact via structures 88. The exemplary semiconductor die 1000 illustrates an exemplary layout and configuration of the various device structures of the present disclosure that are subsequently described. However, the layout and the configuration of the exemplary semiconductor die 1000 in FIGS. 1A-1E are only illustrative, and do not limit the general layout and/or configurations of embodiments of the present disclosure.

The exemplary semiconductor die 1000 includes multiple three-dimensional memory array regions and multiple inter-array regions. The exemplary semiconductor die 1000 can include multiple planes 300 (e.g., 300A, 300B), each of which includes two memory array regions 100, such as a first memory array region 100A and a second memory array region 100B that are laterally spaced apart by a respective inter-array region 200. Generally, a semiconductor die 1000 may include a single plane 300 or multiple planes. The total number of planes in the semiconductor die 1000 may be selected based on performance requirements on the semiconductor die 1000. A pair of memory array regions 100 in a plane 300 may be laterally spaced apart along a first horizontal direction hd1 (which may be the word line direction). A second horizontal direction hd2 (which may be the bit line direction) can be perpendicular to the first horizontal direction hd1.

The size of the first memory array region 100A may be the same as, or may differ from, the size of the second memory array region 100B within a given plane. In one embodiment, each of the first memory array region 100A and the second memory array region 100B may have a respective rectangular area having a same width along the second horizontal direction hd2. In one embodiment, the inter-array region 200 within each plane 300 can be located off-center of the respective plane 300 along the first horizontal direction hd1 (i.e., the inter-array region 200 is located closer to one end than to another end of the respective plane 300). For example, the inter-array region 200 in the left plane 300A may be shifted toward the left edge of the die 1000, while the inter-array region 200 in the right plane 300B may be shifted toward the right edge of the die 1000. Alternatively, the inter-array region 200 within each plane 300 can be centered in the respective plane 300 along the first horizontal direction hd1 (i.e., the inter-array region 200 is located the same distance from both ends of the respective plane 300).

Each memory array region 100 includes first-tier alternating stacks of first-tier insulating layers 132 and first-tier electrically conductive layers 146 (which function as first word lines), optional second-tier alternating stacks of second-tier insulating layers 232 and second-tier electrically conductive layers 246 (which function as second word lines), and optional third-tier alternating stacks of third-tier insulating layers 332 and third-tier electrically conductive layers 346 (which function as third word lines). Each second-tier alternating stack (232, 246) overlies a respective first-tier alternating stack (132, 146), and each third-tier alternating stack (332, 346), if present, overlies a respective second-tier alternating stack (232, 246). Each combination of a first-tier alternating stack (132, 146), an overlying second-tier alternating stack (232, 246), and an optional overlying third-tier alternating stack (332, 346) may be laterally spaced apart from neighboring combinations of a respective first-tier alternating stack (132, 146), an overlying respective second-tier alternating stack (232, 246), and an overlying optional third-tier alternating stack (332, 346) by lateral isolation trench fill structures 76 that laterally extend along the first horizontal direction hd1 (which may be a word line direction). The first-tier insulating layers 132, the second-tier insulating layers 232, and the third-tier insulating layers 332 are collectively referred to as insulating layers 32. The first-tier electrically conductive layers 146, the second-tier electrically conductive layers 246, and the third-tier electrically conductive layers 346 are collectively referred to as electrically conductive layers 46.

As used herein, a “first-tier level” refers to the tier level that is most proximal to a substrate, a “second-tier level” refers to the tier level that is most proximal to the substrate among tier levels that overlie the first-tier level, and a “third-tier level” refers to the tier level that is most proximal to the substrate among tier levels that overlie the second-tier level, etc. A “first-tier” element refers to an element that is located within the first-tier level; a “second-tier” element refers to an element that is located within the second-tier level; a “third-tier” element refers to an element that is located within the second-tier level; etc. Individual tier levels within a structure including multiple tier levels may be labeled as a first tier level, a second tier level, a third tier level, etc. In this case, the first tier level may be any of the multiple tier levels, the second tier level may be a tier level that is different from the first tier level, etc.

A first-tier alternating stack of first-tier insulating layers 132 and first-tier electrically conductive layers 146 is located over the substrate 9 between each neighboring pair of lateral isolation trench fill structures 76. A first-tier retro-stepped dielectric material portion 165 overlies and contacts first stepped surfaces of the first-tier alternating stack (132, 146). A second-tier alternating stack of second-tier insulating layers 232 and second-tier electrically conductive layers 246 overlies the first-tier alternating stack (132, 146), and overlies a horizontal plane including a planar top surface of the first-tier retro-stepped dielectric material portion 165 between each neighboring pair of lateral isolation trench fill structures 76. A second-tier retro-stepped dielectric material portion 265 overlies and contacts second stepped surfaces of the second-tier alternating stack (232, 246). A third-tier alternating stack of third-tier insulating layers 332 and third-tier electrically conductive layers 346, if present, overlies the second-tier alternating stack (232, 246), and overlies a horizontal plane including a planar top surface of the second-tier retro-stepped dielectric material portion 265 between each neighboring pair of lateral isolation trench fill structures 76. A third-tier retro-stepped dielectric material portion 365 overlies and contacts third stepped surfaces of the third-tier alternating stack (332, 346), if present. Vertical steps S of the first stepped surfaces and the second stepped surfaces laterally extend along the second horizontal direction hd2 (which may be a bit line direction). The first-tier retro-stepped dielectric material portion 165, the second-tier retro-stepped dielectric material portion 265, and the third-tier retro-stepped dielectric material portion 365 are collectively referred to as retro-stepped dielectric material portions 65.

In a first embodiment, each of the insulating layers 32 comprises a respective carbon-doped silicate glass layer 32C, as illustrated in FIG. 1F. In a first configuration employed for a first exemplary structure, which is also referred to as “Configuration A,” each of the insulating layers 32 comprises a layer stack including, from bottom to top, a respective base silicate glass layer (i.e., a silicon oxide layer) 32B and a respective carbon-doped silicate glass layer 32C. In a second configuration employed for a second exemplary structure, which is also referred to as “Configuration B,” each of the insulating layers 32 consists of a respective carbon-doped silicate glass layer 32C.

The atomic percentage of carbon atoms in each of the carbon-doped silicate glass layer 32C may be in a range from 0.5% to 15%, such as from 1% to 10%, including from 1% to 2.5%. Generally, a carbon-doped silicate glass can be deposited by a chemical vapor deposition process employing a precursor gas for depositing a silicate glass (such as tetraethyl orthosilicate (TEOS)) and a carbon-containing dopant gas (such as methane, ethane, ethylene, acetylene, propane, propylene, etc.).

If each insulating layer 32 comprises a respective layer stack including, from bottom to top, a respective base silicate glass layer 32B and a respective carbon-doped silicate glass layer 32C, the ratio of the thickness of a carbon-doped silicate glass layer 32C to the thickness of each insulating layer 32 may be in a range from 5% to 90%, such as from 10% to 50%, and/or from 15% to 30%, although lesser and greater thicknesses may also be employed. Each base silicate glass layer 32B may be free of carbon atoms, or may include carbon atoms at an average atomic concentration that is less than 10% of an average atomic concentration of carbon atoms within each carbon-doped silicate glass layer 32C. In one embodiment, the atomic percentage of carbon atoms in the base silicate glass layers 32B may be less than 0.4%, such as less than 0.25%, for example such as 0 to 0.15%.

In the first configuration, each carbon-doped silicate glass layer 32C contacts a top surface of a respective base silicate glass layer 32B, and contacts a bottom surface of a respective overlying sacrificial material layer 42. In the second configuration, each carbon-doped silicate glass layer 32C other than the bottommost carbon-doped silicate glass layer 32C may contact a top surface of a respective underlying sacrificial material layer 42, and may contact a bottom surface of a respective overlying sacrificial material layer 42. The presence of carbon in the carbon-doped silicate glass layers 32C enhances the etch resistance of the carbon-doped silicate glass layers 32C relative to the etch rate of the base silicate glass layer 32B in a subsequent isotropic etch process. For example, the isotropic etch process to be subsequently performed may comprise a wet etch process employing dilute hydrofluoric acid, and the carbon-doped silicate glass material in the carbon-doped silicate glass layers 32C has a lower etch rate in dilute hydrofluoric acid (such as 100:1 dilute hydrofluoric acid) than the silicate glass material in the base silicate glass layers 32B.

The silicate glass material in the base silicate glass layers 32B and the carbon-doped silicate glass material in the carbon-doped silicate glass layers 32C may optionally be doped with non-carbon dopants. Non-carbon dopants that may be present within the base silicate glass layers 32B and the carbon-doped silicate glass layers 32C may include fluorine, boron, phosphorus, arsenic, etc. In an illustrative example, a carbon-doped silicate glass material including carbon atoms at an atomic percentage of 1% and not including any other dopant may have an etch rate in 100:1 dilute hydrofluoric acid that is between 50 and 60% of the etch rate of an undoped silicate glass material (e.g., silicon dioxide).

Memory opening fill structures 58 can be located within each memory array region 100 (which includes a first memory array region 100A and a second memory array region 100B) between each neighboring pair of lateral isolation trench fill structures 76. The memory opening fill structures 58 can be located within memory openings that vertically extend through each layer within the first-tier alternating stack (132, 146), the second-tier alternating stack (232, 246), and the optional third-tier alternating stack (332, 346), if present, that are located between a respective neighboring pair of lateral isolation trench fill structures 76.

In one embodiment, each of the memory opening fill structures 58 comprises a vertical stack of memory elements (e.g., portions of a memory film or vertically separated, discrete memory elements) located at levels of the electrically conductive layers 46 and a vertical semiconductor channel 60 that is electrically connected to a respective overlying metal interconnect structure (such as a bit line). In one embodiment, the inter-array region 200 is free of any memory stack structure that is electrically contacted by any metal interconnect structure (such as a bit line).

Each memory opening fill structure 58 includes a respective memory stack structure, which includes a respective memory film and a respective vertical semiconductor channel. The memory openings and the memory opening fill structures 58 are formed in region in which each layer of a first-tier alternating stack and each layer of the second-tier alternating stack are present. For each area within which a continuous combination of a first-tier alternating stack (132, 146), a second-tier alternating stack (232, 246), and an optional third-tier alternating stack (332, 346) continuously laterally extends, first memory stack structures can be located within a respective first memory array region 100A and second memory stack structures can be located within a respective second memory array region 100B. The second memory array region 100B can be connected to the first memory array region 100A through a respective inter-array region 200, in which a first-tier retro-stepped dielectric material portion 165, a second-tier retro-stepped dielectric material portion 265, and an optional third-tier retro-stepped dielectric material portion 365 are located.

A first-tier retro-stepped dielectric material portion 165 can be located between each neighboring pair of lateral isolation trench fill structures 76. Each first-tier retro-stepped dielectric material portion 165 overlies first stepped surfaces of a respective first-tier alternating stack (132, 146). Each first-tier retro-stepped dielectric material portion 165 can have a sidewall that laterally extends along the first horizontal direction hd1 and contacts a respective lateral isolation trench fill structure 76. The first stepped surfaces comprise vertical steps of the first-tier alternating stack (132, 146) that are laterally spaced apart along the first horizontal direction hd1 and vertically offset from each other.

A second-tier retro-stepped dielectric material portion 265 can be located between each neighboring pair of lateral isolation trench fill structures 76. Each second-tier retro-stepped dielectric material portion 265 overlies second stepped surfaces of a respective second-tier alternating stack (232, 246). Each second-tier retro-stepped dielectric material portion 265 can have a sidewall that laterally extends along the second horizontal direction hd1 and contacts a respective lateral isolation trench fill structure 76. The second stepped surfaces comprise vertical steps of the second-tier alternating stack (232, 246) that are laterally spaced apart along the first horizontal direction hd1 and vertically offset from each other. In one embodiment, each second-tier retro-stepped dielectric material portion 265 overlies and contacts a respective one of the first-tier retro-stepped dielectric material portions 165.

A third-tier retro-stepped dielectric material portion 365 can be located between each neighboring pair of lateral isolation trench fill structures 76. Each third-tier retro-stepped dielectric material portion 365 overlies third stepped surfaces of a respective third-tier alternating stack (332, 346). Each third-tier retro-stepped dielectric material portion 365 can have a sidewall that laterally extends along the second horizontal direction hd2 and contacts a respective lateral isolation trench fill structure 76. The third stepped surfaces comprise vertical steps of the third-tier alternating stack (332, 346) that are laterally spaced apart along the second horizontal direction hd2 and vertically offset from each other. In one embodiment, each third-tier retro-stepped dielectric material portion 365 overlies and contacts a respective one of the second-tier retro-stepped dielectric material portions 265.

Lateral isolation trenches can laterally extend along the first horizontal direction hd1. Each lateral isolation trench can be filled with a lateral isolation trench fill structure 76, which may include a combination of a backside contact via structure and an insulating spacer that laterally surround the backside contact via structure. Alternatively, each lateral isolation trench fill structure 76 may consist of an insulating fill structure. Each vertical stack of a first-tier alternating stack (132, 146), a second-tier alternating stack (232, 246), and an optional third-tier alternating stack (332, 346) can be located between a neighboring pair of lateral isolation trench fill structure 76.

For each vertical stack of a first-tier alternating stack (132, 146), a second-tier alternating stack (232, 246), and an optional third-tier alternating stack (332, 346), a respective first lateral isolation trench fill structure 761 laterally extends along the first horizontal direction hd1 (e.g., word line direction), and may contact a part of the first lengthwise sidewalls of the first-tier alternating stack (132, 146), a part of the first lengthwise sidewalls of the second-tier alternating stack (232, 246), and a part of the first lengthwise sidewalls of the third-tier alternating stack (332, 346), if present. For each vertical stack of a first-tier alternating stack (132, 146), a second-tier alternating stack (232, 246), and an optional third-tier alternating stack (332, 346), a respective second lateral isolation trench fill structure 762 laterally extends along the first horizontal direction hd1, and may contact the entirety of the second lengthwise sidewalls of the first-tier alternating stack (132, 146), the entirety of the second lengthwise sidewalls of the second-tier alternating stack (232, 246), and the entirety of the second lengthwise sidewalls of the third-tier alternating stack (332, 346), if present, as illustrated in FIG. 1E. The first lateral isolation trench fill structure 761 and the second lateral isolation trench fill structure 762 are neighboring pairs of lateral isolation trench fill structures 76. Generally, at least one of the first lateral isolation trench fill structure 761 and the second lateral isolation trench fill structure 762 is in direct contact with each layer within the first-tier alternating stack (132, 146); at least one of the first lateral isolation trench fill structure 761 and the second lateral isolation trench fill structure 762 is in direct contact with each layer within the second-tier alternating stack (232, 246); and at least one of the first lateral isolation trench fill structure 761 and the second lateral isolation trench fill structure 762 is in direct contact with each layer within the third-tier alternating stack (332, 346) in case the third-tier alternating stack (332, 346) is present.

While FIGS. 1A-1E illustrate a configuration in which a first lateral isolation trench fill structure 761 is not in direct contact with the entirety of the first lengthwise sidewalls of the first-tier alternating stack (132, 146), the first lengthwise sidewalls of the second-tier alternating stack (232, 246), or the first lengthwise sidewalls of the third-tier alternating stack (332, 346), and a second lateral isolation trench fill structure 762 is in direct contact with each layer within the first-tier alternating stack (132, 146), with each layer within the second-tier alternating stack (232, 246), and with each layer within the third-tier alternating stack (332, 346), embodiments are expressly contemplated herein in which different combinations in which the first lateral isolation trench fill structure 761 and the second lateral isolation trench fill structure 762 contact or do not contact each of the first-tier alternating stack (132, 146), the second-tier alternating stack (232, 246), and the third-tier alternating stack (332, 346).

Generally, at least the first-tier alternating stack (132, 146) can be formed, and the second-tier alternating stack (232, 246) and/or the third-tier alternating stack (332, 346) may be formed above the first-tier alternating stack (132, 146). The set of all alternating stack(s) in the first exemplary structure may be referred to as at least one alternating stack (32, 46). In one embodiment, each of the electrically conductive layers 46 except the topmost electrically conductive layer 46 may have a first thickness in each area that underlies any other electrically conductive layer 46, and may be locally thickened in each area that does not underlie any other electrically conductive layer 46 to provide a respective locally thickened region having a second thickness. The topmost electrically conductive layer 46 may have the second thickness only within the areas of the stepped surfaces in a top-down view.

A contact-level dielectric layer 80 can be formed over the at least one alternating stack (32, 46). In one embodiment, layer contact via structures 86 vertically extend through a respective subset of the at least one retro-stepped dielectric material portion 65 (which may be a plurality of retro-stepped dielectric material portions 65), through a thickened portion of a respective electrically conductive layer 46, and through underlying electrically conductive layers 46. Each such layer contact via structure 86 can contact a cylindrical sidewall of the thickened portion of the respective electrically conductive layer 46, and can be electrically isolated from the underlying electrically conductive layers by at least one annular dielectric spacer 26. The thickened portions of the electrically conductive layers 46 can be formed by locally thickening sacrificial material layers, and by replacing the sacrificial material layers, during which the electrically conductive layers are formed with local thickening at locations at which the sacrificial material layers are previously thickened. Formation of the annular dielectric spacers 26 and formation of the layer contact via structures 86 in a manner that provides direct contact with cylindrical sidewalls of openings through the electrically conductive layers 46 are described in detail in subsequent sections of the present disclosure.

The inter-array region 200 includes strips of the first-tier insulating layers 132, the first-tier electrically conductive layers 146, the second-tier insulating layers 232, the second-tier electrically conductive layers 246, the third-tier insulating layers 332, and the third-tier electrically conductive layers 346 located between each laterally neighboring pair of lateral isolation trench fill structures 76. Such strips are located in a respective strip-shaped connection regions 240 (i.e., bridge regions) of the inter-array regions 200, which are located adjacent to a respective first-tier retro-stepped dielectric material portion 165, a respective second-tier retro-stepped dielectric material portion 265, or a respective third-tier retro-stepped dielectric material portions 365. The strips have a narrower width along the second horizontal direction hd2 than portions of the alternating stacks (132, 146, 232, 246, 332, 346) located in the memory array regions 100, and portions of the strips located in the remaining portions of the inter-array regions 200 outside of the respective strip-shaped connection regions 240.

For each vertical stack of a first-tier alternating stack (132, 146), a second-tier alternating stack (232, 246), and an optional third-tier alternating stack (332, 346), first memory opening fill structures 58 can be located within a first memory array region 100A in which each layer of the first-tier alternating stack (132, 1446), the second-tier alternating stack (232, 246), and the optional third-tier alternating stack (332, 346) is present. Further, second memory opening fill structures 58 can be located within a second memory array region 100B that is laterally offset along the first horizontal direction hd1 from the first memory array region 100A by the first-tier retro-stepped dielectric material portion 165, the second-tier retro-stepped dielectric material portion 265, and the optional third-tier retro-stepped dielectric material portion 365. Each layer of the first-tier alternating stack (132, 146), the second-tier alternating stack (232, 246), and the optional third-tier alternating stack (332, 346) is present within the second memory array region 100B. Each of the electrically conductive layers 46 within the vertical stack may continuously extend from the first memory array region 100A to the second memory array region 100B through a strip-shaped connection region 240 (which is also referred to as a bridge region). Each strip-shaped connection region 240 is located within an inter-array region 200, and may be located between the lateral isolation trench fill structure 76 and the first-tier retro-stepped dielectric material portion 165 at the level of the first-tier alternating stack (132, 146), or between a lateral isolation trench fill structures 76 and the second-tier retro-stepped dielectric material portion 265 at the level of the second-tier alternating stack (232, 246), or between a lateral isolation trench fill structures 76 and the third-tier retro-stepped dielectric material portion 365 at the level of the third-tier alternating stack (332, 346).

Staircases including first stepped surfaces of a first-tier alternating stack (132, 146), optionally second stepped surfaces of a second-tier alternating stack (232, 246), and optionally third stepped surfaces of a third-tier alternating stack (332, 346) can ascend (i.e., rise) from the substrate along the first horizontal direction hd1, or along the opposite direction of the first horizontal direction hd1. Each region including the staircases is herein referred to as a staircase region. In one embodiment, the direction of rise of the staircases can change for every other pair of vertical stacks of a respective first-tier alternating stack (132, 146), a respective second-tier alternating stack (232, 246), and a respective third-tier alternating stack (332, 346). In other words, the direction of rise is staggered in adjacent alternating stacks that are separated along the second horizontal direction

In some cases, laterally-isolated vertical interconnection structures (484, 486) can be formed through the inter-array region 200. Each laterally-isolated vertical interconnection structure (484, 486) can include a through-memory-level conductive via structure 486 and a tubular insulating spacer 484 that laterally surrounds the conductive via structure 486. The laterally-isolated vertical interconnection structures (484, 486) vertically extend through the strip portions of the first-tier alternating stack (132, 146), the second-tier alternating stack (232, 246), and the third-tier alternating stack (332, 346), and can contact the substrate 9.

Drain contact via structures 88 can contact an upper portion of a respective memory opening fill structure 58 (such as a drain region within the respective memory opening fill structure 58). Bit lines (not illustrated) can laterally extend along the second horizontal direction hd2, and can contact top surfaces of a respective subset of the drain contact via structures. Additional metal interconnect structures embedded in overlying dielectric material layers (not shown) may be employed to provide electrical connection among the various nodes of the three-dimensional memory device located in the semiconductor die 1000.

Each lateral isolation trench fill structure 76 includes an insulating material portion. In one embodiment, each insulating material portion may comprise an insulating spacer that laterally surrounds a layer contact via structure such as a backside contact via structure (not expressly shown). In another embodiment, each insulating material portion may comprise a dielectric wall structure which takes up the entire volume of the respective lateral isolation trench fill structure 76. In one embodiment, each sidewall of the first alternating stacks (132, 146) can be contacted by a sidewall of an insulating material portion of a respective one of the lateral isolation trench fill structures 76.

In one embodiment, each plane 300 within the exemplary semiconductor die 1000 includes a three-dimensional memory device, which includes alternating stacks of insulating layers 32 and electrically conductive layers 46. Each of the alternating stacks {(132, 146), (232, 246), (332, 346)} laterally extends along a first horizontal direction hd1 through a first memory array region 100A and a second memory array region 100B that are laterally spaced apart by an inter-array region 200. Each of the alternating stacks {(132, 146), (232, 246), (332, 346)} includes a set of stepped surfaces (i.e., a staircase) in the inter-array region 200. Each plane 300 within the exemplary semiconductor die 1000 includes retro-stepped dielectric material portions (165, 265, 365) overlying a respective set of stepped surfaces of the alternating stacks {(132, 146), (232, 246), (332, 346)}. Each plane 300 within the exemplary semiconductor die 1000 includes clusters of memory stack structures located within memory opening fill structures 58. Each of the memory stack structures vertically extends through a respective one of the alternating stacks {(132, 146), (232, 246), (332, 346)} and is located within the first memory array region 100A or the second memory array region 100B. Each memory stack structure can include a respective vertical semiconductor channel and a vertical stack of memory elements (e.g., a memory film) located at levels of the electrically conductive layers 46.

Each of the retro-stepped dielectric material portions 65 comprises a respective stepped bottom surface. Each region of the alternating stacks (32, 46) that underlies a respective retro-stepped dielectric material portion 65 constitutes a staircase region. A strip-shaped connection region 240 including each layer within an alternating stack (32, 46) is provided adjacent to each staircase region, and is herein referred to as a bridge region. Each strip-shaped connection region 240 laterally extends along the first horizontal direction hd1, and provides electrically conductive paths between a respective portion located in the first memory array region 100A and a respective portion located in the second memory array region 100B for each electrically conductive layer 46. The strip region has a lesser width (i.e., narrower width along the second horizontal direction hd2) than the portions of the electrically conductive layer 46 located in the first memory array region 100A or in the second memory array region 100B. The portions of the electrically conductive layer 46 located in the first memory array region 100A or in the second memory array region 100B have a width along the second horizontal direction hd2 that is the same as a lateral distance between a neighboring pair of lateral isolation trench fill structures 76.

In contrast, each strip portion of the electrically conductive layer 46 in the strip-shaped connection region 240 has a width along the second horizontal direction hd2 that is the same as the difference between the lateral distance between a neighboring pair of lateral isolation trench fill structures 76 and the width of an adjoining retro-stepped dielectric material portion (165 or 265) along the second horizontal direction hd2. Each electrical connection between a layer contact via structure 86 and a most proximal portion of the second memory array region 100B includes a narrow strip portion of an electrically conductive layer 46 in the strip-shaped connection region 240, while electrical connection between the layer contact via structure 86 and a most proximal portion of the first memory array region 100A does not include any narrow strip portion of the electrically conductive layer 46 because the first memory array region 100A is not separated from the layer contact via structures 86 by the strip-shaped connection region 240.

In one embodiment, the alternating stacks {(132, 146), (232, 246), (332, 346)} are laterally spaced apart along the second horizontal direction hd2 by line trenches (such as lateral isolation trenches) that laterally extend along the first horizontal direction hd1. The line trenches are filled with lateral isolation trench fill structures 76 having dielectric surfaces (such as surfaces of insulating spacers or dielectric wall structures) that contact sidewalls of the alternating stacks {(132, 146), (232, 246), (332, 346)}. In one embodiment, upon sequentially numbering the lateral isolation trench fill structures 76 with positive integers along the second horizontal direction hd2, odd-numbered lateral isolation trench fill structures 76 may contact a respective pair of retro-stepped dielectric material portions (165, 265, 365) (which are located on either side of a respective odd-numbered lateral isolation trench fill structure 76), and even-numbered lateral isolation trench fill structures 76 do not contact any retro-stepped dielectric material portion (165, 265, 365), or alternatively, even-numbered lateral isolation trench fill structures 76 may contact a respective pair of retro-stepped dielectric material portions (165, 265, 365) and odd-numbered lateral isolation trench fill structures 76 do not contact any retro-stepped dielectric material portion (165, 265, 365).

In one embodiment, strip widths of the first-tier electrically conductive layers 146 decrease with a respective vertical distance from the substrate 9. Strip widths of the second-tier electrically conductive layers 246 decrease with a respective vertical distance from the substrate 9. Strip widths of the third-tier electrically conductive layers 346 decrease with a respective vertical distance from the substrate 9. A bottommost second electrically conductive layer 246 within the second-tier alternating stack (232, 246) has a greater strip width than a topmost first electrically conductive layer 146 within the first-tier alternating stack (132, 146). A bottommost third electrically conductive layer 346 within the third-tier alternating stack (332, 346) has a greater strip width than a topmost second electrically conductive layer 246 within the second-tier alternating stack (232, 246).

According to an aspect of the present disclosure shown in FIG. 1E, a set of a first-tier retro-stepped dielectric material portion 165, a second-tier retro-stepped dielectric material portion 265, and a third-tier retro-stepped dielectric material portion 365 can be formed between a neighboring pair of lateral isolation trench fill structures 76, which are herein referred to as a first lateral isolation trench fill structure 761 and a second lateral isolation trench fill structure 762. The width of each strip of an electrically conductive layer 46 along the second horizontal direction in the strip-shaped connection region 240 is herein referred to as a strip width or a bridge width. While the illustrated configuration of the first exemplary structure illustrated in FIGS. 1A-1E includes three tier levels, embodiments are expressly contemplated herein in which one tier level, two tier levels, or four or more tier levels are used in an alternative configuration.

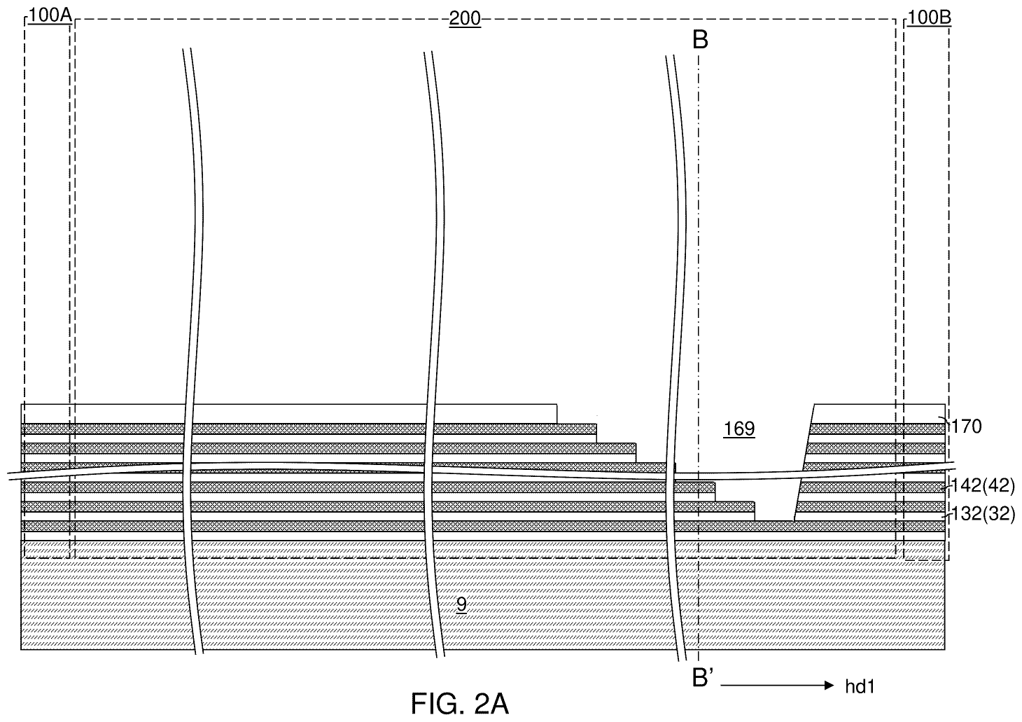

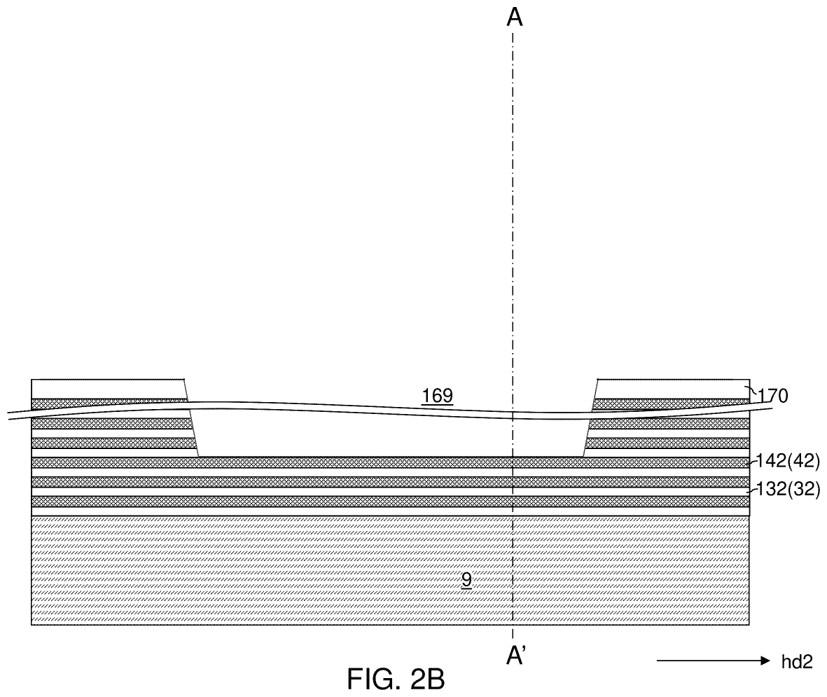

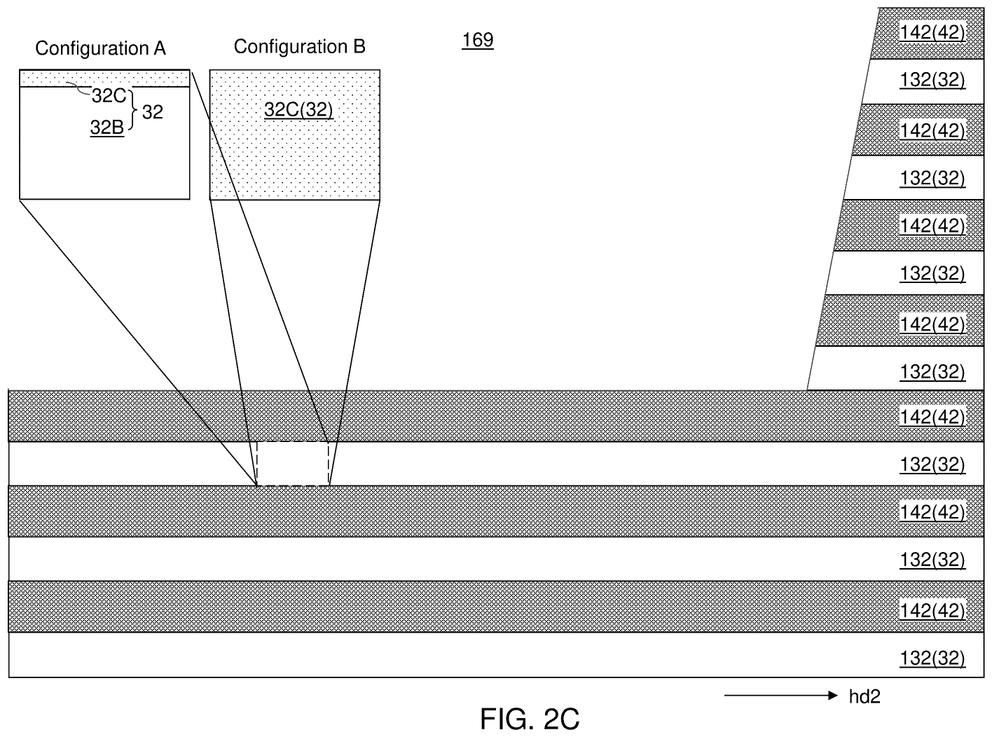

Referring to FIGS. 2A-2C, a first exemplary structure according to an embodiment of the present disclosure is illustrated, which can be employed to form a semiconductor die such as the semiconductor die 1000 illustrated in FIGS. 1A-1E.

A first vertically alternating sequence of first-tier insulating layers 132 and first-tier sacrificial material layers 142 can be formed over a substrate 9. As used herein, a vertically alternating sequence refers to a sequence of multiple instances of a first element and multiple instances of a second element that is arranged such that an instance of a second element is located between each vertically neighboring pair of instances of the first element, and an instance of a first element is located between each vertically neighboring pair of instances of the second element.

The first-tier insulating layers 132 can be composed of the first material, and the first-tier sacrificial material layers 142 can be composed of the second material, which is different from the first material. Each of the first-tier insulating layers 132 is an insulating layer that continuously extends over the entire area of the substrate 8, and may have a uniform thickness throughout. Each of the first-tier sacrificial material layers 142 includes a sacrificial material (which may comprise a dielectric material), and continuously extends over the entire area of the substrate 8, and may have a uniform thickness throughout. Insulating materials that may be used for the first-tier insulating layers 132 include, but are not limited to silicon oxide (including doped or undoped silicate glass), silicon nitride, silicon oxynitride, organosilicate glass (OSG), spin-on dielectric materials, dielectric metal oxides that are commonly known as high dielectric constant (high-k) dielectric oxides (e.g., aluminum oxide, hafnium oxide, etc.) and silicates thereof, dielectric metal oxynitrides and silicates thereof, and organic insulating materials. In one embodiment, the first material of the first-tier insulating layers 132 may be silicon oxide.

The second material of the first-tier sacrificial material layers 142 is a dielectric material, which is a sacrificial material that may be removed selectively to the first material of the first-tier insulating layers 132. As used herein, removal of a first material is “selective to” a second material if the removal process removes the first material at a removal rate that is at least twice the removal rate for the second material. The ratio of the rate of removal of the first material to the rate of removal of the second material is herein referred to as a “selectivity” of the removal process for the first material with respect to the second material.

The thickness of each first-tier insulating layer 132 may be in a range from 12 nm to 50 nm, such as from 15 nm to 30 nm, although lesser and greater thicknesses may also be employed. The thickness of each first-tier sacrificial material layer 142 may be in a range from 15 nm to 50 nm, such as from 20 nm to 30 nm, although lesser and greater thicknesses may also be employed. The second material of the first-tier sacrificial material layers 142 may be subsequently replaced with electrically conductive electrodes which may function, for example, as control gate electrodes of a vertical NAND device. In one embodiment, the first-tier sacrificial material layers 142 may comprise silicon nitride.

Generally, a vertically alternating sequence of unit layer stacks over a substrate. Each of the unit layer stacks comprises a first insulating layer (such as a first insulating layer 132) and a first spacer material layer (such as a first-tier sacrificial material layer 142). Generally, the first spacer material layers are formed as, or are subsequently replaced with, first-tier electrically conductive layers. While the present disclosure is described employing an embodiment in which the first spacer material layers are formed as first-tier sacrificial material layers 142 that are subsequently replaced with first-tier electrically conductive layers, embodiments are expressly contemplated herein in which the first spacer material layers are formed as first-tier electrically conductive layers. In such embodiments, steps for replacing the material of the first spacer material layers with an electrically conductive material can be omitted.

In the first configuration of the first exemplary structure, each insulating layer 32 may include a vertical stack including, from bottom to top, a respective base silicate glass layer 32B and a respective carbon-doped silicate glass layer 32C.

In the second configuration, each of the insulating layers 32 consists of a respective carbon-doped silicate glass layer 32C.

A first-tier insulating cap layer 170 can be formed over the first vertically alternating sequence (132, 142). The first-tier insulating cap layer 170 comprises an insulating material, which may be the same material as the material of the first-tier insulating layers 132. First stepped surfaces can be formed within the staircase regions of the inter-array region 200 by patterning the first-tier insulating cap layer 170 and the first vertically alternating sequence (132, 142). For example, a combination of a sacrificial hard mask layer and a trimming mask layer may be employed to form the first stepped surfaces. In one embodiment, a row of multiple first staircase regions can be formed within each area that corresponds to a combination of the area of a laterally-neighboring pair of first-tier retro-stepped dielectric material portions 165 and an intervening area. In this case, the multiple first staircase regions can be vertically offset by different depths by subsequently performing area recess etch processes.

In an illustrative example, 2^{M} sets of first stepped surfaces can be formed within a combination of the area of a laterally-neighboring pair of first-tier retro-stepped dielectric material portions 165 and an intervening area. M can be an integer in a range from 1 to 8. Each set of first stepped staircases may include P steps such that sidewalls of P first continuous spacer material layers are physically exposed with lateral offsets. P may be an integer from 2 to 64. M area recess etch processes can be performed such that each area recess etch process vertically recesses P times 21 sets of a first insulating layer 132 and a first-tier sacrificial material layer 142, in which i is a different integer from 0 to (M−1). A total of up to 2^{M}×P stepped surfaces can be formed for the first vertically alternating sequence of the first-tier insulating layers 132 and the first-tier sacrificial material layers 142. The total number of the stepped surfaces within each continuous cavity overlying the first stepped surfaces can be the same as the total number of the first-tier sacrificial material layers 142 in the first vertically alternating sequence (132, 142).

A first-tier stepped cavity 169 can be formed over each contiguous set of stepped surfaces of the first vertically alternating sequence (132, 142). The lateral extents of the first-tier sacrificial material layers 142 vary with a vertical distance from the substrate 9. Generally, an alternating stack (32, 42) of insulating layers 32 and sacrificial material layers 42 may be formed over a substrate 9, and stepped surfaces can be formed by patterning the alternating stack (32, 42) such that lateral extents of the sacrificial material layers 42 vary with a vertical distance from the substrate 9 in a staircase region.

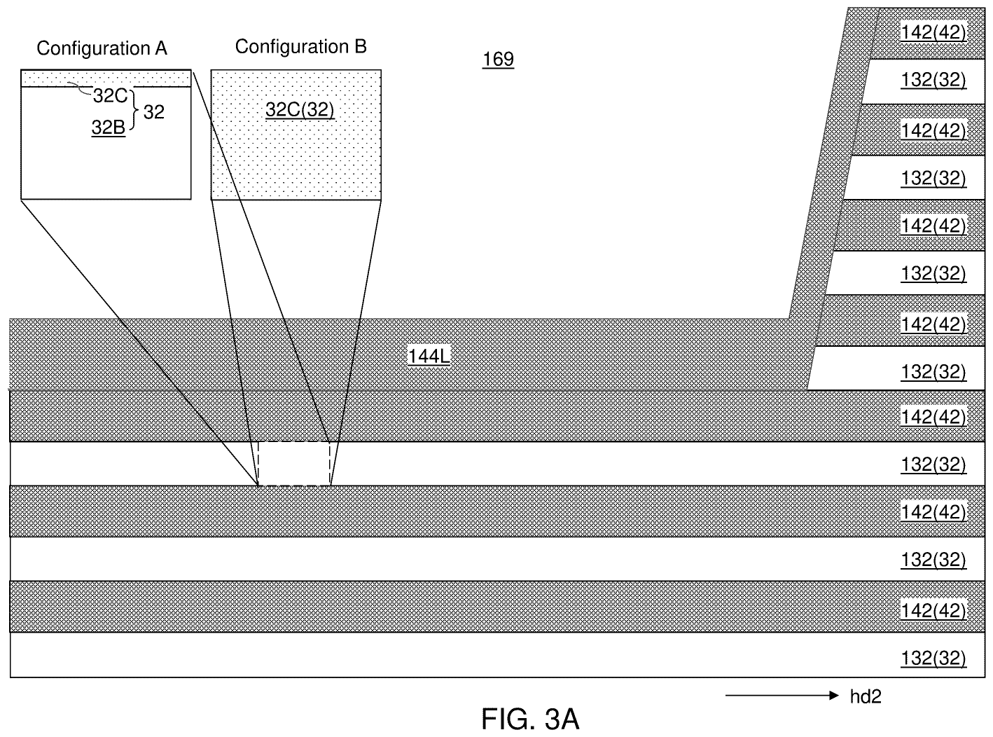

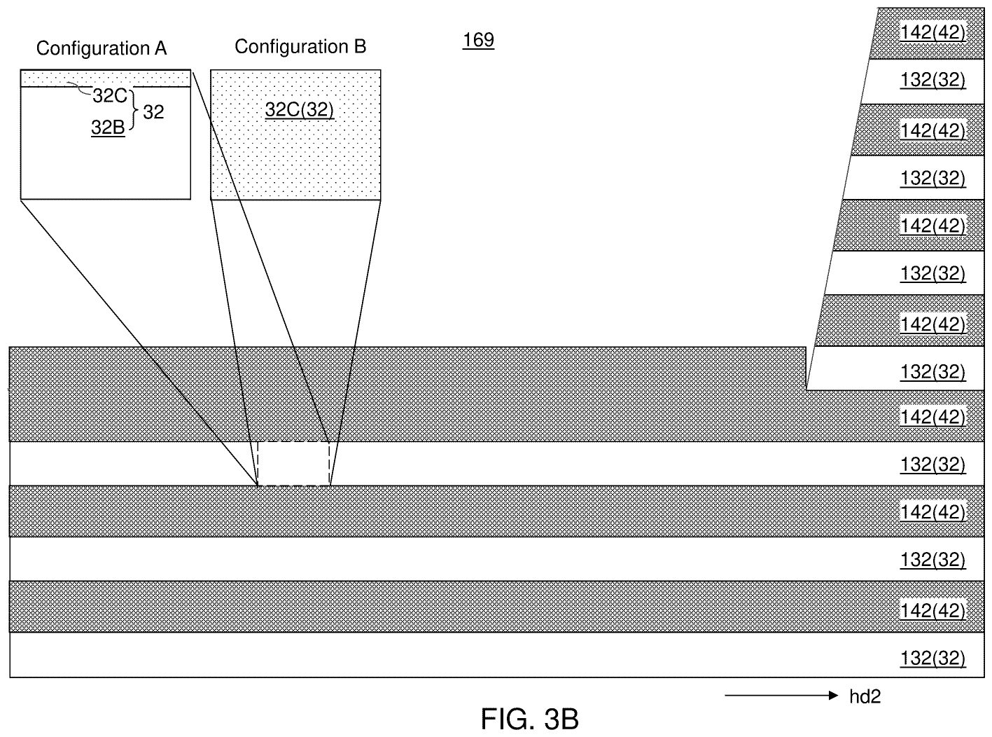

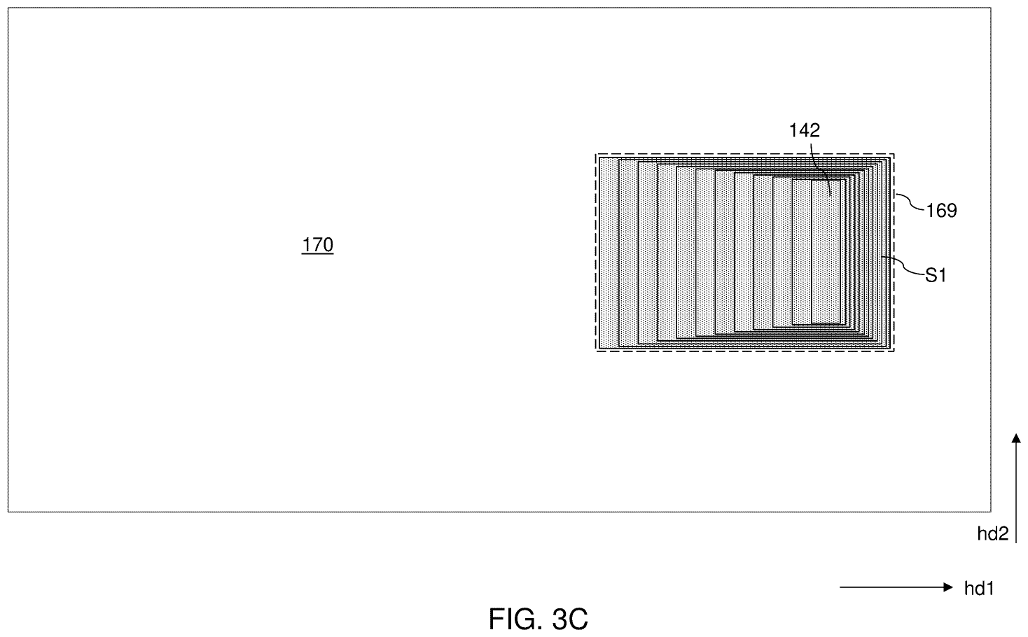

Referring to FIG. 3A, an anisotropic material deposition process can be performed to anisotropically deposit a same material as the material of the first-tier sacrificial material layers 142 to form a non-conformal sacrificial material layer 144L. In one embodiment, the first-tier sacrificial material layers 142 comprise silicon nitride, and the anisotropic material deposition process may deposit a silicon nitride material anisotropically. The non-conformal sacrificial material layer 144L is deposited by a non-conformal deposition process such as a plasma-enhanced chemical vapor deposition (PECVD) process. Preferably, the deposition of the sacrificial material of the non-conformal sacrificial material layer 144L is highly anisotropic such that the thickness of each horizontally-extending portion of the non-conformal sacrificial material layer 144L is greater than (e.g., at least twice) the thickness of non-horizontally-extending portions of the non-conformal sacrificial material layer 144L. In one embodiment the thickness of the horizontally-extending portions of the non-conformal sacrificial material layer 144L may be in a range from 50% to 300% of the thickness of each first-tier sacrificial material layer 142.

Referring to FIG. 3B, an isotropic etch process can be performed to isotropically recess the non-conformal sacrificial material layer 144L. The duration of the isotropic etch process can be selected such that the non-horizontally-extending portions of the non-conformal sacrificial material layer 144L are removed by the isotropic etch process. Remaining horizontally-extending portions of the non-conformal sacrificial material layer 144L overlying a top surface segment of a respective one of the first-tier sacrificial material layers 142 can be incorporated into the respective one of the first-tier sacrificial material layers 142.

Thus, physically-exposed portions of the sacrificial material layers 42 (such as the first-tier sacrificial material layers 142) in the staircase region can be thickened such that the thickened portions of the sacrificial material layers 142 has a thickness in a range from 125% to 250%, such as from 150% to 200%, of the unthickened portion of the first-tier sacrificial material layers 142 (which is the same as the original thickness of each first-tier sacrificial material layers 142). While an embodiment is described in which physically exposed portions of the first-tier sacrificial material layers 142 are locally thickened by anisotropic deposition and isotropic etch-back of a sacrificial material, the physically exposed portions of the first-tier sacrificial material layers 142 may be locally thickened by alternative methods that can selectively increase the thickness of physically exposed portions of the first-tier sacrificial material layers 142.

Referring to FIG. 3C, portions of the non-conformal sacrificial material layer 144L that are deposited outside the areas of the first-tier stepped cavities 169 can be removed, for example, by covering the areas of the first-tier stepped cavities 169 with patterned photoresist materials, and by performing an etch process that etches unmasked portions of the material of the non-conformal sacrificial material layer 144L. First vertical steps S1 of the first stepped surfaces that are perpendicular to the first horizontal direction hd1 are illustrated.

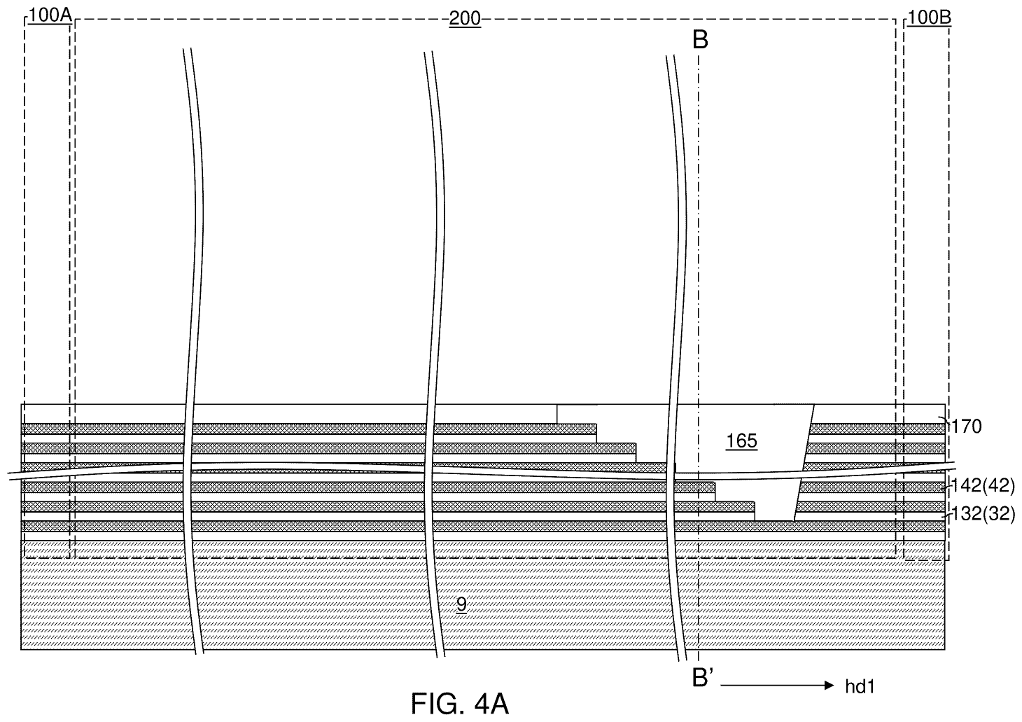

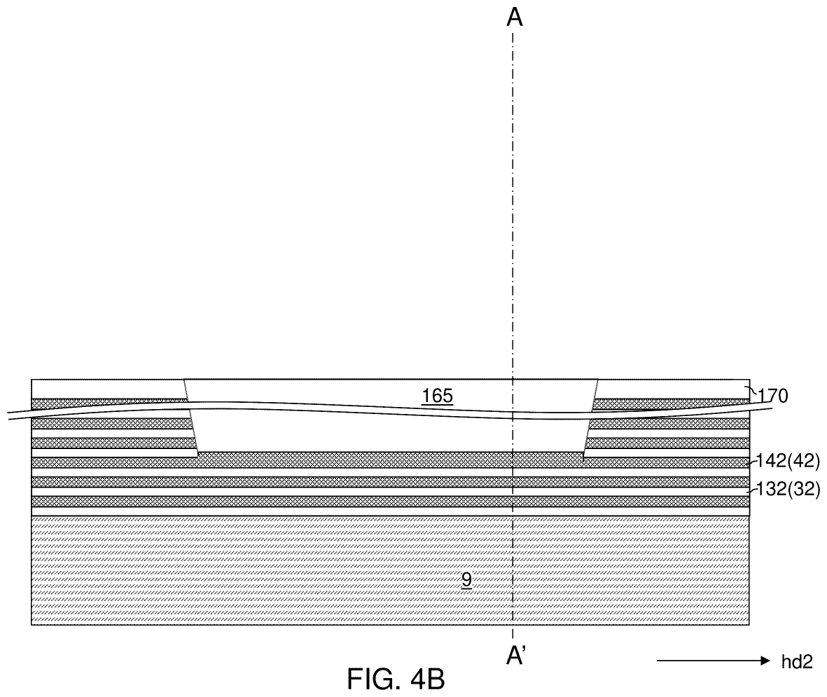

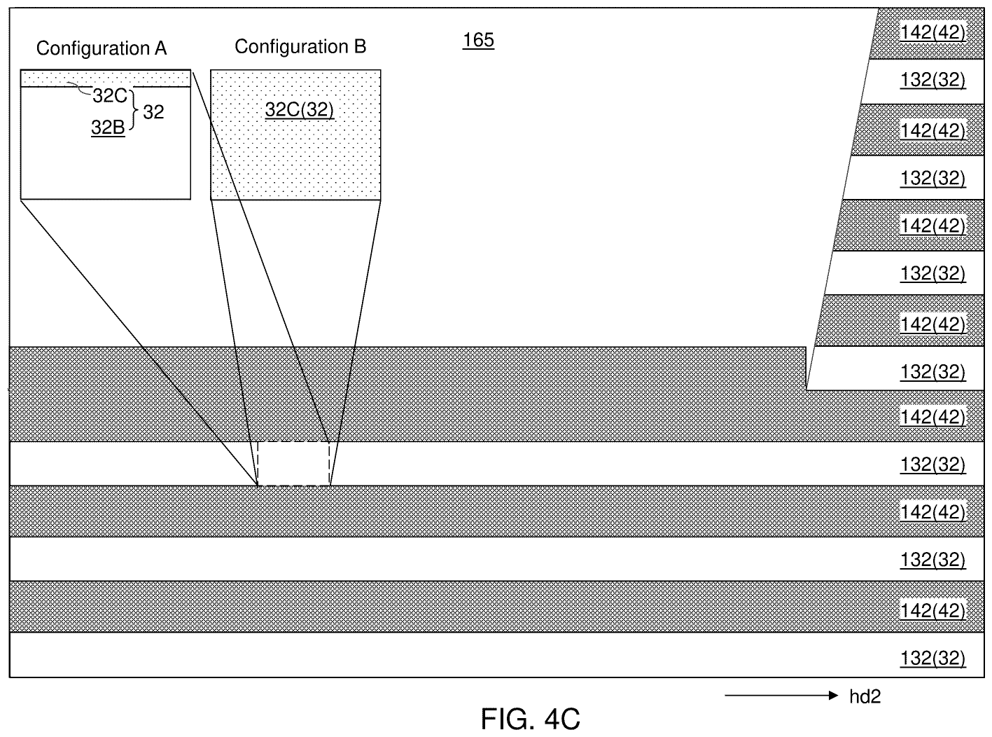

Referring to FIGS. 4A-4C, a first dielectric fill material (such as undoped silicate glass (i.e., silicon oxide) or a doped silicate glass) can be deposited in each first-tier stepped cavity 169. The first dielectric fill material can be planarized to remove excess portions of the first dielectric fill material from above the horizontal plane including the topmost surface of the first vertically alternating sequence (132, 142). Each remaining portion of the first dielectric fill material that fills a respective first-tier stepped cavity 169 constitutes a first-tier retro-stepped dielectric material portion 165. Generally, the first-tier retro-stepped dielectric material portions 165 can be formed in inter-array regions 200 located between a respective first memory array region 100A and a respective second memory array region 100B that are laterally spaced apart along the first horizontal direction hd1. The planar top surface of each first-tier retro-stepped dielectric material portion 165 can be located within a horizontal plane including the top surface of the first-tier insulating cap layer 170.

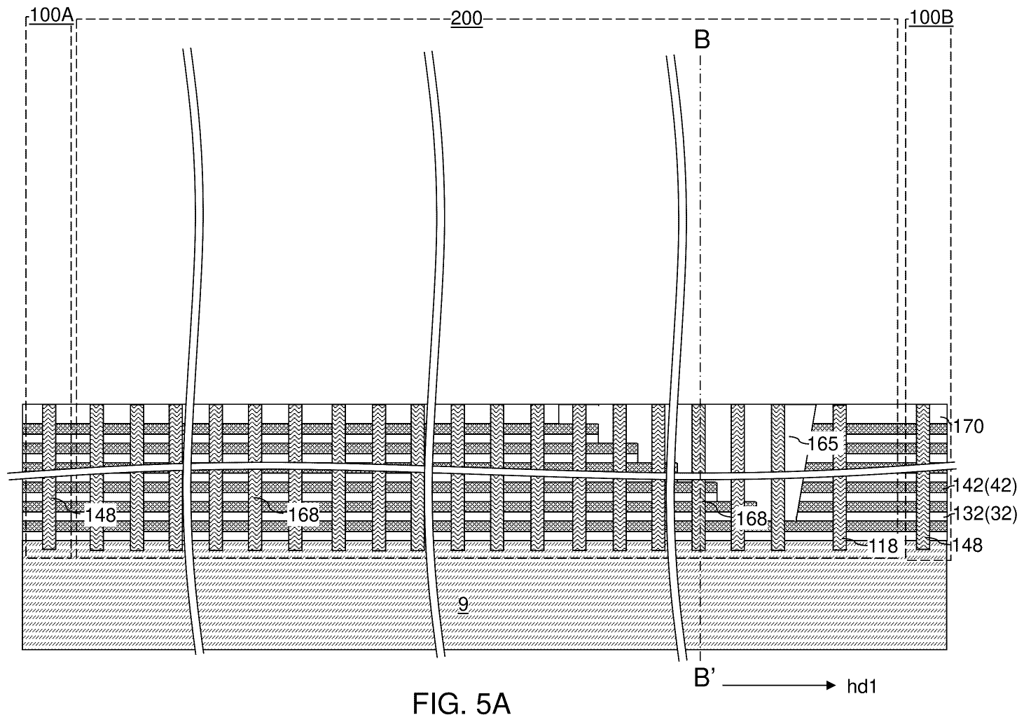

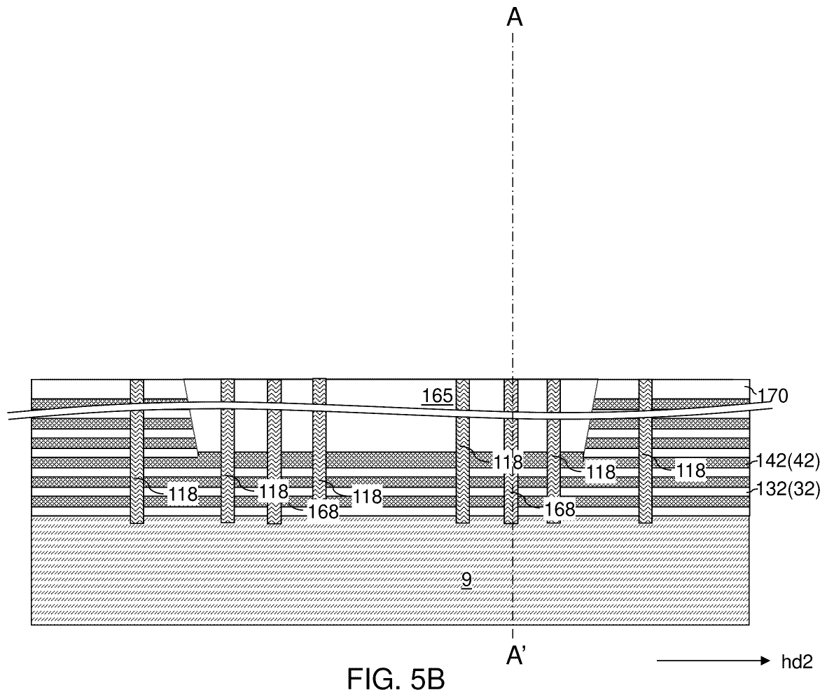

Referring to FIGS. 5A and 5B, various first-tier openings may be formed through the first vertically alternating sequence (132, 142) and into the substrate 9. A photoresist layer (not shown) may be applied over the first vertically alternating sequence (132, 142), and may be lithographically patterned to form various openings therethrough. The pattern of openings in the photoresist layer may be transferred through the first vertically alternating sequence (132, 142) and into the substrate 9 by a first anisotropic etch process to form the various first-tier openings concurrently, i.e., during the first isotropic etch process. The various first-tier openings may include first-tier memory openings formed in the memory array regions 100 and first-tier support openings formed in the inter-array regions 200, and first-tier contact openings formed in the staircase regions (which are located within the inter-array regions 200). Each cluster of first-tier memory openings may be formed as a two-dimensional array of first-tier memory openings. The first-tier support openings are openings that are formed in the inter-array region 200, and are subsequently employed to form support pillar structures. Each first-tier contact opening is formed in a respective area in which a respective layer contact via structure 86 is to be subsequently formed. A subset of the first-tier support openings may be formed through a respective horizontally-extending surface segment of the first stepped surfaces. A subset of the first-tier contact openings is formed through a respective horizontally-extending surface segment of the first stepped surfaces.

According to an aspect of the present disclosure, each first-tier sacrificial material layer 142 comprises a respective locally thickened portion underneath each first-tier retro-stepped dielectric material portion 165. Each of the first-tier contact openings can be formed through a locally thickened portion of a respective first-tier sacrificial material layer 142.

Sacrificial first-tier opening fill structures (148, 118, 168) may be formed in the various first-tier openings. For example, a sacrificial first-tier fill material is concurrently deposited in each of the first-tier openings. The sacrificial first-tier fill material includes a material that may be subsequently removed selectively to the materials of the first-tier insulating layers 132 and the first-tier sacrificial material layers 142. In one embodiment, the sacrificial first-tier fill material may include a semiconductor material such as silicon (e.g., a-Si or polysilicon), a silicon-germanium alloy, germanium, a III-V compound semiconductor material, or a combination thereof. Optionally, a thin etch stop liner (such as a silicon oxide layer or a silicon nitride layer having a thickness in a range from 1 nm to 3 nm) may be used prior to depositing the sacrificial first-tier fill material. The sacrificial first-tier fill material may be formed by a non-conformal deposition or a conformal deposition method.

In another embodiment, the sacrificial first-tier fill material may include a silicon oxide material having a higher etch rate than the material of the first-tier insulating layers 132. For example, the sacrificial first-tier fill material may include borosilicate glass or porous or non-porous organosilicate glass having an etch rate that is at least 100 times higher than the etch rate of densified TEOS oxide (i.e., a silicon oxide material formed by decomposition of tetraethylorthosilicate glass in a chemical vapor deposition process and subsequently densified in an anneal process) in a 100:1 dilute hydrofluoric acid. In this case, a thin etch stop liner (such as a silicon nitride layer having a thickness in a range from 1 nm to 3 nm) may be used prior to depositing the sacrificial first-tier fill material. The sacrificial first-tier fill material may be formed by a non-conformal deposition or a conformal deposition method.

In yet another embodiment, the sacrificial first-tier fill material may include carbon-containing material (such as amorphous carbon or diamond-like carbon) that may be subsequently removed by ashing, or a silicon-based polymer that may be subsequently removed selectively to the materials of the first vertically alternating sequence (132, 142).

Portions of the deposited sacrificial first-tier fill material may be removed from above the topmost layer of the first vertically alternating sequence (132, 142), such as from above the first-tier insulating cap layer 170. For example, the sacrificial first-tier fill material may be recessed to a top surface of the first-tier insulating cap layer 170 using a planarization process. The planarization process may include a recess etch, chemical mechanical planarization (CMP), or a combination thereof. The top surface of the first-tier insulating cap layer 170 may be used as an etch stop layer or a planarization stop layer.

Remaining portions of the sacrificial first-tier fill material comprise sacrificial first-tier opening fill structures (148, 118, 168). Specifically, each remaining portion of the sacrificial first-tier fill material in a first-tier memory opening constitutes a sacrificial first-tier memory opening fill structure 148. Each remaining portion of the sacrificial first-tier fill material in a first-tier support opening constitutes a sacrificial first-tier support opening fill structure 118. Each remaining portion of the sacrificial first-tier fill material in a first-tier contact opening constitutes a sacrificial first-tier contact opening fill structure 168. The various sacrificial first-tier opening fill structures (148, 118, 168) are concurrently formed, i.e., during a same set of processes including the deposition process that deposits the sacrificial first-tier fill material and the planarization process that removes the first-tier deposition process from above the first vertically alternating sequence (132, 142) (such as from above the top surface of the first-tier insulating cap layer 170). The top surfaces of the sacrificial first-tier opening fill structures (148, 118, 168) may be coplanar with the top surface of the first-tier insulating cap layer 170. Each of the sacrificial first-tier opening fill structures (148, 118, 168) may, or may not, include cavities therein. The set of all structures located between the bottommost surface of the first vertically alternating sequence (132, 142) and the topmost surface of the first vertically alternating sequence (132, 142) or embedded within the first vertically alternating sequence (132, 142) constitutes a first-tier structure.

According to an aspect of the present disclosure, each first-tier sacrificial material layer 142 comprises a respective locally thickened portion underneath each first-tier retro-stepped dielectric material portion 165. Each of the first-tier contact openings can be formed through a locally thickened portion of a respective first-tier sacrificial material layer 142. Accordingly, each of the sacrificial first-tier contact opening fill structures 168 can be formed through a locally thickened portion of a respective first-tier sacrificial material layer 142. The sacrificial first-tier contact opening fill structures 168 may vertically extend from a horizontal plane including a top surface of the first-tier alternating stack (132, 142) at least to a horizontal plane including a bottom surface of the first-tier alternating stack (132, 142).

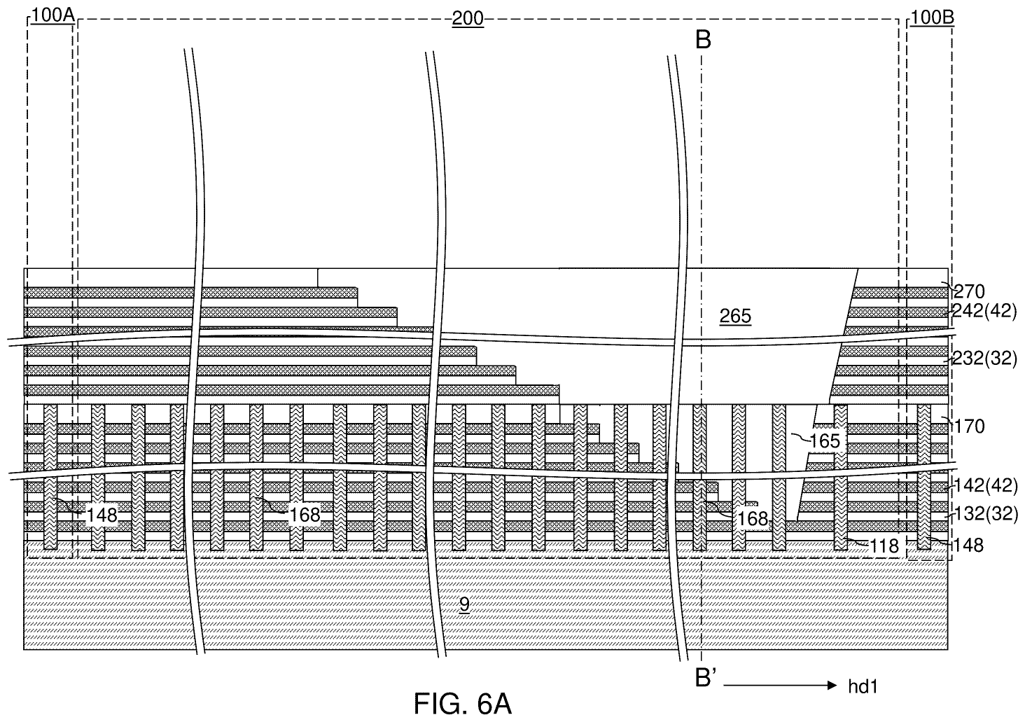

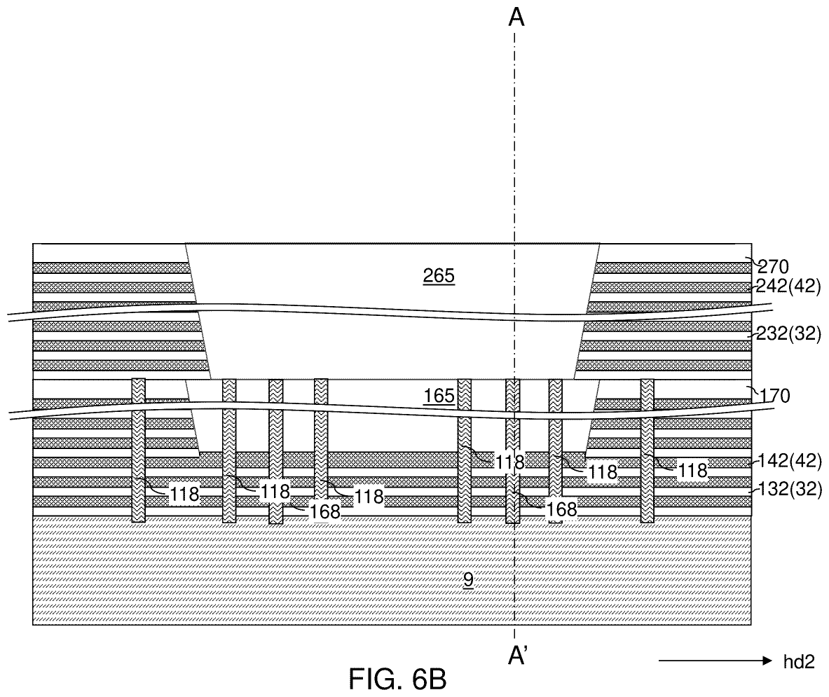

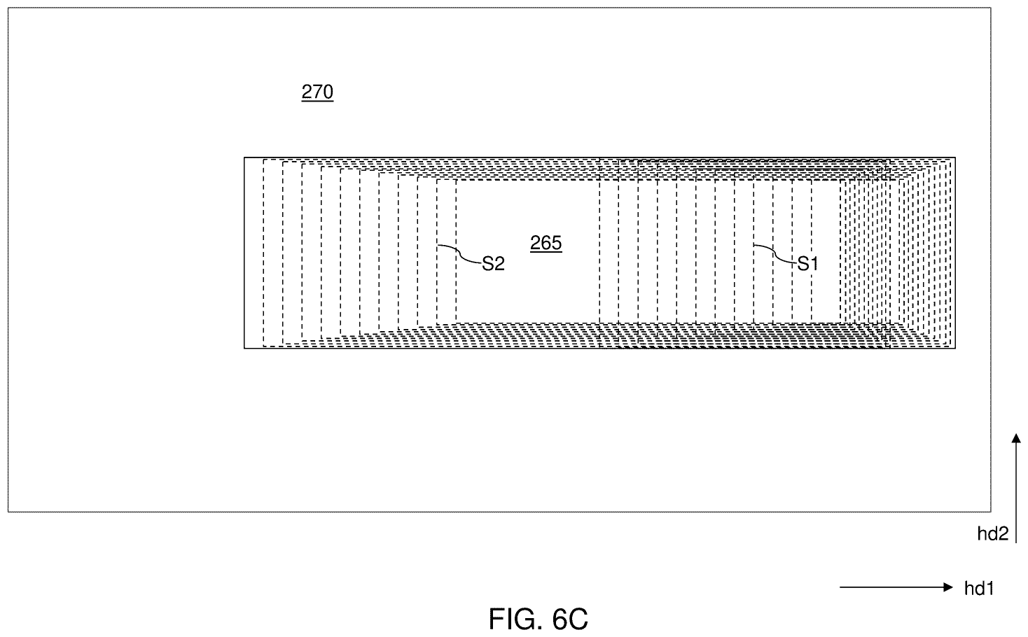

Referring to FIGS. 6A-6C, a second vertically alternating sequence of second-tier insulating layers 232 and second-tier sacrificial material layers 242 can be formed. Each of the second-tier insulating layers 232 is an insulating layer 32 that continuously extends over the entire area of the substrate 8, and may have a uniform thickness throughout. Each of the second-tier sacrificial material layers 242 is a sacrificial material layer 42 that includes a dielectric material and continuously extends over the entire area of the substrate 8, and may have a uniform thickness throughout. The second-tier insulating layers 232 can have the same material composition and the same thickness as the first-tier insulating layers 132. The second-tier sacrificial material layers 242 can have the same material composition and the same thickness as the first-tier sacrificial material layers 142. A second-tier insulating cap layer 270 can be formed over the second vertically alternating sequence (232, 242).

Second stepped surfaces can be formed within the staircase regions of the inter-array region 200 which will be filled with the second-tier retro-stepped dielectric material portions 265. For example, a combination of a sacrificial hard mask layer and a trimming mask layer may be employed to form the second stepped surfaces. Generally, the processing steps described with reference to FIGS. 2A-2C can be performed to form second-tier stepped cavities, under which a respective set of second stepped surfaces of the second vertically alternating sequence (232, 242) are exposed. Each set of second stepped surfaces may be laterally offset relative to an adjacent and underlying set of first stepped surfaces of the first vertically alternating sequence (132, 142) along the first horizontal direction hd1.

In an illustrative example, 2 sets of second stepped surfaces can be formed within a combination of the area of a laterally-neighboring pair of second-tier retro-stepped dielectric material portions 265 and an intervening area. N can be an integer in a range from 2 to 8. Each set of second stepped staircases may include P steps such that sidewalls of Q second continuous spacer material layers are physically exposed with lateral offsets. Q may be an integer from 2 to 64. M area recess etch processes can be performed such that each area recess etch process vertically recesses Q times 21 sets of a second insulating layer 232 and a second-tier sacrificial material layer 242, in which j is a different integer from 0 to (N−1). A total of up to 2^{N}×Q stepped surfaces can be formed for the second vertically alternating sequence of the second-tier insulating layers 232 and the second-tier sacrificial material layers 242. The total number of the stepped surfaces within each continuous cavity overlying the second stepped surfaces can be the same as the total number of the second-tier sacrificial material layers 242 in the second vertically alternating sequence (132, 242).

The processing steps described with reference to FIGS. 3A-3C can be performed with suitable modifications in the masking pattern to locally thicken physically exposed portions of the second-tier sacrificial material layers 242 in each second-tier stepped cavity. A second dielectric fill material (such as undoped silicate glass (i.e., silicon oxide) or a doped silicate glass) can be deposited in each second-tier stepped cavity. The second dielectric fill material can be planarized to remove excess portions of the second dielectric fill material from above the horizontal plane including the topmost surface of the second vertically alternating sequence (232, 242). Each remaining portion of the second dielectric fill material that fills a respective second continuous retro-stepped cavity constitutes a second-tier retro-stepped dielectric material portion 265. First vertical steps S1 of the first stepped surfaces that underlie the first-tier retro-stepped dielectric material portion 165 and second vertical steps S2 of the second stepped surfaces that underlie the second-tier retro-stepped dielectric material portion 265 are illustrated. The second vertical steps S2 are perpendicular to the first horizontal direction hd1.

Generally, a second-tier structure is formed, which comprises a second vertically alternating sequence of second-tier insulating layers 232 and second-tier sacrificial material layers 242 and second-tier retro-stepped dielectric material portions 265 overlying second stepped surfaces of the second vertically alternating sequence that are located in the inter-array regions 200.

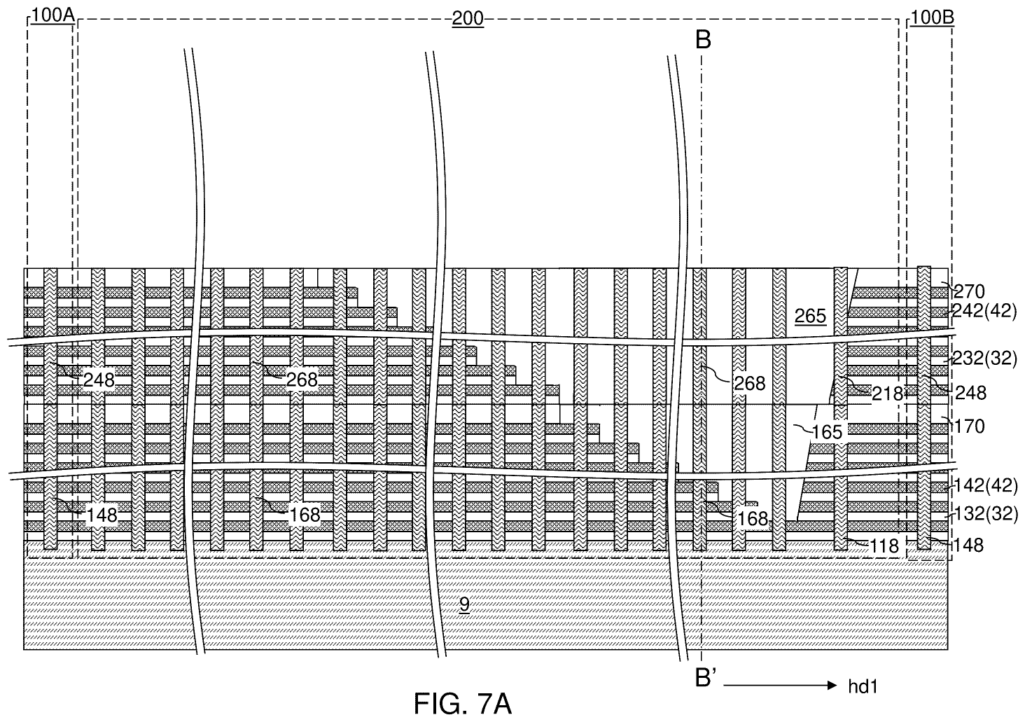

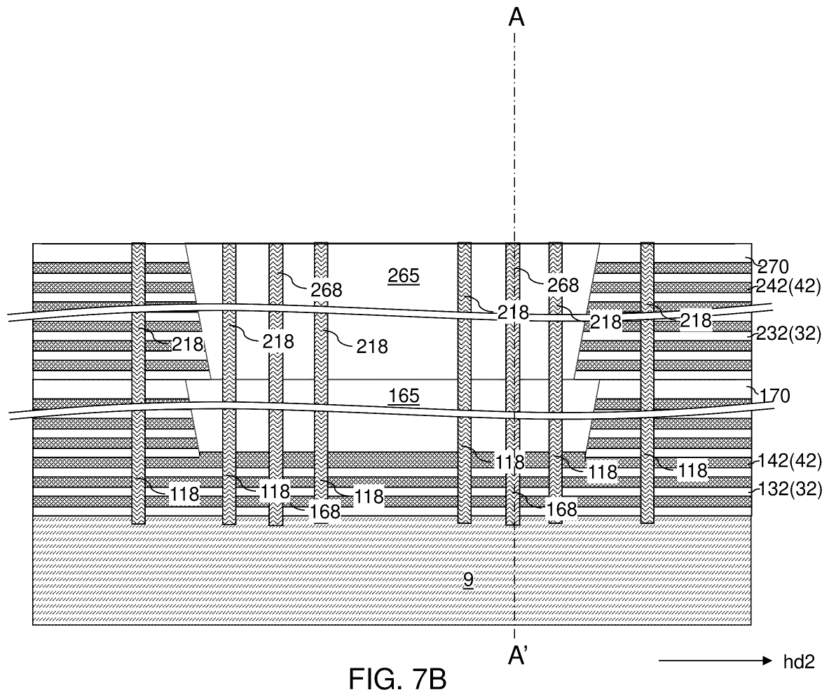

Referring to FIGS. 7A and 7B, various second-tier openings may be formed through the second vertically alternating sequence (232, 242) and over the sacrificial first-tier opening fill structures (148, 118, 168). A photoresist layer (not shown) may be applied over the second vertically alternating sequence (232, 242), and may be lithographically patterned to form various openings therethrough. The pattern of openings in the photoresist layer may be transferred through the second vertically alternating sequence (232, 242) to form the various second-tier openings concurrently, i.e., during the second isotropic recess etch process.

The various second-tier openings may include second-tier memory openings formed in the memory array regions 100, second-tier support openings formed in the inter-array region 200, and second-tier contact openings formed in the staircase region which is located within the inter-array region 200. Each second-tier opening may be formed within the area of a respective one of the sacrificial first-tier opening fill structures (148, 118, 168). Thus, a top surface of a sacrificial first-tier opening fill structure can be physically exposed at the bottom of each second-tier opening. Specifically, each second-tier memory openings can be formed directly over a respective sacrificial first-tier memory opening fill structure 148, each second-tier support opening can be formed directly over a respective sacrificial first-tier support opening fill structure 118, and each second-tier contact opening can be formed directly over a respective sacrificial first-tier contact opening fill structure 168. Each cluster of second-tier memory openings may be formed as a two-dimensional array of second-tier memory openings. The second-tier support openings are openings that are formed in the inter-array region 200, and are subsequently employed to form support pillar structures. A subset of the second-tier support openings may be formed through a respective horizontally-extending surface segment of the second stepped surfaces. A subset of the second-tier contact openings may be formed through a respective horizontally-extending surface segment of the second stepped surfaces.

Sacrificial second-tier opening fill structures may be formed in the various second-tier openings. For example, a sacrificial first-tier fill material is concurrently deposited in each of the second-tier openings. The sacrificial second-tier fill material can include any material that may be employed for the sacrificial first-tier fill material. Portions of the deposited sacrificial second-tier fill material may be removed from above the topmost layer of the second vertically alternating sequence (232, 242). Remaining portions of the sacrificial second-tier fill material comprise sacrificial second-tier opening fill structures (248, 218, 268). Specifically, each remaining portion of the sacrificial second-tier fill material in a second-tier memory opening constitutes a sacrificial second-tier memory opening fill structure 248. Each remaining portion of the sacrificial second-tier fill material in a second-tier support opening constitutes a sacrificial second-tier support opening fill structure 218. Each remaining portion of the sacrificial second-tier fill material in a second-tier contact opening constitutes a sacrificial second-tier contact opening fill structure 268. The top surfaces of the sacrificial second-tier opening fill structures (248, 218, 268) may be coplanar with the top surface of the second-tier insulating cap layer 270. Each of the sacrificial second-tier opening fill structures may, or may not, include cavities therein. The set of all structures located between the bottommost surface of the second vertically alternating sequence (232, 242) and the topmost surface of the second vertically alternating sequence (232, 242) or embedded within the second vertically alternating sequence (232, 242) constitutes a second-tier structure.

According to an aspect of the present disclosure, each second-tier sacrificial material layer 242 comprises a respective locally thickened portion underneath each second-tier retro-stepped dielectric material portion 265. Each of the second-tier contact openings can be formed through a locally thickened portion of a respective second-tier sacrificial material layer 242. Accordingly, each of the sacrificial second-tier contact opening fill structures 268 can be formed through a locally thickened portion of a respective second-tier sacrificial material layer 242. The sacrificial second-tier contact opening fill structures 268 may vertically extend from a horizontal plane including a top surface of the second-tier alternating stack (232, 242) at least to a horizontal plane including a bottom surface of the second-tier alternating stack (232, 242).

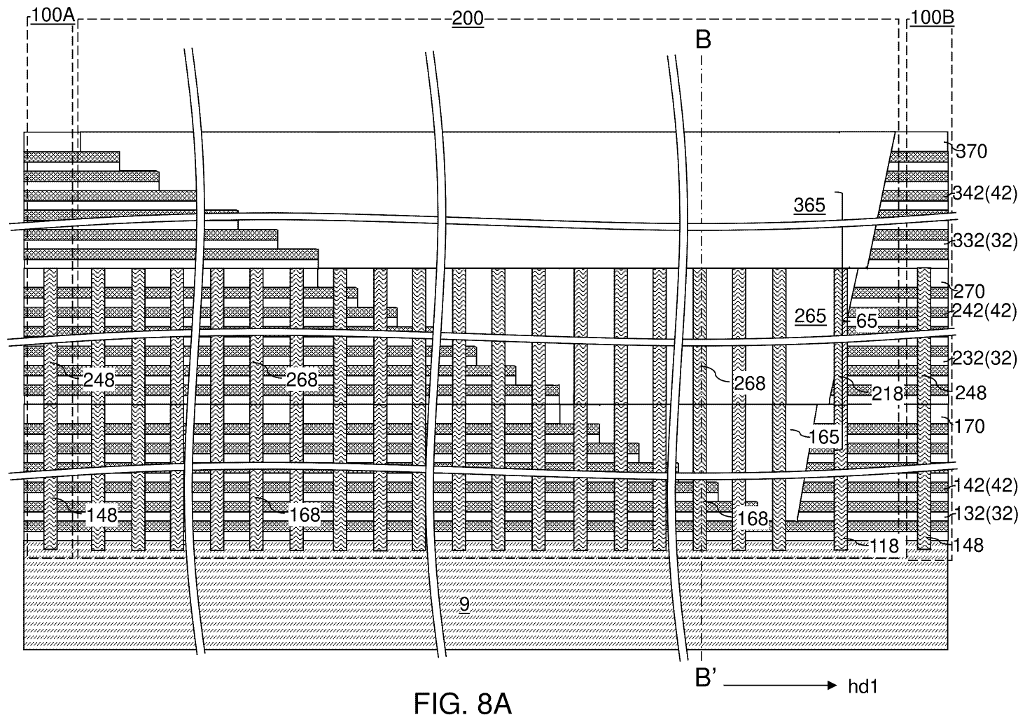

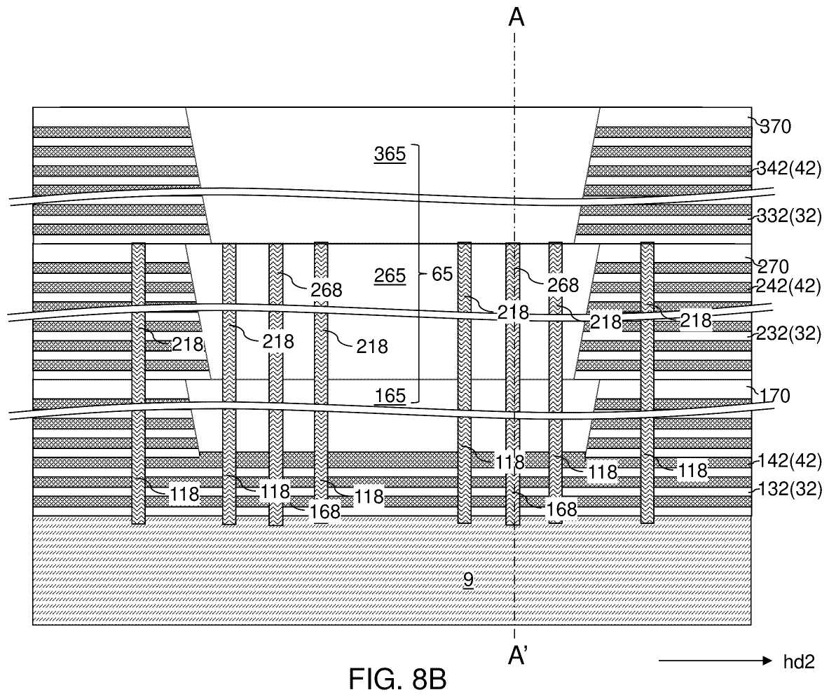

Referring to FIGS. 8A and 8B, a third vertically alternating sequence of third-tier insulating layers 332 and third-tier sacrificial material layers 342 can be formed. Each of the third-tier insulating layers 332 is an insulating layer 32 that continuously extends over the entire area of the substrate 8, and may have a uniform thickness throughout. Each of the third-tier sacrificial material layers 342 is a sacrificial material layer 42 that includes a dielectric material and continuously extends over the entire area of the substrate 8, and may have a uniform thickness throughout. The third-tier insulating layers 332 can have the same material composition and the same thickness as the first-tier insulating layers 132. The third-tier sacrificial material layers 342 can have the same material composition and the same thickness as the first-tier sacrificial material layers 142. A third-tier insulating cap layer 370 can be formed over the third vertically alternating sequence (332, 342).

Third stepped surfaces can be formed within the staircase regions of the inter-array region 200 which will be filled with the third-tier retro-stepped dielectric material portions 365. For example, a combination of a sacrificial hard mask layer and a trimming mask layer may be employed to form the third stepped surfaces. Generally, the processing steps described with reference to FIGS. 2A-2C can be performed to form third-tier stepped cavities, under which a respective set of third stepped surfaces of the third vertically alternating sequence (332, 342) are exposed. Each set of third stepped surfaces may be laterally offset relative to an adjacent and underling set of second stepped surfaces of the second vertically alternating sequence (232, 242) and relative to an adjacent and underlying set of first stepped surfaces of the first vertically alternating sequence (132, 142) along the first horizontal direction hd1.

The processing steps described with reference to FIGS. 3A-3C can be performed with suitable modifications in the masking pattern to locally thicken physically exposed portions of the third-tier sacrificial material layers 342 in each third-tier stepped cavity. A third dielectric fill material (such as undoped silicate glass (i.e., silicon oxide) or a doped silicate glass) can be deposited in each third-tier stepped cavity. The third dielectric fill material can be planarized to remove excess portions of the second dielectric fill material from above the horizontal plane including the topmost surface of the third-tier insulating cap layer 370. Each remaining portion of the third dielectric fill material that fills a respective third continuous retro-stepped cavity constitutes a third-tier retro-stepped dielectric material portion 365.

A third dielectric fill material (such as undoped silicate glass (i.e., silicon oxide) or a doped silicate glass) can be deposited in each third continuous retro-stepped cavity. The third dielectric fill material can be planarized to remove excess portions of the third dielectric fill material from above the horizontal plane including the topmost surface of the third vertically alternating sequence (332, 342). Each remaining portion of the third dielectric fill material that fills a respective third continuous retro-stepped cavity constitutes a third-tier retro-stepped dielectric material portion 365.

Generally, a third-tier structure is formed, which comprises a third vertically alternating sequence of third-tier insulating layers 332 and third-tier sacrificial material layers 342 and third-tier retro-stepped dielectric material portions 365 overlying third stepped surfaces of the third vertically alternating sequence that are located in the inter-array regions 200.

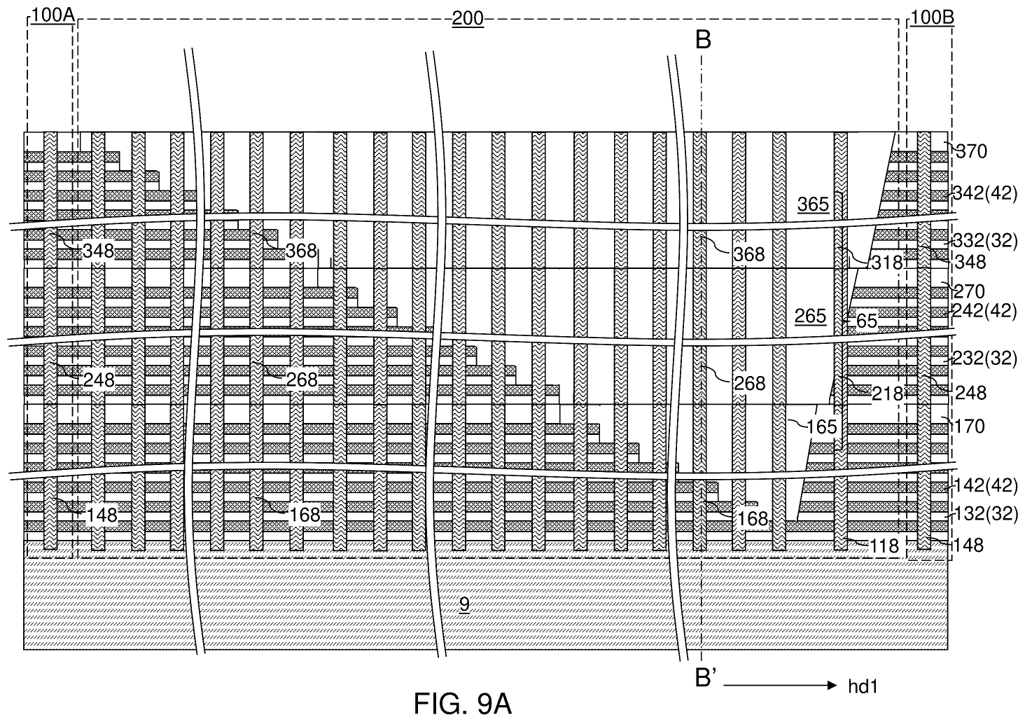

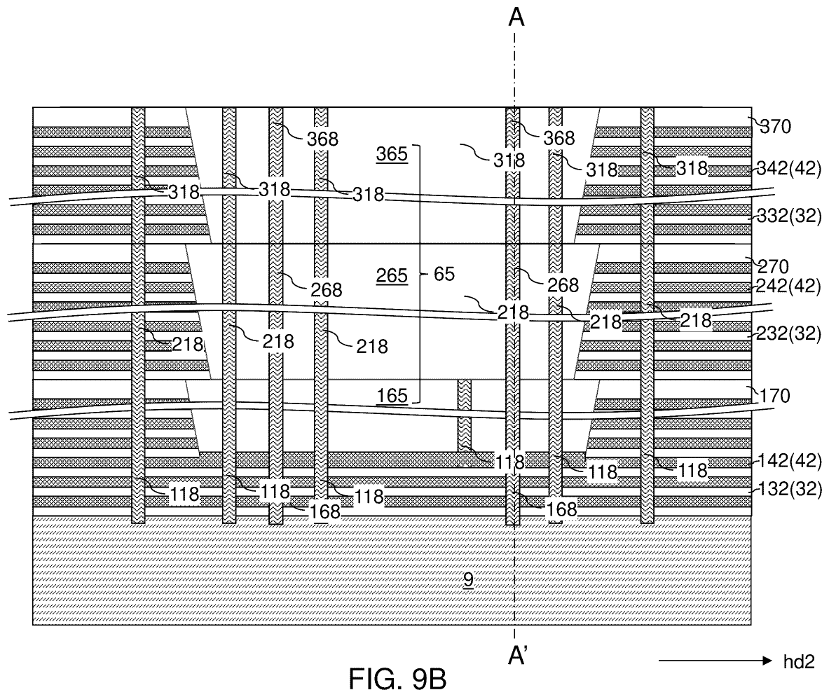

Referring to FIGS. 9A and 9B, various third-tier openings may be formed through the third vertically alternating sequence (332, 342) and over the sacrificial second-tier opening fill structures (248, 218, 268). A photoresist layer (not shown) may be applied over the third vertically alternating sequence (332, 342), and may be lithographically patterned to form various openings therethrough. The pattern of openings in the photoresist layer may be transferred through the third vertically alternating sequence (332, 342) to form the various third-tier openings concurrently, i.e., during the third isotropic etch process.

The various third-tier openings may include third-tier memory openings formed in the memory array regions 100, third-tier support openings formed in the inter-array region 200, and third-tier contact openings formed in the staircase region which is located within the inter-array region 200. Each third-tier opening may be formed within the area of a respective one of the sacrificial second-tier opening fill structures (248, 218, 268). Thus, a top surface of a sacrificial second-tier opening fill structure can be physically exposed at the bottom of each third-tier opening. Specifically, each third-tier memory openings can be formed directly over a respective sacrificial second-tier memory opening fill structure 248, each third-tier support opening can be formed directly over a respective sacrificial second-tier support opening fill structure 218, and each third-tier contact opening can be formed directly over a respective sacrificial second-tier contact opening fill structure 268. Each cluster of third-tier memory openings may be formed as a two-dimensional array of third-tier memory openings. The third-tier support openings are openings that are formed in the inter-array region 200, and are subsequently employed to form support pillar structures. A subset of the third-tier support openings may be formed through a respective horizontally-extending surface segment of the third stepped surfaces. A subset of the third-tier contact openings may be formed through a respective horizontally-extending surface segment of the third stepped surfaces.

Sacrificial third-tier opening fill structures may be formed in the various third-tier openings. For example, a sacrificial second-tier fill material is concurrently deposited in each of the third-tier openings. The sacrificial third-tier fill material can include any material that may be employed for the sacrificial second-tier fill material. Portions of the deposited sacrificial third-tier fill material may be removed from above the topmost layer of the third vertically alternating sequence (332, 342). Remaining portions of the sacrificial third-tier fill material comprise sacrificial third-tier opening fill structures (348, 318, 368). Specifically, each remaining portion of the sacrificial third-tier fill material in a third-tier memory opening constitutes a sacrificial third-tier memory opening fill structure 348. Each remaining portion of the sacrificial third-tier fill material in a third-tier support opening constitutes a sacrificial third-tier support opening fill structure 318. Each remaining portion of the sacrificial third-tier fill material in a third-tier contact opening constitutes a sacrificial third-tier contact opening fill structure 368. The top surfaces of the sacrificial third-tier opening fill structures (348, 318, 368) may be coplanar with the top surface of the third-tier insulating cap layer 370. Each of the sacrificial third-tier opening fill structures may, or may not, include cavities therein. The set of all structures located between the bottommost surface of the third vertically alternating sequence (332, 342) and the topmost surface of the third vertically alternating sequence (332, 342) or embedded within the third vertically alternating sequence (332, 342) constitutes a third-tier structure.

According to an aspect of the present disclosure, each third-tier sacrificial material layer 342 comprises a respective locally thickened portion underneath each third-tier retro-stepped dielectric material portion 365. Each of the third-tier contact openings can be formed through a locally thickened portion of a respective third-tier sacrificial material layer 342. Accordingly, each of the sacrificial third-tier contact opening fill structures 368 can be formed through a locally thickened portion of a respective third-tier sacrificial material layer 342. The sacrificial third-tier contact opening fill structures 368 may vertically extend from a horizontal plane including a top surface of the third-tier alternating stack (332, 342) at least to a horizontal plane including a bottom surface of the third-tier alternating stack (332, 342).

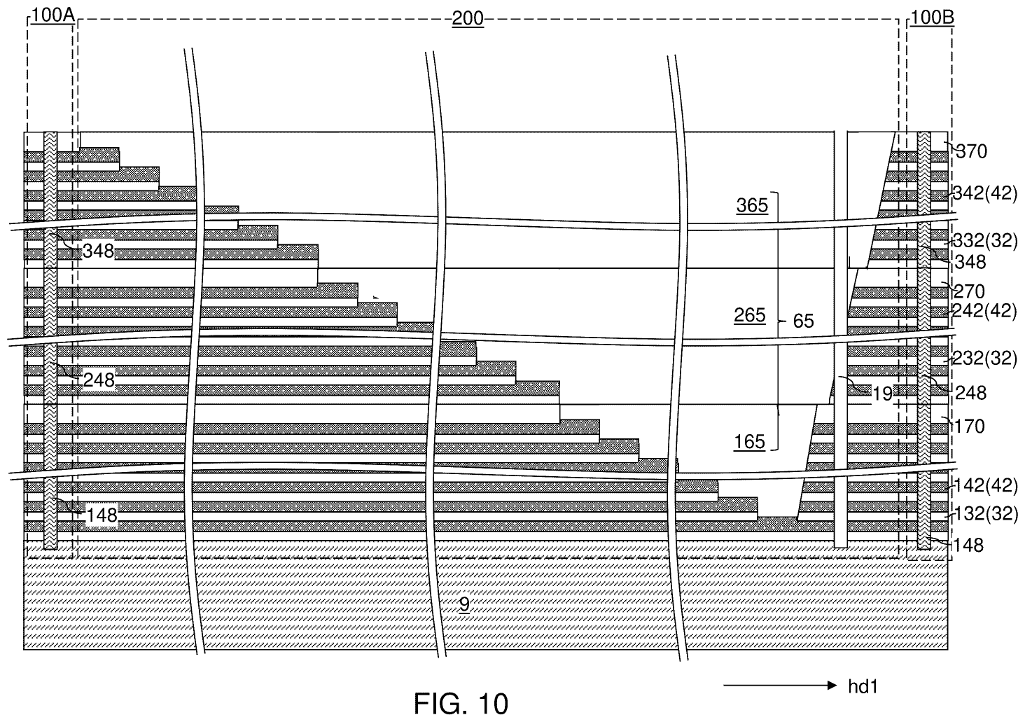

Referring to FIG. 10, a photoresist layer (not shown) can be applied over the third-tier structure, and can be lithographically patterned to form openings over the areas of the sacrificial third-tier support opening fill structures 318. The sacrificial fill materials of the sacrificial third-tier support opening fill structures 318, the sacrificial second-tier support opening fill structures 218, and the sacrificial first-tier support opening fill structures 118 can be removed selectively to the materials of the retro-stepped dielectric material portions 65, the insulating layers 32, and the sacrificial material layers 42. Support pillar cavities can be formed in the volumes from which the materials of the sacrificial third-tier support opening fill structures 318, the sacrificial second-tier support opening fill structures 218, and the sacrificial first-tier support opening fill structures 118 are removed. The photoresist layer can be subsequently removed, for example, by ashing.

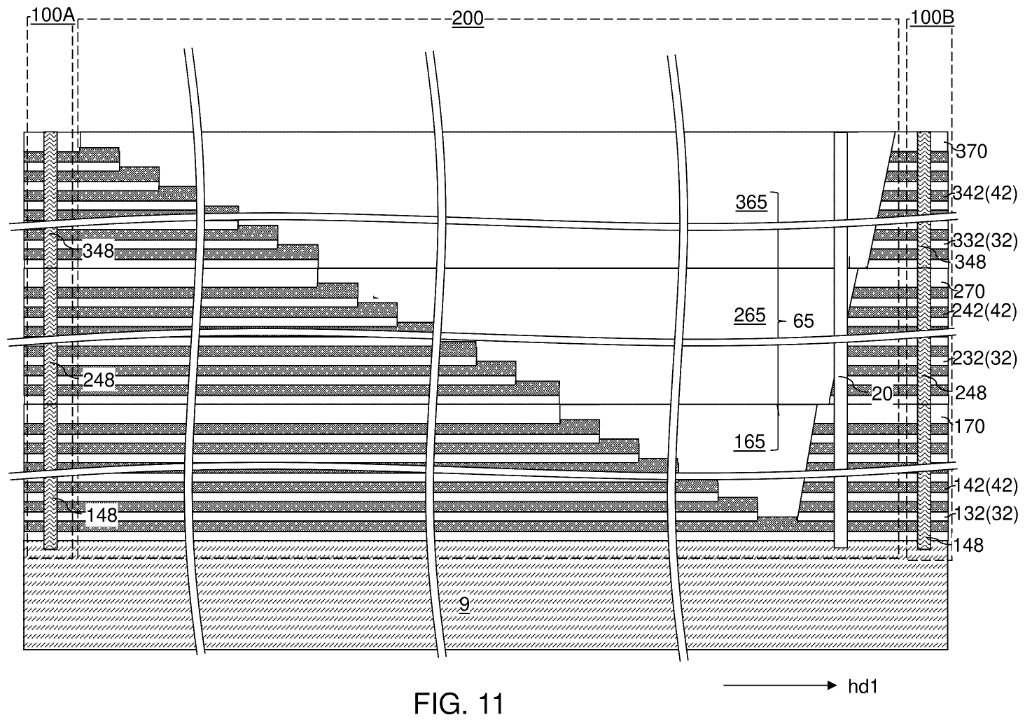

Referring to FIG. 11, a dielectric fill material can be deposited in the support pillar cavities by performing a conformal deposition process. The dielectric fill material comprises a dielectric material that is different from the material of the sacrificial material layers 42. For example, the dielectric fill material may comprise undoped silicate glass or a doped silicate glass. Excess portions of the dielectric fill material can be removed from above the horizontal plane including the top surface of the topmost retro-stepped dielectric material portions 65 (such as the third-tier retro-stepped dielectric material portion 365). Each remaining portion of the dielectric fill material that fills a respective support pillar cavity constitutes a support pillar structure 20. The support pillar structures 20 can be formed in the inter-array region 200, and may vertically extend from the substrate 9 to a horizontal plane including the topmost surfaces of the retro-stepped dielectric material portions 65 and the third-tier insulating cap layer 370.

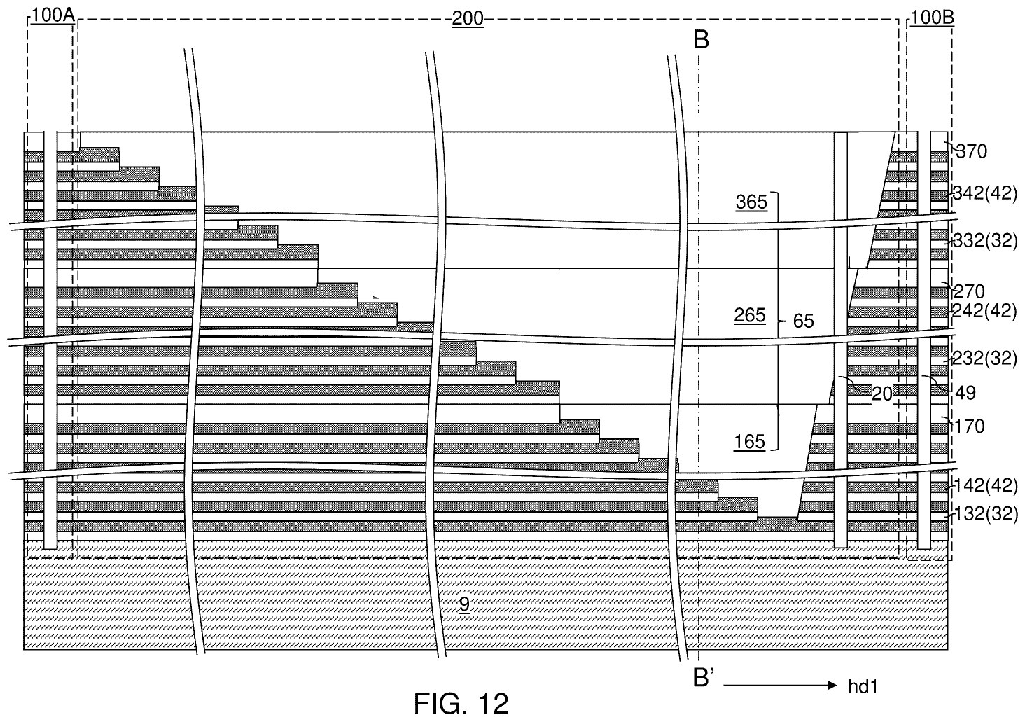

Referring to FIG. 12, a photoresist layer (not shown) can be applied over the third-tier structure, and can be lithographically patterned to cover the inter-array regions 200 without covering the memory array regions 100. The sacrificial fill materials of the sacrificial memory opening fill structures (148, 248, 348) can be removed selectively to the materials of the insulating layers 32, the sacrificial material layers 42, and the substrate 9. Memory openings 49 are formed in the voids from which the sacrificial fill materials of the sacrificial memory opening fill structures (148, 248, 348) are removed.

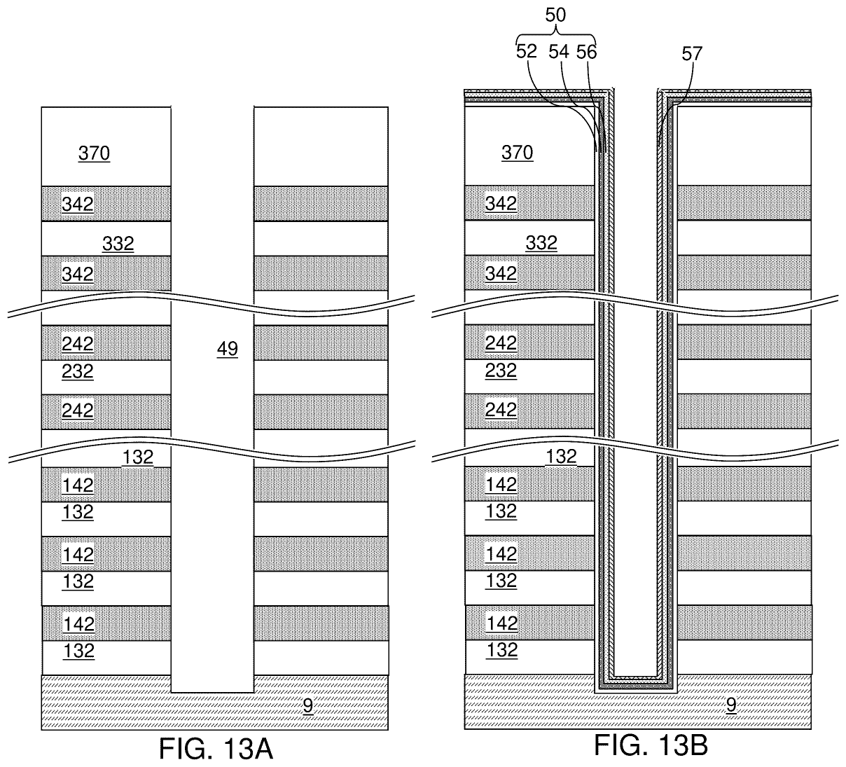

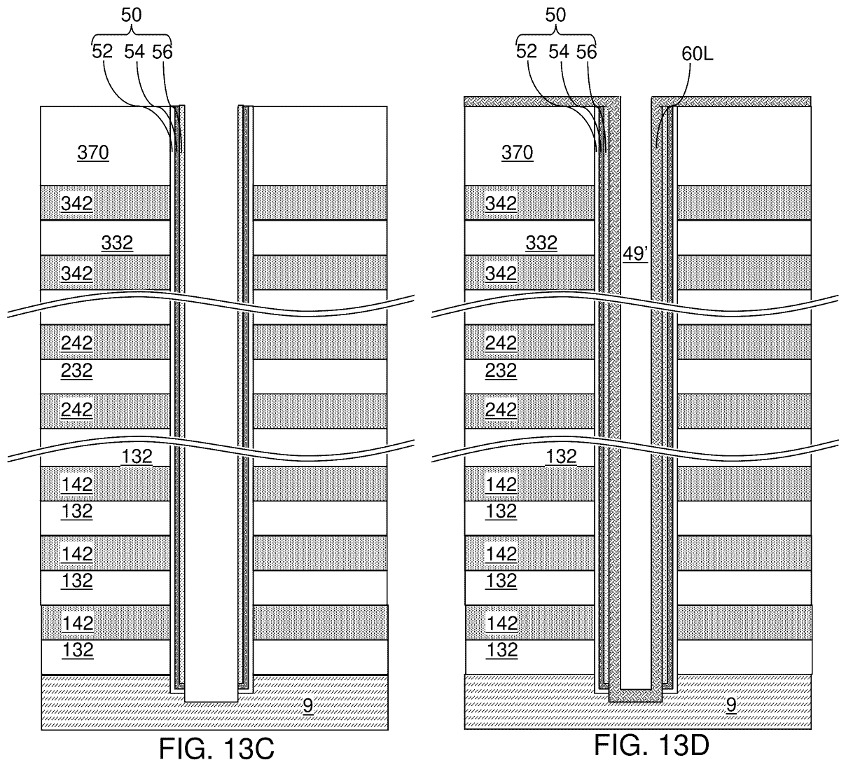

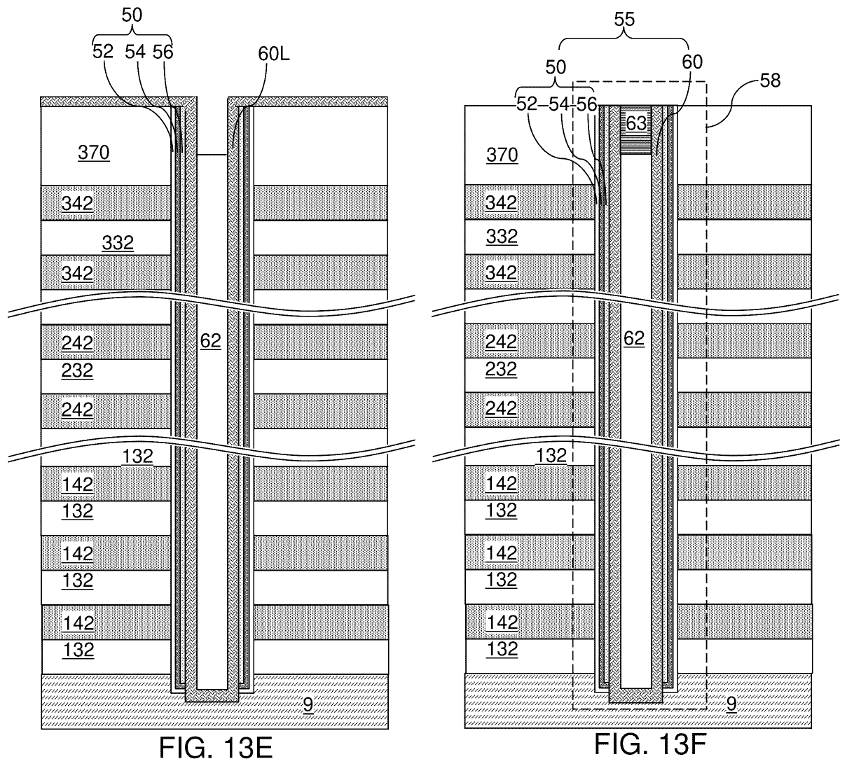

FIGS. 13A-13F illustrate sequential vertical cross-sectional views of a memory opening during formation of a memory opening fill structure according to an embodiment of the present disclosure.

Referring to FIG. 13A, a memory opening 49 in the first exemplary structure of FIG. 12 is illustrated.

Referring to FIG. 13B, a stack of layers including a blocking dielectric layer 52, a memory material layer 54, a dielectric liner 56, and an optional sacrificial cover layer 57 may be sequentially deposited in the inter-tier memory openings 49. The blocking dielectric layer 52 may include a single dielectric material layer or a stack of a plurality of dielectric material layers. In one embodiment, the blocking dielectric layer 52 may include a dielectric metal oxide layer consisting essentially of a dielectric metal oxide. As used herein, a dielectric metal oxide refers to a dielectric material that includes at least one metallic element and at least oxygen. The dielectric metal oxide may consist essentially of the at least one metallic element and oxygen, or may consist essentially of the at least one metallic element, oxygen, and at least one non-metallic element such as nitrogen. In one embodiment, the blocking dielectric layer 52 may include a dielectric metal oxide having a dielectric constant greater than 7.9, i.e., having a dielectric constant greater than the dielectric constant of silicon nitride. The thickness of the dielectric metal oxide layer may be in a range from 1 nm to 20 nm, although lesser and greater thicknesses may also be used. The dielectric metal oxide layer may subsequently function as a dielectric material portion that blocks leakage of stored electrical charges to control gate electrodes. In one embodiment, the blocking dielectric layer 52 includes aluminum oxide. Alternatively or additionally, the blocking dielectric layer 52 may include a dielectric semiconductor compound such as silicon oxide, silicon oxynitride, silicon nitride, or a combination thereof.

Subsequently, the memory material layer 54 may be formed. Generally, the memory material layer 54 may comprise any memory material known in the art. In one embodiment, the memory material layer 54 may be a continuous layer or patterned discrete portions of a charge trapping material including a dielectric charge trapping material, which may be, for example, silicon nitride. Alternatively, the memory material layer 54 may include a continuous layer or patterned discrete portions of a conductive material such as doped polysilicon or a metallic material that is patterned into multiple electrically isolated portions (e.g., floating gates), for example, by being formed within lateral recesses into sacrificial material layers 42. In one embodiment, the memory material layer 54 includes a silicon nitride layer. In one embodiment, the sacrificial material layers 42 and the insulating layers 32 may have vertically coincident sidewalls, and the memory material layer 54 may be formed as a single continuous layer. Alternatively, the sacrificial material layers 42 may be laterally recessed with respect to the sidewalls of the insulating layers 32, and a combination of a deposition process and an anisotropic etch process may be used to form the memory material layer 54 as a plurality of memory material portions that are vertically spaced apart. The thickness of the memory material layer 54 may be in a range from 2 nm to 20 nm, although lesser and greater thicknesses may also be used.

The dielectric liner 56 includes a dielectric material. In one embodiment, the dielectric liner 56 may comprise a tunneling dielectric layer through which charge tunneling may be performed under suitable electrical bias conditions. The charge tunneling may be performed through hot-carrier injection or by Fowler-Nordheim tunneling induced charge transfer depending on the mode of operation of the monolithic three-dimensional NAND string memory device to be formed. The dielectric liner 56 may include silicon oxide, silicon nitride, silicon oxynitride, dielectric metal oxides (such as aluminum oxide and hafnium oxide), dielectric metal oxynitride, dielectric metal silicates, alloys thereof, and/or combinations thereof. In one embodiment, the dielectric liner 56 may include a stack of a first silicon oxide layer, a silicon oxynitride layer, and a second silicon oxide layer, which is commonly known as an ONO stack. In one embodiment, the dielectric liner 56 may include a silicon oxide layer that is substantially free of carbon or a silicon oxynitride layer that is substantially free of carbon. The thickness of the dielectric liner 56 may be in a range from 2 nm to 20 nm, although lesser and greater thicknesses may also be used. The stack of the blocking dielectric layer 52, the memory material layer 54, and the dielectric liner 56 constitutes a memory film 50 that stores memory bits.

The sacrificial cover layer 57 may comprise a sacrificial material that may be subsequently removed selectively to the material of the dielectric liner 56. For example, the sacrificial cover layer may comprise a semiconductor material (e.g., amorphous silicon), silicon oxide, or a carbon-based material (such as amorphous carbon or diamond-like carbon). The thickness of the sacrificial cover layer may be in a range from 1 nm to 10 nm, although lesser and greater thicknesses may also be employed.

Referring to FIG. 13C, an anisotropic etch process may be performed to remove horizontal portions of the sacrificial cover layer 57, the dielectric liner 56, the memory material layer 54, and the blocking dielectric layer 52. Remaining cylindrical portions of the sacrificial cover layer 57 may be removed selectively to the material of the dielectric liner 56 during the anisotropic etch process, or by an isotropic etch process (such as a wet etch process) or by ashing. Alternatively, if the sacrificial cover layer 57 comprises a semiconductor material (e.g., amorphous silicon), then it may be retained.

Referring to FIG. 13D, a semiconductor channel material layer 60L can be deposited by a conformal deposition process. The semiconductor channel material layer 60L includes a p-doped semiconductor material such as at least one elemental semiconductor material, at least one III-V compound semiconductor material, at least one II-VI compound semiconductor material, at least one organic semiconductor material, or other semiconductor materials known in the art. In one embodiment, the semiconductor channel material layer 60L may have a uniform doping. In one embodiment, the semiconductor channel material layer 60L has a p-type doping in which p-type dopants (such as boron atoms) are present at an atomic concentration in a range from 1.0×10¹²/cm³ to 1.0×10¹⁸/cm³, such as from 1.0×10¹⁴/cm³ to 1.0×10¹⁷/cm³. In one embodiment, the semiconductor channel material layer 60L includes, and/or consists essentially of, boron-doped amorphous silicon or boron-doped polysilicon. In another embodiment, the semiconductor channel material layer 60L has an n-type doping in which n-type dopants (such as phosphor atoms or arsenic atoms) are present at an atomic concentration in a range from 1.0×10¹²/cm³ to 1.0×10¹⁸/cm³, such as from 1.0×10¹⁴/cm³ to 1.0×10¹⁷/cm³. The semiconductor channel material layer 60L may be formed by a conformal deposition method such as a low pressure chemical vapor deposition (LPCVD) process. The thickness of the semiconductor channel material layer 60L may be in a range from 2 nm to 10 nm, although lesser and greater thicknesses may also be used. A cavity 49′ is formed in the volume of each inter-tier memory opening 49 that is not filled with the deposited material layers (52, 54, 56, 60L).

Referring to FIG. 13E, if the cavity 49′ in each memory opening 49 is not completely filled by the semiconductor channel material layer 60L, a dielectric core layer may be deposited in the cavity 49′ to fill any remaining portion of the cavity 49′ within each memory opening 49. The dielectric core layer includes a dielectric material such as silicon oxide or organosilicate glass. The dielectric core layer may be deposited by a conformal deposition method such as a low pressure chemical vapor deposition (LPCVD) process, or by a self-planarizing deposition process such as spin coating. The horizontal portion of the dielectric core layer overlying the third-tier insulating cap layer 370 may be removed, for example, by a recess etch. The recess etch continues until top surfaces of the remaining portions of the dielectric core layer are recessed to a height between the top and bottom surfaces of the third-tier insulating cap layer 370. Each remaining portion of the dielectric core layer constitutes a dielectric core 62.

Referring to FIG. 13F, a doped semiconductor material having a doping of a second conductivity type may be deposited in cavities overlying the dielectric cores 62. The second conductivity type is the opposite of the first conductivity type. For example, if the first conductivity type is p-type, the second conductivity type is n-type, and vice versa. Portions of the deposited doped semiconductor material, the semiconductor channel material layer 60L, the dielectric liner 56, the memory material layer 54, and the blocking dielectric layer 52 that overlie the horizontal plane including the top surface of the third-tier insulating cap layer 370 may be removed by a planarization process such as a chemical mechanical planarization (CMP) process.

Each remaining portion of the doped semiconductor material of the second conductivity type constitutes a drain region 63. The dopant concentration in the drain regions 63 may be in a range from 5.0×10¹⁸/cm³ to 2.0×10²¹/cm³, although lesser and greater dopant concentrations may also be used. The doped semiconductor material may be, for example, doped polysilicon.

Each remaining portion of the semiconductor channel material layer 60L constitutes a vertical semiconductor channel 60 through which electrical current may flow when a vertical NAND device including the vertical semiconductor channel 60 is turned on. A dielectric liner 56 is surrounded by a memory material layer 54, and laterally surrounds a vertical semiconductor channel 60. Each adjoining set of a blocking dielectric layer 52, a memory material layer 54, and a dielectric liner 56 collectively constitute a memory film 50, which may store electrical charges with a macroscopic retention time. In some embodiments, a blocking dielectric layer 52 may not be present in the memory film 50 at this step, and a blocking dielectric layer may be subsequently formed after formation of lateral recesses. As used herein, a macroscopic retention time refers to a retention time suitable for operation of a memory device as a permanent memory device such as a retention time in excess of 24 hours.

Each combination of a memory film 50 and a vertical semiconductor channel 60 within an inter-tier memory opening 49 constitutes a memory stack structure 55. The memory stack structure 55 is a combination of a vertical semiconductor channel 60, a dielectric liner 56, a plurality of memory elements comprising portions of the memory material layer 54, and an optional blocking dielectric layer 52. The memory stack structures 55 can be formed through memory array regions 100 of the first and second vertically alternating sequences in which all layers of the first and second vertically alternating sequences are present. Each combination of a memory stack structure 55, a dielectric core 62, and a drain region 63 within an inter-tier memory opening 49 constitutes a memory opening fill structure 58. Generally, memory opening fill structures 58 are formed within the memory openings 49. Each of the memory opening fill structures 58 comprises a respective memory film 50 and a respective vertical semiconductor channel 60.

In one embodiment, each of the memory stack structures 55 comprises vertical NAND string including the respective vertical stack of memory elements (comprising portions of a memory material layer 54 located at levels of the sacrificial material layers 42) and a vertical semiconductor channel 60 that vertically extend through the sacrificial material layers 42 adjacent to the respective vertical stack of memory elements.

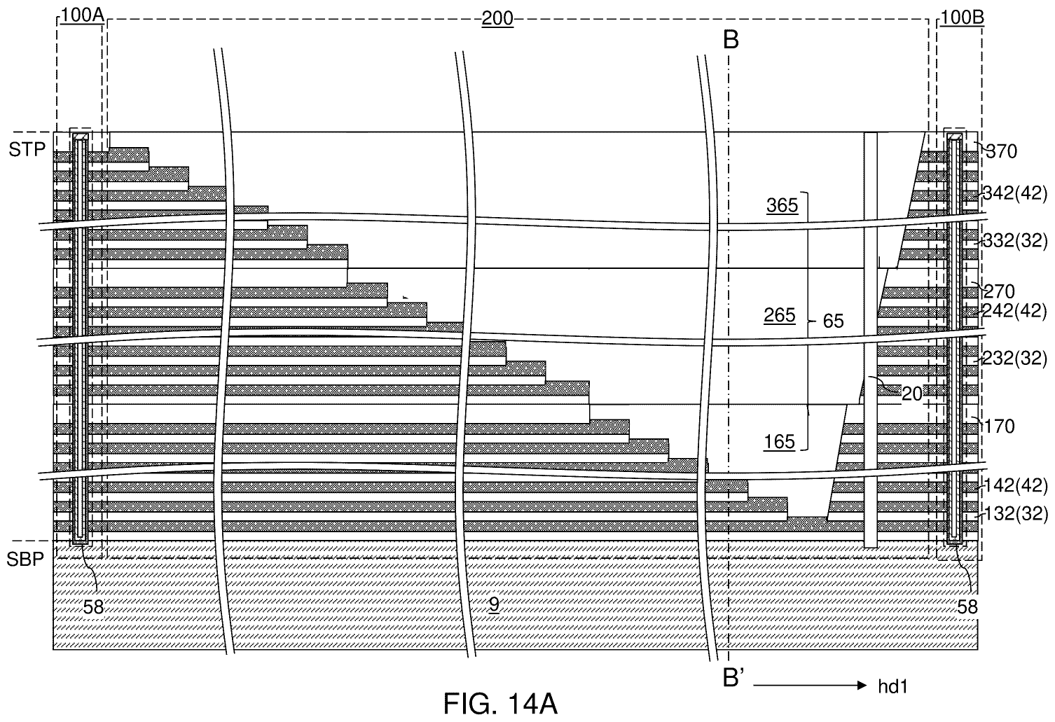

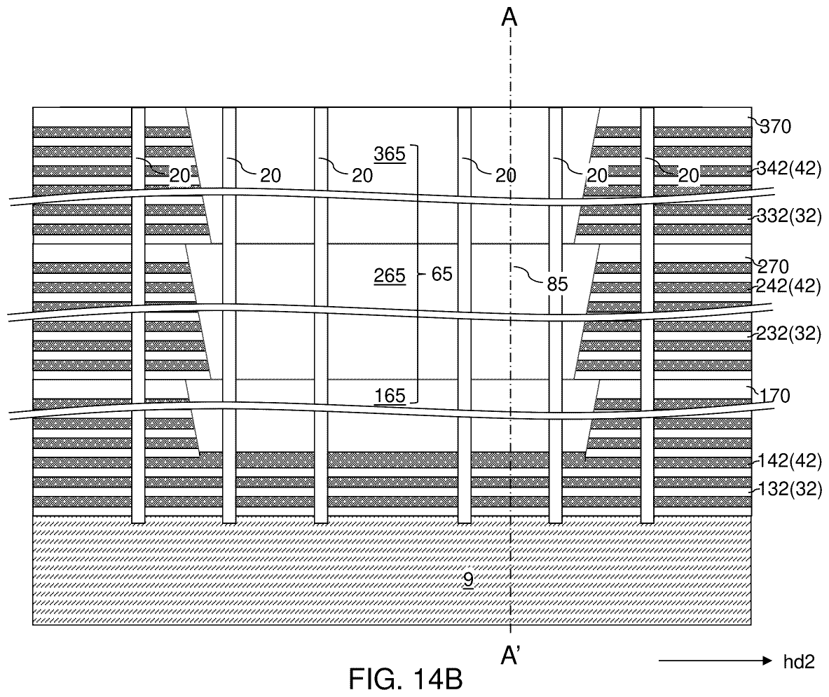

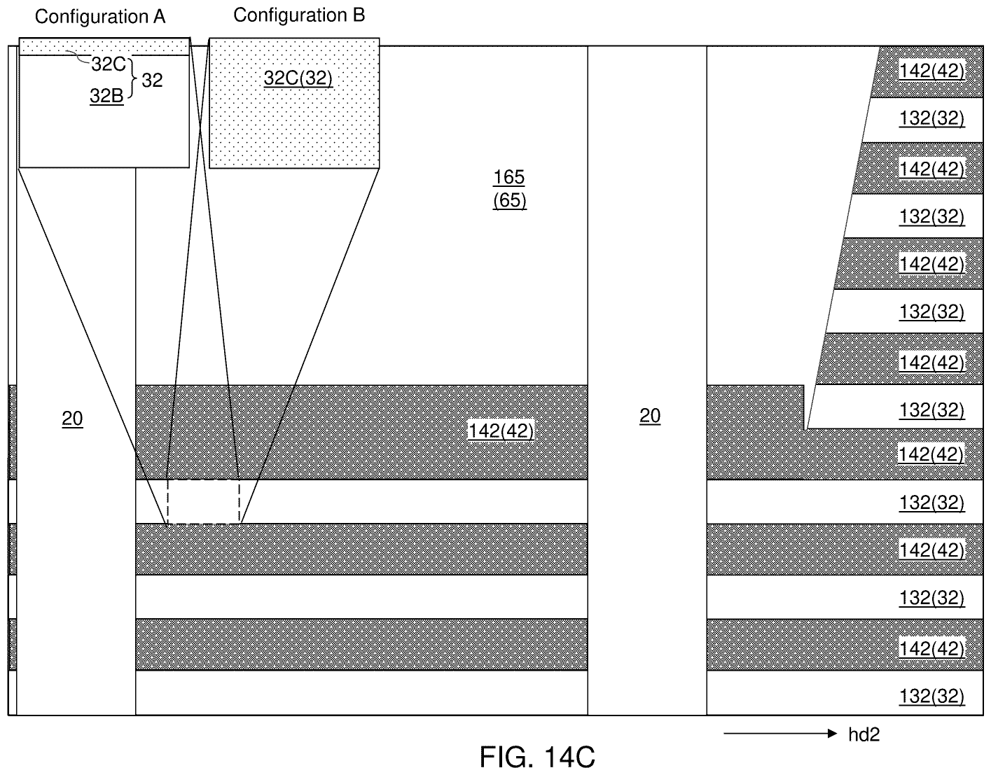

Referring to FIGS. 14A-14C, the first exemplary structure is illustrated after the processing steps of FIG. 13F, i.e., after formation of the memory opening fill structures 58 in the memory openings 49. In one embodiment, support pillar structures (not shown) may be formed in the support openings. Generally, each of the memory opening fill structures 58 comprises a respective vertical stack of memory elements located at levels of the electrically conductive layers 46 within the plurality of tier structures, and further comprises a respective vertical semiconductor channel 60 that vertically extends through the plurality of tier structures. The horizontal plane including a bottommost surface of the alternating stacks (32, 42) is herein referred to as a stack bottom plane SBP. The horizontal plane including the topmost surfaces of the memory opening fill structures 58 is herein referred to as a stack top plane STP. The topmost surfaces of the topmost retro-stepped dielectric material portions 65 (such as the top surfaces of the third-tier retro-stepped dielectric material portions 365) may be formed within the stack top plate STP. Each memory opening fill structure 58 vertically extends from below the stack bottom plane SBP including a bottommost surface of the at least one alternating stack (32, 42) to a stack top plane STP including the top surfaces of the memory opening fill structures 58.

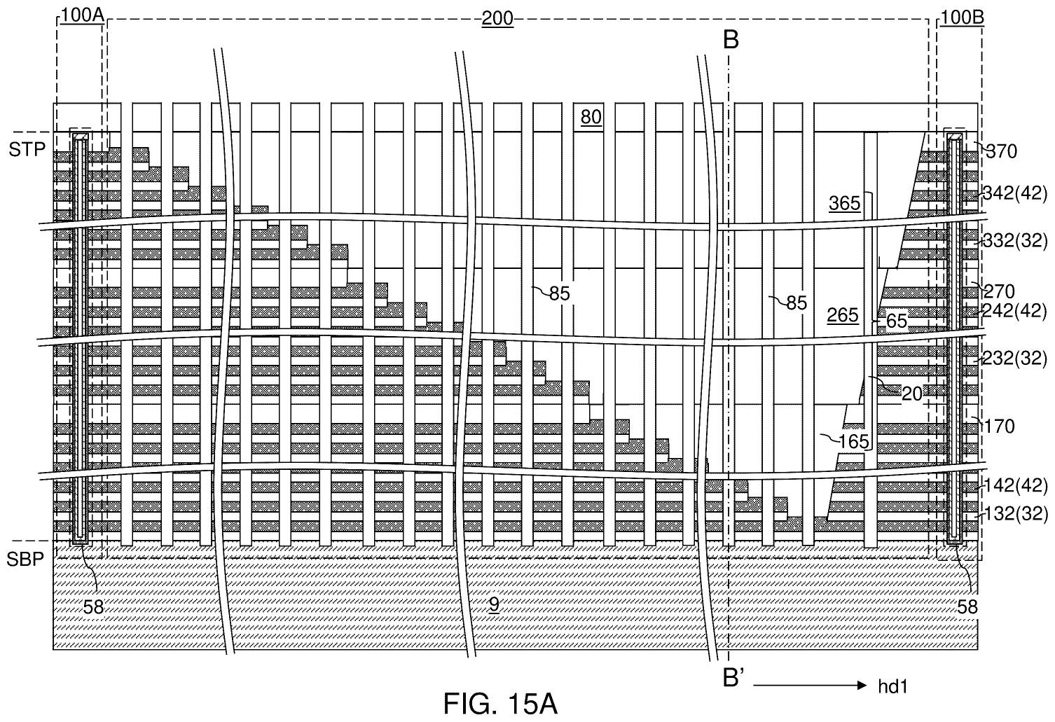

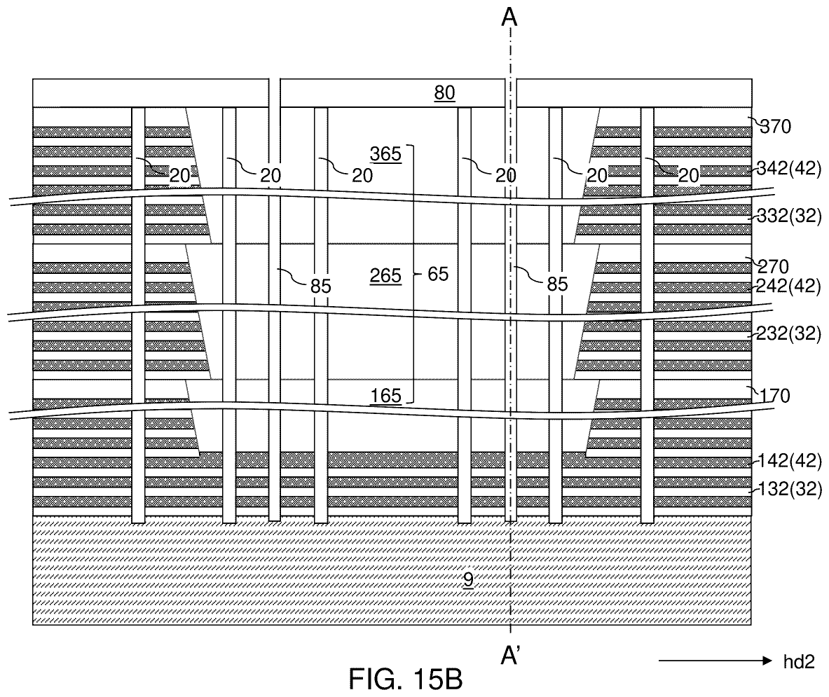

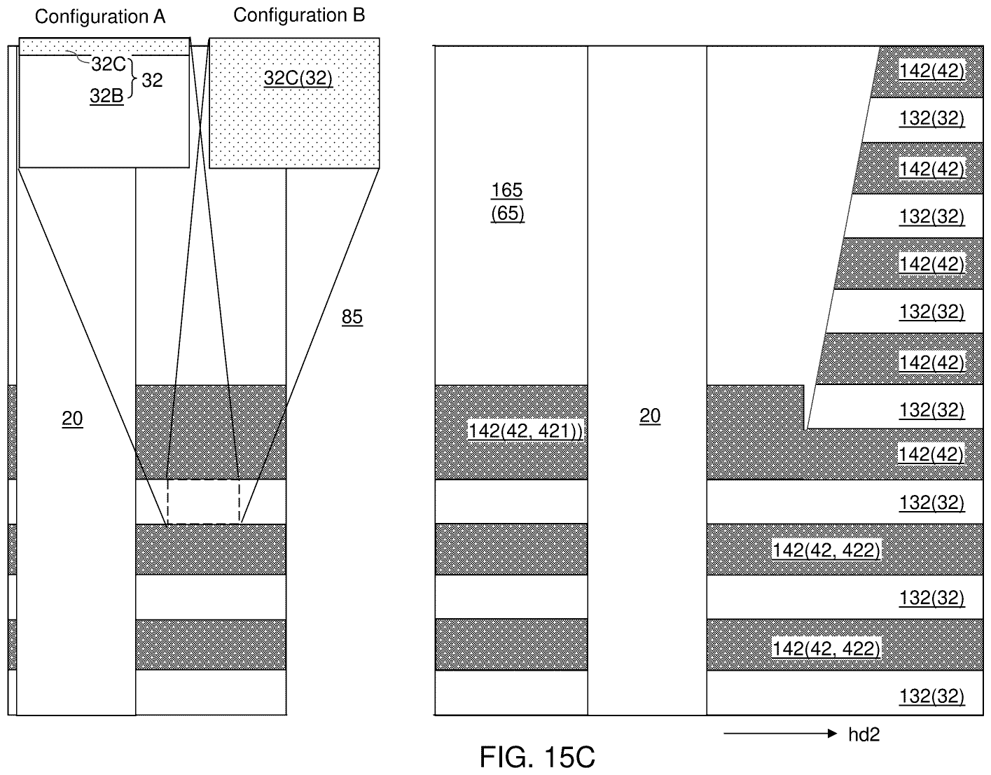

Referring to FIGS. 15A-15C, a contact-level dielectric layer 80 can be deposited over the third-tier insulating cap layer 370 and the third-tier retro-stepped dielectric material portions 365. The contact-level dielectric layer 80 comprises a dielectric material such as silicon oxide, and may have a thickness in a range from 100 nm to 800 nm, although lesser and greater thicknesses may also be employed.

A photoresist layer (not shown) can be applied over the contact-level dielectric layer, and can be lithographically patterned to cover the memory array regions 100 without covering the inter-array regions 200. The sacrificial fill materials of the sacrificial third-tier contact opening fill structures 368, the sacrificial second-tier contact opening fill structures 268, and the sacrificial first-tier contact opening fill structures 168 can be removed selectively to the materials of the retro-stepped dielectric material portions 65, the insulating layers 32, the sacrificial material layers 42, and the support pillar structures 20. Contact via cavities 85 are formed in the volumes from which the materials of the sacrificial third-tier contact opening fill structures 368, the sacrificial second-tier contact opening fill structures 268, and the sacrificial first-tier contact opening fill structures 168 are removed. Each contact via cavity 85 vertically extends from the horizontal plane including the planar top surfaces of the third-tier retro-stepped dielectric material portion 365 to the substrate 9. Each contact via cavity 85 may vertically extend through a respective set of at least one insulating layer 32 and a respective set of at least one sacrificial material layer 42 of an alternating stack of insulating layers 32 and sacrificial material layers 42. Each contact via cavity 85 vertically extends through a thickened portion of the topmost sacrificial material layer within the respective set of at least one sacrificial material layer 42.

For each contact via cavity 85 other than contact via cavities 85 that vertically extends through a bottommost first-tier sacrificial material layer 142, the contact via cavity 85 vertically extends through at least one retro-stepped dielectric material portion 65 and a subset of the sacrificial material layers 42 within the alternating stack (32, 46). In this case, the subset of the sacrificial material layers 42 comprises a first sacrificial material layer 421 which is a topmost sacrificial material layer 42 of the subset of the sacrificial material layers 42 and further comprises at least one second sacrificial material layer 422 (which may be a plurality of second sacrificial material layers 422) that underlie the first sacrificial material layer 421 as illustrated in FIG. 15C.

Generally, an alternating stack (32, 42) of insulating layers 32 and sacrificial material layers 42 can be formed over a substrate 9. Each of the insulating layers 32 comprises a respective carbon-doped silicate glass layer 32C. Stepped surfaces can be formed by patterning the alternating stack (32, 42) in a staircase region. Physically exposed portions of the sacrificial material layers 42 are locally thickened after formation of the stepped surfaces. A retro-stepped dielectric material portion 65 is formed over the stepped surfaces. Contact via cavities 85 can be formed through the retro-stepped dielectric material portion 65 and a respective subset of the sacrificial material layers 42 within the alternating stack (32, 42). For each contact via cavity 85 that vertically extends through a respective plurality of sacrificial material layers 42, the respective subset of the sacrificial material layers 42 comprises a first sacrificial material layer 421 which is a topmost sacrificial material layer 42 of the respective subset of the sacrificial material layers 42 and further comprises at least one second sacrificial material layer 422 that underlies the first sacrificial material layer 421. One of the contact via cavities 85 may vertically extend only through the bottommost sacrificial material layer 42. Each contact via cavity 85 may be formed through a locally thickened portion of a respective first sacrificial material layer 421.

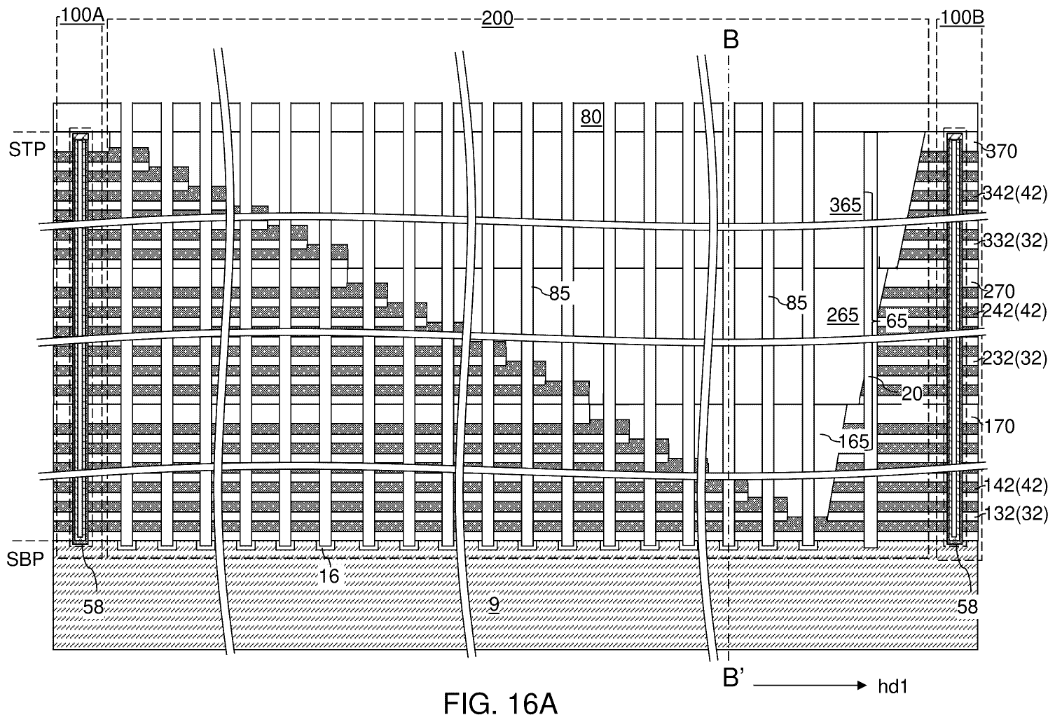

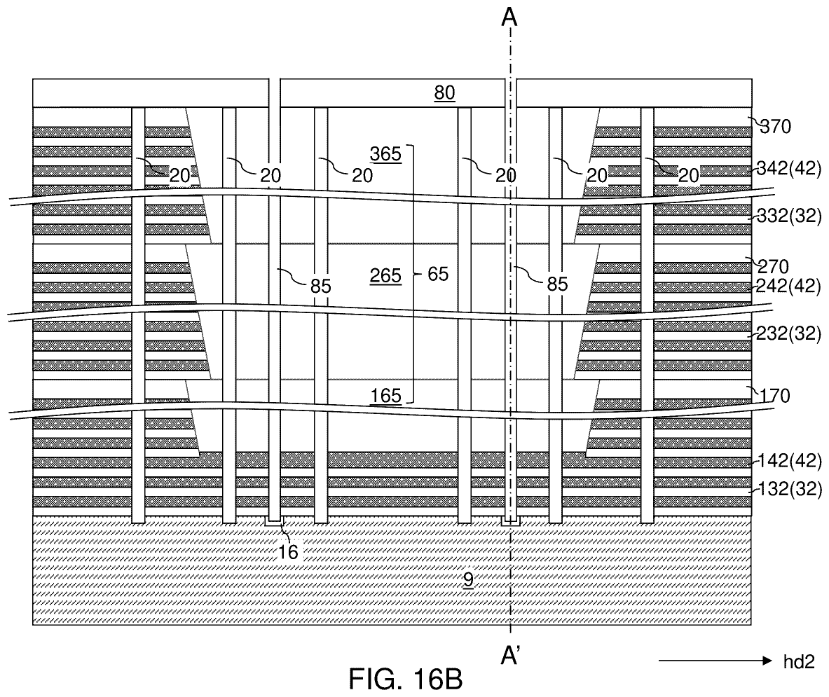

Referring to FIGS. 16A and 16B, if the substrate 9 comprises a semiconductor material such as silicon, an oxidation process may be performed to convert physically exposed surface portions of the substrate 9 underneath the contact via cavities 85 into semiconductor oxide (e.g., silicon oxide) spacer liners 16. The thickness of the semiconductor oxide spacer liners 16 may be in a range from 3 nm to 8 nm, although lesser and greater thicknesses may also be employed. In one embodiment, collateral oxidation of the physically exposed surfaces of the sacrificial material layers 42 may be minimized by reducing the thickness of the semiconductor oxide spacer liners 16.

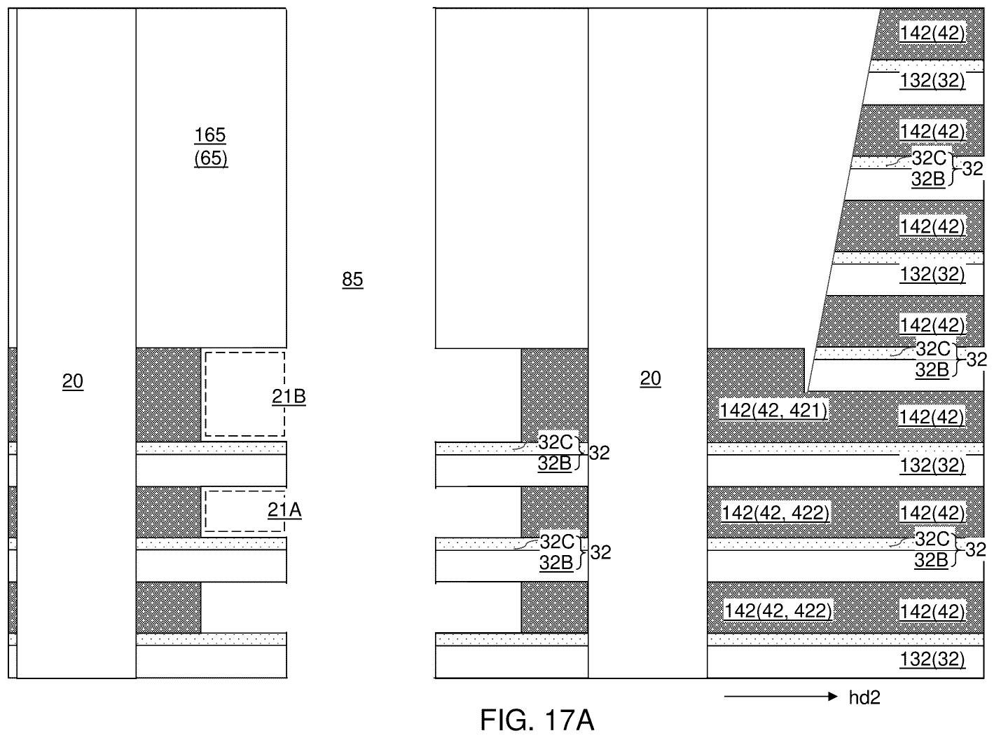

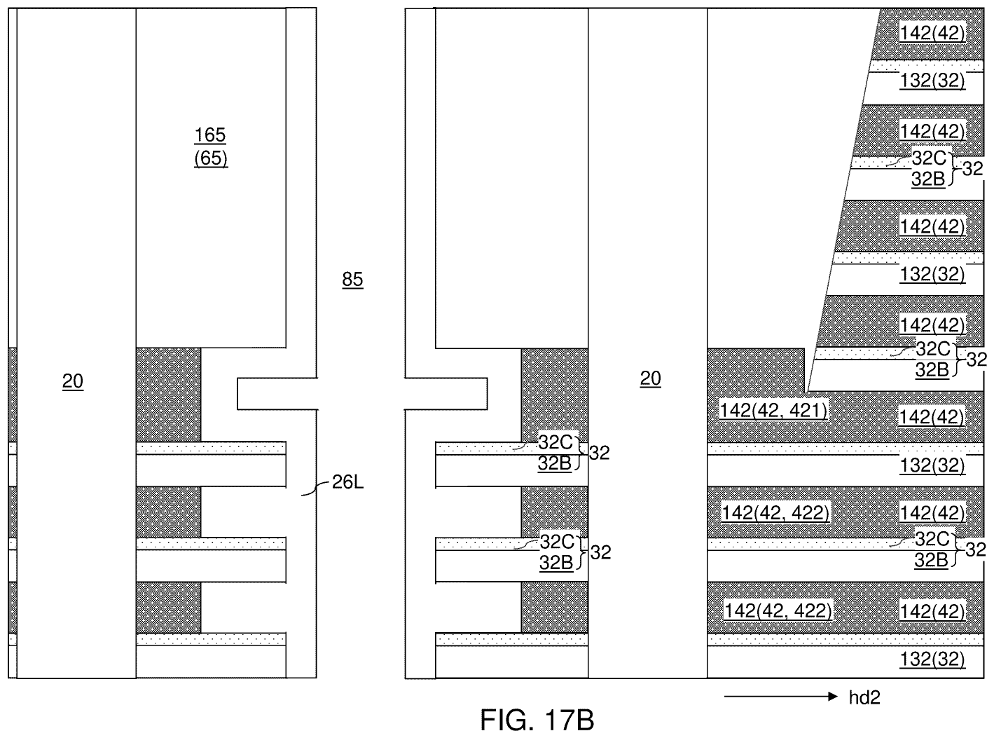

Referring to FIG. 17A, a first isotropic etch process can be performed to isotropically etch proximal portions of the sacrificial material layers 42 around each contact via cavity 85 selectively to the insulating layers 32 and the at least one retro-stepped dielectric material portion 65. For example, if the sacrificial material layers 42 comprise silicon nitride and if the at least one retro-stepped dielectric material portion 65 comprises silicon oxide, the first isotropic etch process may comprise a wet etch process employing hot phosphoric acid which etches silicon nitride selectively to silicon oxide materials. The duration of the first isotropic etch process can be selected such that the lateral recess distance of the first isotropic recess etch process is in a range from 100% to 1,000%, such as from 200% to 500%, of the thickness of unthickened portions of the sacrificial material layers 42. For each contact via cavity 85 that vertically extends through a plurality of sacrificial material layers 42, at least one first annular recess region 21A may be formed in volumes from which material portions of at least one second sacrificial material layer 422 are removed selectively to the insulating layers 32. For each contact via cavity 85, a second annular recess region 21B can be formed by isotropically etching a proximal portion of the respective first sacrificial material layer 421 selectively to the insulating layers 32. The carbon-doped silicate glass layer 32C prevents or reduces over etching of the insulating layers 32, and thus decreases a probability that the second annular recess region 21B is unintentionally merged with the underlying first annular recess region 21A. In other words, the carbon-doped silicate glass layer 32C ensures that a sufficient insulating layer 32 thickness is maintained after the etch process.

Referring to FIG. 17B, a recess-fill dielectric material layer 26L can be formed by conformally depositing a recess-fill dielectric material, such as silicon oxide, in the first annular recess regions 21A and the second annular recess regions 21B, and over sidewalls of the contact via cavities 85. In one embodiment, the recess-fill dielectric material layer 26L may have the same material composition as the base silicate glass layers 32B (if the first configuration is employed), and/or may comprise a carbon-free silicate glass material (such as undoped silicate glass). The thickness of the recess-fill dielectric material layer 26L can be greater than one half of the thickness of the unthickened portions of the sacrificial material layers 42, and can be less than one half of the thickness of the thickened portions of the sacrificial material layers 42. Thus, each first annular recess region 21A is completely filled with the recess-fill dielectric material layer 26L, while each second annular recess region 21B is only partly filled by the recess-fill dielectric material layer 26L.

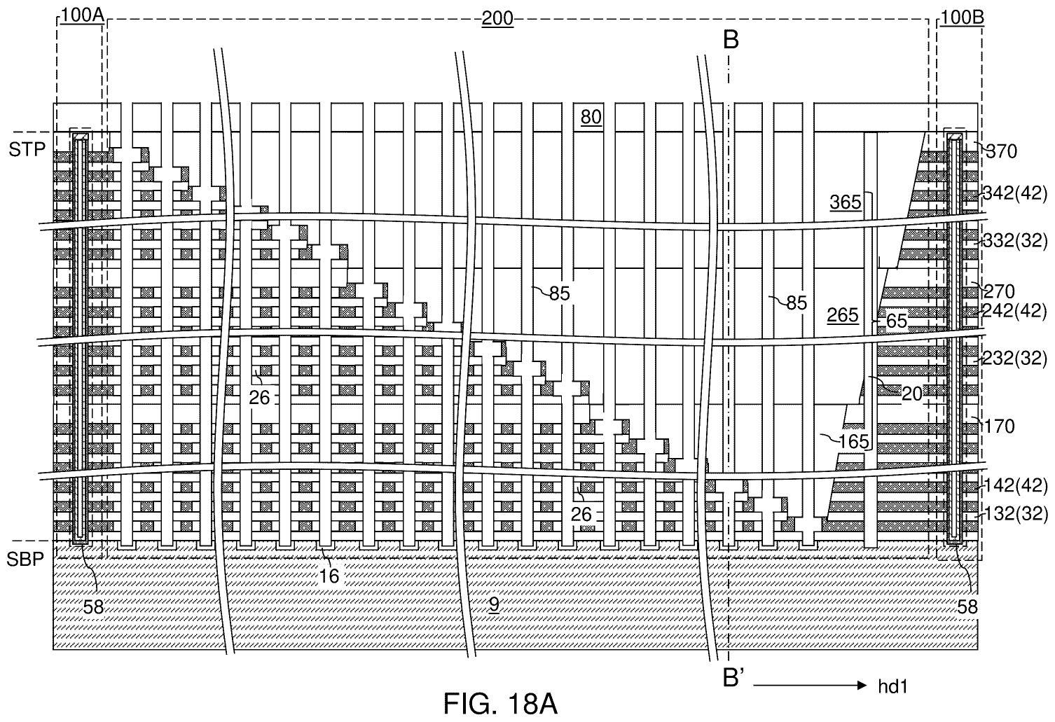

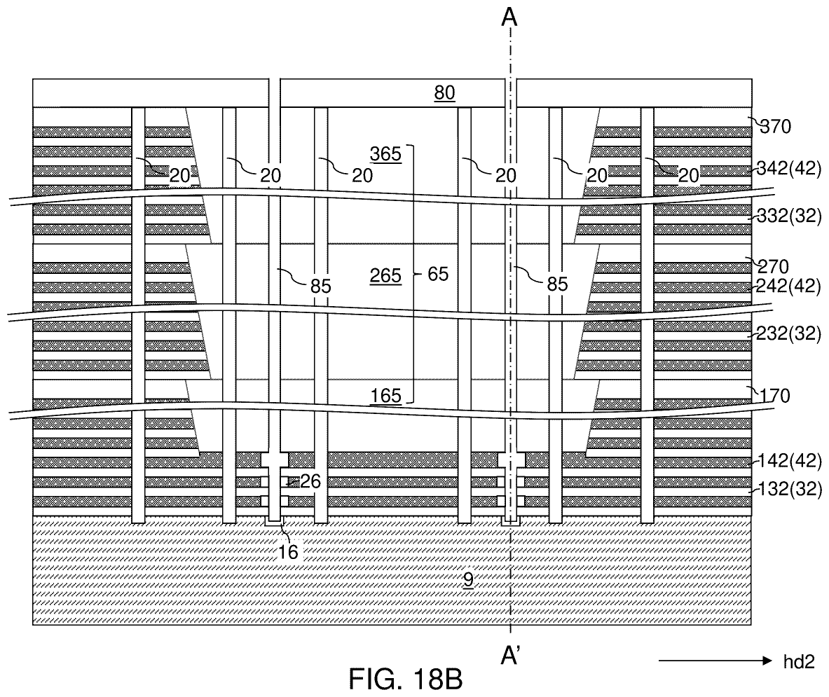

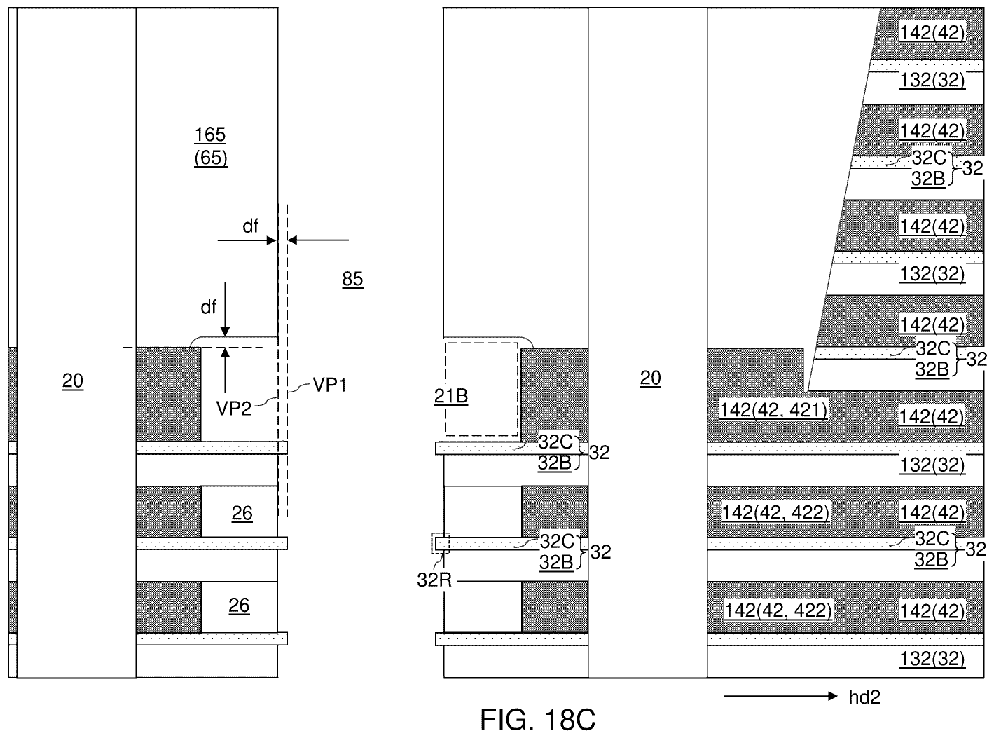

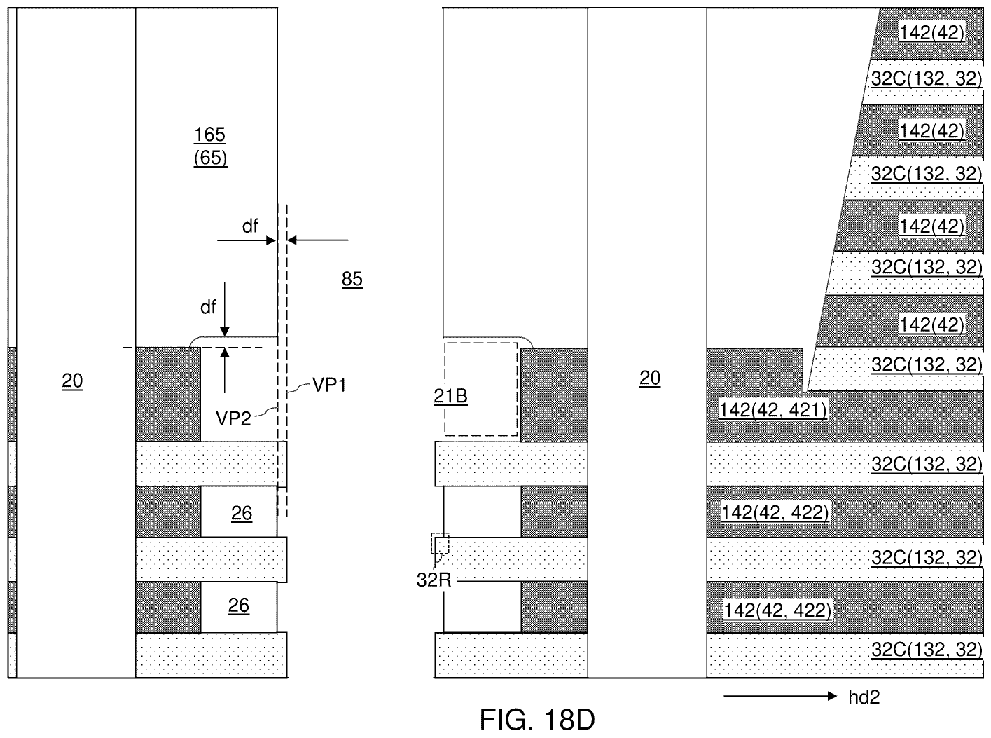

Referring to FIGS. 18A-18D, a second isotropic etch process can be performed to isotropically etch the material of the recess-fill dielectric material layer 26L. FIG. 18C illustrates the first configuration, and FIG. 18D illustrates the second configuration. For example, the second isotropic etch process may comprise a wet etch process employing dilute hydrofluoric acid, such as 100:1 dilute hydrofluoric acid which etches undoped silicate glass at a higher etch than the carbon-doped silicate glass. According to an aspect of the present disclosure, the duration of the second isotropic etch process can be selected to ensure removal of the entirety of each portion of the recess-fill dielectric material layer 26L that fills the second annular recess regions 21B of the contact via cavities 85. In one embodiment, the duration of the second isotropic etch process can be selected such that the recess etch distance of the second isotropic etch process for the material of the recess-fill dielectric material layer 26L is in a range from 105% to 150%, such as from 100% to 130%, of the thickness of the recess-fill dielectric material layer 26L. The recess-fill dielectric material layer 26L is entirely removed from each second annular recess region 21B.

The second isotropic etch process removes the recess-fill dielectric material layer 26L from an entire volume of each second annular recess region 21B. Each remaining portion of the recess-fill dielectric material layer 26L that fills a respective one of the first annular recess regions 21A comprises an annular dielectric spacer 26. Each first annular recess region 21A can be filled with a respective annular dielectric spacer 26. The second isotropic etch process etches the material of the recess-fill dielectric material layer 26L and the material of each retro-stepped dielectric material portion 65 at a higher etch rate than the material of the carbon-doped silicate glass layers 32C. The carbon-doped silicate glass layer 32C ensures that a sufficient insulating layer 32 thickness is maintained under the second annular recess region 21B after the etch process.

In one embodiment, the sidewall of the opening in each carbon-doped silicate glass layer 32C around a contact via cavity 85 may be formed within a respective first cylindrical vertical plane VP1. In one embodiment, the inner sidewall of each annular dielectric spacer 26 that laterally surrounds the contact via cavity 85 may be formed within a respective second cylindrical vertical plane VP2. The offset distance df between the first cylindrical vertical plane VP1 and the second cylindrical vertical plane VP2 corresponds to the recess etch distance for the material of the recess-fill dielectric material layer 26L caused by a terminal portion of the second isotropic etch process that is performed after recessing the material of the recess-fill dielectric material layer 26L by the thickness of the recess-fill dielectric material layer 26L. In one embodiment, the offset distance “df” may be in a range from 2.5% to 25%, such as from 5% to 15%, of the thickness of each insulating layer 32.

In the first configuration illustrated in FIG. 18C, each of the insulating layers 32 comprises a respective base silicate glass layer 32B and a carbon-doped silicate glass layer 32C. The second isotropic etch process etches the base silicate glass layer 32B at a higher etch rate than the carbon-doped silicate glass layers 32C. In this case, the sidewall of each base silicate glass layer 32B around a contact via cavity 85 may be laterally recessed outward from a respective first cylindrical vertical plane VP1 by the offset distance df. Likewise, each sidewall of the at least one retro-stepped dielectric material portion 65 around a respective contact via cavity 85 can be laterally recessed by the offset distance df. In one embodiment, sidewalls of each annular dielectric spacer 26 around a contact via cavity 85, sidewalls of each base silicate glass layer 32B around the contact via cavity 85, and each sidewall of the at least one retro-stepped dielectric material portion 65 around the contact via cavity 85 can be formed within the second cylindrical vertical plane VP2. Further, each physically exposed annular bottom surface segment of the at least one retro-stepped dielectric material portion 65 can be vertically recessed by the offset distance df.

In the second configuration illustrated in FIG. 18D, each of the carbon-doped silicate glass layers 32C except the bottommost carbon-doped silicate glass layer 32C contacts a top surface of a respective underlying sacrificial material layers 42 and contacts a bottom surface of a respective overlying sacrificial material layers 42. In this case, each sidewall of the at least one retro-stepped dielectric material portion 65 around a respective contact via cavity 85 can be laterally recessed by the offset distance df. In one embodiment, sidewalls of each annular dielectric spacer 26 around a contact via cavity 85 and each sidewall of the at least one retro-stepped dielectric material portion 65 around the contact via cavity 85 can be formed within the second cylindrical vertical plane VP2. Further, each physically exposed annular bottom surface segment of the at least one retro-stepped dielectric material portion 65 can be vertically recessed by the offset distance df.

For each contact via cavity 85 that vertically extends through three or more sacrificial material layers 42, a vertical stack of annular dielectric spacers 26 can be formed around the contact via cavity 85. In one embodiment, each annular dielectric spacer 26 within the vertical stack of annular dielectric spacers 26 is in contact with an annular top surface of a respective carbon-doped silicate glass layer 32C. Each portion of the carbon-doped silicate glass layers 32C that protrudes inside a second cylindrical vertical plane VP2 is herein referred to as an annular rim portion 32R of a respective carbon-doped silicate glass layer 32C.

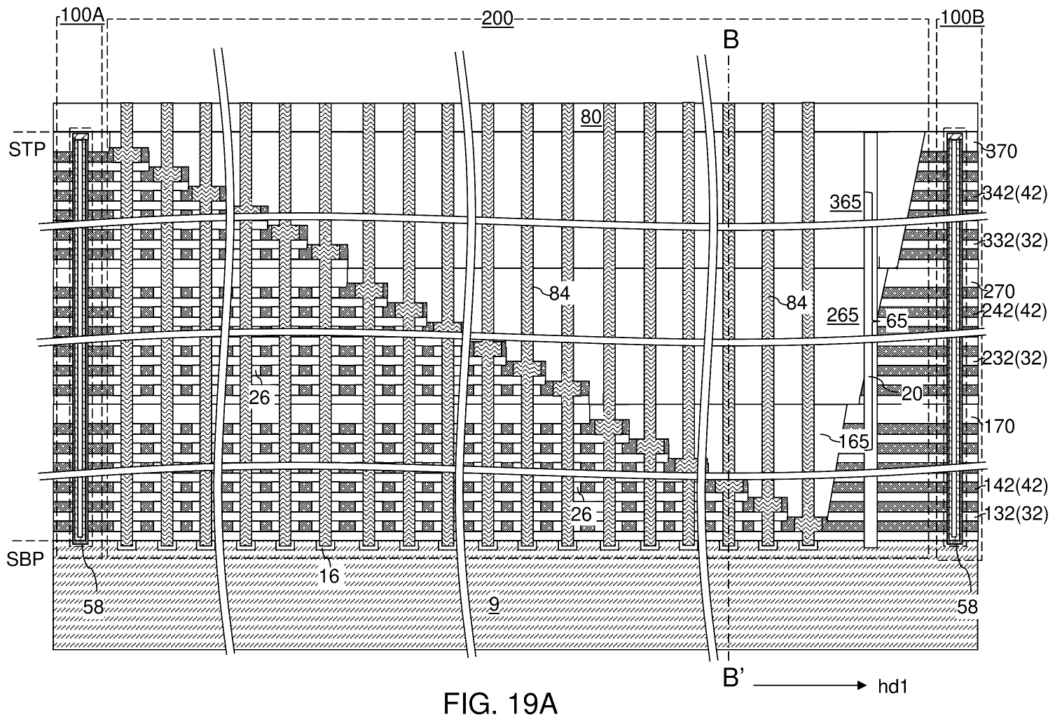

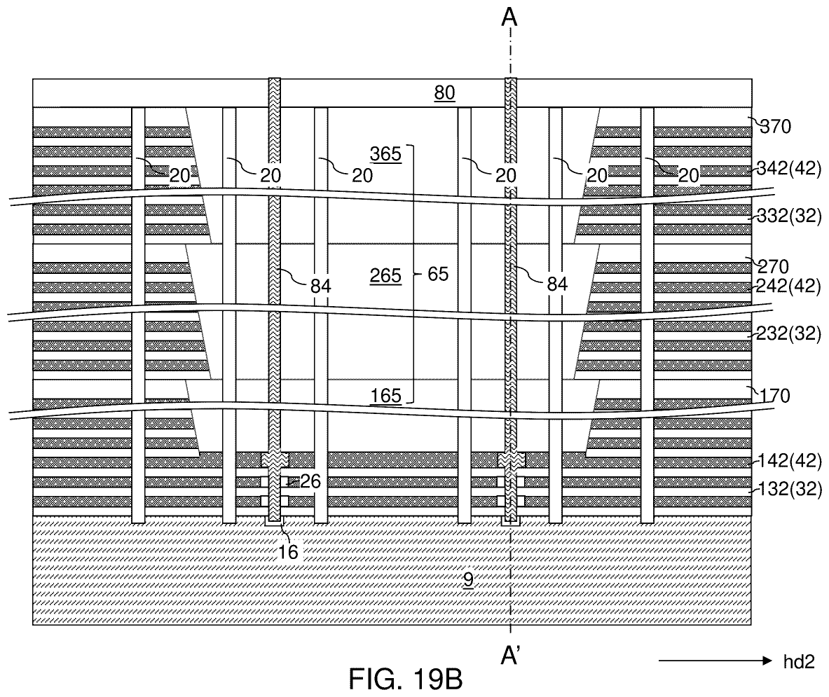

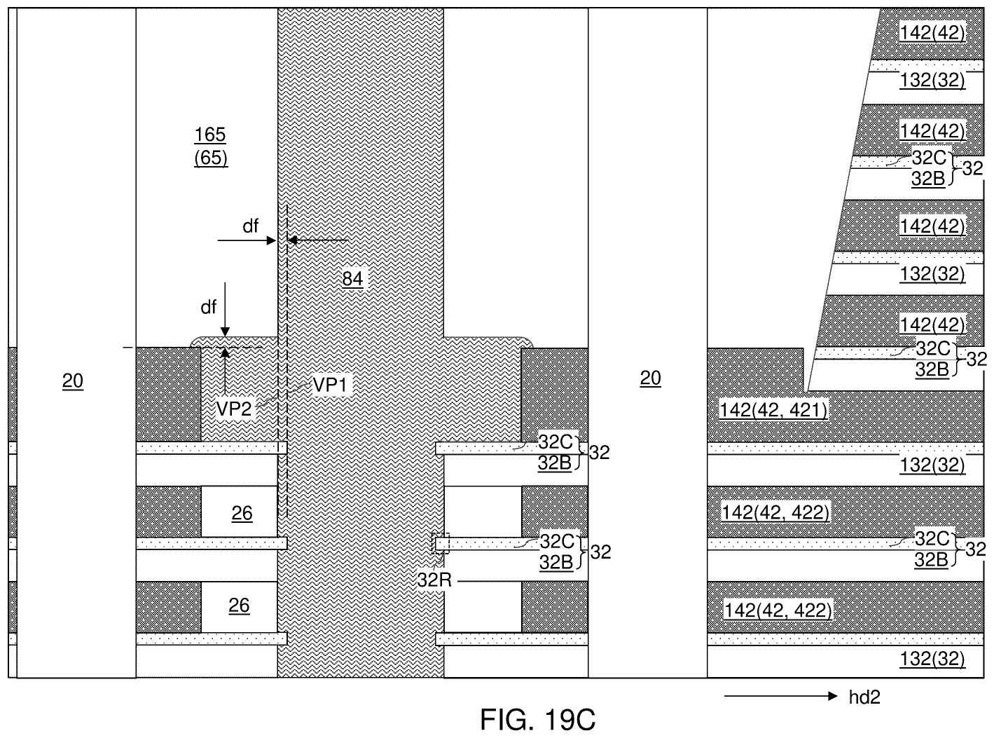

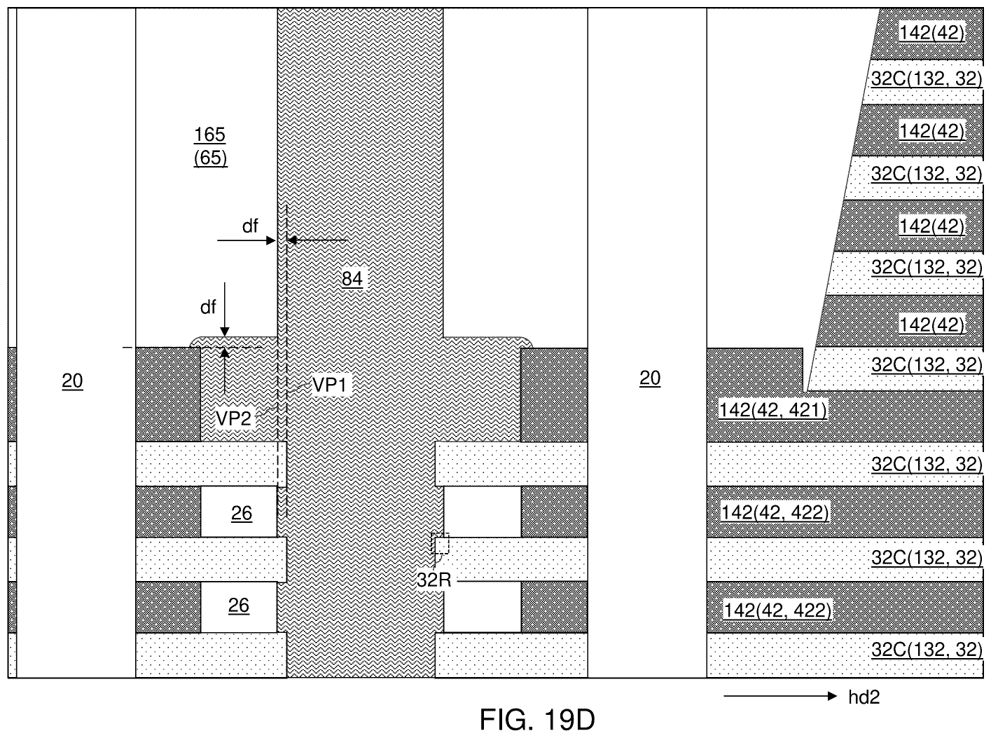

Referring to FIGS. 19A-19D, the first exemplary structure is illustrated after formation of sacrificial contact via structures 84. FIG. 19C illustrates the first configuration, and FIG. 19D illustrates the second configuration. Specifically, a sacrificial via fill material can be deposited in the contact via cavities 85, and excess portions of the sacrificial via fill material can be removed from above the horizontal plane including the top surface of the contact-level dielectric layer 80. The sacrificial via fill material may comprise a semiconductor material, such as amorphous silicon or polysilicon, or may comprise a carbon-based material such as amorphous carbon. Each remaining portion of the sacrificial via fill material that fills a contact via cavity 85 comprises a sacrificial contact via structure 84. Each sacrificial contact via structure 84 may comprise a respective cylindrical portion and a respective laterally bulging portion that contacts a sidewall of an opening in a thickened portion of a respective first sacrificial material layer 421.

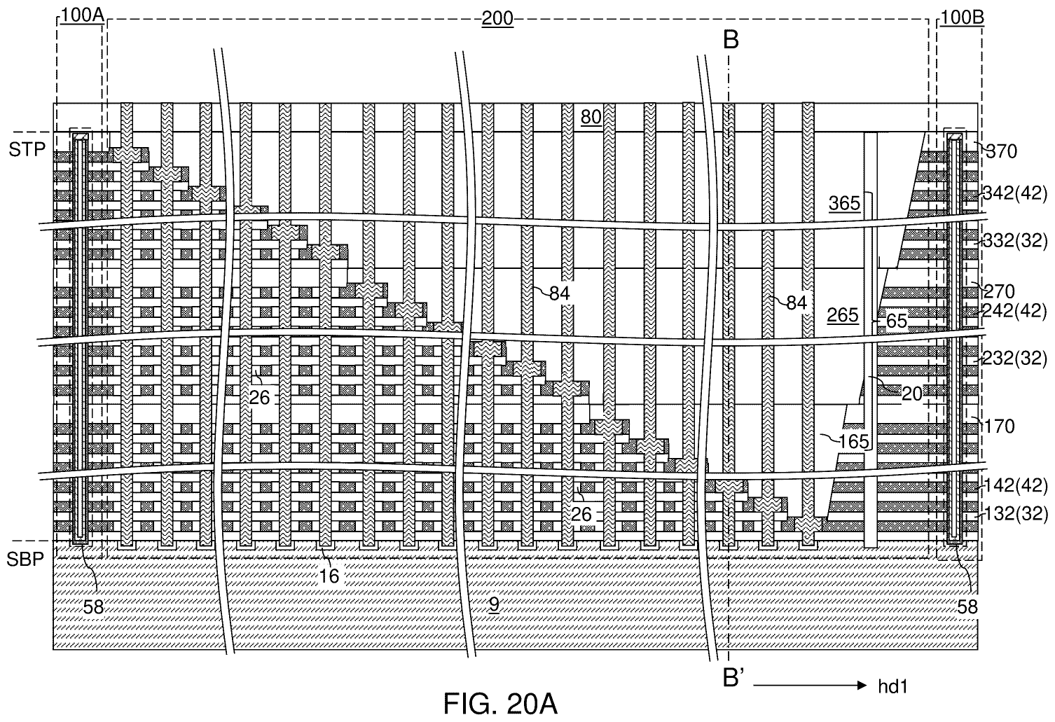

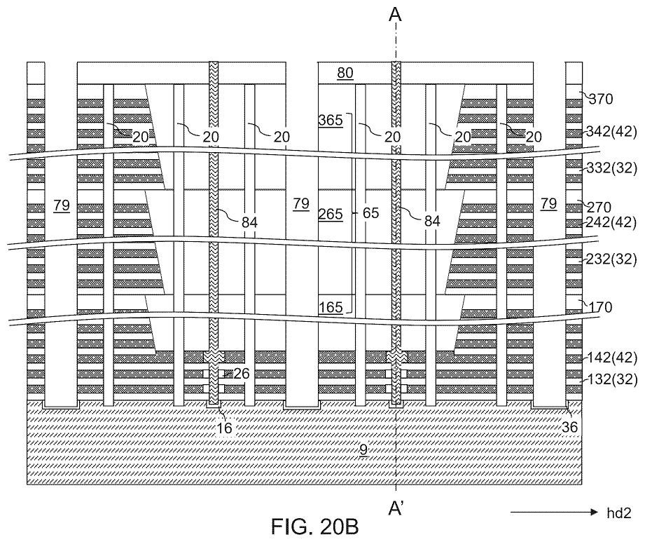

Referring to FIGS. 20A and 20B, a photoresist layer (not shown) can be applied over the contact-level dielectric layer 80, and can be lithographically patterned to form elongated rectangular openings that laterally extend along the first horizontal direction hd1. The pattern of the elongated rectangular openings can be the same as the pattern of the lateral isolation trench fill structures 76 illustrated in FIG. 1B. An anisotropic etch process can be performed to transfer the pattern of the elongated openings in the photoresist layer through the contact-level dielectric layer 80, the various insulating cap layers (170, 270, 370), and alternating stacks (32, 42). Lateral isolation trenches 79 can be formed in the volumes from which the materials of the contact-level dielectric layer 80, the various insulating cap layers (170, 270, 370), and alternating stacks (32, 42) are removed. Optionally, an oxidation process may be performed to convert physically exposed surface portions of the substrate 9 into semiconductor oxide trench liners 36.

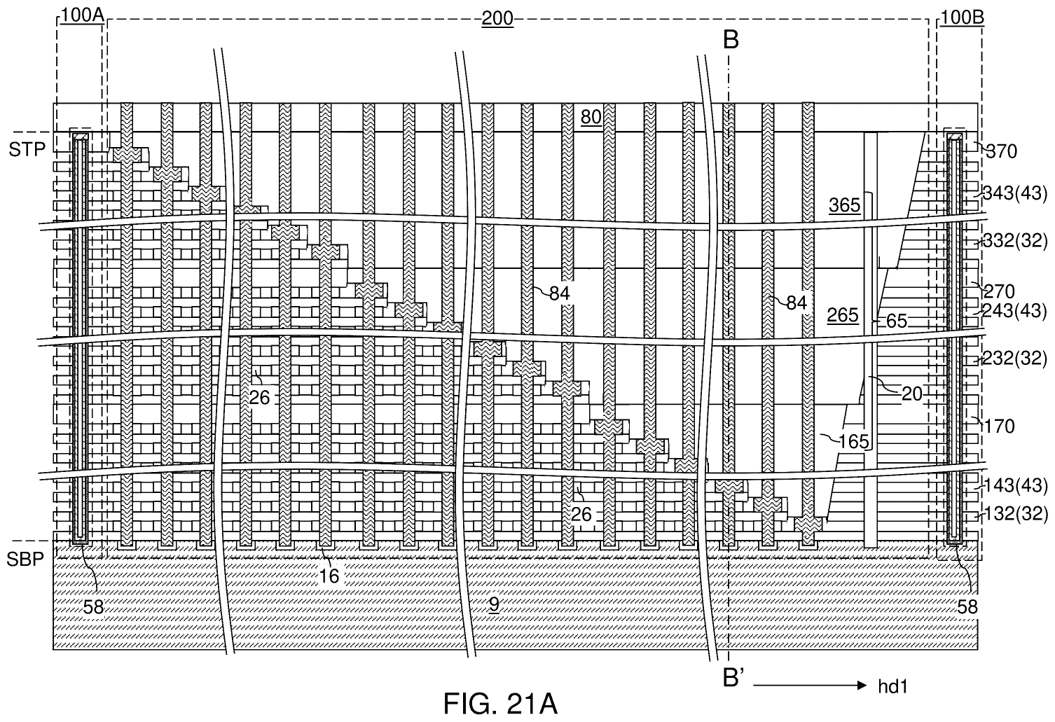

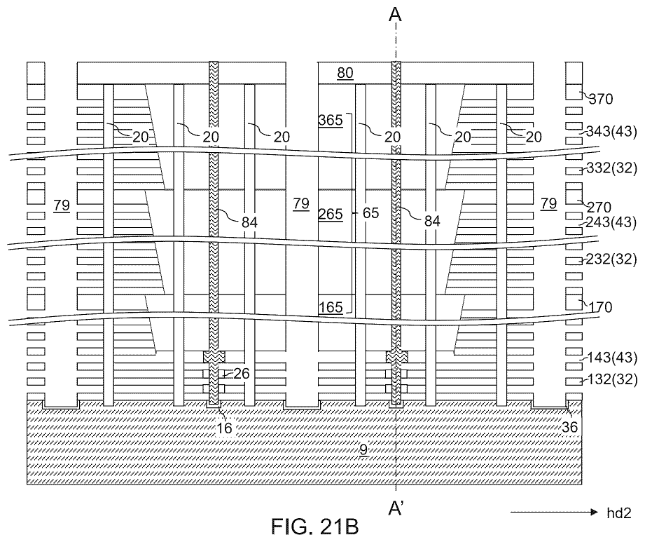

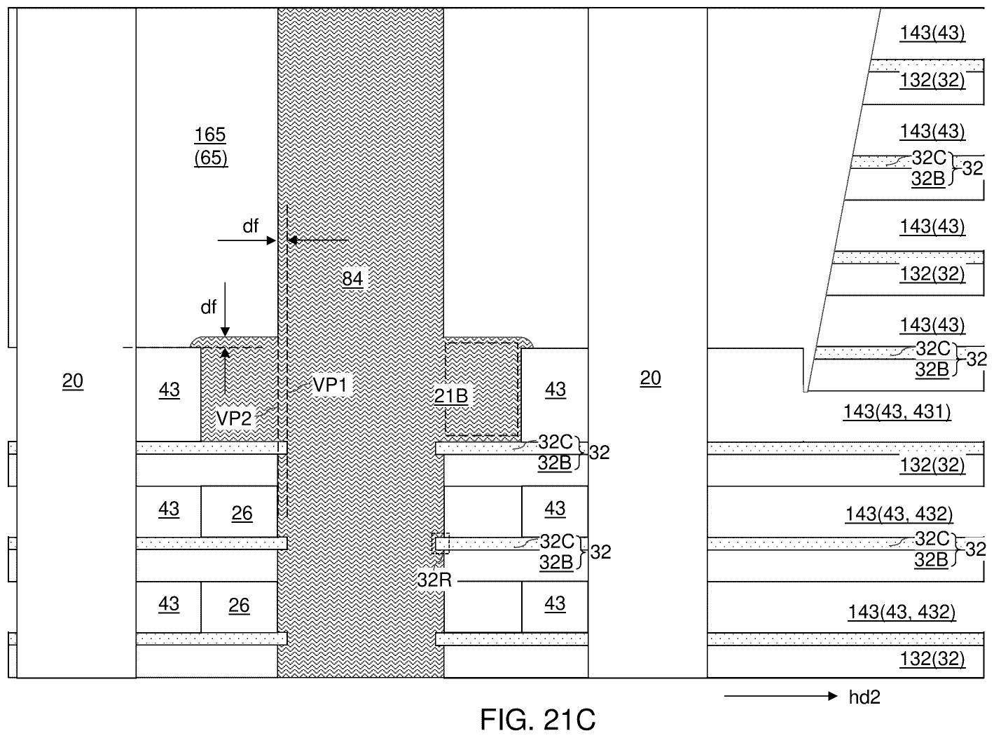

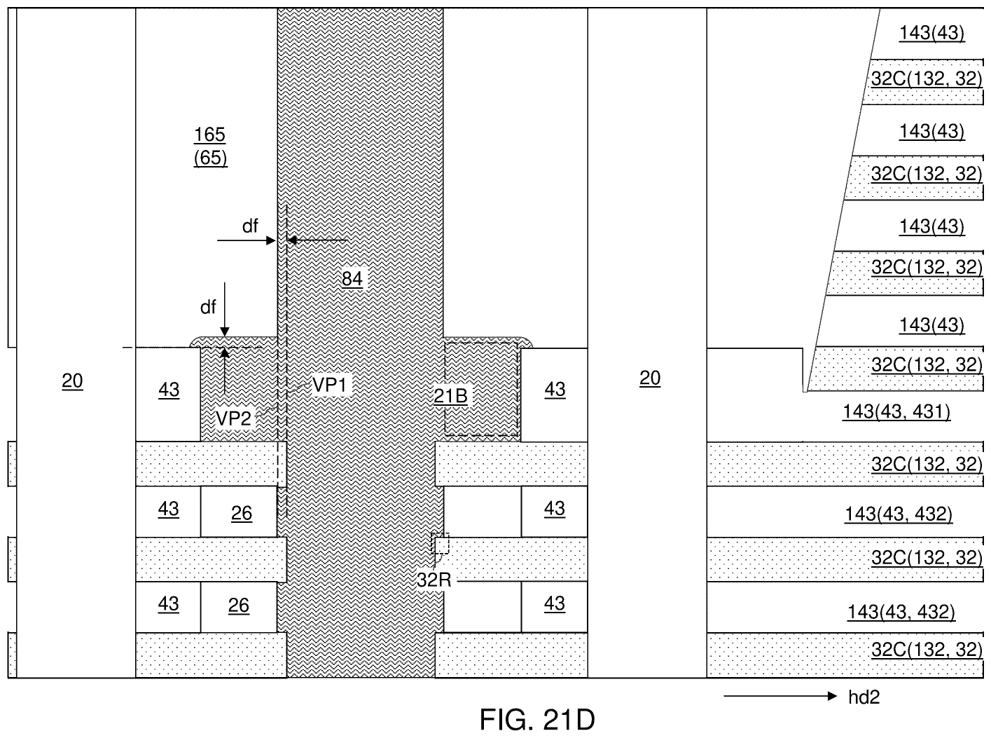

Referring to FIGS. 21A-21D, lateral recesses 43 can be formed by selective removal of the sacrificial material layers 42. FIG. 21C illustrates the first configuration, and FIG. 21D illustrates the second configuration. Specifically, the sacrificial material layers 42 may be isotropically etched selectively to the insulating layers 32, the annular dielectric spacers 26, and the retro-stepped dielectric material portions 65 by supplying an isotropic etchant into the lateral isolation trenches 79. In one embodiment, an etchant that selectively etches the materials of the sacrificial material layers 42 with respect to the materials of the insulating layers 32, the annular dielectric spacers 26, the retro-stepped dielectric material portions (165, 265, 365), and the material of the outermost layer of the memory films 50 may be introduced into the lateral isolation trenches, for example, using an isotropic etch process.

The isotropic etch process may be a wet etch process using a wet etch solution, or may be a gas phase (dry) etch process in which the etchant is introduced in a vapor phase into the lateral isolation trench. For example, if the sacrificial material layers 42 comprise silicon nitride, and if the insulating layers 32, the retro-stepped dielectric material portions (165, 265, 365), and the outermost layer of the memory films 50 comprise silicon oxide materials, the etch process may comprise a wet etch tank employing hot phosphoric acid, which etches silicon nitride selectively to silicon oxide, silicon, and various other materials used in the art.

Lateral recesses 43 are formed in volumes from which the sacrificial material layers 42 are removed. The lateral recesses 43 include first lateral recesses 143 that are formed in volumes from which the first-tier sacrificial material layers 142 are removed, second lateral recesses 243 that are formed in volumes from which the second-tier sacrificial material layers 242 are removed, and third lateral recesses 343 that are formed in volumes from which the third-tier sacrificial material layers 342 are removed. Each of the lateral recesses 43 may be a laterally extending cavity having a greater lateral dimension that is greater than a vertical extent. In other words, the lateral dimension of each of the lateral recesses 43 may be greater than the height of the respective lateral recess. A plurality of lateral recesses 43 may be formed in the volumes from which the material of the sacrificial material layers 42 is removed. Each of the lateral recesses 43 may extend substantially parallel to the top surface of the substrate 9. A lateral recess 43 may be vertically bounded by a top surface of an underlying insulating layer 32 and a bottom surface of an overlying insulating layer 32.

For each sacrificial contact via structure 84, a respective subset of at least one lateral recess 43 is provided, which laterally surrounds the sacrificial contact via structure 84. Within the respective subset of at least one lateral recess 43, a topmost lateral recess 43 is herein referred to as a first lateral recess 431, and any underlying lateral recess 43 is herein referred to as a second lateral recess 432.

Referring to FIG. 22, an outer blocking dielectric layer 44 may be conformally deposited in peripheral portions of the lateral recesses 43, the contact via cavities 85, and the lateral isolation trenches 79. The outer blocking dielectric layer 44 includes a dielectric material, such as a dielectric metal oxide (e.g., aluminum oxide), silicon oxide, or a combination thereof. The outer blocking dielectric layer 44 may be formed as a continuous material layer having a uniform thickness throughout by a conformal deposition process such as an atomic layer deposition process and/or a chemical vapor deposition process. The thickness of the outer blocking dielectric layer 44 may be in a range from 2 nm to 10 nm, such as from 3 nm to 8 nm, although lesser and greater thicknesses may also be employed.

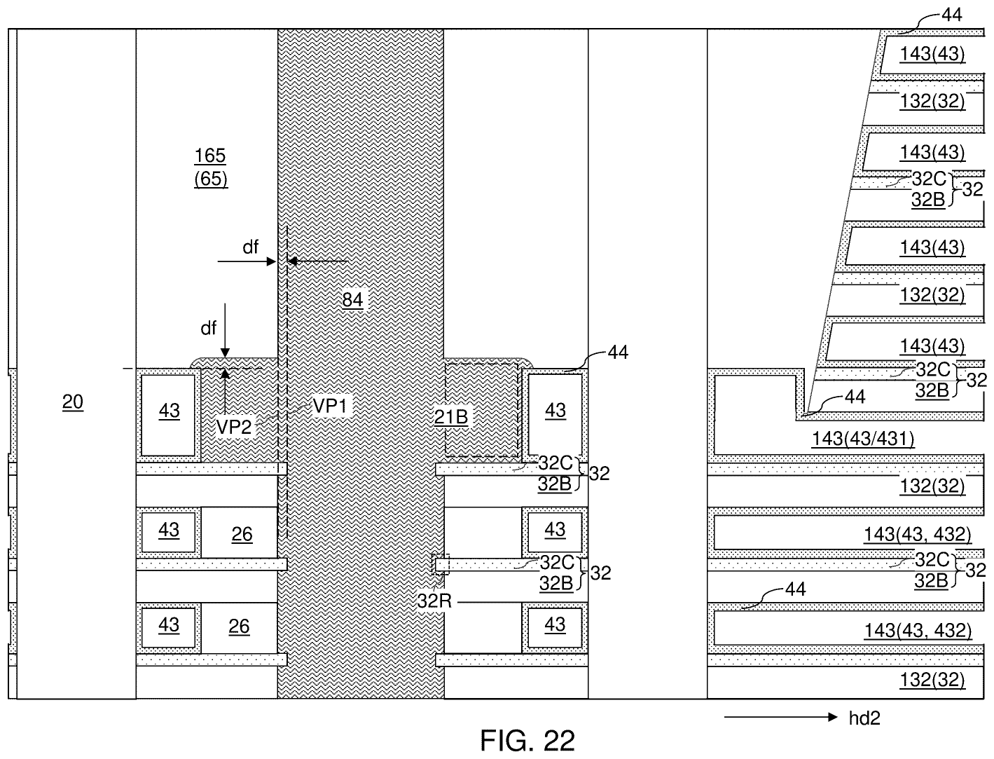

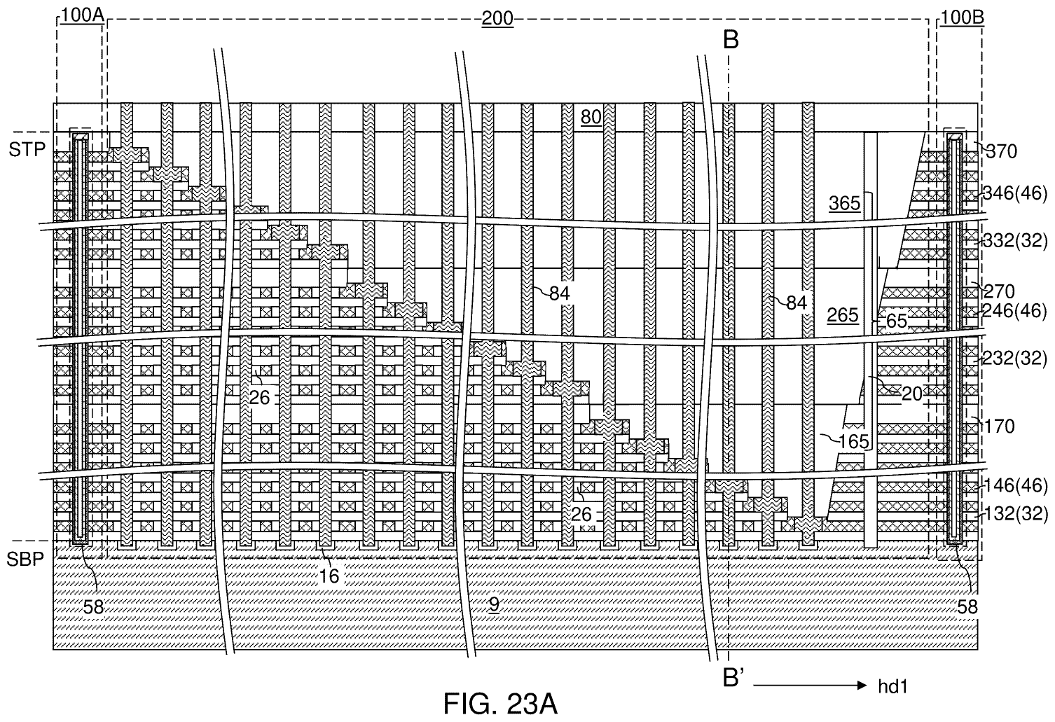

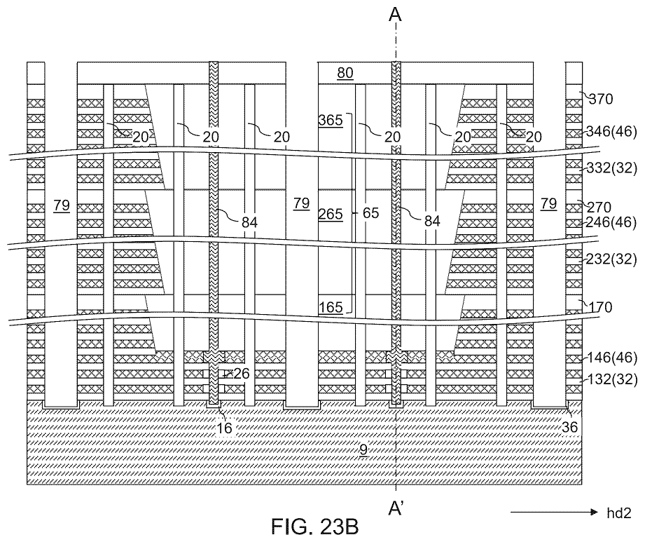

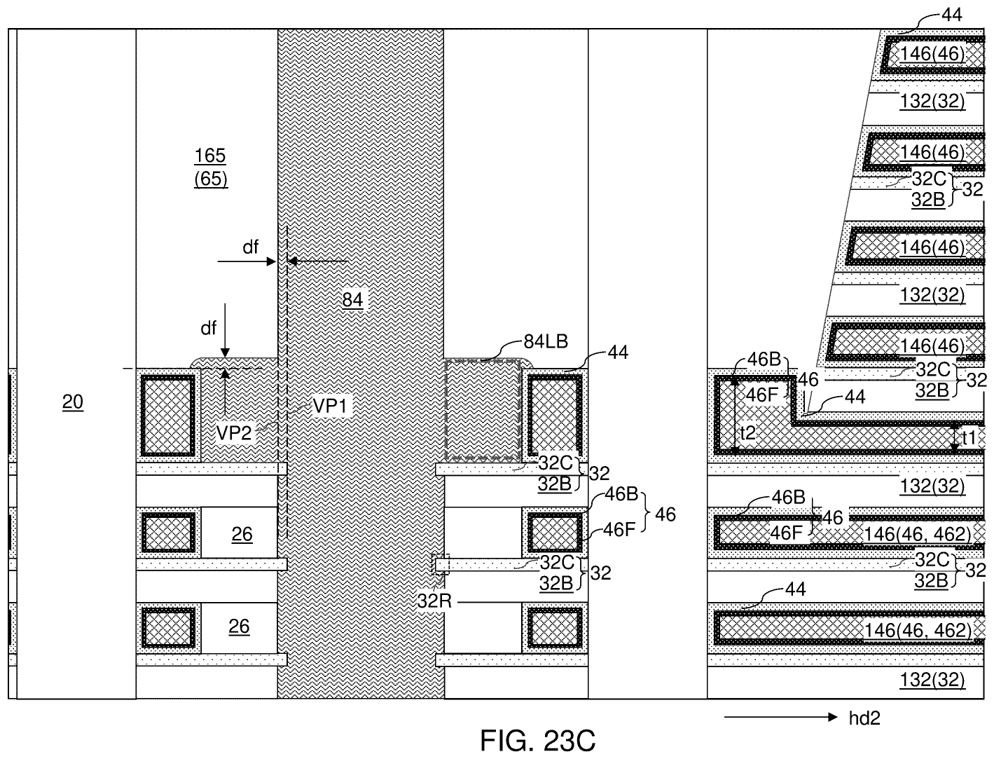

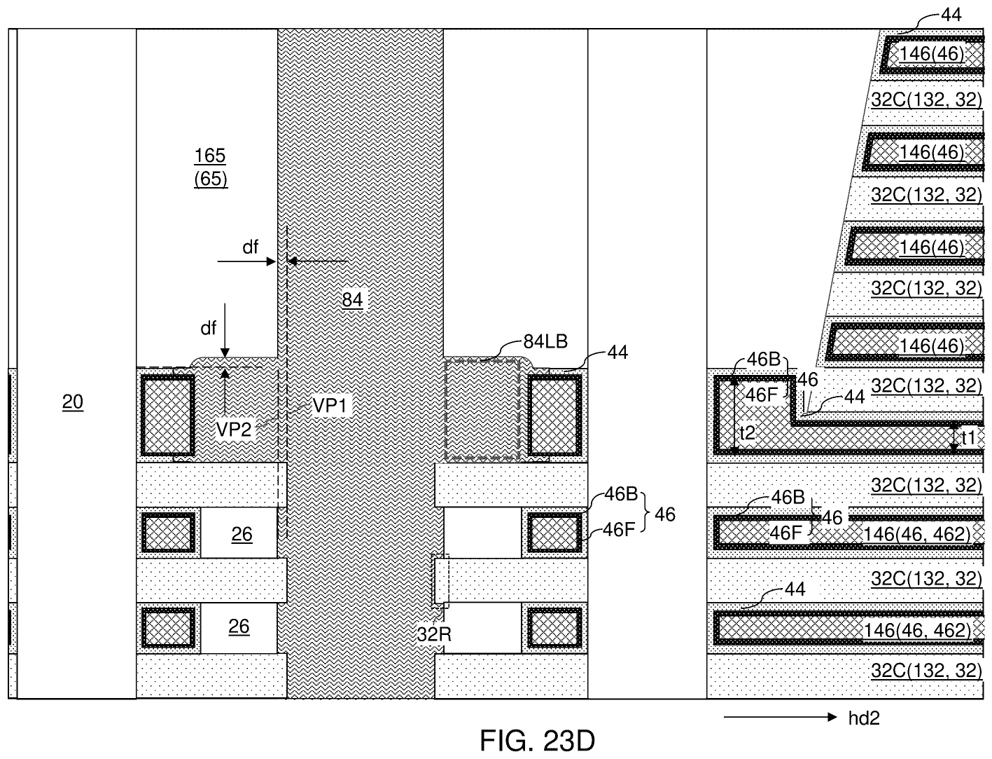

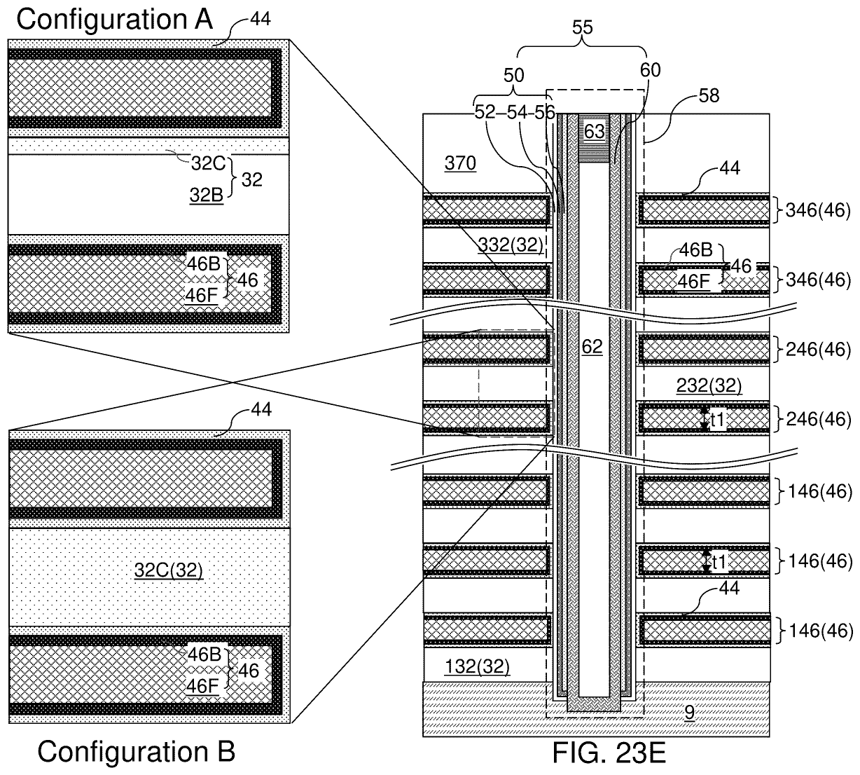

Referring to FIGS. 23A-23E, electrically conductive layers 46 can be formed in remaining unfilled volumes of the lateral recesses 43. FIG. 23C illustrates the first configuration, and FIG. 23D illustrates the second configuration. FIG. 23E is a vertical cross-sectional view of the first exemplary structure of FIGS. 23A-23D around a memory opening fill structure 58.

Specifically, a metallic barrier liner 46B may be conformally deposited on the physically exposed surfaces of the outer blocking dielectric layer 44 in peripheral portions of the lateral recesses 43, and the lateral isolation trenches 79. The metallic barrier liner 46B comprises a metallic diffusion barrier material. For example, the metallic barrier liner 46B comprises a conductive metallic nitride material such as TiN, TaN, WN, and/or MoN. The metallic barrier liner 46B may be formed as a continuous material layer having a uniform thickness throughout by a conformal deposition process such as an atomic layer deposition process and/or a chemical vapor deposition process. The thickness of the metallic barrier liner 46B may be in a range from 1.5 nm to 8 nm, such as from 3 nm to 6 nm, although lesser and greater thicknesses may also be employed. In one embodiment, the metallic barrier liner 46B extends continuously over the entirety of the outer blocking dielectric layer 44 as a single continuous material layer.

A metallic fill material layer may be conformally deposited on the physically exposed surfaces of the metallic barrier liner 46B in remaining unfilled volumes of the lateral recesses 43 and in peripheral regions of the lateral isolation trenches 79. The metallic fill material layer comprises a metallic fill material that provides high electrical conductivity. For example, the metallic fill material layer comprises, and/or consists essentially of, an elemental metal such as W, Co, Ru, Mo, Cu, or a combination thereof. The metallic fill material layer may be formed by a conformal deposition process such as a chemical vapor deposition process. The lateral isolation trenches 79 may be employed as a conduit for a reactant that deposits the metallic fill material layer. In one embodiment, the metallic fill material layer extends continuously over the entirety of the metallic barrier liner 46B as a single continuous material layer.

The combination of the outer blocking dielectric layer 44, the metallic barrier liner 46B, and the metallic fill material layer may fill the entirety of the lateral recesses 43, and may fill peripheral portions of the lateral isolation trenches 79. Generally, at least one conformal deposition process can be performed after formation of the outer blocking dielectric layer 44 to deposit at least one first electrically conductive material of the electrically conductive material layer in remaining volumes of the lateral recesses 43, and in an elongated tubular region of each lateral isolation trench 79. The portions of the electrically conductive material layer that replace unthickened portions of the sacrificial material layers 42 may have a first thickness t1, and the portions of the electrically conductive material layer that replace the thickened portions of the sacrificial material layers 42 may have a second thickness t2 which is greater than the first thickness t1.

A selective etch process can be performed to etch back the electrically conductive material selectively to the material of the outer blocking dielectric layer 44. Each portion of the electrically conductive material can be removed from the peripheral regions of the lateral isolation trenches 79.

Remaining portions of electrically conductive material comprise electrically conductive layers 46. The electrically conductive layers 46 comprise first-tier electrically conductive layers 146, second-tier electrically conductive layers 246, and third-tier electrically conductive layers 346. A plurality of first-tier electrically conductive layers 146 may be formed in the plurality of first lateral recesses 143, a plurality of second-tier electrically conductive layers 246 may be formed in the plurality of second lateral recesses 243, and a plurality of third-tier electrically conductive layers 346 may be formed in the plurality of third lateral recesses 343. Each of the electrically conductive layers 46 may include a respective metallic barrier liner 46B and a respective metallic fill material portion 46F.

Generally, the sacrificial material layers 42 are replaced with replacement material portions that comprise electrically conductive layers 46 employing the lateral isolation trenches 79 as a conduit for an etchant that removes the sacrificial material layers 42 and as a conduit for reactants that deposits the electrically conductive layers 46. Each electrically conductive layer 46 can be formed in the volume of a respective one of the sacrificial material layers 42.

For each sacrificial contact via structure 84 located within a respective contact via cavity 85 and having a respective laterally bulging portion 84LB, an electrically conductive layer 46 laterally surrounding the laterally bulging portion is provided, which is herein referred to as a first electrically conductive layer 461 for the sacrificial contact via structure 84 and for the contact via cavity 85. In other words, a first electrically conductive layer 461 can be defined for each sacrificial contact via structure 84 or for each contact via cavity 85. In case a sacrificial contact via structure 84 vertically extends through a set of two or more electrically conductive layers 46, the topmost electrically conductive layer 46 within the set of two or more electrically conductive layers 46 is the first electrically conductive layer 461 for the sacrificial contact via structure 84, and all other electrically conductive layers 46 within the set of two or more electrically conductive layers 46 constitutes second electrically conductive layers 462 for the sacrificial contact via structure 84. In other words, each “first” electrically conductive layer is defined relative to a selected sacrificial contact via structure 84 or relative to a selected contact via cavity 85. Each electrically conductive layer 46 may have a first thickness t1 around memory opening fill structures 58, and may have a second thickness t2 in a thickened portion.

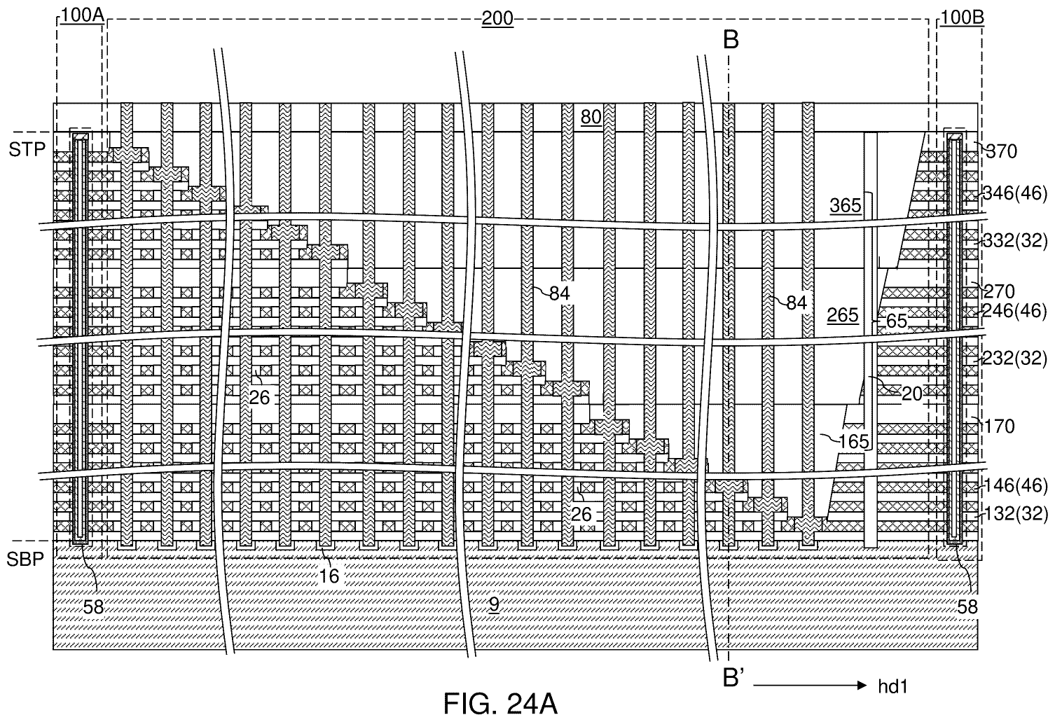

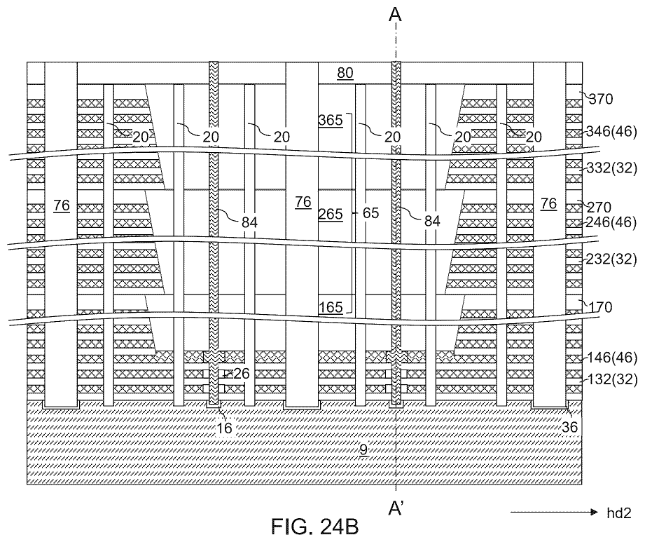

Referring to FIGS. 24A and 24B, a dielectric fill material such as undoped silicate glass or a doped silicate glass can be deposited in the lateral isolation trenches 79 by a conformal deposition process. A planarization process can be performed to remove the portion of the deposited dielectric fill material from above the horizontal plane including the top surface of the contact-level dielectric layer 80. The planarization process may comprise a recess etch process and/or a chemical mechanical polishing process. Each remaining portion of the dielectric fill material that fills a respective one of the lateral isolation trenches 79 constitute a lateral isolation trench fill structure 76.

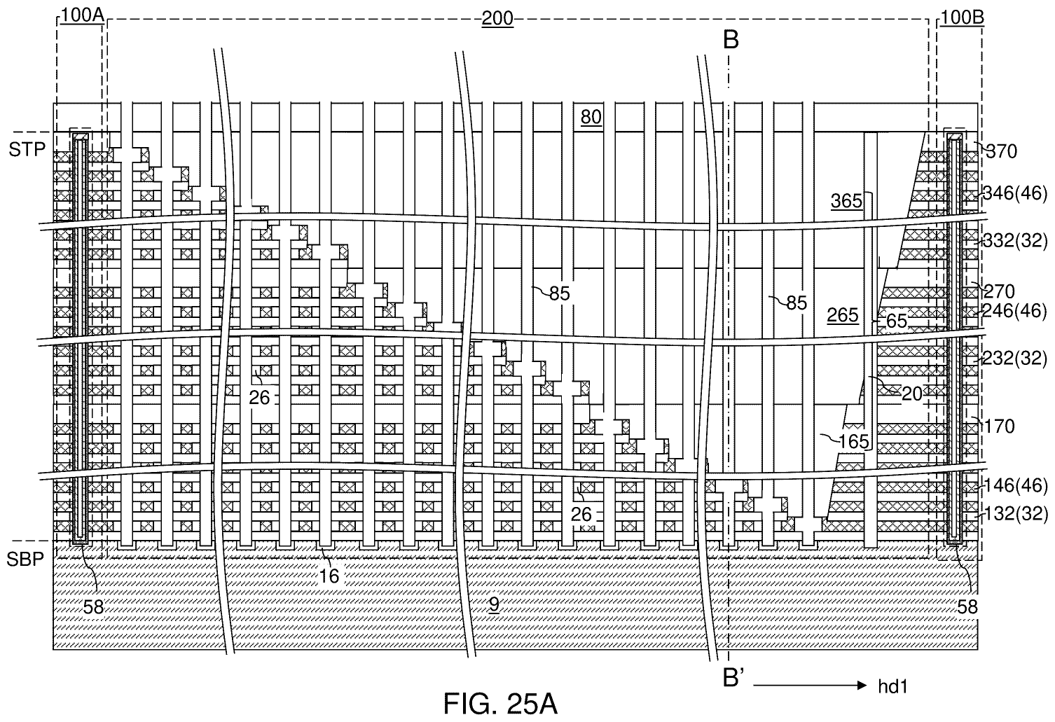

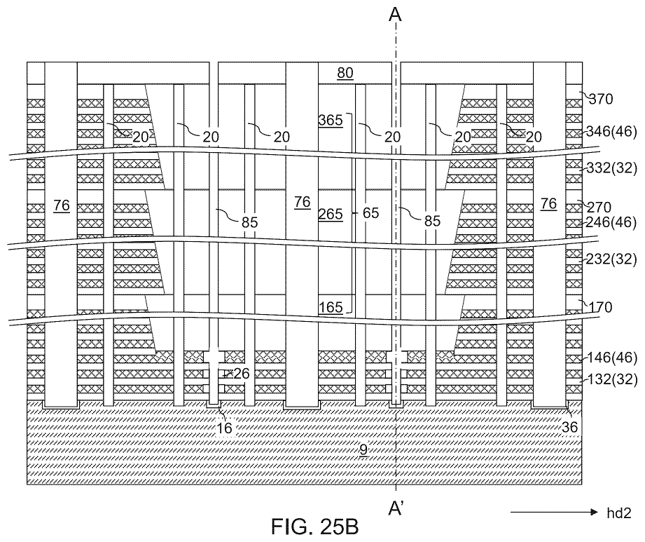

Referring to FIGS. 25A-25C, the sacrificial contact via structures 84 can be removed selectively to the contact-level dielectric layer 80, the lateral isolation trench fill structures 76, and the semiconductor oxide spacer liners 16 by performing a selective removal process. Voids are formed in the volumes of the contact via cavities 85. The selective removal process may comprise a selective etch process or an ashing process. In an illustrative example, if the sacrificial contact via structures 84 comprise amorphous silicon, the sacrificial contact via structures 84 may be removed by a wet etch process using hot trimethyl-2 hydroxyethyl ammonium hydroxide (“hot TMY”) or tetramethyl ammonium hydroxide (TMAH). If the sacrificial contact via structures 84 comprise a carbon-based material, the sacrificial contact via structures 84 may be removed by ashing.

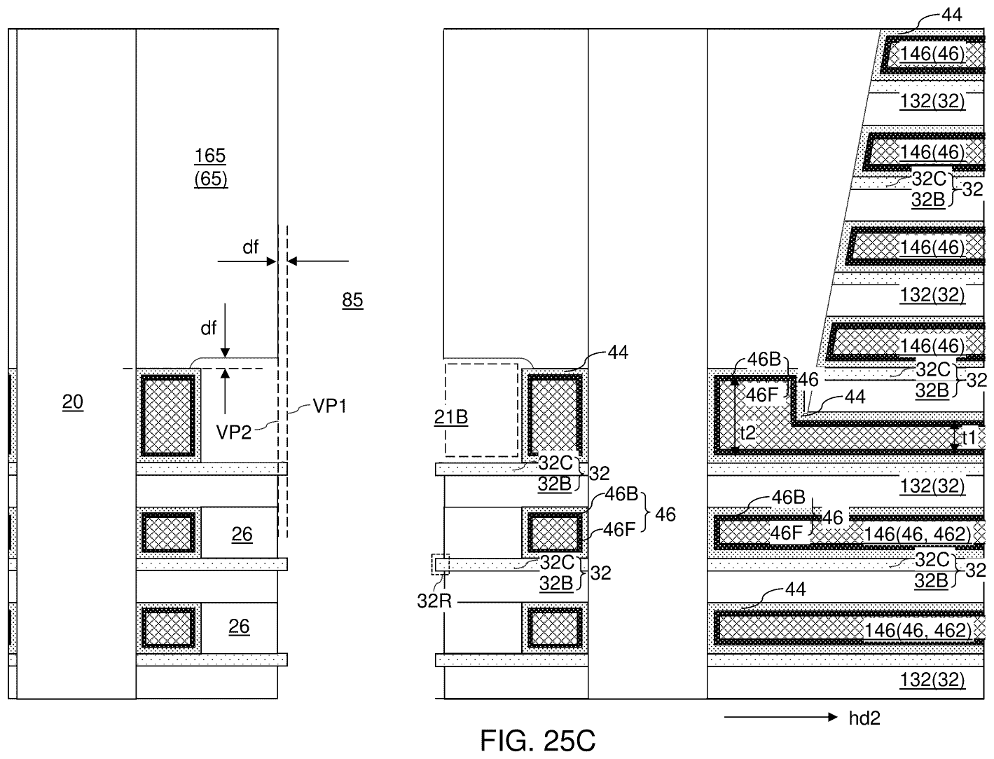

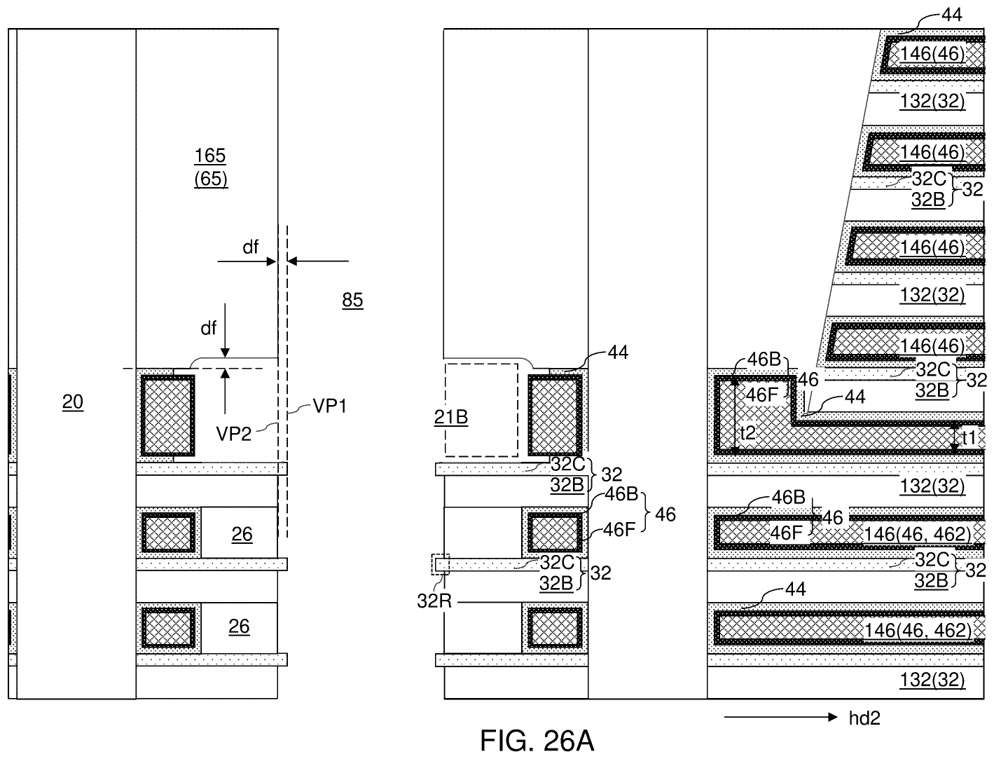

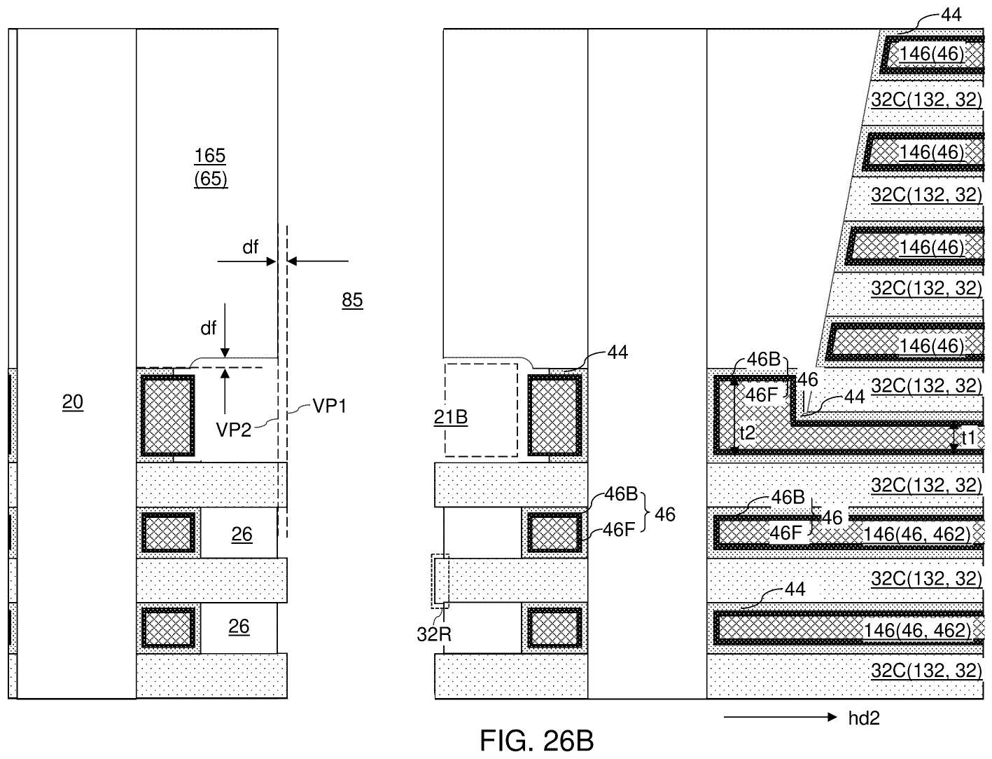

Referring to FIGS. 26A and 26B, a region around a contact via cavity 85 is illustrated after removal of proximal portions of the outer blocking dielectric layers 44 that are exposed to the contact via cavities 85. FIG. 26A illustrates the first configuration, and FIG. 26B illustrates the second configuration.

Specifically, an isotropic etch process that isotropically etches the material of the outer blocking dielectric layers 44 selectively to the materials of the electrically conductive layers 46, the insulating layers 32, the at least one retro-stepped dielectric material portion 65, the contact-level dielectric layer 80, and the various insulating cap layers (170, 270, 370) can be performed. In an illustrative example, if the outer blocking dielectric layers 44 comprise aluminum oxide, a wet etch process employing hot phosphoric acid can be performed. For each contact via cavity 85, surface segments of a respective first electrically conductive layer 461 can be physically exposed. The physically exposed surface segments of each first electrically conductive layer 461 may comprise a cylindrical surface segment, an annular top surface segment, and an annular bottom surface segment.

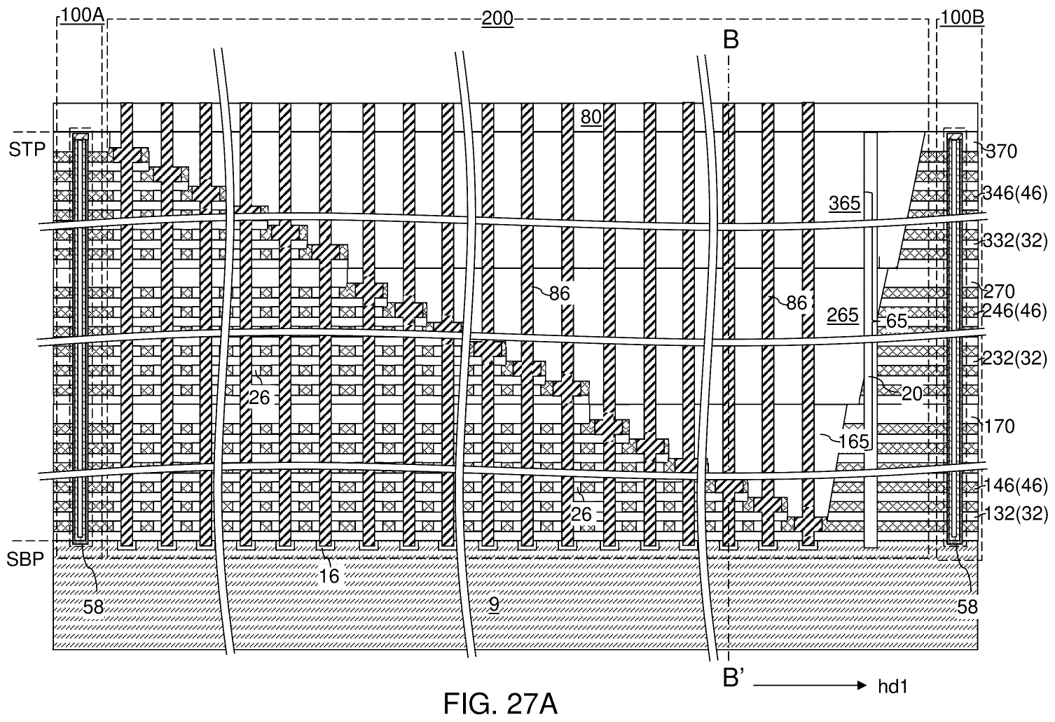

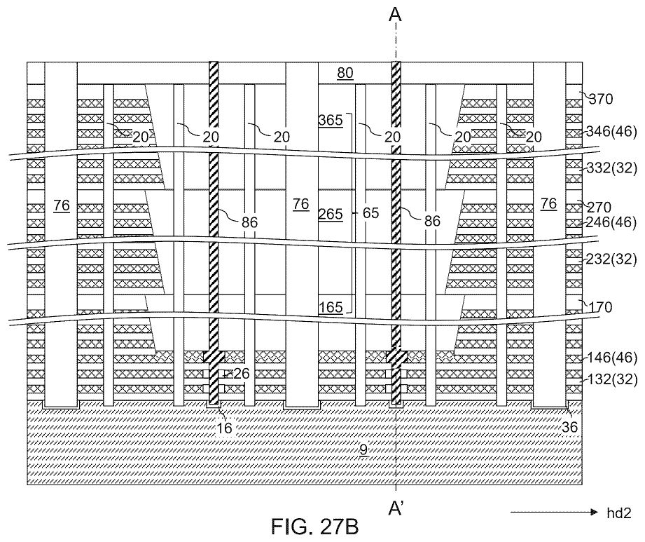

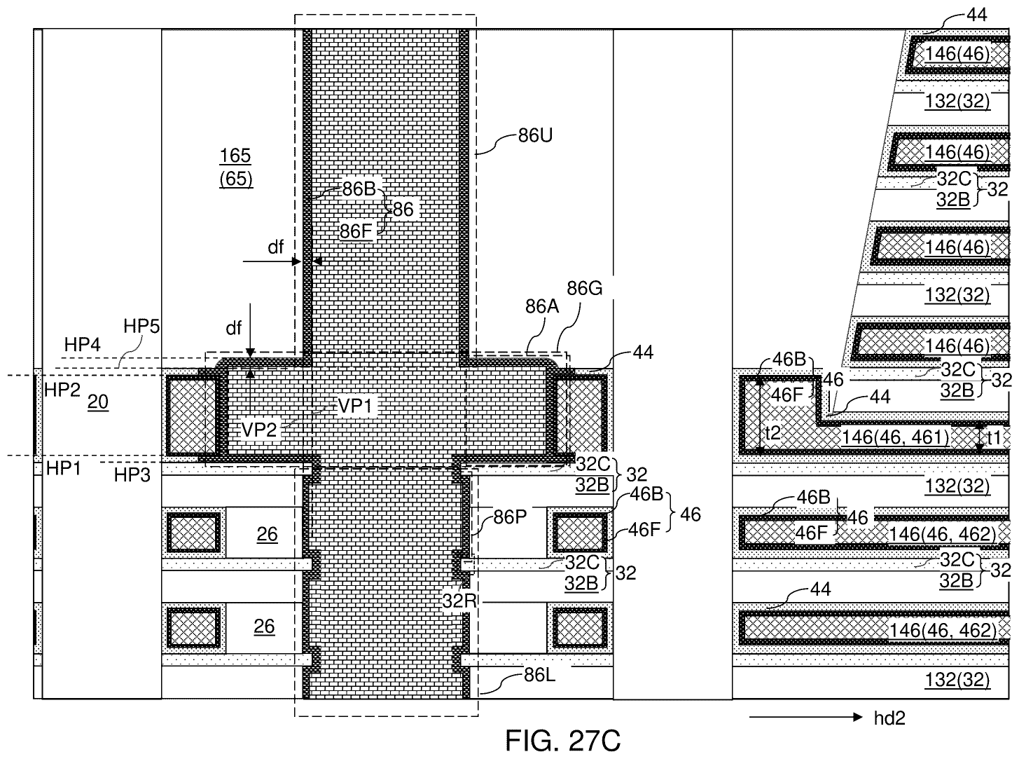

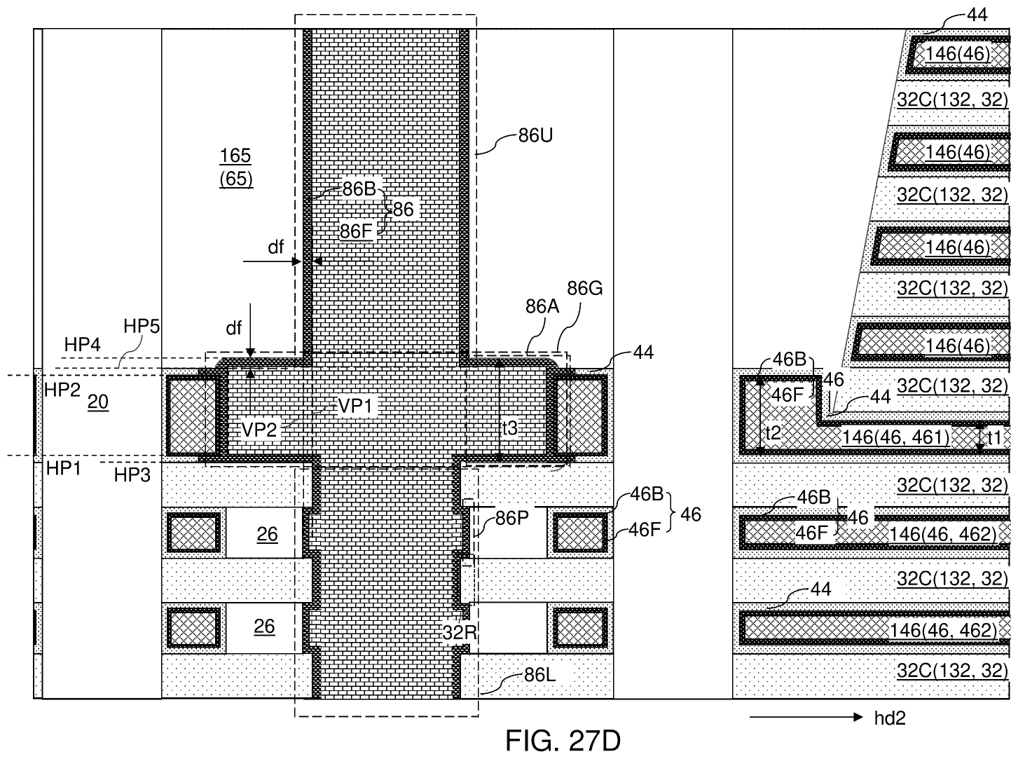

Referring to FIGS. 27A-27D, a contact via structure 86 can be formed in each contact via cavity 85. FIG. 27C illustrates the first configuration, and FIG. 27D illustrates the second configuration.

Specifically, at least one second electrically conductive material can be deposited in each of the contact via cavities 85. Excess portions of the at least one second electrically conductive material can be removed from above the horizontal plane including the top surface of the contact-level dielectric layer 80. Each remaining portion of the at least one second electrically conductive material that fills a respective one of the contact via cavities 85 constitutes a contact via structure that contacts a respective first electrically conductive layer 461 the electrically conductive layers 46. Each such contact via structure is herein referred to as a layer contact via structure 86.

In one embodiment, the at least one second electrically conductive material may comprise a contact-via metallic barrier material and a contact-via metallic fill material. In this case, each layer contact via structure 86 may comprise a metallic barrier liner (which is herein referred to as a contact-via metallic barrier liner 86B) and a metallic fill material portion (which is herein referred to as a contact-via metallic fill material portion 86F) that is laterally surrounded by the contact-via metallic barrier liner 86B. The contact-via metallic barrier liner 86B comprises the contact-via metallic barrier material, and the contact-via metallic fill material portion 86F comprises the contact-via metallic fill material.

The contact-via metallic barrier material comprises a metallic diffusion barrier material that can be employed to block diffusion of impurity atoms, hydrogen atoms, moisture, etc. For example, the contact-via metallic barrier material comprises a conductive metallic nitride material such as TiN, TaN, WN, and/or MoN. The contact-via metallic barrier material may be deposited as a continuous material layer having a uniform thickness throughout by a conformal deposition process such as a chemical vapor deposition process. The thickness of the contact-via metallic barrier material may be in a range from 3 nm to 60 nm, such as from 6 nm to 30 nm, although lesser and greater thicknesses may also be employed.

The contact-via metallic fill material comprises a metallic fill material that provides high electrical conductivity. For example, the contact-via metallic fill material comprises, and/or consists essentially of, an elemental metal such as W, Co, Ru, Mo, Cu, or a combination thereof. The contact-via metallic fill material may be formed by a conformal deposition process such as a chemical vapor deposition process.

Each layer contact via structure 86 contacts a cylindrical surface of a respective one of the electrically conductive layers 46. Thus, for each layer contact via structure 86, a first electrically conductive layer 461 can be defined as the electrically conductive layer 46 that is contacted by the layer contact via structure 86. In other words, each layer contact via structure 86 can be formed in a respective contact via cavity 85 directly on a cylindrical surface of a respective first electrically conductive layer 461. In case any electrically conductive layer 46 underlies the first electrically conductive layer 461 (which is defined once a layer contact via structure 86 is selected), any such underlying electrically conductive layer 46 is herein referred to as a second electrically conductive layer 462.

Generally, each contact via cavity 85 can be filled with a respective contact via structure 86 (which may be referred to as a layer contact via structure). Each contact via structure 86 contacts a cylindrical sidewall of a respective first electrically conductive layer 461 of the electrically conductive layers 46 which is formed within a volume of a respective first sacrificial material layer 421. Each contact via structure 86 comprises a respective upper portion 86U, a respective lower portion 86L, and a respective laterally bulging portion 86G. The upper portion 86U vertically extends through and contacts a cylindrical sidewall of each of the at least one retro-stepped dielectric material portion 65. The upper portion 86U comprises a cylindrical sidewall located entirely within a respective second cylindrical vertical plane VP2. Each laterally bulging portion 86G comprises an annular portion 86A located outside the respective second cylindrical vertical plane VP2. The carbon-doped silicate glass layer 32C ensures that a sufficient insulating layer 32 thickness is maintained under the annular portion 86A. Thus, the likelihood of a short circuit or a leakage current between the annular portion 86A and the underlying second electrically conductive layer 462 is reduced.

The first exemplary structure illustrated in FIGS. 27A-27D comprises a device structure that includes: at least one alternating stack (32, 46) of respective insulating layers 32 and respective electrically conductive layers 46, wherein each of the at least one alternating stack (32, 46) comprises respective stepped surfaces located in a staircase region, and wherein each of the insulating layers 32 comprises a respective carbon-doped silicate glass layer 32C; at least one retro-stepped dielectric material portion 65 overlying portions of the at least one alternating stack (32, 46) located in the staircase region; a memory opening 49 vertically extending through each layer within the at least one alternating stack (32, 46); a memory opening fill structure 58 located in the memory opening 49 and comprising a vertical stack of memory elements (which may be embodied as portions of a memory material layer 54 located at levels of the electrically conductive layers 46); and a contact via structure 86 comprising a laterally bulging portion 86G in contact with a first electrically conductive layer 461 of the electrically conductive layers 46 within the at least one alternating stack (32, 46), an upper portion 86U that vertically extends upward from the laterally bulging portion 86G and through one or more of the at least one retro-stepped dielectric material portion 65, and a lower portion 86L that vertically extends through a subset of the electrically conductive layers 46 that underlies the first electrically conductive layer 461.

In one embodiment, each carbon-doped silicate glass layer 32C within the alternating stack (32, 46) that underlies the first electrically conductive layer 461 is in contact with a respective cylindrical surface segment of the lower portion of the contact via structure 86.

In one embodiment, the respective carbon-doped silicate glass layer 32C comprises 0.5 to 15 atomic percent carbon. In one embodiment, each insulating layer 32 within the alternating stack comprises a respective base silicate glass layer 32B that is free of carbon atoms or includes carbon atoms at an average atomic concentration that is less than 10 percent of an average atomic concentration of carbon atoms within the respective carbon-doped silicate glass layer 32C. In another embodiment, each of the insulating layers 32 consists of the respective carbon-doped silicate glass layer 32C.

In one embodiment, the first electrically conductive layer 461 has a first thickness t1 around the memory opening fill structure 58; the first electrically conductive layer 461 has a second thickness t2 around the contact via structure 86, wherein the second thickness t2 is greater than the first thickness t1; a bottom surface of the first electrically conductive layer 461 is located within a first horizontal plane HP1; and a top surface of a portion of the first electrically conductive layer 461 around the contact via structure 86 is located within a second horizontal plane HP2. In one embodiment, the laterally bulging portion 86G of the contact via structure 86 has a third thickness t3 that is greater than the second thickness t2. In one embodiment, the laterally bulging portion 86G of the contact via structure 86 comprises an annular bottom surface located within a third horizontal plane HP3 that underlies the first horizontal plane HP1; and the laterally bulging portion 86G of the contact via structure 86 comprises a first annular top surface located within a fourth horizontal plane HP4 that overlies the second horizontal plane HP2.

In one embodiment, the third horizontal plane HP3 is vertically offset from the first horizontal plane HP1 by a first vertical spacing; the fourth horizontal plane HP4 is vertically offset from the second horizontal plane HP2 by a second vertical spacing; and the second vertical spacing is greater than the first vertical spacing by an offset dimension df. In one embodiment, the first electrically conductive layer 461 is embedded within a first outer blocking dielectric layer 44; and the first vertical spacing equals to a thickness of the first outer blocking dielectric layer 44.

In one embodiment, the lower portion 86L of the contact via structure 86 has a ribbed vertical cross-sectional profile including a plurality of annular lateral protrusions 86P; each pf the respective carbon-doped silicate glass layers 32C that underlies the first electrically conductive layer 461 contacts a respective cylindrical surface segment of the lower portion of the contact via structure 86 within a first cylindrical vertical plane VP1; and sidewalls of the plurality of annular lateral protrusions 86P are located within a second cylindrical vertical plane VP2 that is laterally offset outward from the first cylindrical vertical plane VP1 by the offset dimension df.

In one embodiment, the device structure further comprises a vertical stack of annular dielectric spacers 26 laterally surrounding, and contacting, the contact via structure 86 and located at each level of electrically conductive layers 46 within the subset of the electrically conductive layers 46. In one embodiment, each annular dielectric spacer 26 within the vertical stack of annular dielectric spacers 26 is in contact with an annular top surface of the respective carbon-doped silicate glass layer 32C. In one embodiment, each of the respective carbon-doped silicate glass layers 32C that underlies the first electrically conductive layer 461 contacts comprises: a respective annular top surface segment that contacts a respective bottom surface segment of the contact via structure 86; and a respective annular bottom surface segment that contacts a respective top surface segment of the contact via structure 86.

In one embodiment, the laterally bulging portion 86G of the contact via structure 86 comprises a second annular top surface located within a fifth horizontal plane HP5 that overlies the second horizontal plane HP2 and underlies the fourth horizontal plane HP4; and the fifth horizontal plane HP5 is vertically offset from the second horizontal plane HP2 by the first vertical spacing.

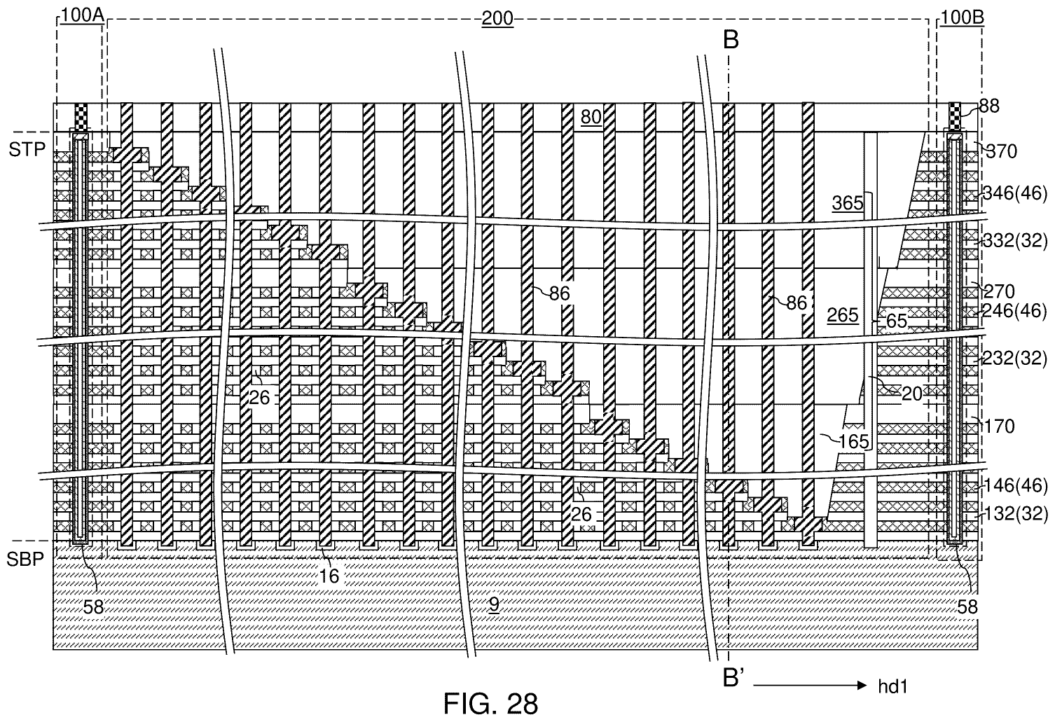

Referring to FIG. 28, drain contact via structures 88 can contact an upper portion of a respective memory opening fill structure 58 (such as a drain region within the respective memory opening fill structure 58). Laterally-isolated vertical interconnection structures (484, 486) (shown in FIGS. 1A-1E) can be formed in the inter-array region 200.

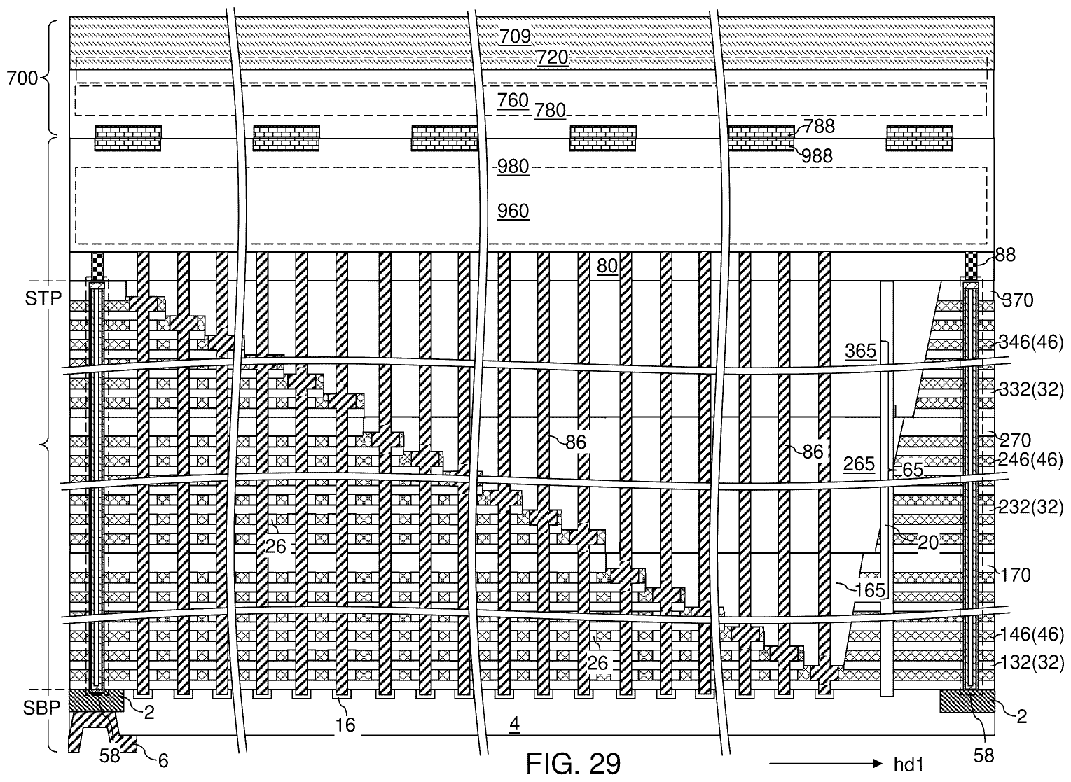

Referring to FIG. 29, additional dielectric material layers can be formed over the contact-level dielectric layer 80. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The dielectric material layers that are formed above the contact-level dielectric layer 80 are herein collectively referred to as memory-side dielectric material layers 960. The additional metal interconnect structures are collectively referred to as memory-side dielectric material layers 960. The memory-side dielectric material layers 960 comprise a bit-line-level dielectric material layer embedding bit lines, which are a subset of the memory-side metal interconnect structures 980.

Metal bonding pads, which are herein referred to as memory-side bonding pads 988, may be formed at the topmost level of the memory-side dielectric material layers 960. The memory-side bonding pads 988 may be electrically connected to the memory-side metal interconnect structures 980 and various nodes of the three-dimensional memory array including the alternating stacks of insulating layers 32 and electrically conductive layers 46 and the memory opening fill structures 58. A memory die 900 can thus be provided.

The memory-side dielectric material layers 960 are formed over the alternating stacks (32, 46). The memory-side metal interconnect structures 980 are embedded in the memory-side dielectric material layers 960. The memory-side bonding pads 988 can be embedded within the memory-side dielectric material layers 960, and specifically, within the topmost layer of the memory-side dielectric material layers 960. The memory-side bonding pads 988 can be electrically connected to the memory-side metal interconnect structures 980.

In summary, the memory die 900 comprises a memory array (32, 46, 58), memory-side metal interconnect structures 980, and memory-side bonding pads 988 embedded within memory-side dielectric material layers 960. The memory array may comprise a three-dimensional memory array including an alternating stack of insulating layers 32 and electrically conductive layers 46, and further comprises a two-dimensional array of NAND strings (e.g., memory opening fill structures 58) vertically extending through the alternating stack (32, 46). In one embodiment, the electrically conductive layers 46 comprise word lines and select gate electrodes of the two-dimensional array of NAND strings. In one embodiment, the memory-side metal interconnect structures 980 comprise bit lines for the two-dimensional array of NAND strings.

Further, a logic die 700 can be provided. The logic die 700 includes a logic-side substrate 709, a peripheral circuit 720 located on the logic-side substrate 709 and comprising logic-side semiconductor devices (such as field effect transistors), logic-side metal interconnect structures 780 embedded within logic-side dielectric material layers 760, and logic-side bonding pads 778. The peripheral circuit 720 can be configured to control operation of the memory array within the memory die 900. Specifically, the peripheral circuit 720 can be configured to drive various electrical components within the memory array including, but not limited to, the electrically conductive layers 46, the drain regions 63, and a source contact structure to be subsequently formed. The peripheral circuit 720 can be configured to control operation of the vertical stack of memory elements in the memory array in the memory die 900. Particularly, the peripheral circuit 720 comprises word line driver transistors configured to drive the word lines in the memory die 900.

The logic die 700 can be attached to the memory die 900, for example, by bonding the logic-side bonding pads 788 to the memory-side bonding pads 988 at a bonding interface. The bonding between the memory die 900 and the logic die 700 may be performed employing a wafer-to-wafer bonding process in which a two-dimensional array of memory dies 900 is bonded to a two-dimensional array of logic dies 700, by a die-to-die bonding process, or by a die-to-wafer bonding process. The logic-side bonding pads 788 within each logic die 700 can be bonded to the memory-side bonding pads 988 within a respective memory die 900.

The substrate 9 can be removed, for example, by grinding, polishing, cleaving, an isotropic etch process, an anisotropic etch process, and/or a combination thereof. In one embodiment, at least a terminal step of at least one removal process that is employed to remove the substrate 9 may comprise a selective wet etch process that etches the material of the substrate 9 (which may be a semiconductor material) selectively to dielectric materials of the memory films 50. In an illustrative example, if the substrate 9 comprises silicon, the terminal step of the at least one removal process may comprise a wet etch process using hot trimethyl-2 hydroxyethyl ammonium hydroxide (“hot TMY”) or tetramethyl ammonium hydroxide (TMAH). The entirety of the substrate 9 can be removed by the selective wet etch process. Backside end surfaces of the support pillar structures 20 can be physically exposed upon removal of the substrate 9.

An end portion of each memory opening fill structure 58 can be removed. In one embodiment, an end portion of each memory film 50 may be removed by performing a sequence of wet etch processes. A horizontal end portion of each vertical semiconductor channel 60 may be physically exposed. In one embodiment, the sequence of wet etch processes may be selectively to the material of the vertical semiconductor channels 60.

At least one source structure 2 (e.g., a source region and/or source line) can be formed in contact vertical semiconductor channels 60. The at least one source structure 2 may comprise a heavily doped semiconductor material and/or a metallic material (e.g., a metal and/or an electrically conductive metal nitride or silicide). A backside dielectric layer 4 and backside contact structures 6 can be subsequently formed.

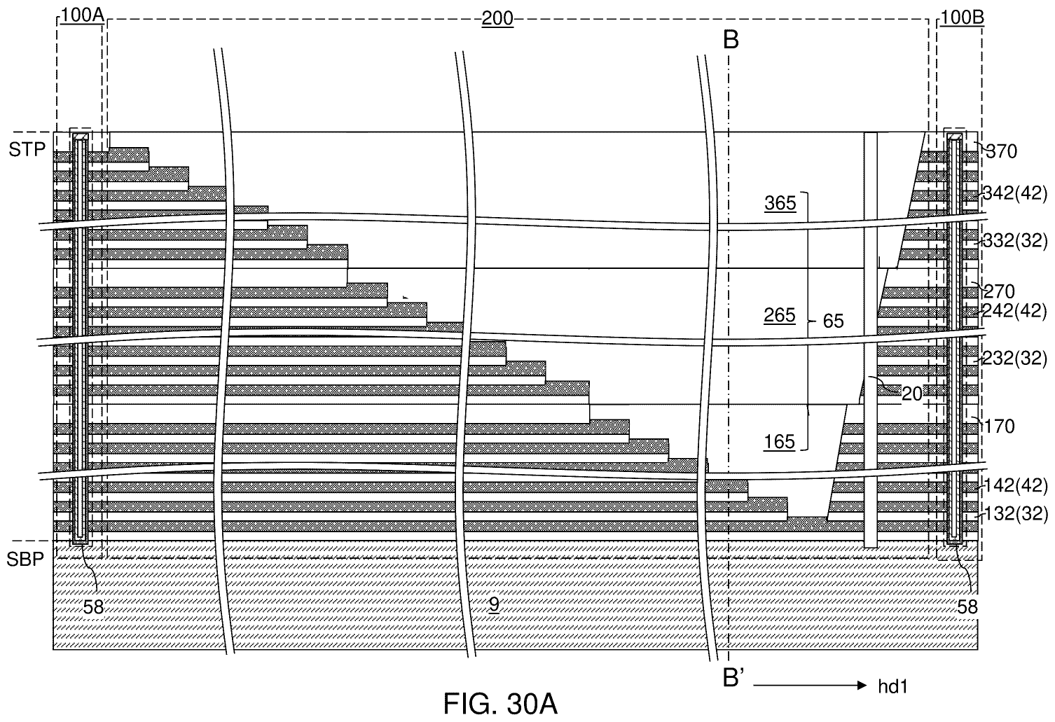

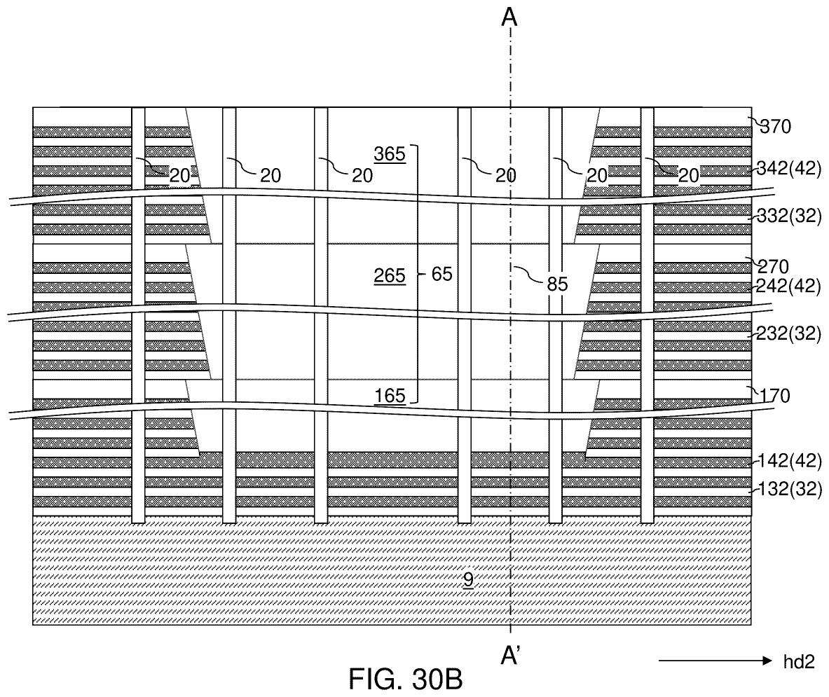

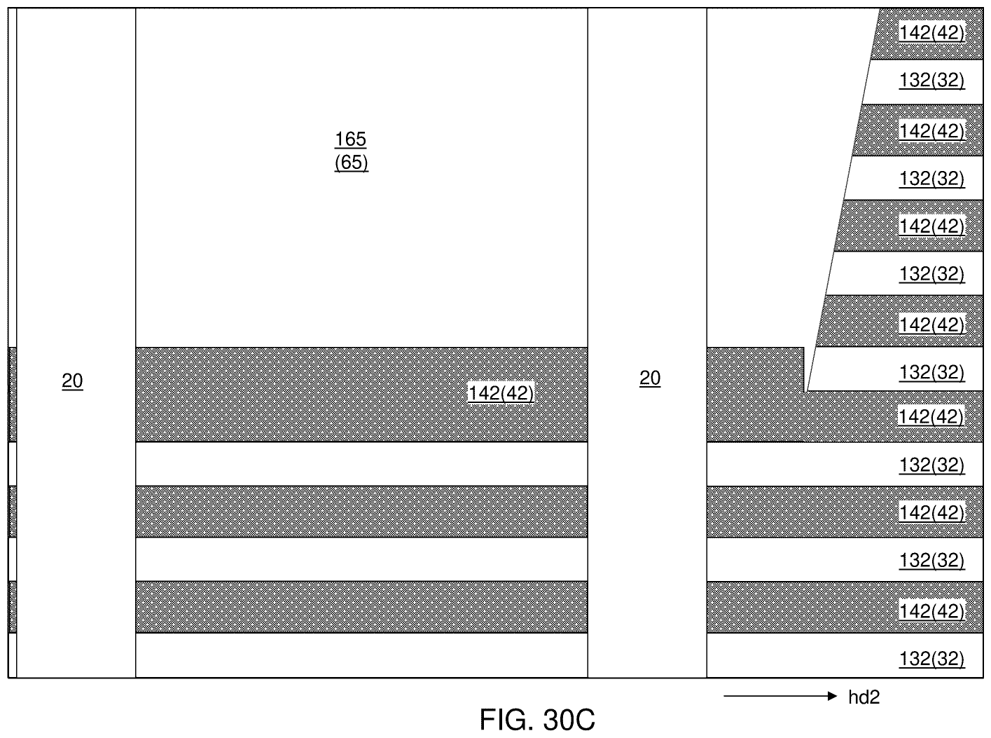

Referring to FIGS. 30A-30C, a second exemplary structure according to an embodiment of the present disclosure can be derived from the first exemplary structure illustrated in FIGS. 14A-14C by employing a homogeneous material layer having a uniform material composition throughout for each insulating layer 32. For example, each insulating layer 32 may consist of undoped silicate glass (i.e., silicon oxide) or a doped silicate glass such as borosilicate glass or borophosphosilicate glass. In one embodiment, each insulating layer 32 may consist essentially of undoped silicate glass.

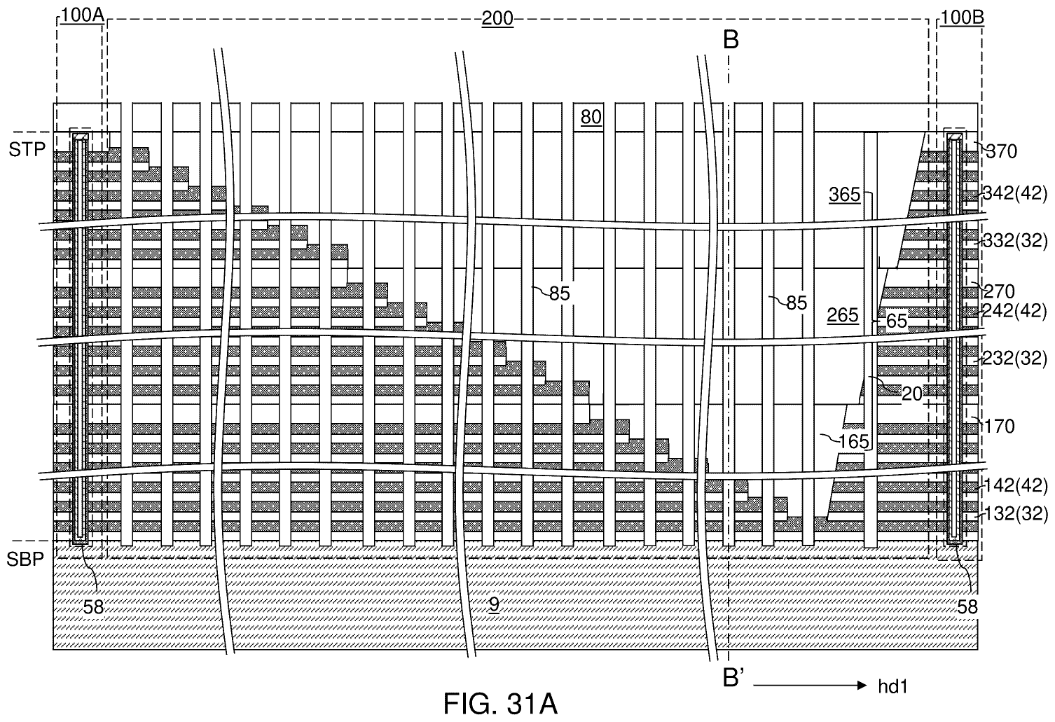

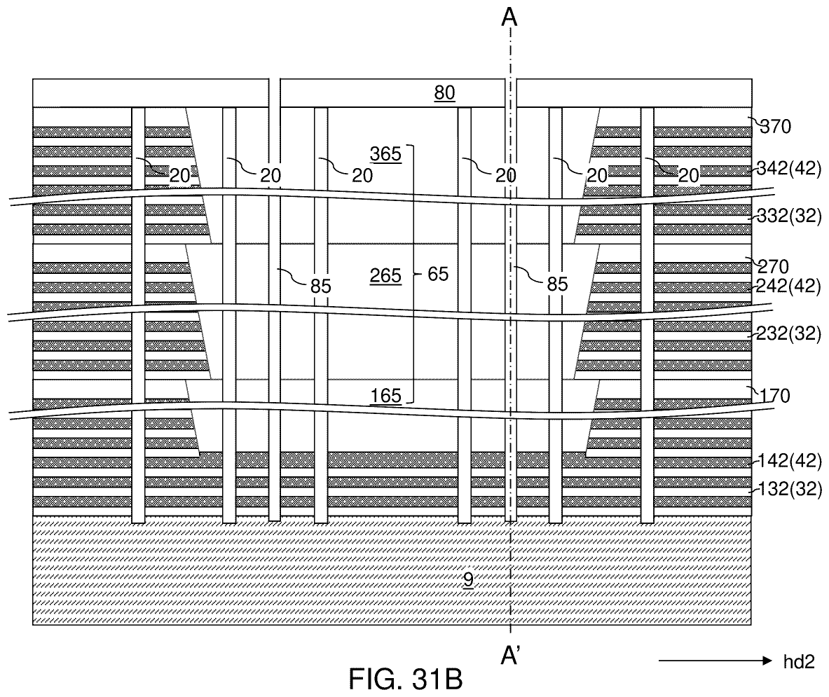

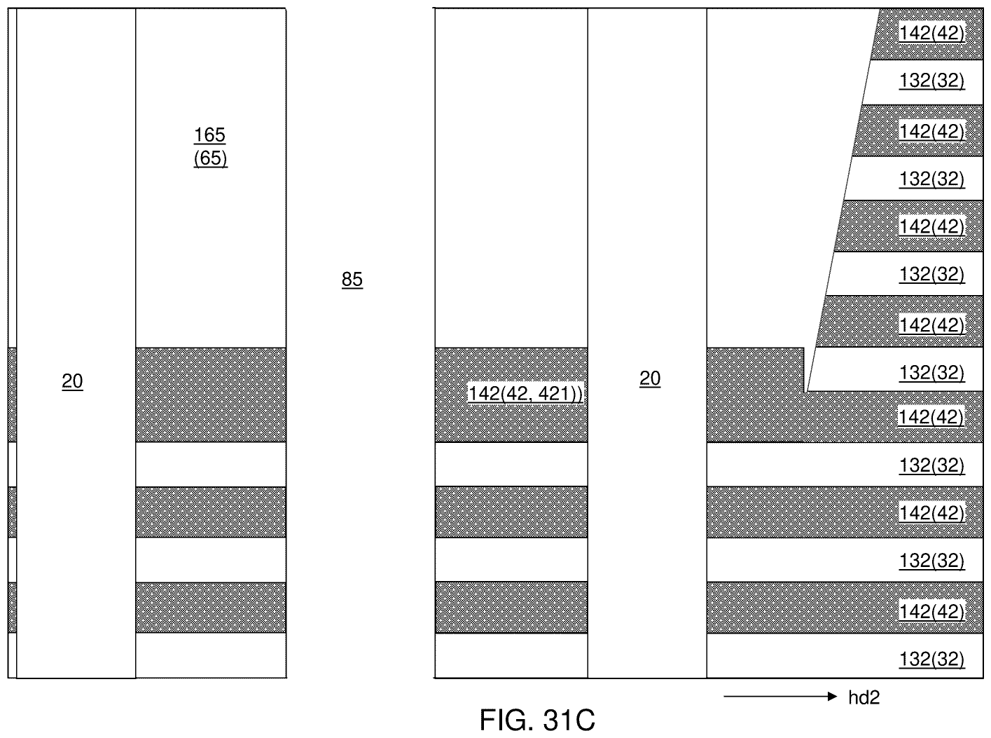

Referring to FIGS. 31A-31C, the processing steps described with reference to FIGS. 15A-15C can be performed to form contact via cavities 85. Each contact via cavity 85 is formed through a respective subset of at least one sacrificial material layer 42. For each contact via cavity 85, the topmost sacrificial material layer 42 within the respective subset of the at least one sacrificial material layer 42 constitutes a first sacrificial material layer 421, and any underlying sacrificial material layer 42 constitutes a second sacrificial material layer 422. Each contact via cavity 85 is formed through a thickened portion of the respective first sacrificial material layer 421.

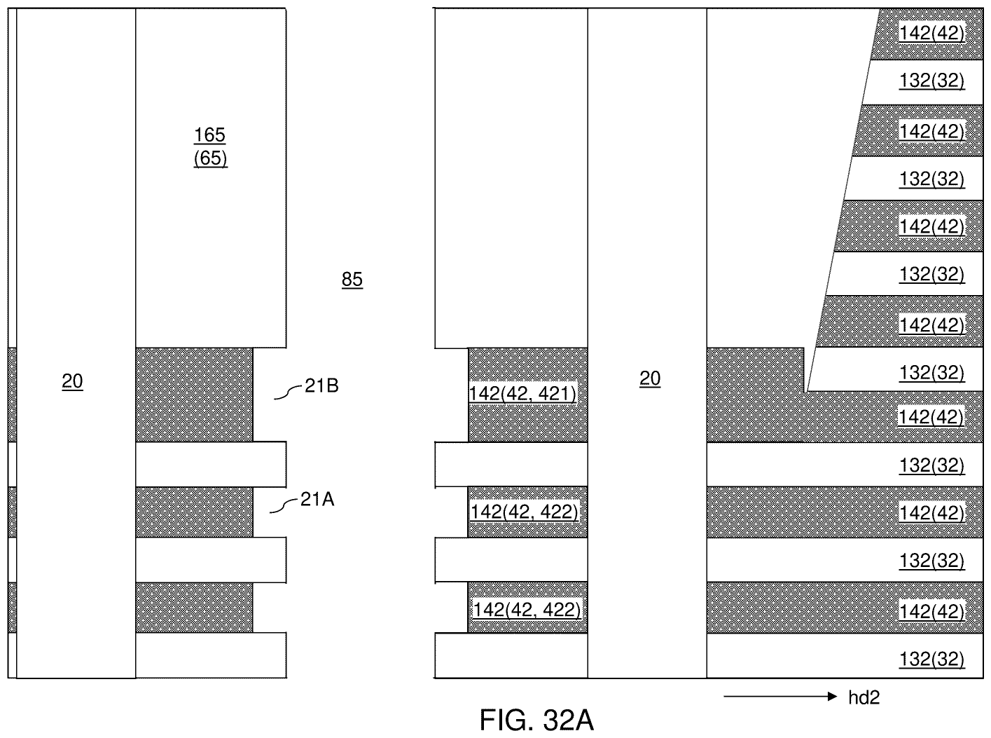

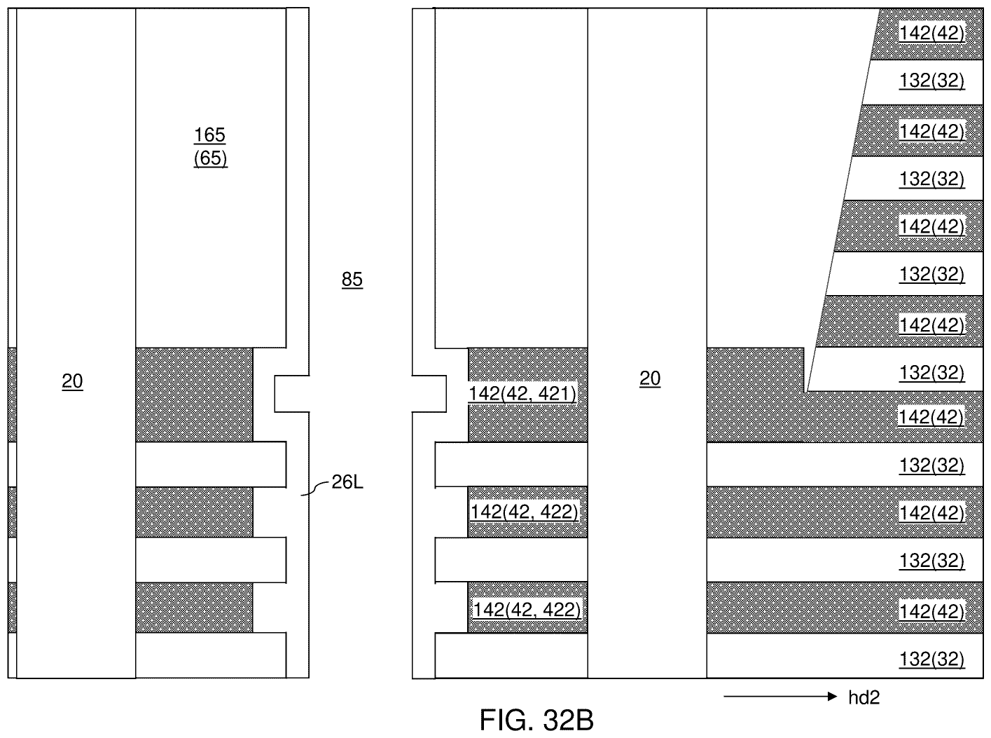

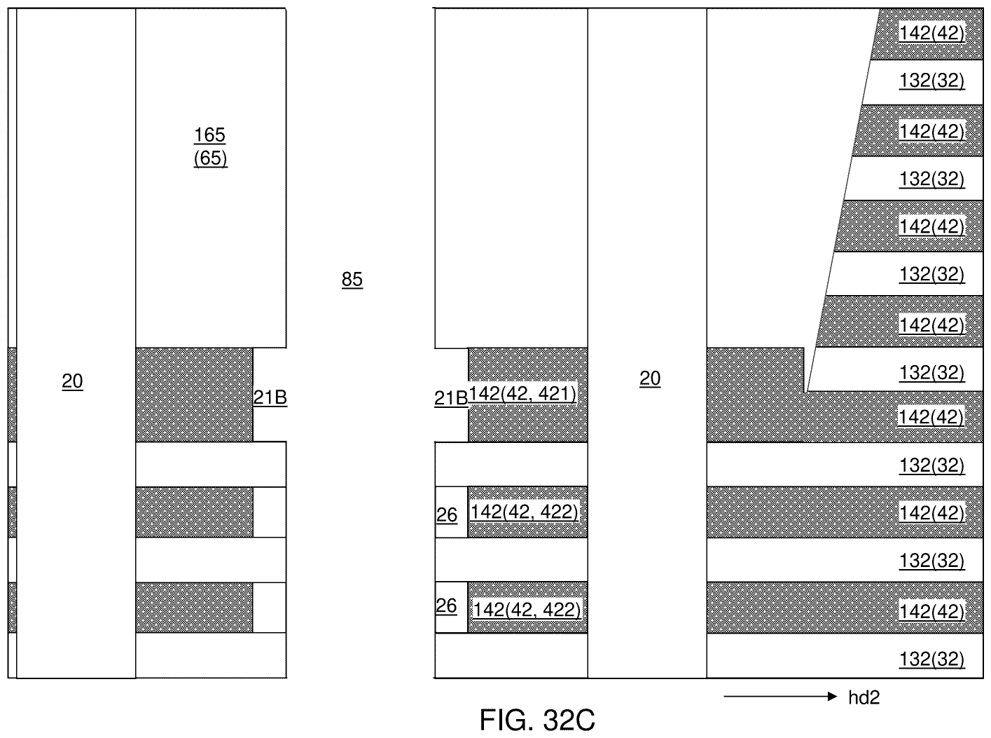

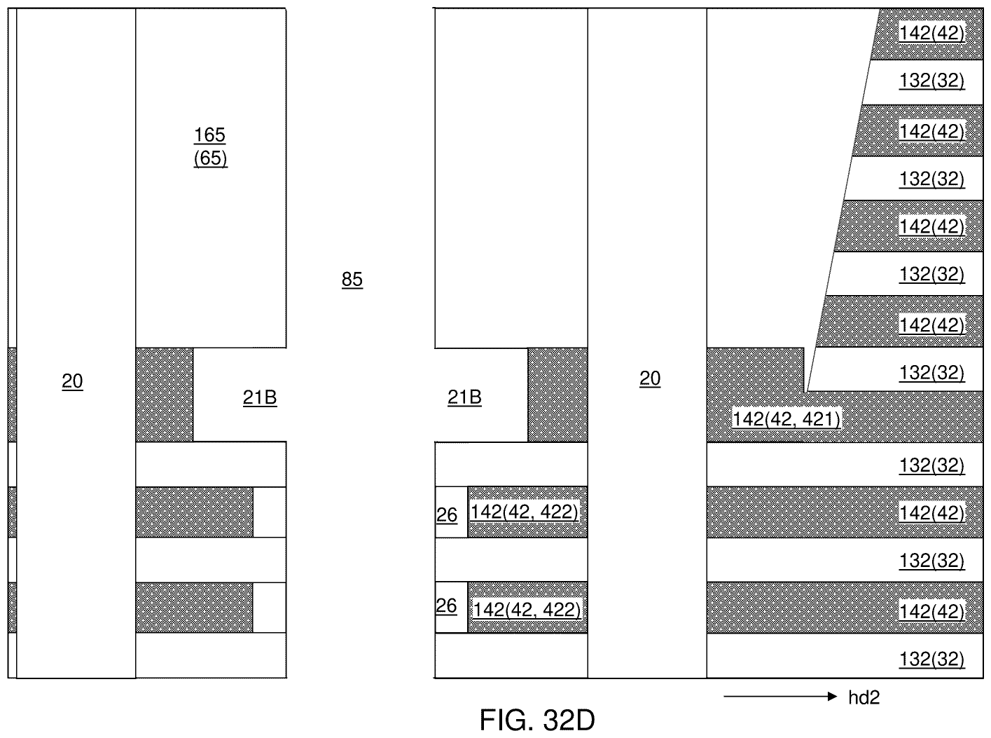

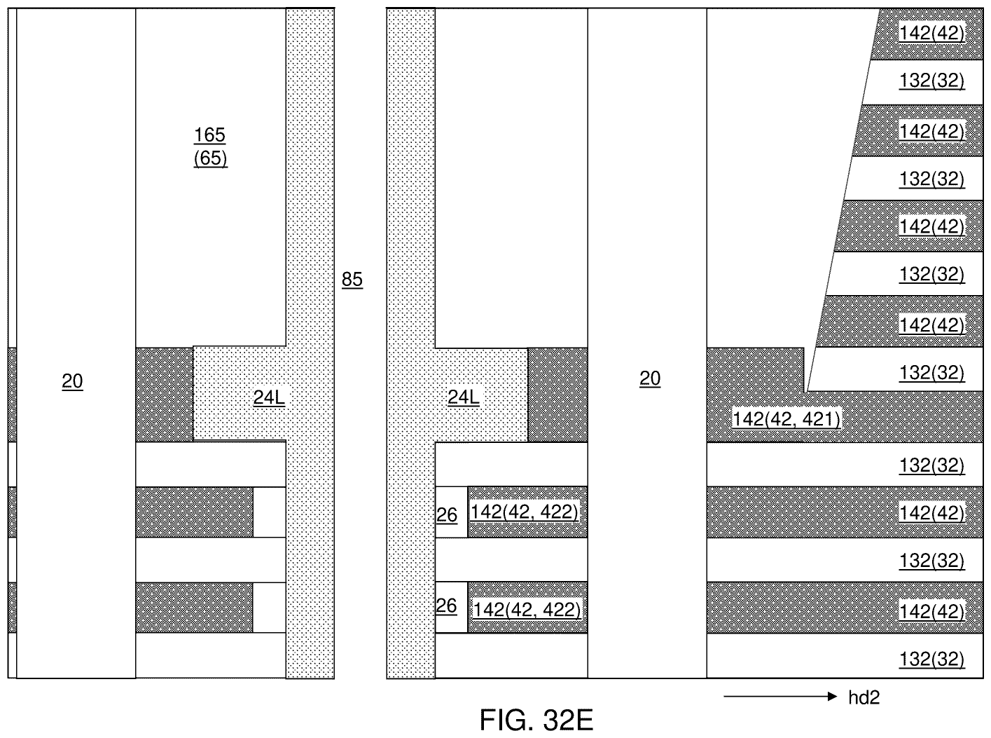

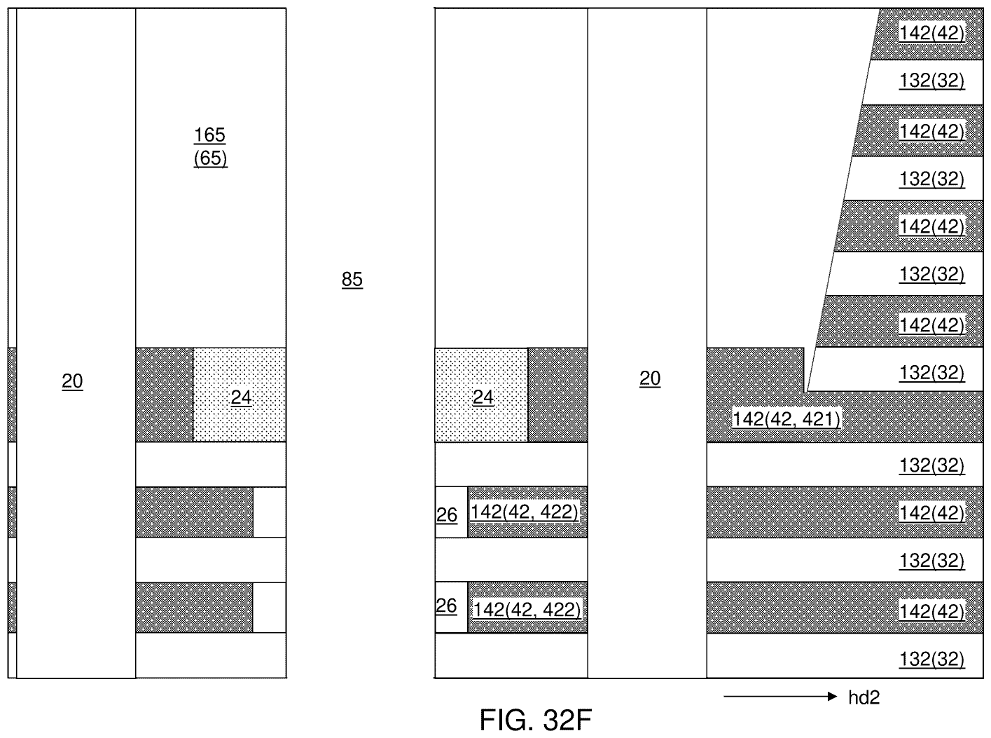

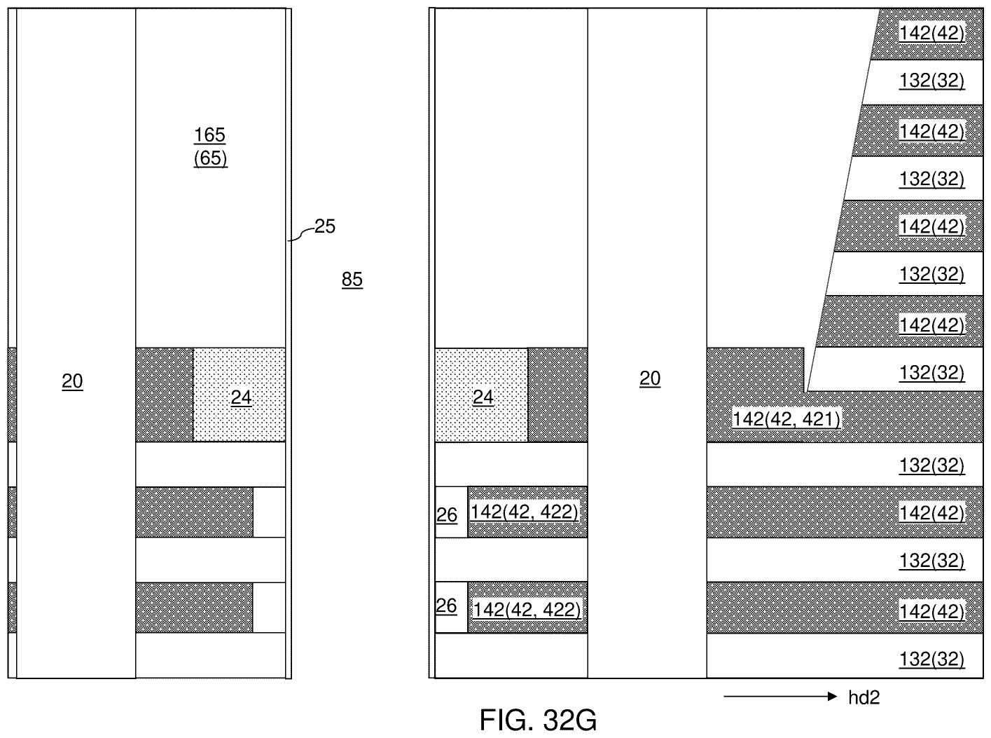

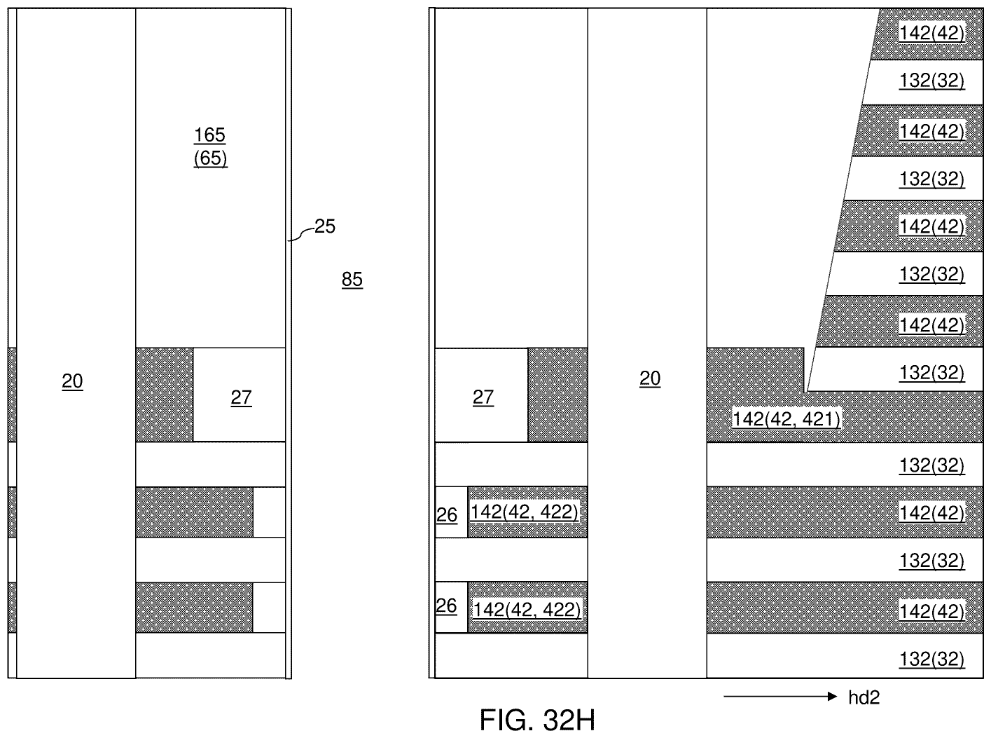

FIGS. 32A-32H are vertical cross-sectional views of a region of the second exemplary structure around a contact via cavity 85 during formation of annular dielectric spacers 26, a sacrificial fill material spacer 24, a sacrificial permeable liner 25, and an annular void 27 according to an embodiment of the present disclosure.

Referring to FIG. 32A, the processing steps described with reference to FIG. 17A can be performed to form first annular recess regions 21A and second annular recess regions 21B around the contact via cavities 85. First annular recess regions 21A are formed in volumes from which portions of the second sacrificial material layer 422 are removed, and a second annular recess region 21B is formed in a volume from which a portion of the first sacrificial material layer 421 is removed.

Referring to FIG. 32B, the processing steps described with reference to FIG. 17B can be performed to conformally deposit a recess-fill dielectric material layer 26L in the first annular recess regions 21A and in the second annular recess region 21B. The entirety of each of the first annular recess regions 21A can be filled with the recess-fill dielectric material layer 26L without completely filling the second annular recess region 21B.

Referring to FIG. 32C, the processing steps described with reference to FIGS. 18A-18D can be performed. Specifically, a second isotropic etch process can be performed to isotropically etch the material of the recess-fill dielectric material layer 26L. The second isotropic etch process removes the recess-fill dielectric material layer 26L from an entire volume of each second annular recess region 21B. Each remaining portion of the recess-fill dielectric material layer 26L that fills a respective one of the first annular recess regions 21A comprises an annular dielectric spacer 26.

Referring to FIG. 32D, a selective isotropic etch process may be optionally performed to laterally recess physically exposed surfaces of a respective first sacrificial material layer 421 in the second annular recess region 21B around each contact via cavity 85. For example, a wet etch process employing hot phosphoric acid may be performed to isotropically recess physically exposed sidewalls of the sacrificial material layers 42 around the second annular recess regions 21B. Each second annular recess region 21B may be expanded outward by the selective isotropic etch process. In this case, each physically exposed cylindrical sidewall of a first sacrificial material layer 421 around a respective contact via cavity 85 may be laterally offset outward farther from a cylindrical portion of the respective contact via cavity 85 than cylindrical sidewalls of the respective second sacrificial material layers 422 in contact with outer cylindrical sidewalls of annular dielectric spacers 26 that laterally surround the respective contact via cavity 85.

Referring to FIG. 32E, a sacrificial fill material may be conformally deposited in the second annular recess regions 21B and over sidewalls of the contact via cavities 85 to form a sacrificial fill material layer 24L. The sacrificial fill material layer 24L comprises a carbon-containing material that can be subsequently volatilized into a gas. In one embodiment, the sacrificial fill material layer 24L comprises, and/or consists essentially of, a material comprising carbon atoms at an atomic percentage greater than 50%, such as a polymer material.

In an illustrative example, the sacrificial fill material layer 24L comprises a carbon-based polymer material that can be decomposed at a temperature in a range from 350 degrees Celsius to 700 degrees Celsius into a volatile carbon-containing gas. Exemplary carbon-based polymer materials include polyacrylonitrile (PAN), polycarbonate (PC), polyvinyl chloride (PVC), polyethylene terephthalate (PET), phenolic resins, polyurethane (PU), and polypropylene (PP). The sacrificial fill material layer 24L may be formed at a low temperature (e.g., between 70 and 200 degrees Celsius)

Referring to FIG. 32F, an anisotropic etch process can be performed to remove portions of the sacrificial fill material layer 24L that are located outside the volumes of the second annular recess regions 21B. Portions of the sacrificial fill material layer 24L that are located in peripheral portions of the contact via cavities 85 can be removed. Each remaining portion of the material of the sacrificial fill material layer 24L located within the volume of a respective second annular recess region 21B comprises a sacrificial fill material spacer 24. Each sacrificial fill material spacer 24 may have an annular configuration, and may have a cylindrical inner sidewall, a cylindrical outer sidewall, an annular top surface, and an annular bottom surface. In one embodiment, the cylindrical inner sidewall of each sacrificial fill material spacer 24 may be vertically coincident with (i.e., located within a same vertical plane as) a cylindrical sidewall of a respective contact via cavity 85. In one embodiment, the material of the sacrificial fill material spacers 24 may comprise carbon atoms at an atomic percentage greater than 50%. In one embodiment, the material of the sacrificial fill material spacers 24 may comprise polymer spacers. Thus, for each contact via cavity 85, an annular portion of a respective first sacrificial material layer 421 that is proximal to the contact via cavity 85 can be replaced with a sacrificial fill material spacer 24.

Referring to FIG. 32G, a sacrificial permeable liner 25 can be conformally deposited on the inner cylindrical sidewall of each sacrificial fill material spacer 24, for example, by a conformal deposition process, such as a chemical vapor deposition process. For example, the sacrificial permeable liner 25 comprises undoped silicate glass, a doped silicate glass, or porous or nonporous organosilicate glass. The thickness of the sacrificial permeable liner 25 may be in a range from 0.6 nm to 3 nm, such as from 1 nm to 2 nm, although lesser and greater thicknesses may also be employed.

Referring to FIG. 32H, an anneal process can be performed at above the decomposition temperature of the sacrificial fill material spacers 24 to decompose and completely vaporize the material of the sacrificial fill material spacers 24. The elevated temperature of the anneal process may be in a range from 350 degrees Celsius to 850 degrees Celsius, such as from 380 degrees Celsius to 450 degrees Celsius. The sacrificial fill material of the sacrificial fill material spacers 24 is decomposed into volatile gases, which diffuse through the sacrificial permeable liner 25 into the contact via cavities 85. The volatile gases (e.g., carbon containing gases) are then pumped out of the process chamber used to perform the decomposition anneal process. The duration of the anneal process can be selected such that the entirety of the sacrificial fill material spacers 24 is volatilized and is removed during the anneal process, such a duration of 5 to 10 minutes. The anneal may be performed in a vacuum or in an oxidizing ambient, such as in an oxygen and/or water vapor ambient. The oxidizing ambient may assist in chemically decomposing the carbon-based sacrificial fill material spacers 24. For example, a catalytic water vapor generation process may be used to provide a water vapor oxidizing ambient. Thus, an annular void (i.e., air gap) 27 is formed within the volume of each second annular recess region 21B by removing the sacrificial fill material spacer 24.

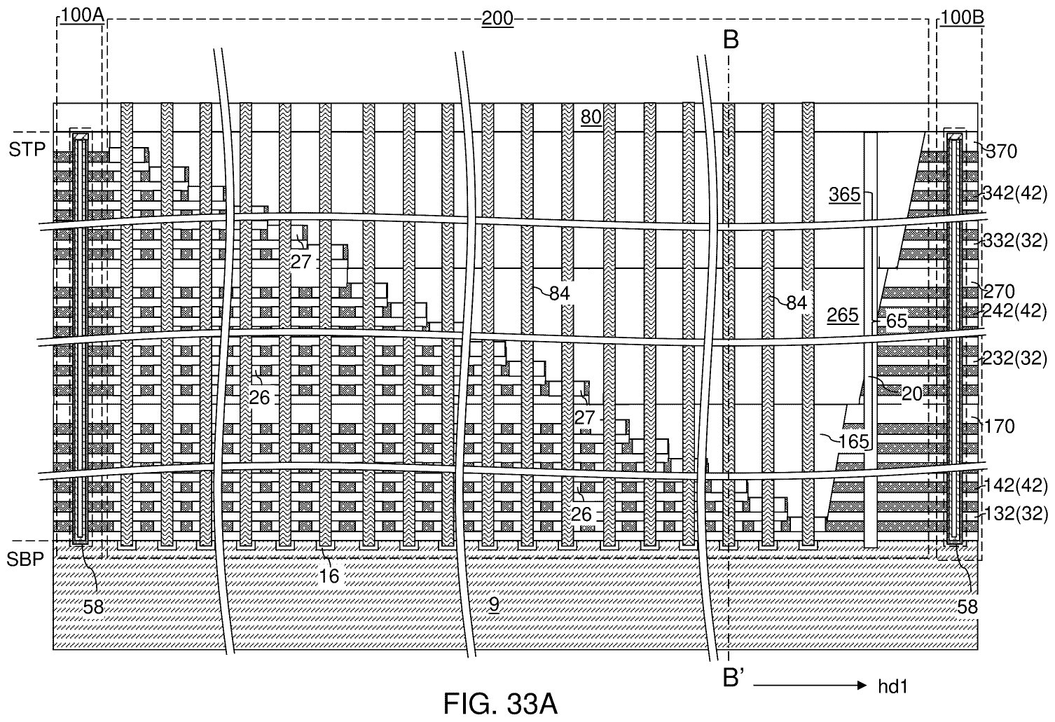

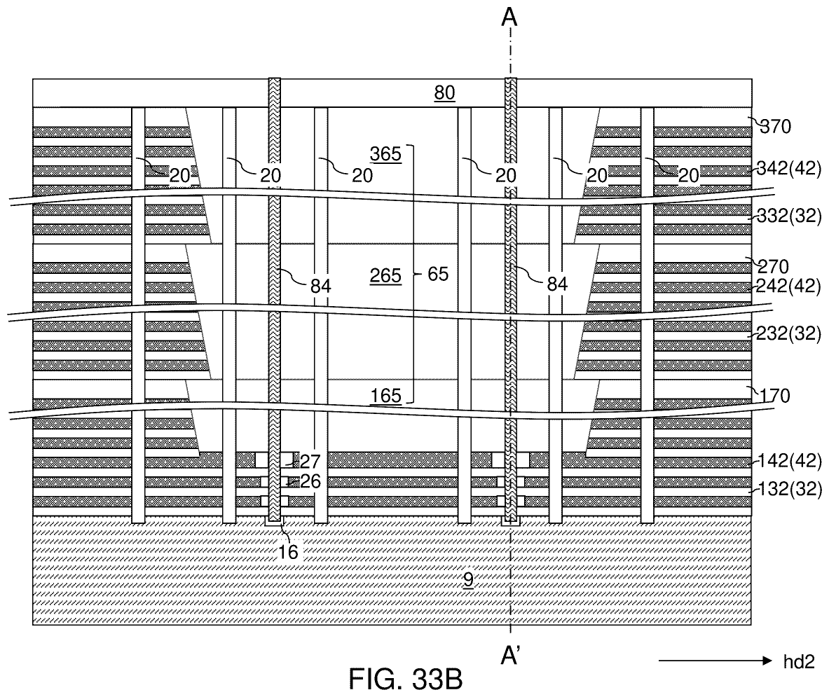

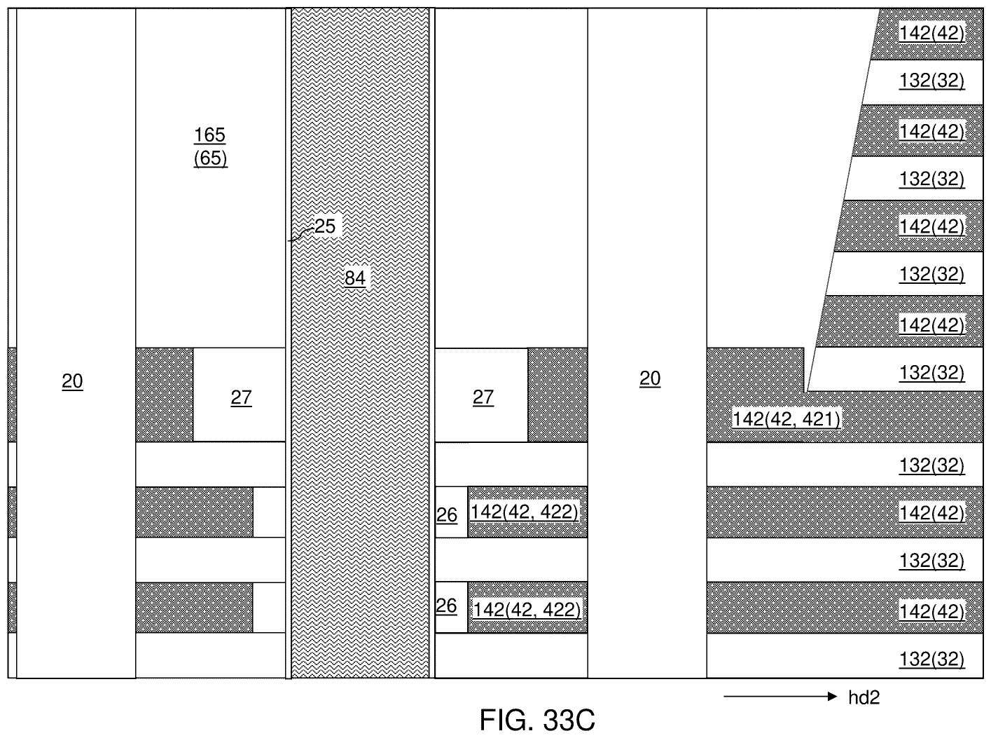

Referring to FIGS. 33A-33C, the processing steps described with reference to FIGS. 19A-19D can be performed to form a sacrificial contact via structure 84 within each contact via cavity 85. Each sacrificial via fill structure 84 may be formed entirely outside a volume of a respective annular void 27, and may be laterally surrounded by the respective annular void 27. Each sacrificial via fill structure 84 can be spaced from the respective annular void 27 by the sacrificial permeable liner 25. In one embodiment, at least one annular dielectric spacer 26 may underlie a respective annular void 27, and may contact a cylindrical outer sidewall of a sacrificial permeable liner 25. In one embodiment, each sacrificial contact via structure 84 may have a straight sidewall that vertically extends at least from a horizontal plane including a top surface of a topmost retro-stepped dielectric material portion 65 to a horizontal plane including a bottommost surface of a bottommost retro-stepped dielectric material portion 65.

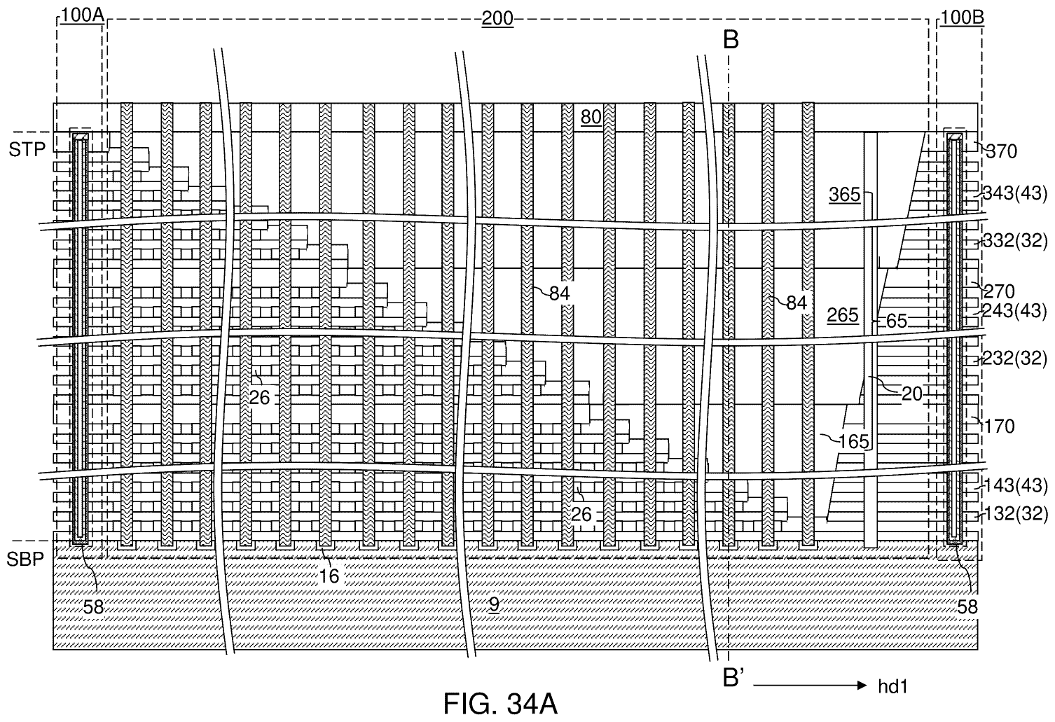

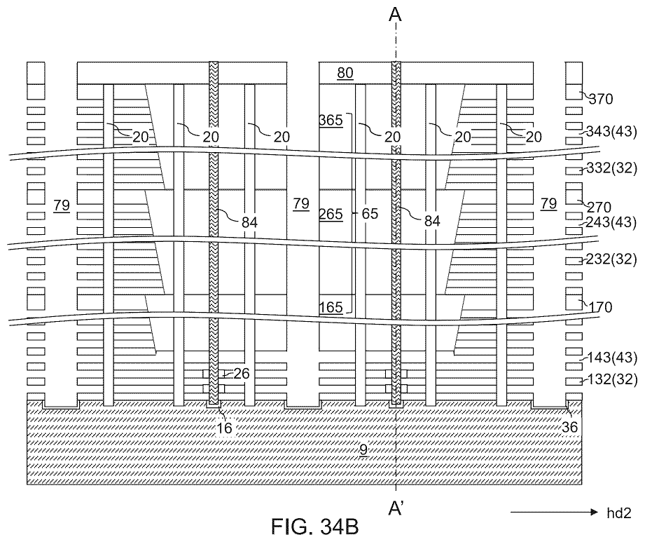

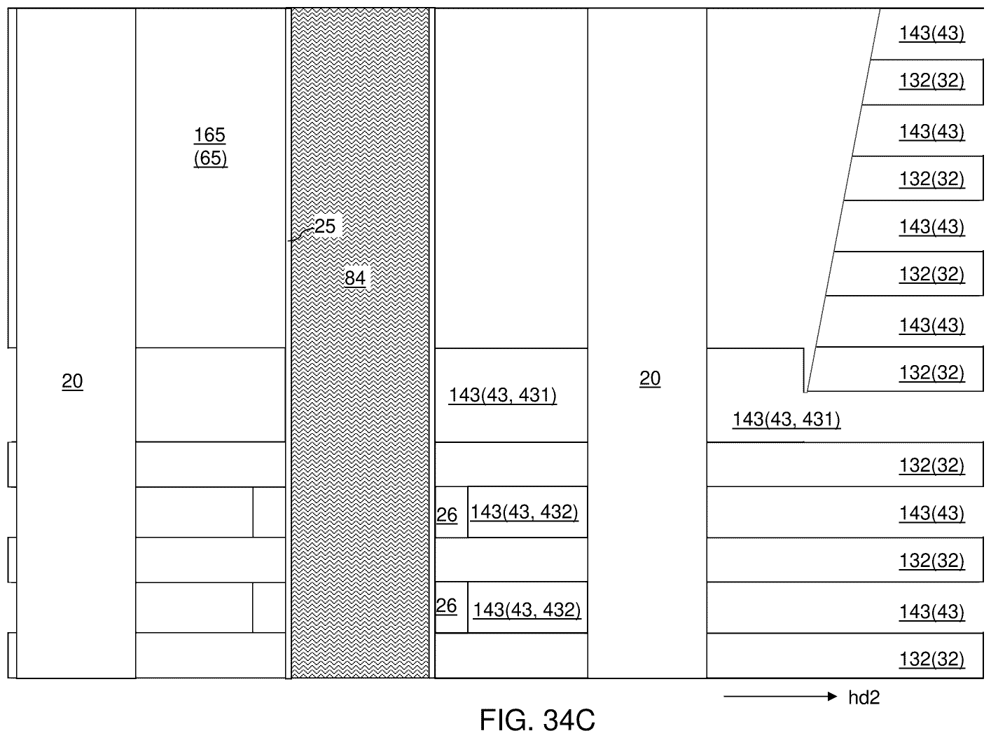

Referring to FIGS. 34A-34C, the processing steps described with reference to FIGS. 20A and 20B can be performed to form lateral isolation trenches 79. Subsequently, the processing steps described with reference to FIGS. 21A-21D can be performed to form lateral recesses 43.

Specifically, the lateral recesses 43 can be formed by selective removal of the sacrificial material layers 42. Specifically, the sacrificial material layers 42 may be isotropically etched selectively to the insulating layers 32, the annular dielectric spacers 26, and the retro-stepped dielectric material portions 65 by supplying an isotropic etchant into the lateral isolation trenches 79. In one embodiment, an etchant that selectively etches the materials of the sacrificial material layers 42 with respect to the materials of the insulating layers 32, the annular dielectric spacers 26, the retro-stepped dielectric material portions (165, 265, 365), the sacrificial permeable liner 25, and the material of the outermost layer of the memory films 50 may be introduced into the lateral isolation trenches, for example, using an isotropic etch process.

Lateral recesses 43 are formed in volumes from which the sacrificial material layers 42 are removed. The lateral recesses 43 include first lateral recesses 143 that are formed in volumes from which the first-tier sacrificial material layers 142 are removed, second lateral recesses 243 that are formed in volumes from which the second-tier sacrificial material layers 242 are removed, and third lateral recesses 343 that are formed in volumes from which the third-tier sacrificial material layers 342 are removed. Upon removal of the sacrificial material layers 42, each annular void 27 can be incorporated into a respective adjoining lateral recess 43.

Each of the lateral recesses 43 may be a laterally extending cavity having a greater lateral dimension that is greater than a vertical extent. In other words, the lateral dimension of each of the lateral recesses 43 may be greater than the height of the respective lateral recess. A plurality of lateral recesses 43 may be formed in the volumes from which the material of the sacrificial material layers 42 is removed. Each of the lateral recesses 43 may extend substantially parallel to the top surface of the substrate 9. A lateral recess 43 may be vertically bounded by a top surface of an underlying insulating layer 32 and a bottom surface of an overlying insulating layer 32.

For each sacrificial contact via structure 84, a respective subset of at least one lateral recess 43 is provided, which laterally surrounds the sacrificial contact via structure 84. Within the respective subset of at least one lateral recess 43, a topmost lateral recess 43 is herein referred to as a first lateral recess 431, and any underlying lateral recess 43 is herein referred to as a second lateral recess 432.

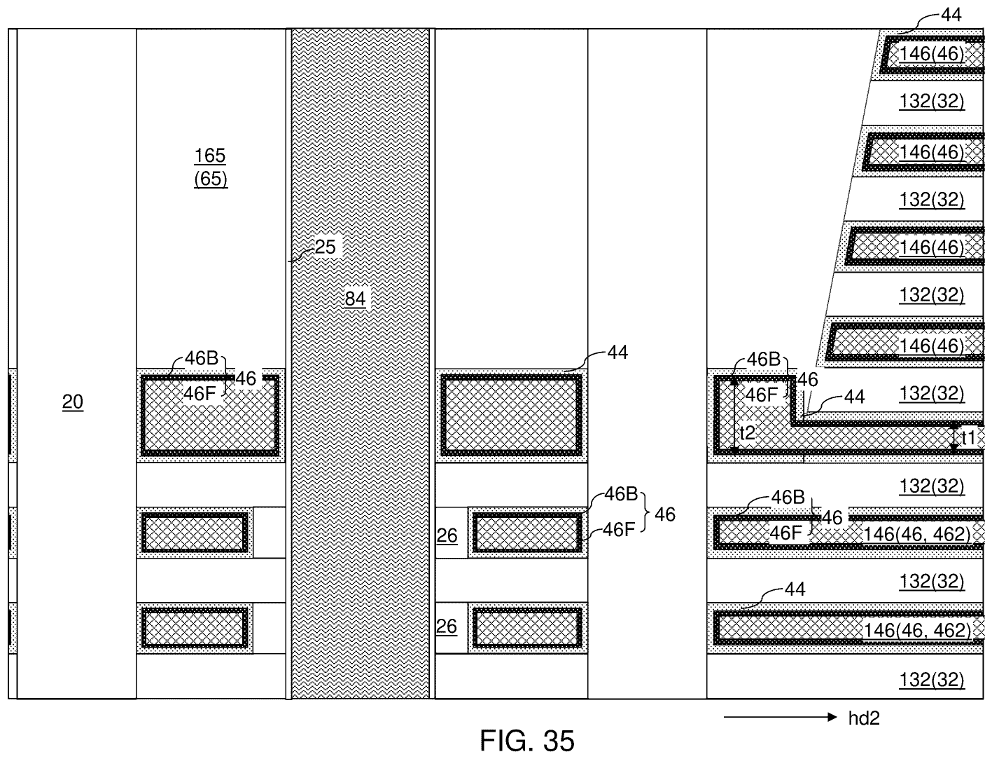

Referring to FIG. 35, the processing steps described with refence to FIGS. 22 and 23A-23D can be performed to form an outer blocking dielectric layer 44 and electrically conductive layers 46 within the lateral recesses 43. The sacrificial material layers 42 are replaced with combinations of an outer blocking dielectric layer 44 and an electrically conductive layer 46. A first electrically conductive layer 461 of the electrically conductive layers 46 occupies a volume of an annular void 27, which comprises a volume of a sacrificial fill material spacer 24.

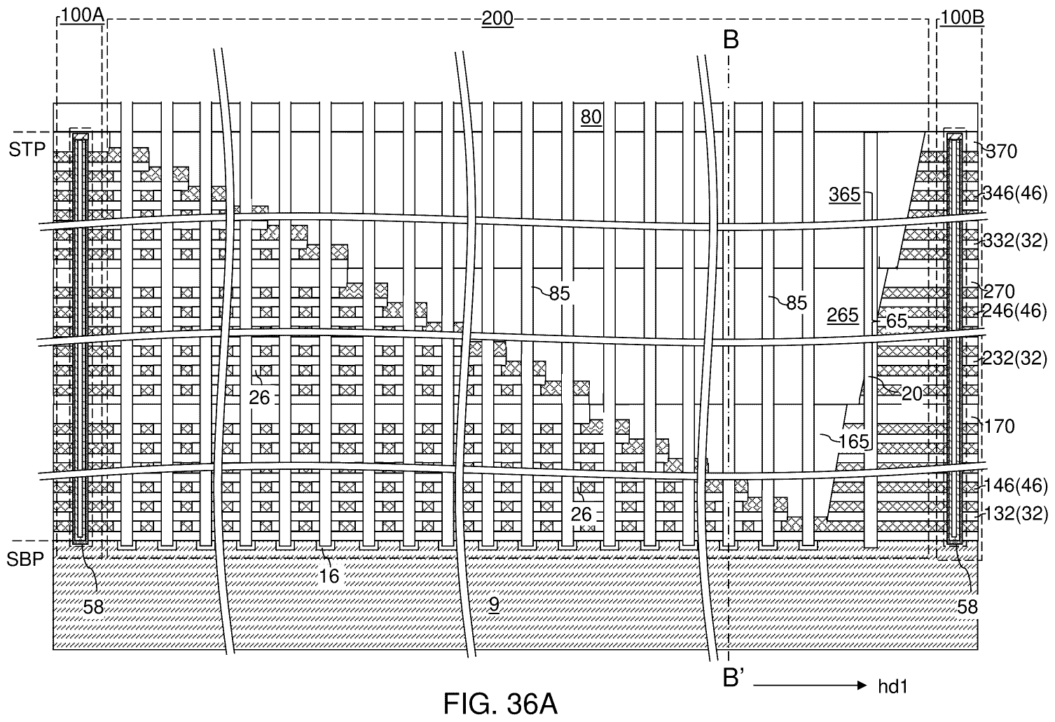

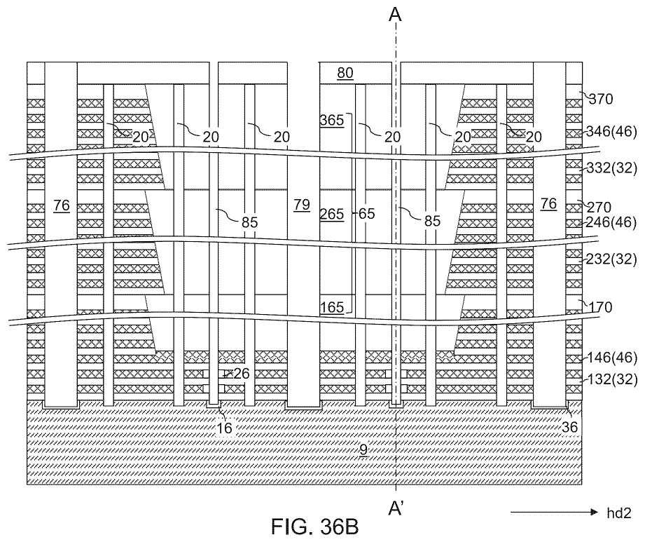

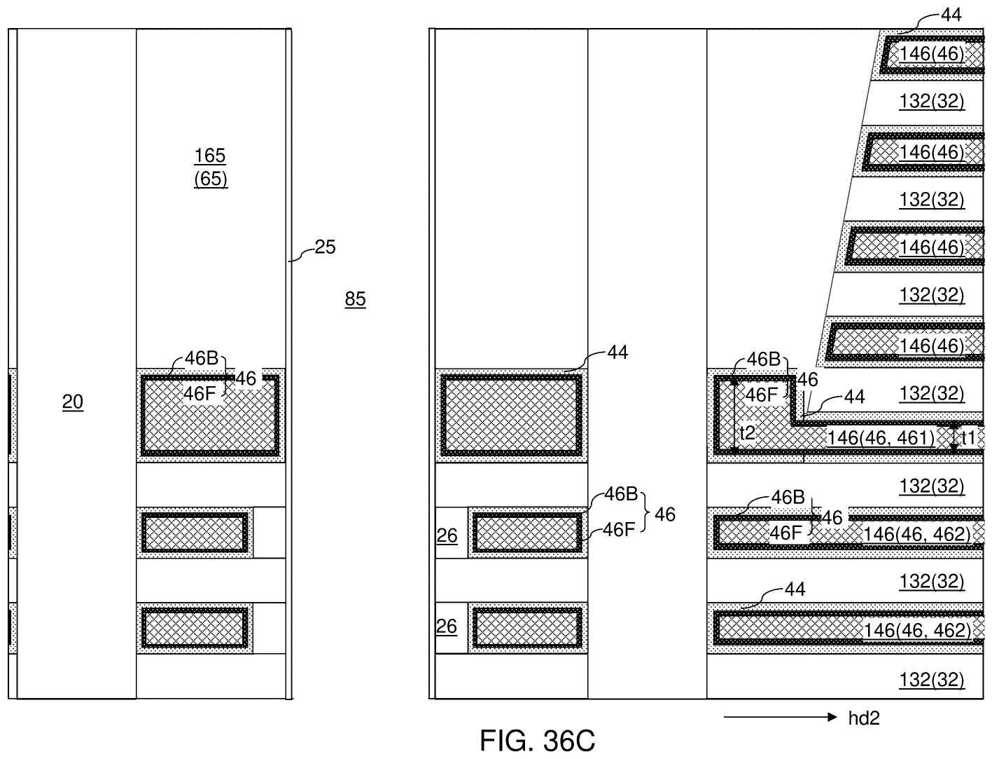

Referring to FIGS. 36A-36C, the processing steps described with reference to FIGS. 24A and 24B can be performed to form lateral isolation trench fill structures 76. Subsequently, the processing steps described with reference to FIGS. 25A-25C can be performed to remove the sacrificial contact via structures 84. In one embodiment, removal of the sacrificial contact via structures 84 may be performed employing an etch chemistry that is selective to the material of the sacrificial permeable liner 25. Voids are formed in the volumes of the contact via cavities 85. The selective removal process may comprise a selective etch process or an ashing process, as described above.

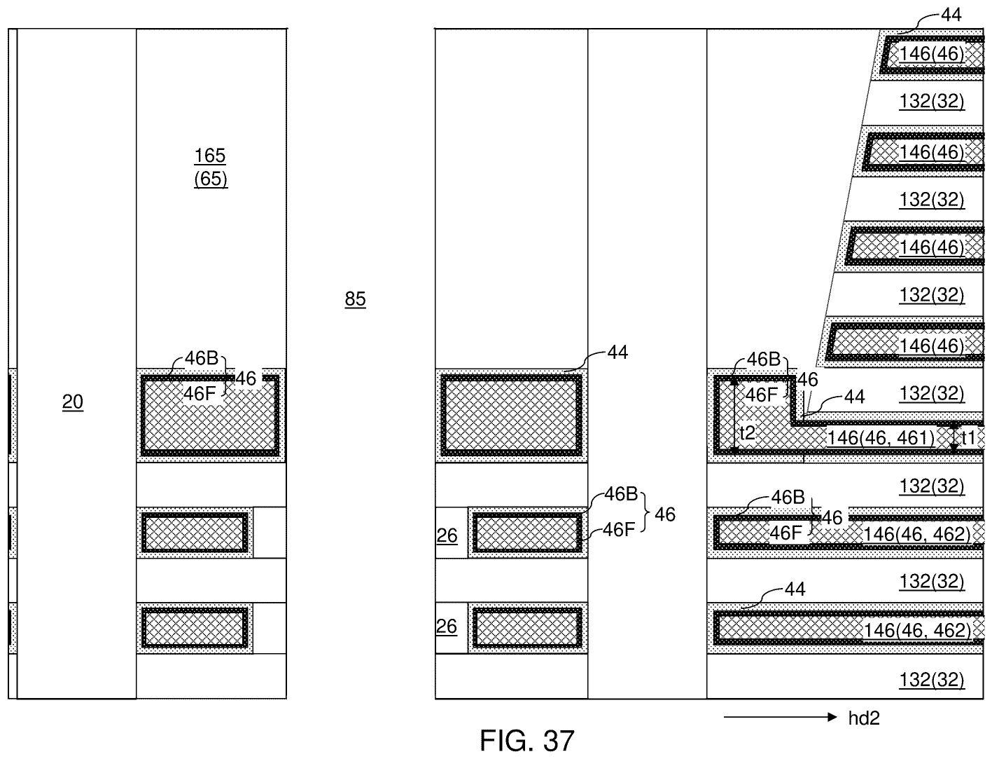

Referring to FIG. 37, an isotropic etch process can be performed to remove the sacrificial permeable liner 25. For example, a wet etch process employing dilute hydrofluoric acid may be performed to remove the sacrificial permeable liner 25.

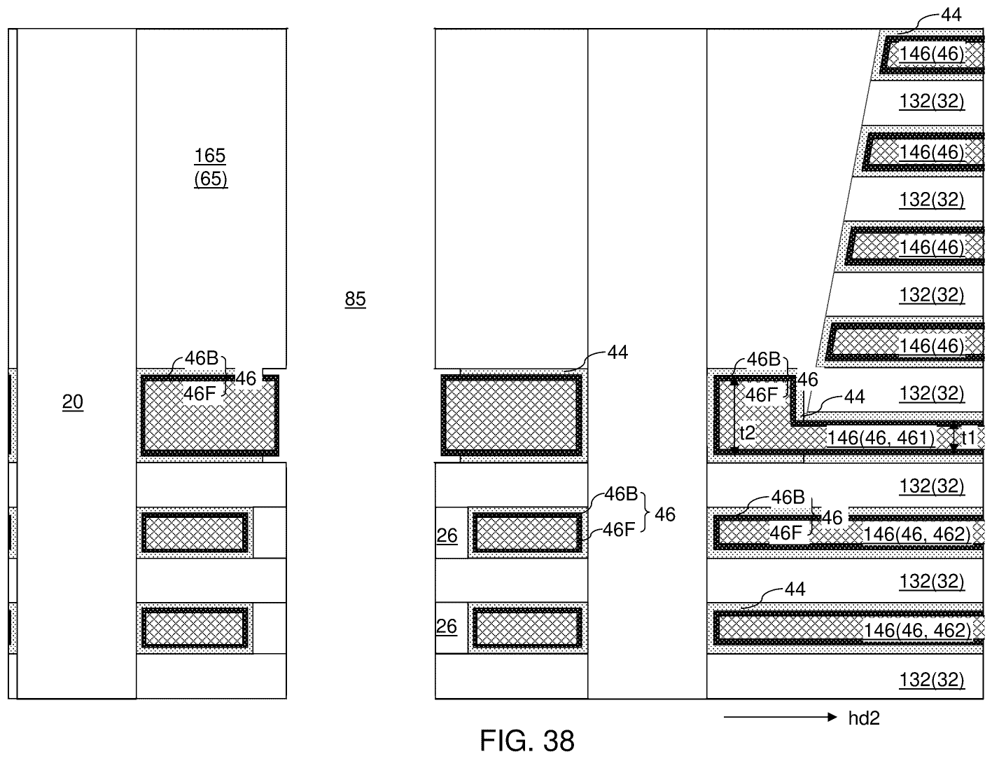

Referring to FIG. 38, an isotropic etch process that isotropically etches the material of the outer blocking dielectric layers 44 selectively to the materials of the electrically conductive layers 46, the insulating layers 32, the at least one retro-stepped dielectric material portion 65, the contact-level dielectric layer 80, and the various insulating cap layers (170, 270, 370) can be performed. In an illustrative example, if the outer blocking dielectric layers 44 comprise aluminum oxide, a wet etch process employing hot phosphoric acid can be performed. For each contact via cavity 85, surface segments of a respective first electrically conductive layer 461 can be physically exposed. The physically exposed surface segments of each first electrically conductive layer 461 may comprise a cylindrical surface segment, an annular top surface segment, and an annular bottom surface segment.

In this embodiment, the first electrically conductive layer 461 fills the annular void 27. Therefore, the edge of the first electrically conductive layer 461 is located closer to the contact via cavity 85 than if the annular void 27 was omitted. The isotropic etch process removes a relatively small horizontal length of the outer blocking dielectric layers 44. Therefore, the remaining portions of the outer blocking dielectric layers 44 act as an etch stop to reduce or prevent the etching of the insulating layers 32 during the isotropic etch process. Thus, a sufficient thickness of the insulating layer 32 is present under first electrically conductive layer 461 to prevent or reduce a short circuit or leakage current between the first electrically conductive layer 461 and the underlying second electrically conductive layer 462.

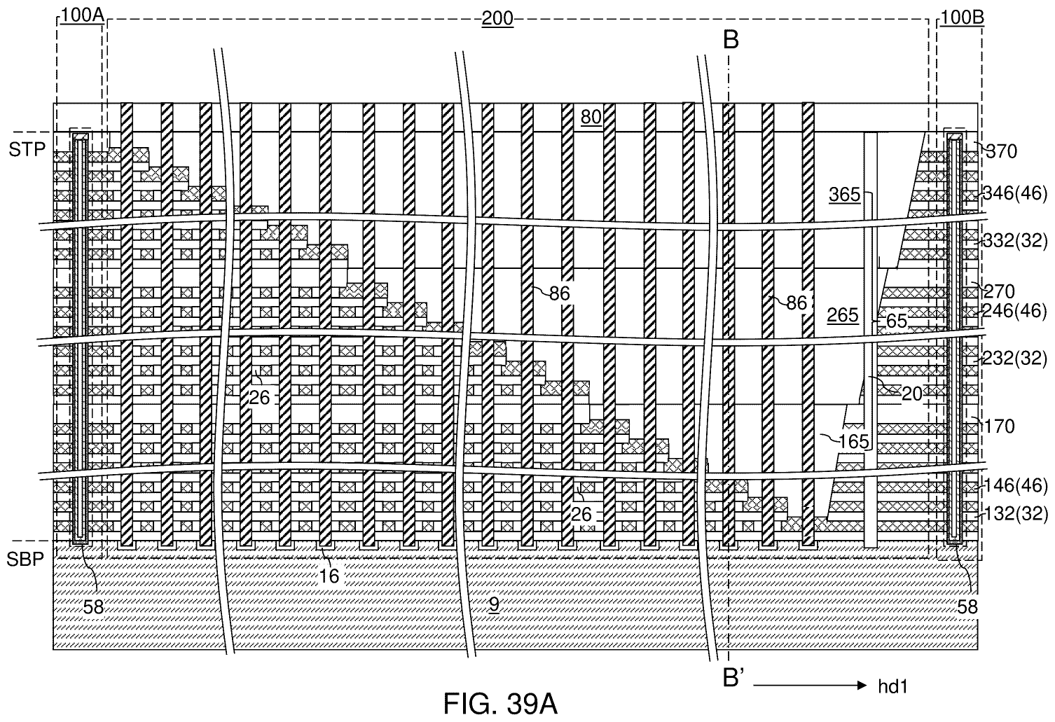

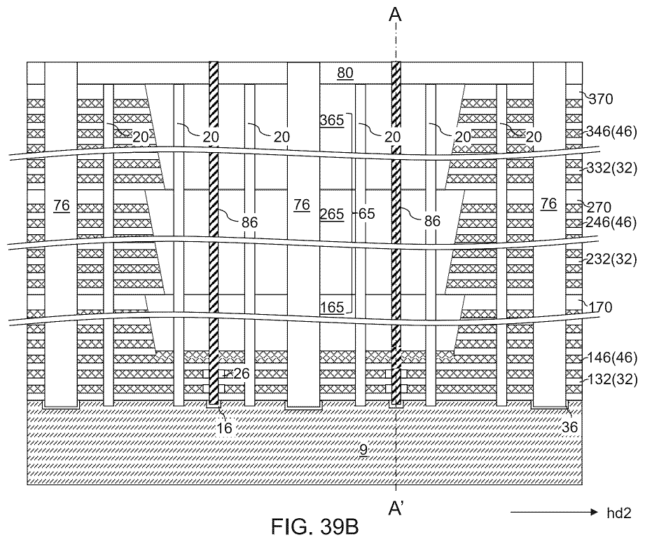

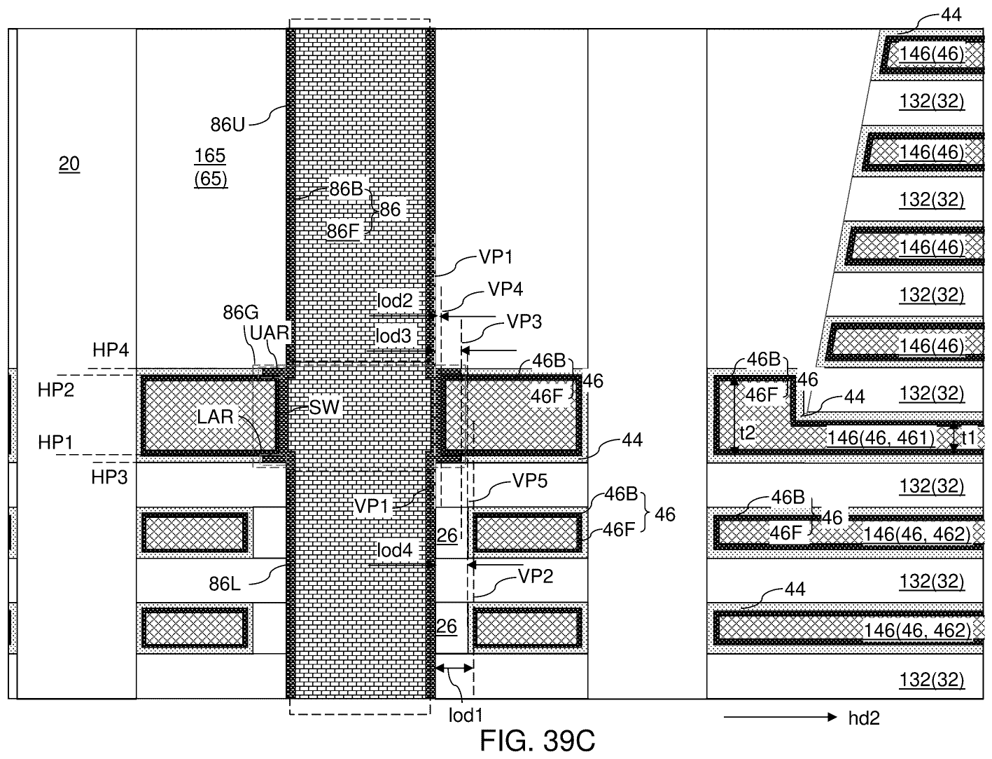

Referring to FIGS. 39A-39C, a contact via structure 86 can be formed in each contact via cavity 85. Specifically, at least one second electrically conductive material can be deposited in each of the contact via cavities 85. Excess portions of the at least one second electrically conductive material can be removed from above the horizontal plane including the top surface of the contact-level dielectric layer 80. Each remaining portion of the at least one second electrically conductive material that fills a respective one of the contact via cavities 85 constitutes a contact via structure that contacts a respective first electrically conductive layer 461 of the electrically conductive layers 46. Each such contact via structure is herein referred to as a layer contact via structure 86, which is described above.

In one embodiment, the at least one second electrically conductive material may comprise a contact-via metallic barrier material and a contact-via metallic fill material. In this case, each layer contact via structure 86 may comprise a metallic barrier liner (which is herein referred to as a contact-via metallic barrier liner 86B) and a metallic fill material portion (which is herein referred to as a contact-via metallic fill material portion 86F) that is laterally surrounded by the contact-via metallic barrier liner 86B, as described above.

Each layer contact via structure 86 contacts a cylindrical vertical sidewall surface segment, an annular top horizontal surface segment, and an annular bottom horizontal surface segment of a respective one of the electrically conductive layers 46. Thus, for each layer contact via structure 86, a first electrically conductive layer 461 can be defined as the electrically conductive layer 46 that is contacted by the layer contact via structure 86. In other words, each layer contact via structure 86 can be formed in a respective contact via cavity 85 directly on a cylindrical surface of a respective first electrically conductive layer 461. In case any electrically conductive layer 46 underlies the first electrically conductive layer 461, then it is herein referred to as a second electrically conductive layer 462.

Generally, each contact via cavity 85 can be filled with a respective contact via structure 86 (which may be referred to as a layer contact via structure). Each contact via structure 86 contacts a cylindrical sidewall of a respective first electrically conductive layer 461 of the electrically conductive layers 46 which is formed within a volume of a respective first sacrificial material layer 421. Each contact via structure 86 comprises a respective upper portion 86U, a respective lower portion 86L, and a respective laterally bulging portion 86G.

The second exemplary structure illustrated in FIGS. 39A-39C comprises a device structure, which includes: at least one alternating stack (32, 46) of respective insulating layers 32 and respective electrically conductive layers 46, wherein each of the at least one alternating stack (32, 46) comprises a respective stepped surface located in a staircase region; at least one retro-stepped dielectric material portion 65 overlying portions of the at least one alternating stack (32, 46) located in the staircase region; a memory opening 49 vertically extending through each layer within the at least one alternating stack (32, 46); a memory opening fill structure 58 located in the memory opening 49 and comprising a vertical stack of memory elements (which may comprise portions of a memory material layer 54 located at levels of the electrically conductive layers 46) and a vertical semiconductor channel 60; and a contact via structure 86 comprising a laterally bulging portion 86G in contact with a first electrically conductive layer 461 of the electrically conductive layers 46 within the at least one alternating stack (32, 46), an upper portion 86U that vertically extends upward from the laterally bulging portion 86G and through he at least one retro-stepped dielectric material portion 65, and a lower portion 86L that vertically extends through second electrically conductive layers 462 of the electrically conductive layers 46 that underlie the first electrically conductive layer 461. The second electrically conductive layers 462 are laterally offset from a first cylindrical vertical plane VP1 including an outer sidewall of the lower portion 86L of the contact via structure 86 by a first lateral offset distance lod1; and the first electrically conductive layer 461 is laterally offset from the first cylindrical vertical plane VP1 by a second lateral offset distance lod2 that is less than the first lateral offset distance lod1.

In one embodiment, an outermost surface of the laterally bulging portion 86G is laterally offset from the first cylindrical vertical plane VP1 by a third lateral offset distance lod3 that is less than the first lateral offset distance lod1. In one embodiment, the laterally bulging portion 86G of the contact via structure 86 comprises an upper annular rim portion UAR, a lower annular rim portion LAR, and a connecting cylindrical surface segment (i.e., a vertical sidewall) SW that connects an inner periphery of an annular bottom surface of the upper annular rim portion UAR and an inner periphery of an annular top surface of the lower annular rim portion LAR. In one embodiment, the connecting cylindrical surface segment SW, the annular bottom surface of the upper annular rim portion UAR, and the annular top surface of the lower annular rim portion LAR are in contact surface segments of the first electrically conductive layer 461. In one embodiment, the outermost surface of the laterally bulging portion 86G comprises a cylindrical sidewall of the upper annular rim portion UAR and/or a cylindrical sidewall of the lower annular rim portion LAR.

In one embodiment, the connecting cylindrical surface segment SW is located within an additional cylindrical vertical plane (such as a fourth cylindrical vertical plane VP4) that is laterally offset from the first cylindrical vertical plane VP1 by the second lateral offset distance lod2 that is less than the third lateral offset distance lod3. In one embodiment, the device structure comprises a first outer blocking dielectric layer 44 in contact with the first electrically conductive layer 461 and comprising a tubular portion that laterally surrounds the memory opening fill structure 58, wherein the second lateral offset distance lod2 equals a thickness of the first outer blocking dielectric layer 44. In one embodiment, a cylindrical sidewall of the upper annular rim portion UAR contacts a sidewall of an opening in a first horizontally-extending portion of the first outer blocking dielectric layer 44; and a cylindrical sidewall of the lower annular rim portion LAR contacts a sidewall of an opening in a second horizontally-extending portion of the first outer blocking dielectric layer 44.

In one embodiment, the first electrically conductive layer 461 is embedded within the first outer blocking dielectric layer 44; and an annular bottom surface of the lower annular rim portion LAR is vertically offset from a first horizontal plane HP1 including a bottom surface of the first electrically conductive layer 461 by a first vertical offset distance that equals a thickness of the first outer blocking dielectric layer 44. In one embodiment, an annular top surface of the upper annular rim portion UAR is vertically offset from a second horizontal plane HP2 including a top surface of the first electrically conductive layer 461 by a second vertical offset distance that equals the first vertical offset distance.

In one embodiment, the device structure further comprises a vertical stack of annular dielectric spacers 26 laterally surrounding the lower portion of the contact via structures 86, and laterally surrounded by the second electrically conductive layers 462. In one embodiment, cylindrical outer sidewalls of the annular dielectric spacers 26 are laterally offset from the first cylindrical vertical plane VP1 by an additional lateral offset distance lod4 that is greater than the third offset distance lod3 and is less than the first lateral offset distance lod1. In one embodiment, each of the second electrically conductive layers 462 is embedded within a respective outer backside blocking dielectric layer 44; and the first lateral offset distance lod1 is greater than the additional lateral offset distance lod4 by a thickness of each of the outer backside blocking dielectric layers 44. In one embodiment, cylindrical inner sidewalls of the annular dielectric spacers 26 contact the lower portion of the contact via structure 86 within the first cylindrical vertical plane VP1. In one embodiment, cylindrical outer sidewalls of the annular dielectric spacers 26 contact sidewalls of openings in outer blocking dielectric layers 44 within a cylindrical vertical plane (which is herein referred to as a fifth cylindrical vertical plane VP5) which is located between the second cylindrical vertical plane VP2 and the third cylindrical vertical plane VP3. The lateral offset distance between the fifth cylindrical vertical plane VP5 and the first cylindrical vertical plane VP1 is herein referred to as a fourth lateral offset distance lod4.

In one embodiment, the first electrically conductive layer 461 has a first thickness t1 in a first portion that laterally surrounds the memory opening fill structure 58; and has a second thickness t2 that is greater than the first thickness t1 in a second portion that laterally surrounds the contact via structure 86.

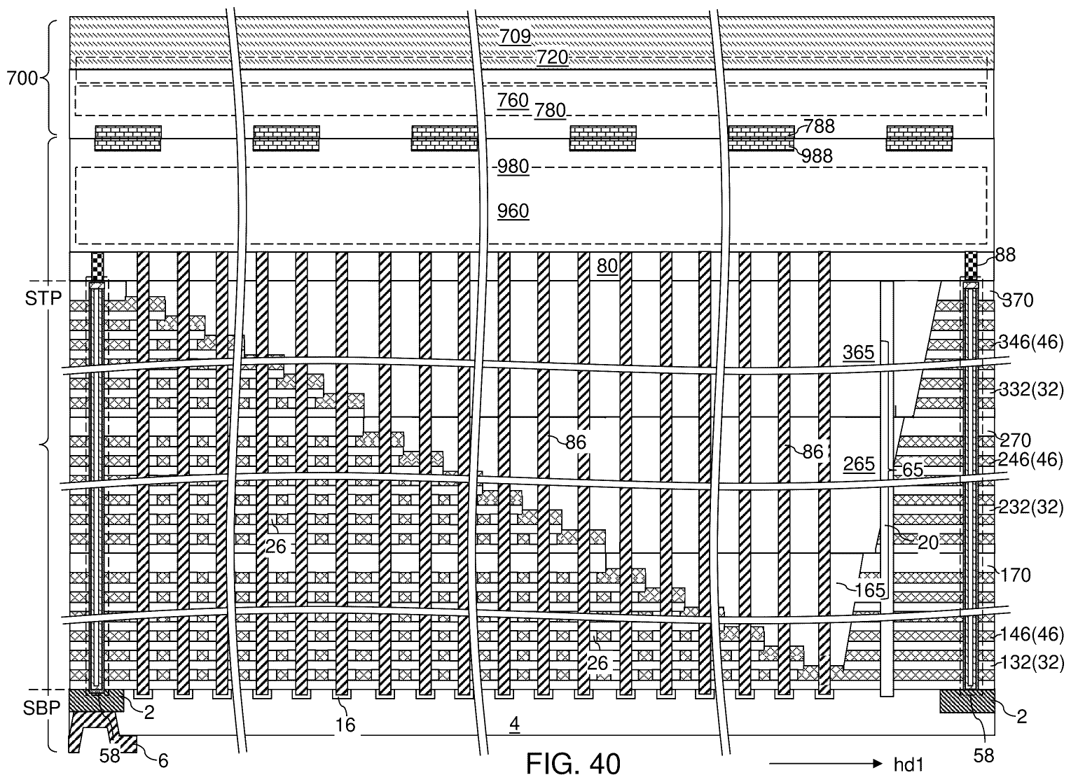

Referring to FIG. 40, the processing steps described with reference to FIGS. 28 and 29 can be performed to form a memory die 900, to bond the memory die 900 to a logic die 700, to remove a carrier substrate (in case the substrate 9 is a carrier substrate), and to form source-side structures (2, 4, 6).

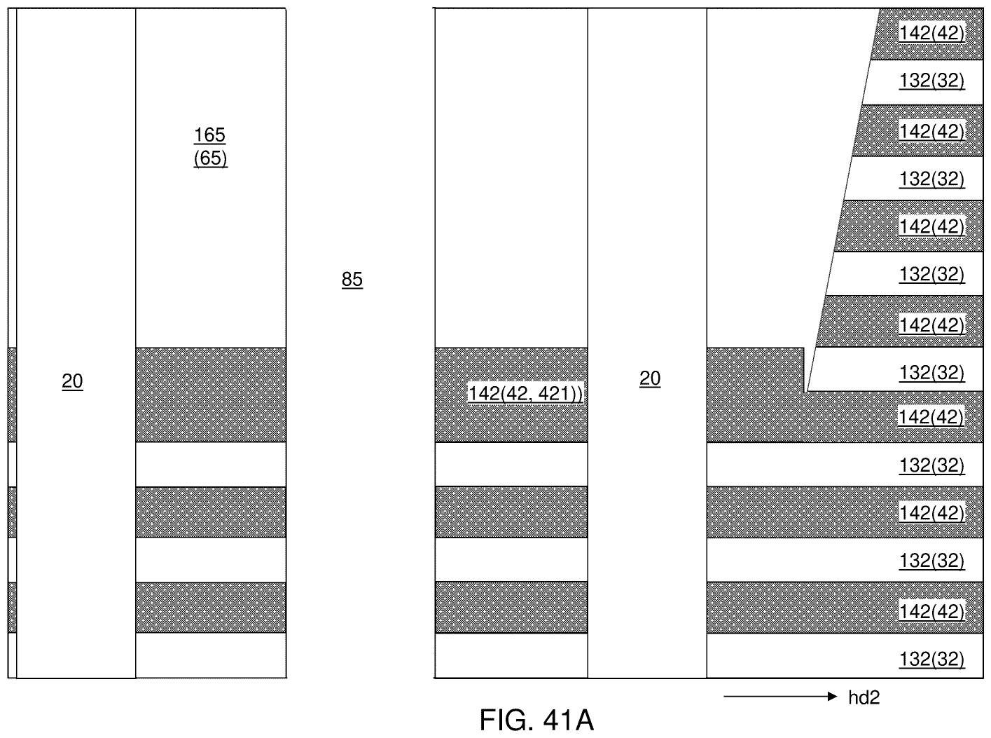

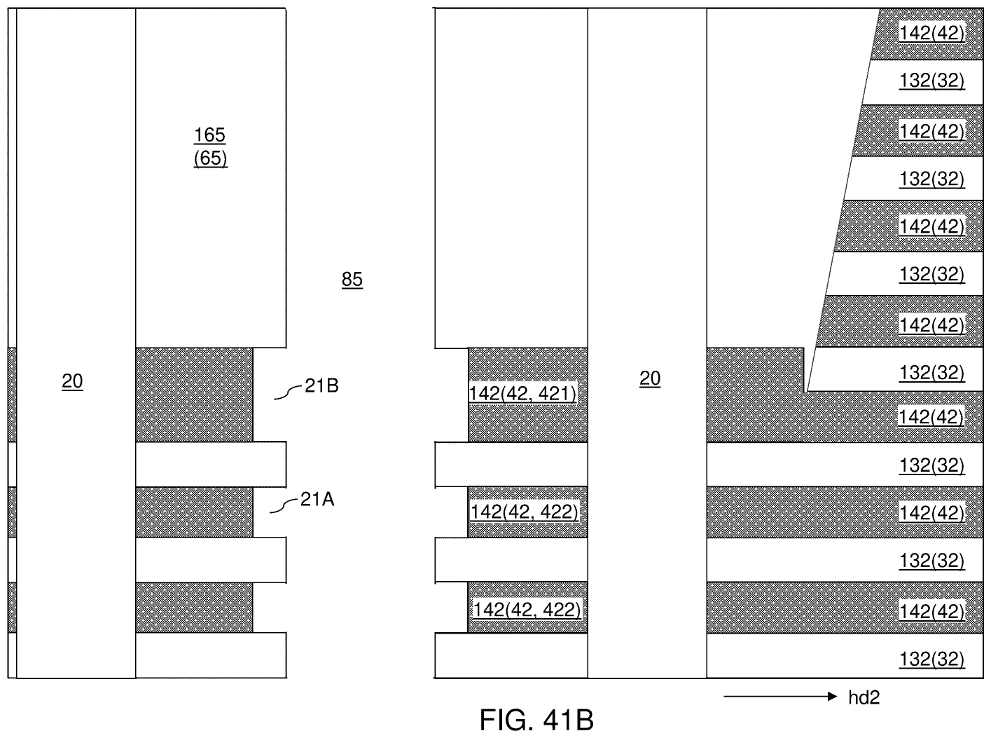

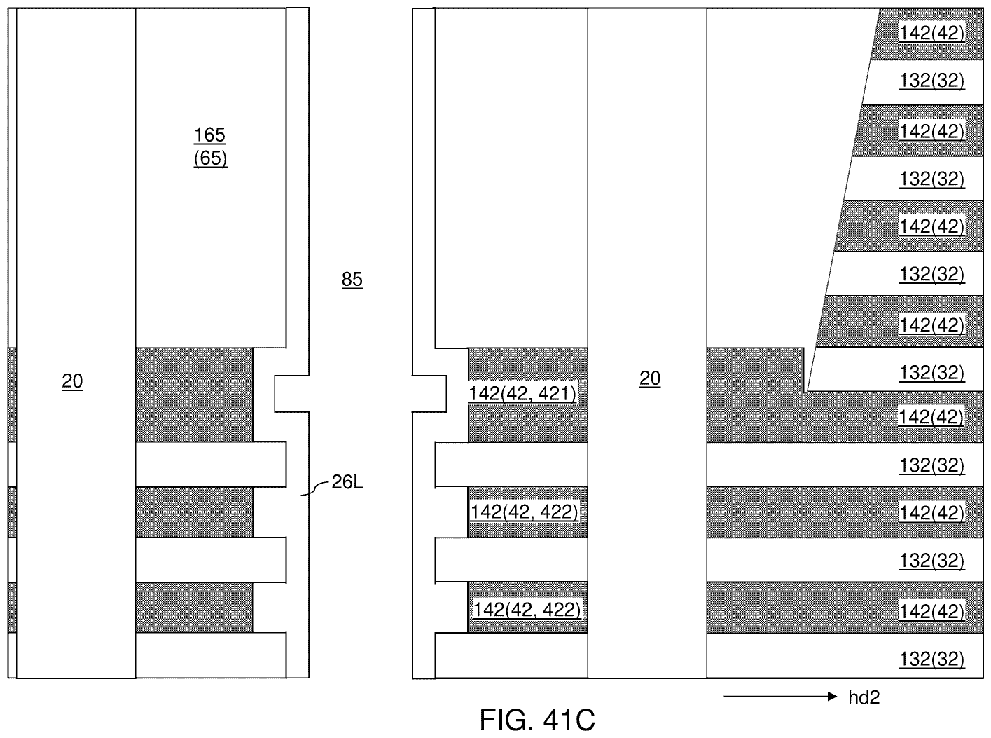

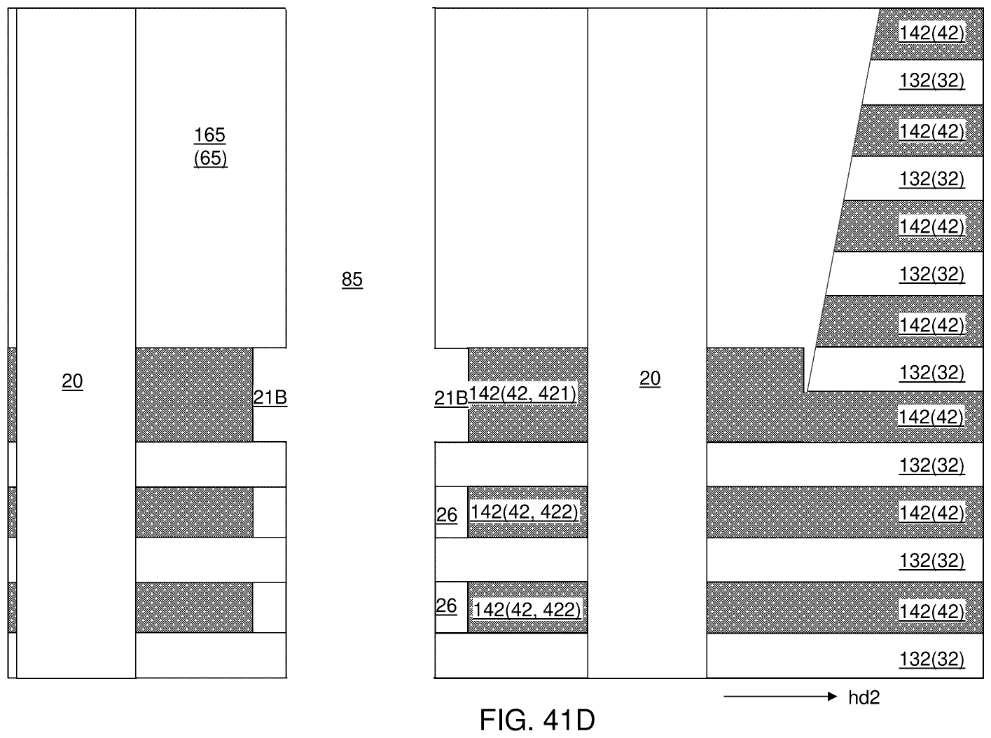

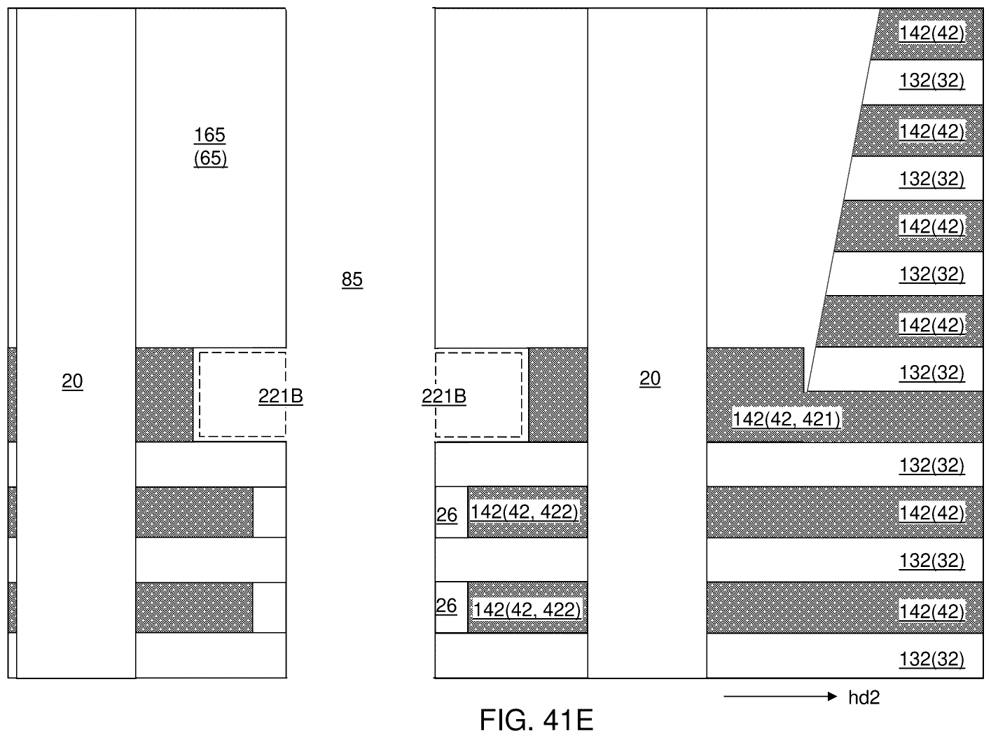

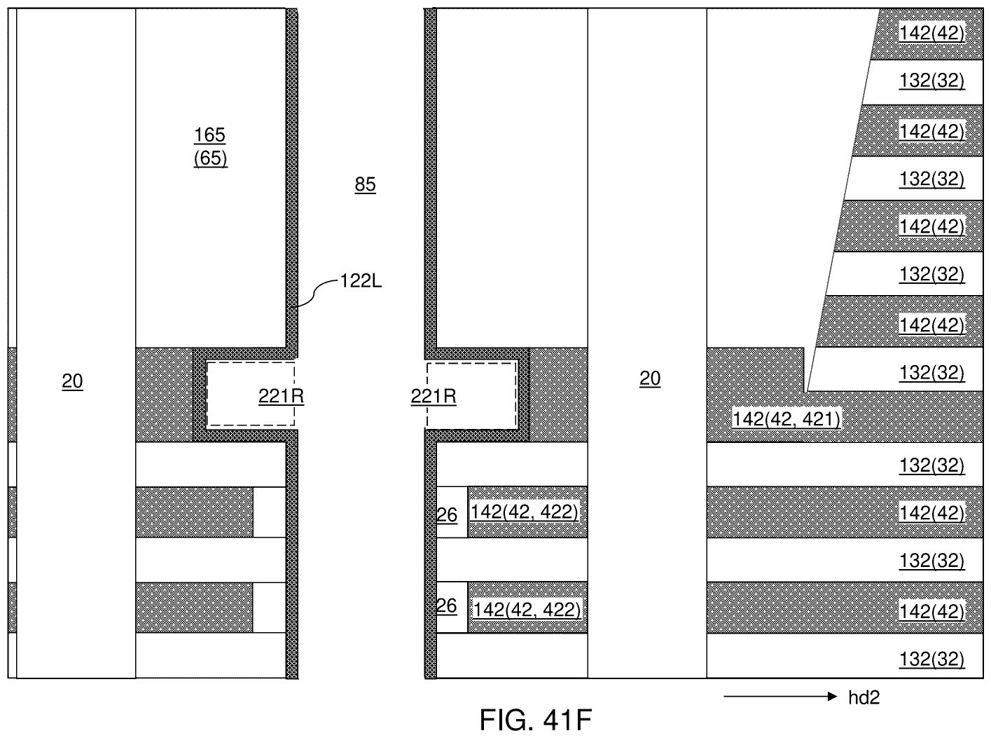

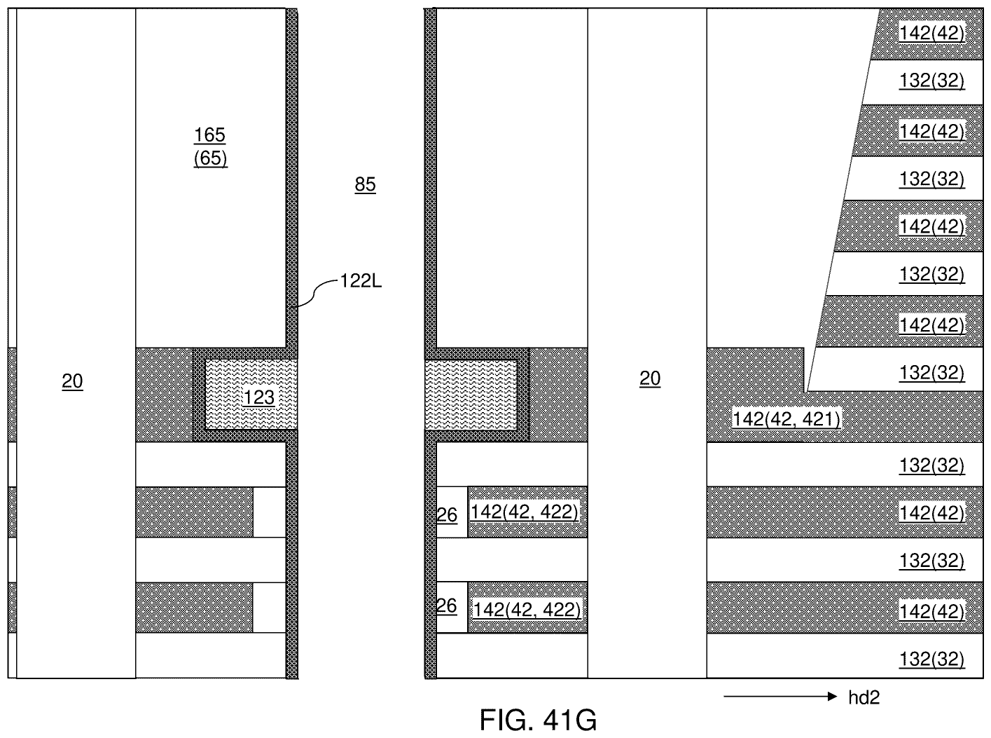

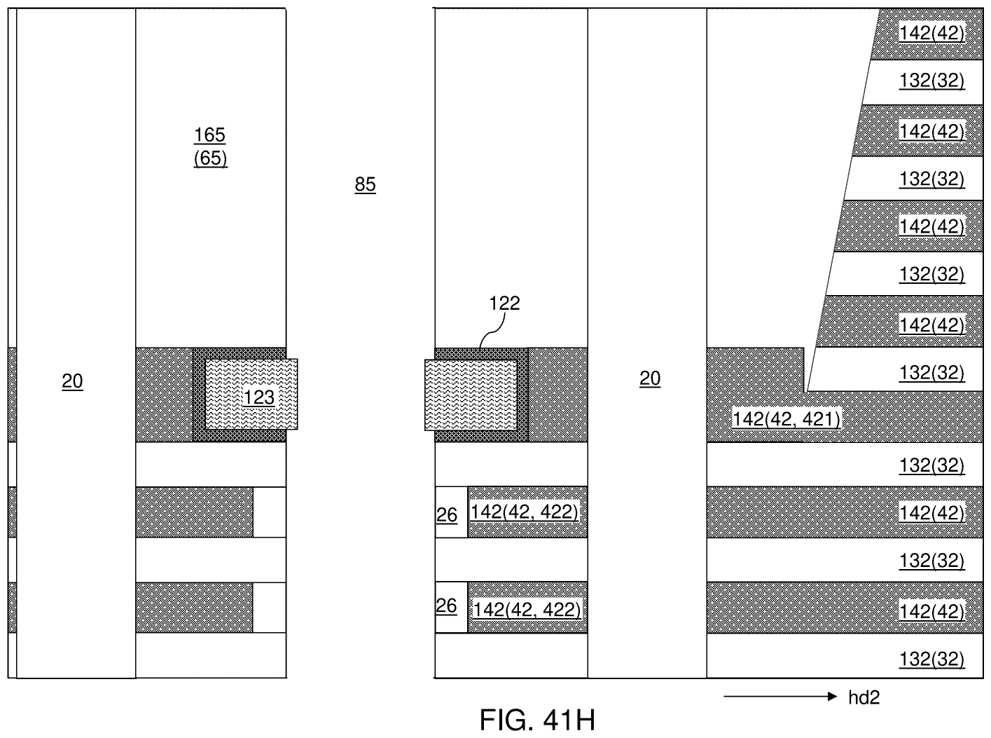

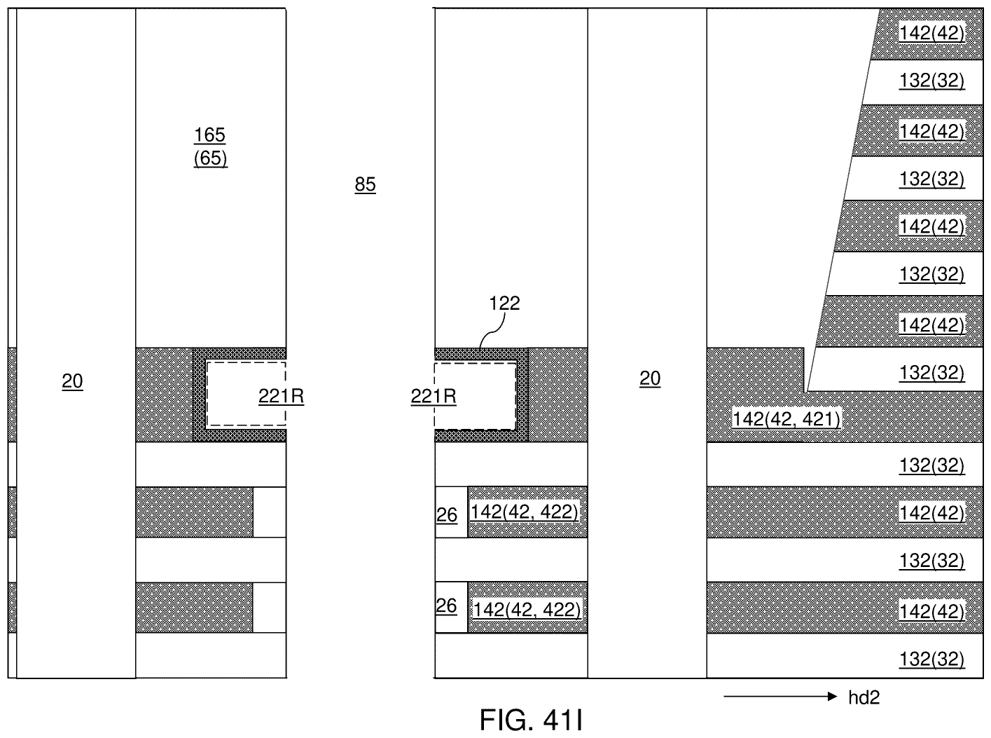

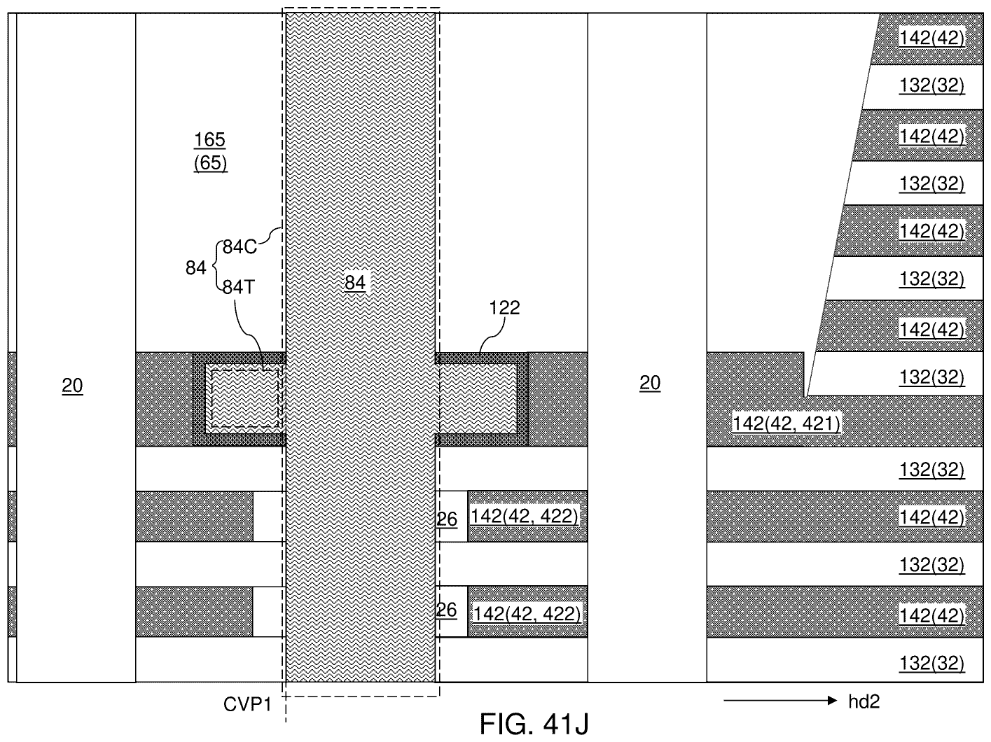

FIGS. 41A-41J are sequential vertical cross-sectional views of a region of a third exemplary structure during formation of a sacrificial contact via structure 84 around a contact via cavity 85 according to a third embodiment of the present disclosure.

Referring to FIG. 41A, the third exemplary structure is illustrated after formation of contact via cavities 85. The third exemplary structure can be the same as the second exemplary structure illustrated in FIGS. 31A-31C. Generally, an alternating stack (32, 42) of insulating layers 32 and sacrificial material layers 42 can be formed over a substrate 9. Stepped surfaces can be formed by patterning the alternating stack (32, 42) in a staircase region. At least one retro-stepped dielectric material portion 65 can be formed over the stepped surfaces. Contact via cavities 85 can be formed through the retro-stepped dielectric material portion 65 and a respective subset of the sacrificial material layers 42 within the alternating stack (32, 42). For each contact via cavity 85, the subset of the sacrificial material layers 42 comprises a first sacrificial material layer 421 which is a topmost sacrificial material layer 42 of the subset of the sacrificial material layers 42 and optionally further comprises at least one second sacrificial material layer 422 that underlie the first sacrificial material layer 421. The first sacrificial material layer 421 and the at least one sacrificial material layer 422 is defined for each contact via cavity 85. For each sacrificial material layer 42, a contact via cavity 85 can be formed such that the sacrificial material layer 42 constitutes a first sacrificial material layer for the contact via cavity 85. For each contact via cavity 85 that vertically extends through two or more sacrificial material layers 42, a first sacrificial material layer 421 and at least one second sacrificial material layer 422 can be defined. For a contact via cavity 85 that vertically extends through only a single sacrificial material layer 42 (such as the bottommost sacrificial material layer), the single sacrificial material layer 42 constitutes a first sacrificial material layer 421.

Referring to FIG. 41B, a first isotropic etch process can be performed to isotropically etch proximal portions of the sacrificial material layers 42 around each contact via cavity 85 selectively to the insulating layers 32 and the at least one retro-stepped dielectric material portion 65. For example, if the sacrificial material layers 42 comprise silicon nitride and if the at least one retro-stepped dielectric material portion 65 comprises silicon oxide, the first isotropic etch process may comprise a wet etch process employing hot phosphoric acid which etches silicon nitride selectively to silicon oxide materials. The duration of the first isotropic etch process can be selected such that the lateral recess distance of the first isotropic recess etch process is in a range from 50% to 300%, such as from 100% to 200%, of the thickness of unthickened portions of the sacrificial material layers 42. For each contact via cavity 85 that vertically extends through a plurality of sacrificial material layers 42, at least one first annular recess region 21A may be formed in volumes from which material portions of at least one second sacrificial material layer 422 are removed selectively to the insulating layers 32. For each contact via cavity 85, a second annular recess region 21B can be formed by isotropically etching a proximal portion of the respective first sacrificial material layer 421 selectively to the insulating layers 32.

Referring to FIG. 41C, a recess-fill dielectric material layer 26L can be formed by conformally depositing a recess-fill dielectric material, such as silicon oxide, in the first annular recess regions 21A and the second annular recess regions 21B, and over sidewalls of the contact via cavities 85. In one embodiment, the recess-fill dielectric material layer 26L may comprise a silicate glass material. The thickness of the recess-fill dielectric material layer 26L can be greater than one half of the thickness of the unthickened portions of the sacrificial material layers 42, and can be less than one half of the thickness of the thickened portions of the sacrificial material layers 42. Thus, each first annular recess region 21A is completely filled with the recess-fill dielectric material layer 26L, while each second annular recess region 21B is only partly filled by the recess-fill dielectric material layer 26L.

Referring to FIG. 41D, a second isotropic etch process can be performed to isotropically etch the material of the recess-fill dielectric material layer 26L. According to an aspect of the present disclosure, the duration of the second isotropic etch process can be selected to ensure removal of the entirety of each portion of the recess-fill dielectric material layer 26L that fills the second annular recess regions 21B of the contact via cavities 85. In one embodiment, the duration of the second isotropic etch process can be selected such that the recess etch distance of the second isotropic etch process for the material of the recess-fill dielectric material layer 26L is in a range from 105% to 150%, such as from 100% to 130%, of the thickness of the recess-fill dielectric material layer 26L. The recess-fill dielectric material layer 26L is entirely removed from each second annular recess region 21B. The second isotropic etch process removes the recess-fill dielectric material layer 26L from an entire volume of each second annular recess region 21B. Each remaining portion of the recess-fill dielectric material layer 26L that fills a respective one of the first annular recess regions 21A comprises an annular dielectric spacer 26. Each first annular recess region 21A can be filled with a respective annular dielectric spacer 26.

Referring to FIG. 41E, a third isotropic etch process can be performed to isotropically etch proximal portions of a respective first sacrificial material layer 421 around each contact via cavity 85 selectively to the insulating layers 32, the annular dielectric spacers 26, and the at least one retro-stepped dielectric material portion 65. For example, if the sacrificial material layers 42 comprise silicon nitride and if the insulating layers 32, the annular dielectric spacers 26 and the at least one retro-stepped dielectric material portion 65 comprise silicon oxide, the third isotropic etch process may comprise a wet etch process employing hot phosphoric acid which etches silicon nitride selectively to silicon oxide materials. The duration of the third isotropic etch process can be selected such that the lateral offset distance between a laterally recessed sidewall of each first sacrificial material layer 421 around a contact via cavity 85 relative to a cylindrical sidewall of a retro-stepped dielectric material portion 65 that is exposed to the contact via cavity 85 is in a range from 150% to 1,000%, such as from 200% to 400%, of the thickness of unthickened portions of the sacrificial material layers 42.

Thus, each contact via cavity 85 can be laterally expanded by laterally recessing a respective first sacrificial material layer 421 around the contact via cavity 85. The annular volume of a void formed by removal of a portion of the first sacrificial material layer 421 has a generally toroidal shape and has a vertical cross-sectional profile including a rectangular shape. The annular volume of the void is herein referred to as a rectangular-vertical-profiled toroidal void 221B, i.e., a toroidal void having a vertical profile (i.e., a vertical cross-sectional view) that includes a rectangle as a boundary of the toroidal void. In other words, the annular volume of the void may be generated by rotating a rectangle located within a vertical plane and having a pair of vertically-extending sides around a vertical axis that is laterally offset from the rectangle. Each contact via cavity 85 comprises a rectangular-vertical-profiled toroidal void 221B that includes a volume from which a portion of the first sacrificial material layer 421 is removed.

Referring to FIG. 41F, a conformal sacrificial material layer 122L can be deposited in a peripheral region of each contact via cavity 85. The conformal sacrificial material layer 122L comprises a material that is different from the materials of the insulating layers 32, the at least one retro-stepped dielectric material portion 65, and the annular dielectric spacers 26, and can be subsequently removed selectively to the materials of the insulating layers 32, the at least one retro-stepped dielectric material portion 65, and the annular dielectric spacers 26. The material of the conformal sacrificial material layer 122L may optionally be the same as the material of the sacrificial material layers 42. In one embodiment, the sacrificial material layers 42 and the conformal sacrificial material layer 122L may comprise silicon nitride. The thickness of the conformal sacrificial material layer 122L is less than one half of the thickness of the rectangular-vertical-profiled toroidal voids 221B, and less than one half of the thickness of the thickened portion of each sacrificial material layer 42, and may be in a range from 3% to 20%, such as from 6% to 15%, of the thickness of the thickened portions of the sacrificial material layers 42. For example, the thickness of the conformal sacrificial material layer 122L may be in a range from 3 nm to 15 nm, although lesser and greater thicknesses may also be employed. The conformal sacrificial material layer 122L only partially fills the rectangular-vertical-profiled toroidal void 221B. An unfilled lateral recess 221R remains in the remaining volume of the rectangular-vertical-profiled toroidal void 221B.

Referring to FIG. 41G, optional annular etch mask material portions 123 may be formed within the unfilled lateral recesses 221R in the volumes of the rectangular-vertical-profiled toroidal voids 221B. In one embodiment, the annular etch mask material portions 123 may comprise a byproduct of chemical dry etching of silicon nitride conformal sacrificial material layer 122L. The byproduct accumulates in the unfilled lateral recess 221R during the chemical dry etching.

In an alternative embodiment, the annular etch mask material portions 123 may comprise a semiconductor material (such as amorphous silicon), a carbon-based material (such as amorphous carbon or diamond-like carbon), or a polymer material. In this alternative embodiment, the etch mask material may be conformally deposited and subsequently etched back such that the etch mask material remains only within the unfilled lateral recesses 221R.

In one embodiment, each annular etch mask material portion 123 may have a respective inner cylindrical sidewall that is located within or adjacent to a cylindrical vertical plane including a physically exposed cylindrical inner sidewall of the conformal sacrificial material layer 122L. In another embodiment, the annular etch mask material portions 123 may be omitted.

Referring to FIG. 41H, in one embodiment, a selective etch process can be performed to etch unmasked portions of the conformal sacrificial material layer 122L selectively to the materials of the insulating layers 32, the at least one retro-stepped dielectric material portion 65, the annular dielectric spacers 26, and the annular etch mask material portions 123. For example, if the conformal sacrificial material layer 122L comprises silicon nitride and the annular etch mask material portions 123 comprise a silicon nitride etch byproduct, the selective etch process may comprise a chemical dry etch process which forms the byproduct. Alternatively, if the conformal sacrificial material layer 122L comprises silicon nitride and the annular etch mask material portions 123 comprises amorphous silicon, the selective etch process may comprise a wet etch process employing hot phosphoric acid. Each remaining portion of the conformal sacrificial material layer 122L comprises a dual-inward-flanged tube 122 having a tubular portion that extends vertically and a pair of inward-protruding flange portions that protrude inward from the inner sidewall of the tubular portion at the top of the tubular portion and at the bottom of the tubular portion. Each dual-inward-flanged tube 122 comprises a sacrificial material, and is formed in a respective rectangular-vertical-profiled toroidal void 221B. Each dual-inward-flanged tube 122 comprises a tubular portion, an upper annular plate portion that is adjoined to a top end of an inner sidewall of the tubular portion, and a lower annular plate portion that is adjoined to a bottom end of the inner sidewall of the tubular portion.

Referring to FIG. 41I, each annular etch mask material portions 123 can be removed without removing the materials of the dual-inward-flanged tubes 122, the insulating layers 32, the at least one retro-stepped dielectric material portion 65, and the annular dielectric spacers 26. The annular etch mask material portions 123 may be removed by a selective isotropic etch process or by ashing. Unfilled lateral recesses 221R are re-formed in the volumes from which the annular etch mask material portions 123 are removed.

In an alternative embodiment, formation of the annular etch mask material portions 123 is omitted, and the steps shown in FIGS. 41G and 41H are not performed. Instead, the conformal sacrificial material layer 122L shown in FIG. 41F is anisotropically etched (e.g., etched using reactive ion etching) to remove the conformal sacrificial material layer 122L from the sidewalls of the contact via cavities without removing the conformal sacrificial material layer 122L from the rectangular-vertical-profiled toroidal voids 221B. The anisotropic etching forms the dual-inward-flanged tubes 122 surrounding the unfilled lateral recesses 221R, as shown in FIG. 41I.

Referring to FIG. 41J, a sacrificial via fill material can be deposited in the contact via cavities 85, and excess portions of the sacrificial via fill material can be removed from above the horizontal plane including the top surface of the contact-level dielectric layer 80. The sacrificial via fill material may comprise a semiconductor material, such as amorphous silicon or polysilicon, or may comprise a carbon-based material, such as amorphous carbon or diamond-like carbon. Each remaining portion of the sacrificial via fill material that fills a contact via cavity 85 comprises a sacrificial contact via structure 84. Each sacrificial contact via structure 84 may comprise a respective cylindrical portion 84C and a respective laterally bulging, toroidal sacrificial material portion 84T that contacts a sidewall of an opening in a thickened portion of a respective first sacrificial material layer 421.

In the third exemplary structure, for each sacrificial contact via structure 84 located within a respective contact via cavity 85 and laterally surrounded by a respective first sacrificial material layer 421 and second sacrificial material layers 422, the second sacrificial material layers 422 are laterally offset from a first cylindrical vertical plane CVP1 including an outer sidewall of the lower portion of the sacrificial contact via structure 84 by a first lateral offset distance, and the first sacrificial material layer 421 is laterally offset from the first cylindrical vertical plane CVP1 by a second lateral offset distance that is greater than the first lateral offset distance. A vertical stack of annular dielectric spacers 26 laterally surrounding the lower portion of the sacrificial contact via structure 84, and is laterally surrounded by the second sacrificial material layers 42. The rectangular-vertical-profiled toroidal void 221B is filled by a combination of a dual-inward-flanged tube 122 and a toroidal sacrificial material portion 84T.

Subsequently, the processing steps described with reference to FIGS. 20A-21D can be performed to form lateral isolation trenches 79 and lateral recesses 43.

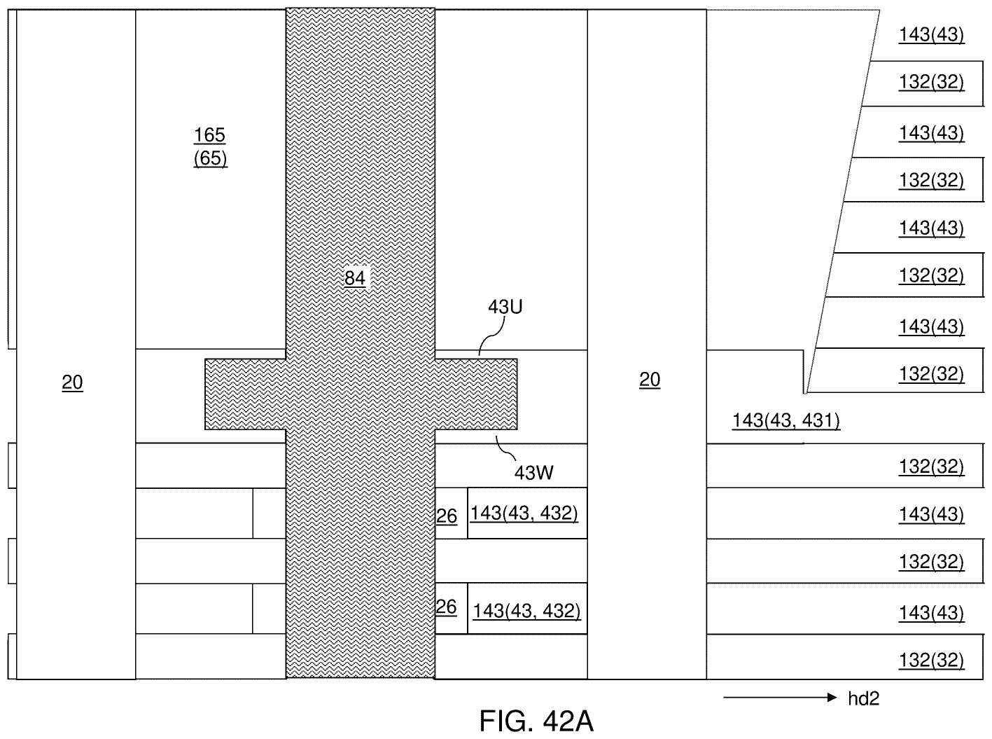

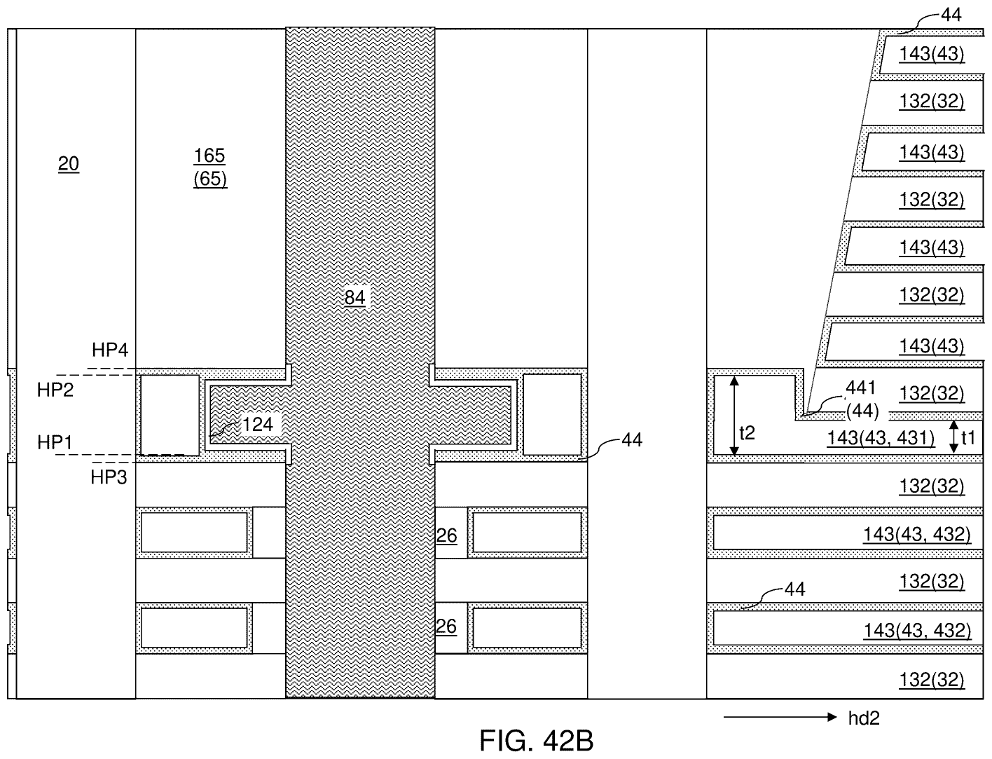

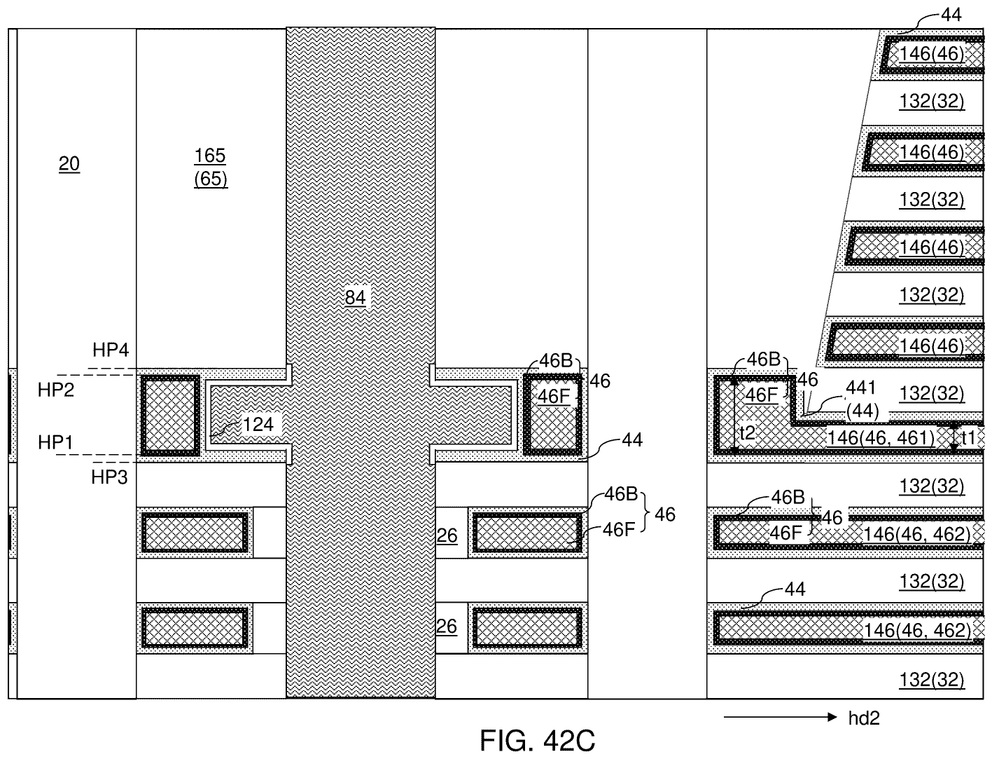

FIGS. 42A-42C are sequential vertical cross-sectional views of a region of the third exemplary structure during replacement of the sacrificial material layers 42 with outer blocking dielectric layers 44 and electrically conductive layers 46, according to the third embodiment of the present disclosure.

Referring to FIG. 42A, a region around a sacrificial contact via structure 84 is illustrated after formation of the lateral recesses 43. According to an aspect of the present disclosure, the selective isotropic etch process that removes the sacrificial material layers 42 also removes the dual-inward-flanged tubes 122 which may comprise the same material as the sacrificial material layers 42. Thus, the lateral recesses 43 include volumes of voids formed by removal of the sacrificial material layers 42 and volumes of voids formed by removal of the dual-inward-flanged tubes 122. An upper annular gap 43U is present between an annular top surface of each toroidal sacrificial material portion 84T and an overlying portion of the at least one retro-stepped dielectric material portion 65. A lower annular gap 43W is present between an annular bottom surface of each toroidal sacrificial material portion 84T and an underlying insulating layer 32.

Referring to FIG. 42B, an outer blocking dielectric layer 44 may be conformally deposited in peripheral portions of the lateral recesses 43 and the lateral isolation trenches 79. The outer blocking dielectric layer 44 includes a dielectric material, such as a dielectric metal oxide (e.g., aluminum oxide), silicon oxide, or a combination thereof. The outer blocking dielectric layer 44 may be formed as a continuous material layer by a conformal deposition process, such as an atomic layer deposition process and/or a chemical vapor deposition process. In one embodiment, each sacrificial contact via structure 84 may comprise a semiconductor material such as silicon and the outer blocking dielectric layer 44 comprises a dielectric oxide material. In this case, surface portions of the sacrificial contact via structures 84 that are in contact with the outer blocking dielectric layer 44 may be converted into semiconductor oxide liners 124 including a semiconductor oxide material (such as silicon oxide). The thickness of the semiconductor oxide liners 124 may be in a range from 0.5 nm to 3 nm, although lesser and greater thicknesses may also be employed. The semiconductor oxide liners 124 may be formed by oxidation of the exposed portions of the semiconductor sacrificial contact via structures 84 in the lateral recesses 43 in an oxidizing ambient, such as ozone, oxygen or water vapor.

The thickness of the outer blocking dielectric layer 44 is greater than one half of the thickness of each dual-inward-flanged tubes 122, and thus, is greater than one half of the height of each annular gap (43U, 43W) between an annular horizontal surface of a toroidal sacrificial material portion 84T and a most proximal horizontal surface of the insulating layers 32 and or the retro-stepped dielectric material portion 65. Thus, the entire volume of each annular gap (43U, 43W) overlying or underlying an annular horizontal surface of a toroidal sacrificial material portion 84T can be filled with the outer blocking dielectric layer 44 and optionally the semiconductor oxide liner 124. In one embodiment, the thickness of the outer blocking dielectric layer 44 outside the volumes that fill the annular gaps may be in a range from 2 nm to 10 nm, such as from 3 nm to 5 nm, although lesser and greater thicknesses may also be employed. The vertical thickness of the portions of the outer blocking dielectric layer 44 that fill the volumes of the annular gaps may be in a range from 110% to 200%, such as from 120% to 180%, and/or from 130% to 170%, of the thickness of the outer blocking dielectric layer 44 outside the volumes that fill the annular gaps (43U, 43W).

Optionally, a selective etch process may be performed to reduce the thickness of the portions of the outer blocking dielectric layer 44 located outside the annular gaps (43U, 43W) by providing a selective etchant into the lateral recesses 43.

Referring to FIG. 42C, the processing steps described with reference to FIGS. 23A-23E can be performed to form the electrically conductive layers 46. Specifically, a metallic barrier liner 46B and a metal fill material layer 46F may be conformally deposited in remaining unfilled volumes of the lateral recesses 43 and in peripheral regions of the lateral isolation trenches 79. The combination of the outer blocking dielectric layer 44, the metallic barrier liner 46B, and the metal fill material layer 46F may fill the entirety of the lateral recesses 43, and may fill peripheral portions of the lateral isolation trenches 79. The portions of the electrically conductive material layers that replace unthickened portions of the sacrificial material layers 42 may have a first thickness t1, and the portions of the electrically conductive material layer that replace the thickened portions of the sacrificial material layers 42 may have a second thickness t2 which is greater than the first thickness t1.

A selective etch process can be performed to etch back the electrically conductive material selectively to the material of the outer blocking dielectric layer 44. Each portion of the electrically conductive material can be removed from the peripheral regions of the lateral isolation trenches 79. Portions of the outer blocking dielectric layer 44 deposited in the lateral isolation trenches 79 may optionally be etched. Remaining portions of electrically conductive material comprise electrically conductive layers 46. The electrically conductive layers 46 comprise first-tier electrically conductive layers 146, second-tier electrically conductive layers 246, and third-tier electrically conductive layers 346. A plurality of first-tier electrically conductive layers 146 may be formed in the plurality of first lateral recesses 143, a plurality of second-tier electrically conductive layers 246 may be formed in the plurality of second lateral recesses 243, and a plurality of third-tier electrically conductive layers 346 may be formed in the plurality of third lateral recesses 343. Each of the electrically conductive layers 46 may include a respective metallic barrier liner 46B and a respective metal fill material portion 46F.

Generally, the sacrificial material layers 42 and the dual-inward-flanged tube 122 are replaced with at least electrically conductive layers 46 (e.g., with the electrically conductive layers 46, the outer blocking dielectric layers 44 and optionally the semiconductor oxide liners 124) employing the lateral isolation trenches 79 as a conduit for an etchant that removes the sacrificial material layers 42 and as a conduit for reactants that deposits the electrically conductive layers 46 (as well as the outer blocking dielectric layers 44 and the optional semiconductor oxide liners 124). The outer blocking dielectric layers 44 each embed a respective one of the electrically conductive layers 46. The outer blocking dielectric layers 44 are formed by conformally depositing a blocking dielectric material in peripheral regions of the lateral recesses at a thickness that is greater than one half of a thickness of the upper annular plate portion or the lower annular plate portion of each dual-inward-flanged tube 122.

For each sacrificial contact via structure 84 located within a respective contact via cavity 85 and having a respective laterally bulging, toroidal sacrificial material portion 84T, an electrically conductive layer 46 laterally surrounding the laterally bulging, toroidal sacrificial material portion 84T is provided, which is herein referred to as a first electrically conductive layer 461 for the sacrificial contact via structure 84 and for the contact via cavity 85. In other words, a first electrically conductive layer 461 can be defined for each sacrificial contact via structure 84 or for each contact via cavity 85. In case a sacrificial contact via structure 84 vertically extends through a set of two or more electrically conductive layers 46, the topmost electrically conductive layer 46 within the set of two or more electrically conductive layers 46 is the first electrically conductive layer 461 for the sacrificial contact via structure 84, and all other electrically conductive layers 46 within the set of two or more electrically conductive layers 46 constitutes second electrically conductive layers 462 for the sacrificial contact via structure 84. In other words, each “first” electrically conductive layer is defined relative to a selected sacrificial contact via structure 84 or relative to a selected contact via cavity 85. Each electrically conductive layer 46 may have a first thickness t1 around memory opening fill structures 58, and may have a second thickness t2 in a thickened portion.

Each of the electrically conductive layers 46 is embedded within a respective outer blocking dielectric layer 44 and is vertically spaced from a most proximal one of the insulating layers 32 by a horizontally-extending portion of the respective outer blocking dielectric layer 44. For each sacrificial contact via structure 84, the first electrically conductive layer 461 occupies a fraction of a volume of the first sacrificial material layer 421 upon replacement of the first sacrificial material layer 421 with a respective first outer blocking dielectric layer 441 and the first electrically conductive layer 461. The first electrically conductive layer 461 is embedded within a first outer blocking dielectric layer 441 of the outer blocking dielectric layers 44. A first portion of the first electrically conductive layer 461 laterally surrounds a set of memory opening fill structures 58 and has a first thickness t1, and a second portion of the first electrically conductive layer 461 laterally surrounds the toroidal sacrificial material portion 84T of the sacrificial contact via structure 84 and has a second thickness t2 that is greater than the first thickness t1. Since each electrically conductive layer 46 is a first electrically conductive layer 461 for a respective one of the sacrificial contact via structures 84, a first portion of each electrically conductive layer 461 laterally surrounds a set of memory opening fill structures 58 and has a first thickness t1, and a second portion of each electrically conductive layer 461 laterally surrounds the toroidal sacrificial material portion 84T of the respective one of the sacrificial contact via structures 84 and has a second thickness t2 that is greater than the first thickness t1.

Subsequently, the processing steps described with reference to FIGS. 24A-25C may be performed to form lateral isolation trench fill structures 76 and to remove the sacrificial contact via structures 84.

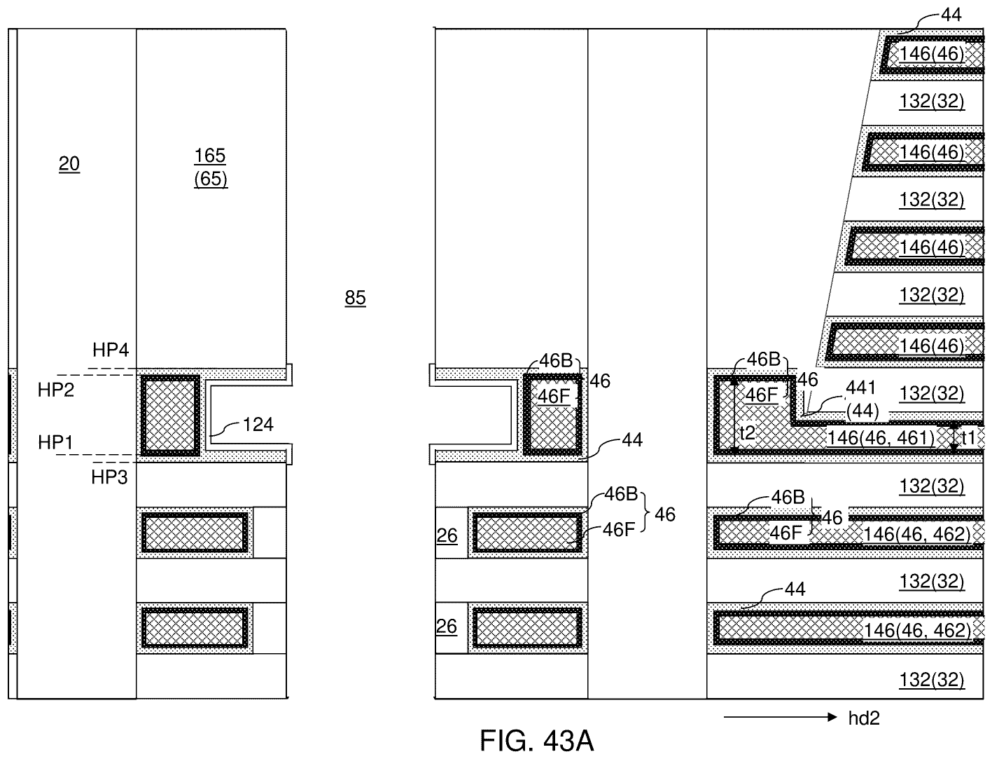

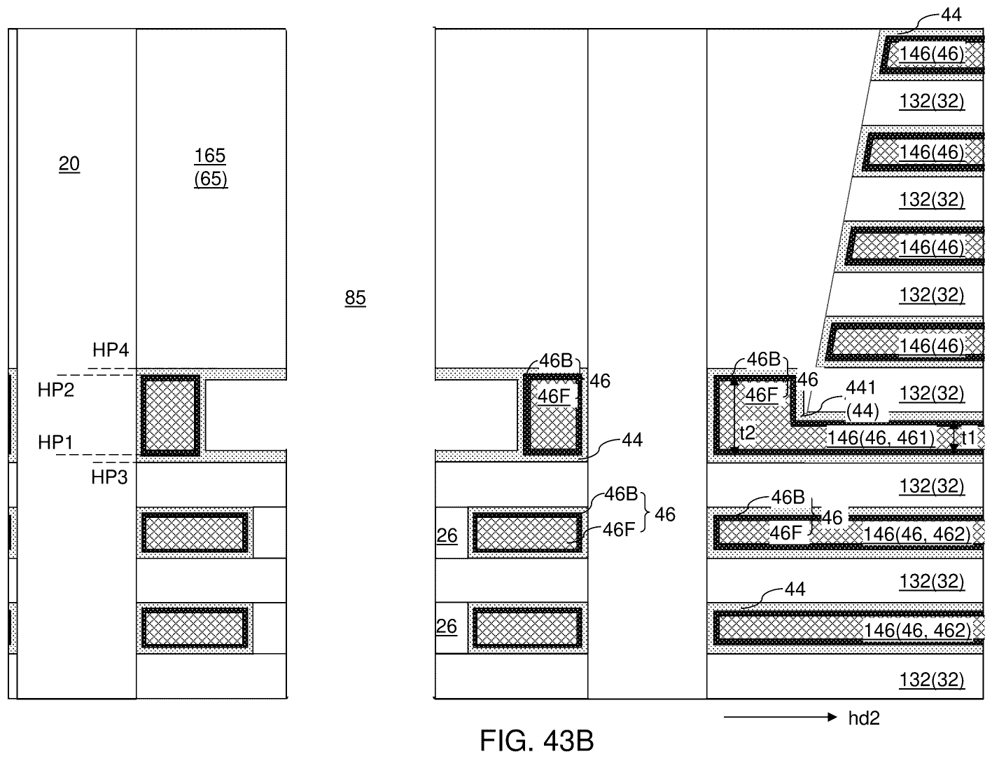

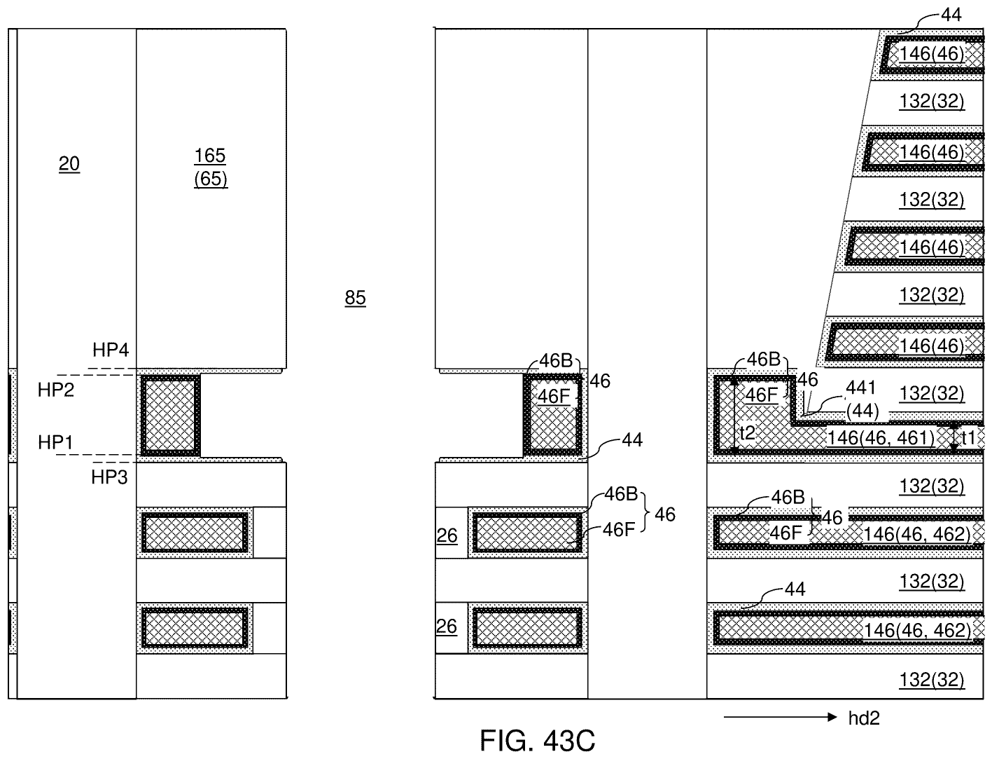

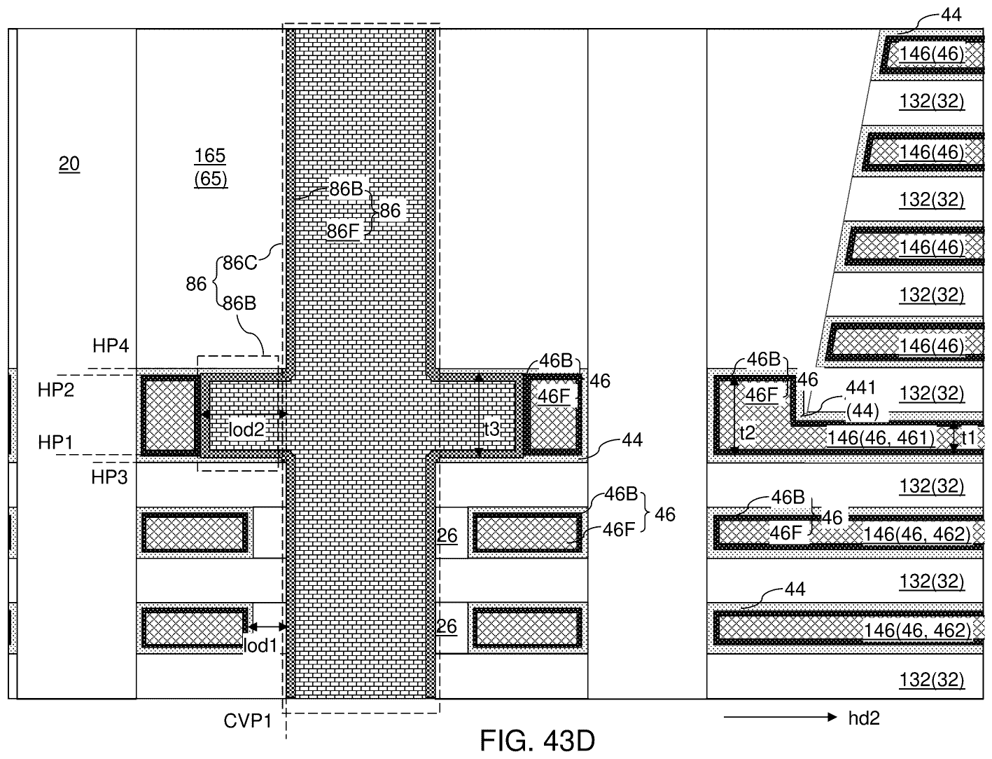

FIGS. 43A-43D are sequential vertical cross-sectional views of a region of the third exemplary structure during replacement of a sacrificial contact via structure 84 with a contact via structure 86 according to the third embodiment of the present disclosure.

Referring to FIG. 43A, the sacrificial contact via structures 84 can be removed selectively to the contact-level dielectric layer 80, the lateral isolation trench fill structures 76, the at least one retro-stepped dielectric material portion 65, the insulating layers 32, the annular dielectric spacers 26, and the optional semiconductor oxide liners 124 by performing a selective removal process. Voids are formed in the volumes of the contact via cavities 85. The selective removal process may comprise a selective etch process or an ashing process. In an illustrative example, if the sacrificial contact via structures 84 comprise amorphous silicon, the sacrificial contact via structures 84 may be removed by a wet etch process using hot trimethyl-2 hydroxyethyl ammonium hydroxide (“hot TMY”) or tetramethyl ammonium hydroxide (TMAH). If the sacrificial contact via structures 84 comprise a carbon-based material, the sacrificial contact via structures 84 may be removed by ashing.

Referring to FIG. 43B, in case semiconductor oxide liners 124 are present, the semiconductor oxide liners 124 may be removed by performing an isotropic etch process, such as a wet etch process employing dilute hydrofluoric acid.

Referring to FIG. 43C, a selective isotropic etch process is performed through the contact via cavities 85 to recess physically exposed surface portions of the outer blocking dielectric layers 44. As discussed above, the vertical thickness of the portions of the outer blocking dielectric layer 44 that fill the volumes of the annular gaps (which are formed by removal of horizontal annular portions of the dual-inward-flanged tubes 122) is greater than the thickness of each outer blocking dielectric layer 44 outside the volumes that fill the annular gaps. The duration of the selective isotropic etch process can be selected such that the etch distance of the selective isotropic etch process for the material of the outer blocking dielectric layers 44 is greater than the lateral thickness of cylindrical portions of the outer blocking dielectric layers 44 that are exposed to the contact via cavities 85, and is less than the vertical thickness of the portions of the outer blocking dielectric layer 44 that fill the volumes of the annular gaps (43U, 43W). Thus, the duration of the selective isotropic etch process can be selected such that cylindrical sidewalls of the thick portions of the electrically conductive layers 46 are physically exposed to the contact via cavities 85, while annular horizontally-extending remaining portions of the outer blocking dielectric layers 44 are located above and below a laterally bulging portion of the contact via cavities 85.

The annular horizontally-extending remaining portions of the outer blocking dielectric layers 44 protect the insulating layers 32 from being thinned (i.e., collaterally etched) during the previous etching steps. Breakdown and/or short circuits between the first electrically conductive layer 461 and the adjacent underlying second electrically conductive layer 462 can be avoided or reduced because the thickness of the insulating layer 32 between these electrically conductive layers (461, 462) is not significantly reduced by various etching steps.

Referring to FIG. 43D, at least one second electrically conductive material can be deposited in each of the contact via cavities 85. Excess portions of the at least one second electrically conductive material can be removed from above the horizontal plane including the top surface of the contact-level dielectric layer 80. Each remaining portion of the at least one second electrically conductive material that fills a respective one of the contact via cavities 85 constitutes a contact via structure 86 that contacts a respective first electrically conductive layer 461 of the electrically conductive layers 46. Each such contact via structure is herein referred to as a layer contact via structure 86. Each layer contact via structure 86 contacts a cylindrical surface of a respective one of the electrically conductive layers 46.

In one embodiment, the at least one second electrically conductive material may comprise a contact-via metallic barrier material and a contact-via metal fill material. In this case, each layer contact via structure 86 may comprise a metallic barrier liner (which is herein referred to as a contact-via metallic barrier liner 86B) and a metal fill material portion (which is herein referred to as a contact-via metal fill material portion 86F) that is laterally surrounded by the contact-via metallic barrier liner 86B. The contact-via metallic barrier liner 86B comprises the contact-via metallic barrier material, and the contact-via metallic fill material portion 86F comprises the contact-via metallic fill material.

The contact-via metallic barrier material comprises a metallic diffusion barrier material. For example, the contact-via metallic barrier material comprises a conductive metallic nitride material such as TiN, TaN, WN, and/or MoN. The contact-via metallic barrier material may be deposited as a continuous material layer having a uniform thickness throughout by a conformal deposition process such as a chemical vapor deposition process. The thickness of the contact-via metallic barrier material may be in a range from 3 nm to 60 nm, such as from 6 nm to 30 nm, although lesser and greater thicknesses may also be employed. The contact-via metal fill material comprises a metal fill material that provides a high electrical conductivity. For example, the contact-via metal fill material comprises and/or consists essentially of an elemental metal such as W, Co, Ru, Mo, Cu, or a combination thereof. The contact-via metal fill material may be formed by a conformal deposition process, such as a chemical vapor deposition process.

Generally, each contact via cavity 85 can be filled with a respective contact via structure 86 (which may be referred to as a layer contact via structure). Each contact via structure 86 contacts a cylindrical sidewall of a respective first electrically conductive layer 461 of the electrically conductive layers 46. Each contact via structure 86 comprises a respective cylindrical portion 86C and a respective laterally bulging portion 86B. Thus, each sacrificial contact via structure 84 is replaced with a respective contact via structure 86.

The laterally bulging portion 86B of each contact via structure 86 is formed directly on a cylindrical sidewall of a respective first electrically conductive layer 461. The first electrically conductive layer 461 is embedded within a first outer blocking dielectric layer 441 of the outer blocking dielectric layers 44. The laterally bulging portion 86B of the contact via structure 86 comprises an annular horizontal top surface in contact with an annular horizontal bottom surface segment of the first outer blocking dielectric layer 441. In one embodiment, a horizontal top surface of the first outer blocking dielectric layer 441 contacts a bottom surface of a retro-stepped dielectric material portion 65.

For each contact via structure 86, a sidewall of the upper portion of the contact via structure 86 extends vertically from a periphery of the bottom surface of the at least one retro-stepped dielectric material portion 65 at least to a topmost surface of the at least one retro-stepped dielectric material portion 65 with a straight vertical cross-sectional profile. In one embodiment, the first portion of the first electrically conductive layer 461 laterally surrounds the memory opening fill structure 58 and has a first thickness t1, and a second portion of the first electrically conductive layer 461 laterally surrounds the laterally bulging portion 86B of the contact via structure 86 and has a second thickness t2 that is greater than the first thickness t1. In one embodiment, the laterally bulging portion 86B of the contact via structure 86 has a third thickness t3 that is greater than the second thickness t2.

For each contact via structure 86, the second portion of the first electrically conductive layer 461 comprises a bottom surface located within a first horizontal plane HP1 and a top surface located within a second horizontal plane HP2, and the laterally bulging portion 86B of the contact via structure 86 comprises an annular horizontal bottom surface that underlies the first horizontal plane HP1, and an annular horizontal top surface that overlies the second horizontal plane HP2. In one embodiment, the first electrically conductive layer 461 is embedded within a first outer blocking dielectric layer 441; the first outer blocking dielectric layer 441 comprises a bottommost surface located within a third horizontal plane HP3 and a topmost surface located within a fourth horizontal plane HP4; the annular horizontal bottom surface of the laterally bulging portion 86B is located above the third horizontal plane HP3; and the annular horizontal top surface of the laterally bulging portion 86B is located below the fourth horizontal plane HP4. In one embodiment, a thickness of a first annular portion of the first outer blocking dielectric layer 441 that overlies and contacts the annular horizontal top surface of the laterally bulging portion 86B is less than a thickness of a horizontally-extending portion of the first outer blocking dielectric layer 44 that overlies and contacts the first electrically conductive layer 461.

In one embodiment, the second electrically conductive layers 462 are laterally offset from a first cylindrical vertical plane CVP1 including an outer sidewall of the lower portion of the contact via structure 86 by a first lateral offset distance lod1; and the first electrically conductive layer 461 is laterally offset from the first cylindrical vertical plane CVP1 by a second lateral offset distance lod2 that is greater than the first lateral offset distance lod1. A vertical stack of annular dielectric spacers 26 may laterally surround the lower portion of the contact via structure 86, and may be laterally surrounded by the second electrically conductive layers 462.

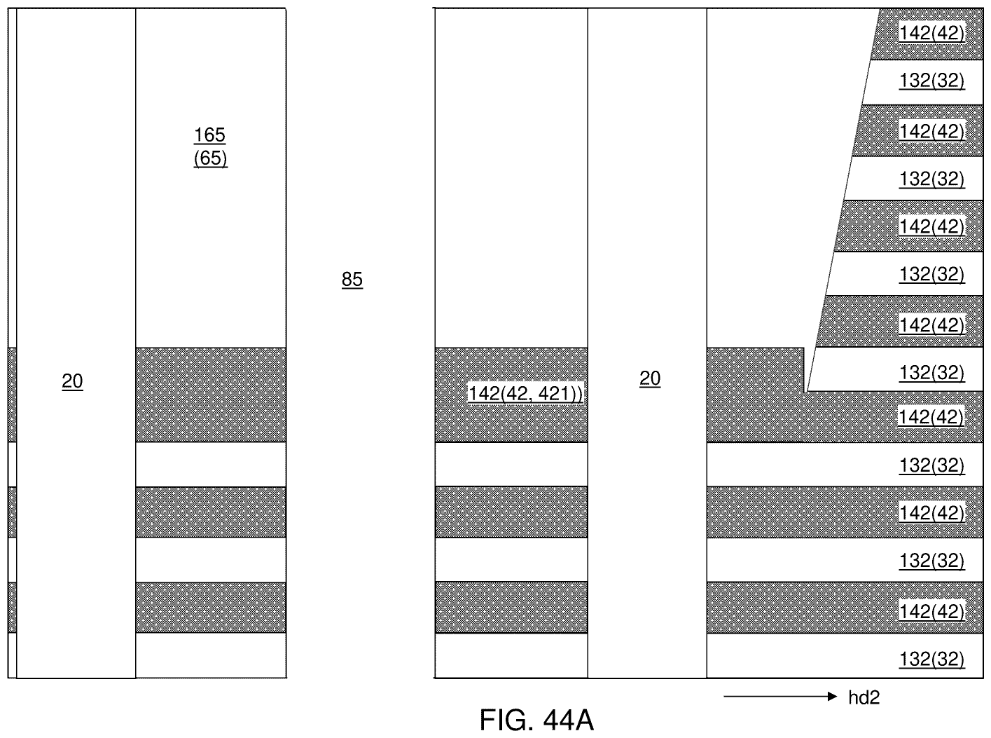

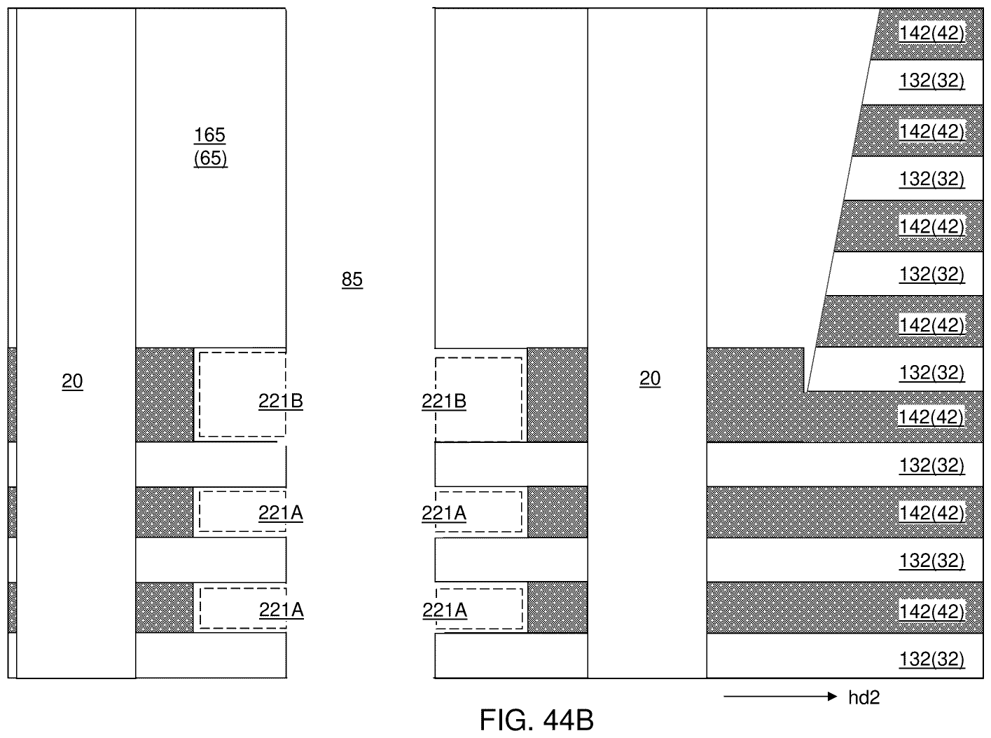

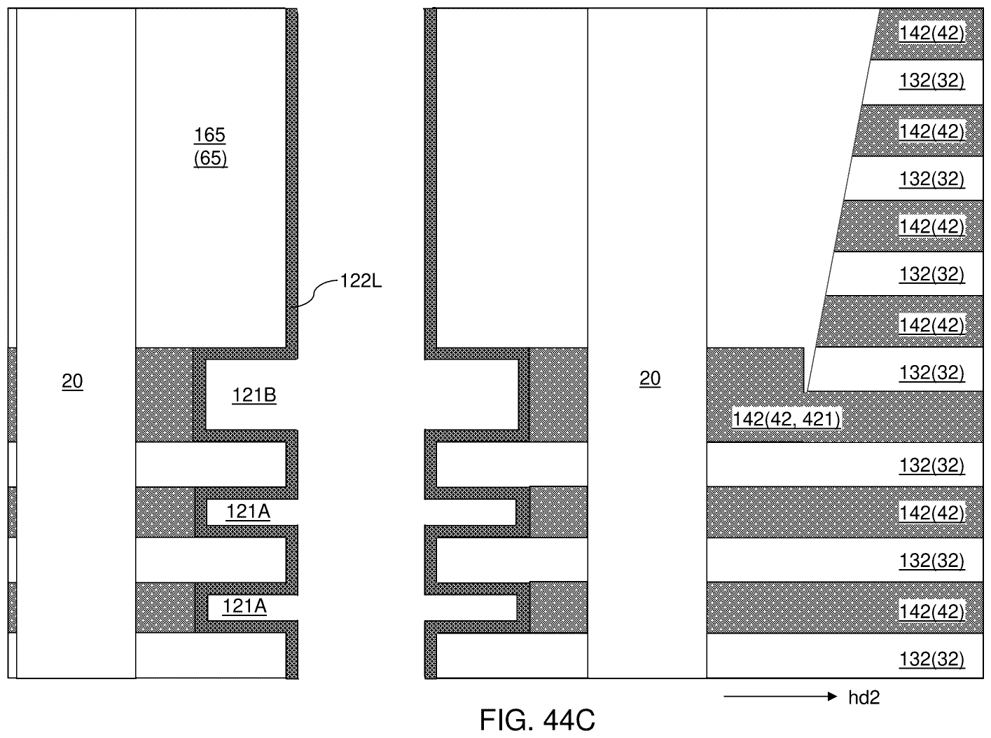

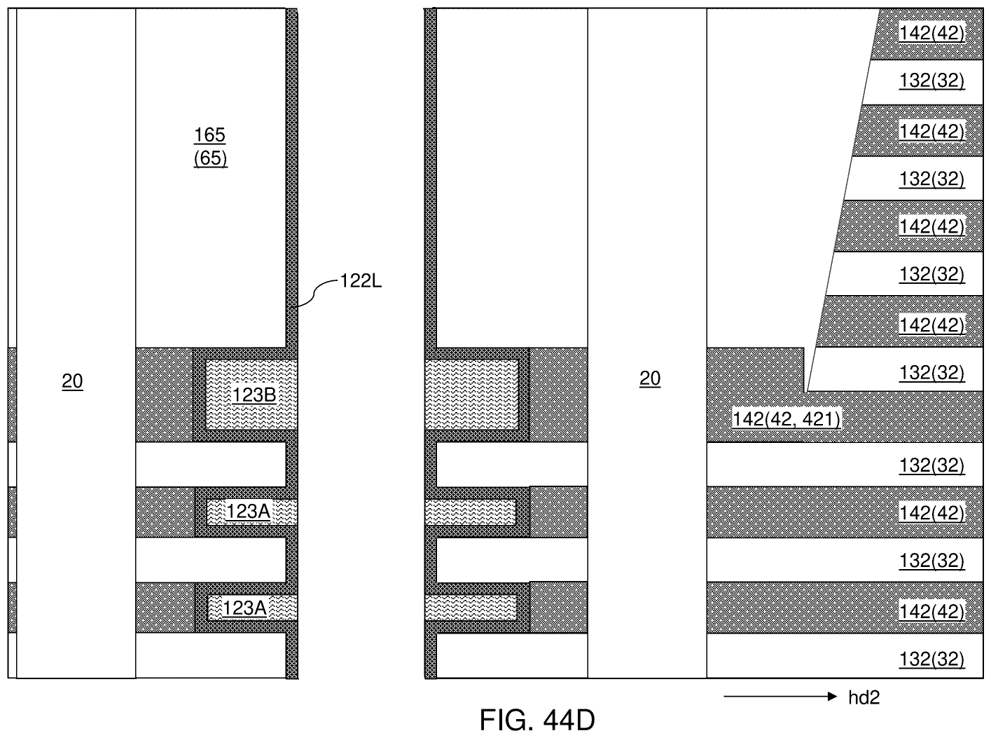

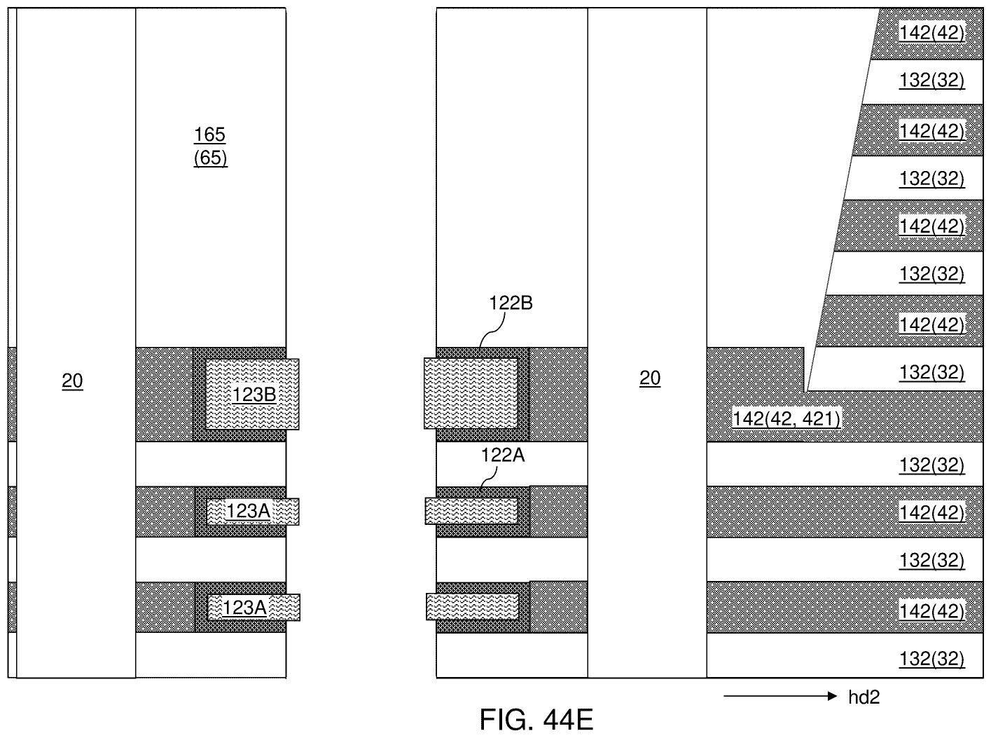

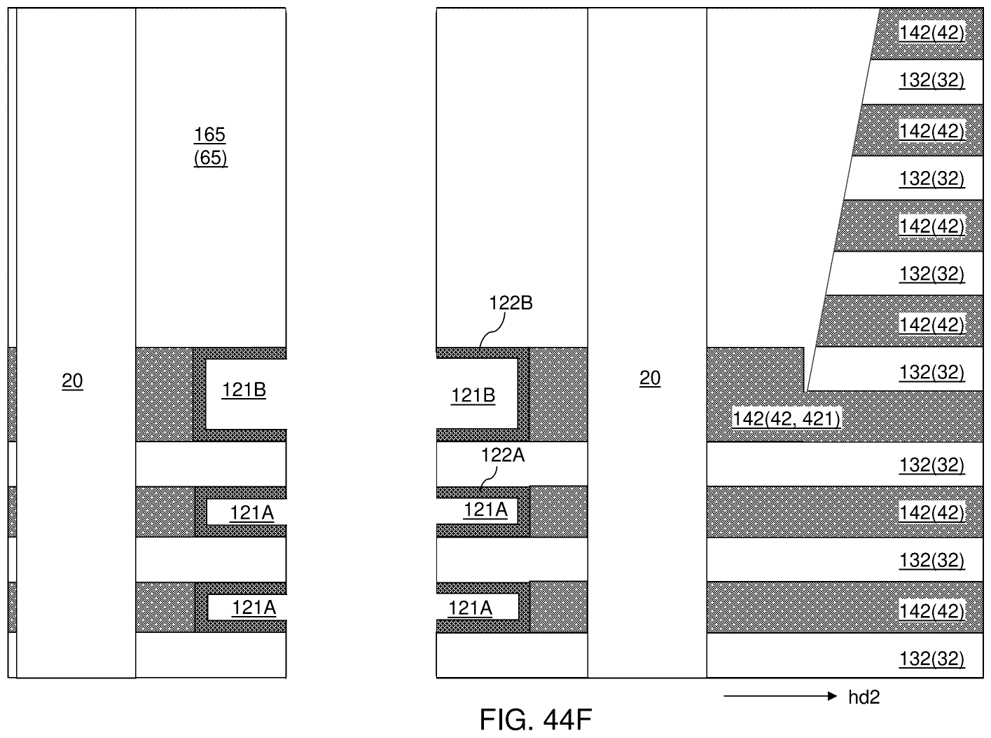

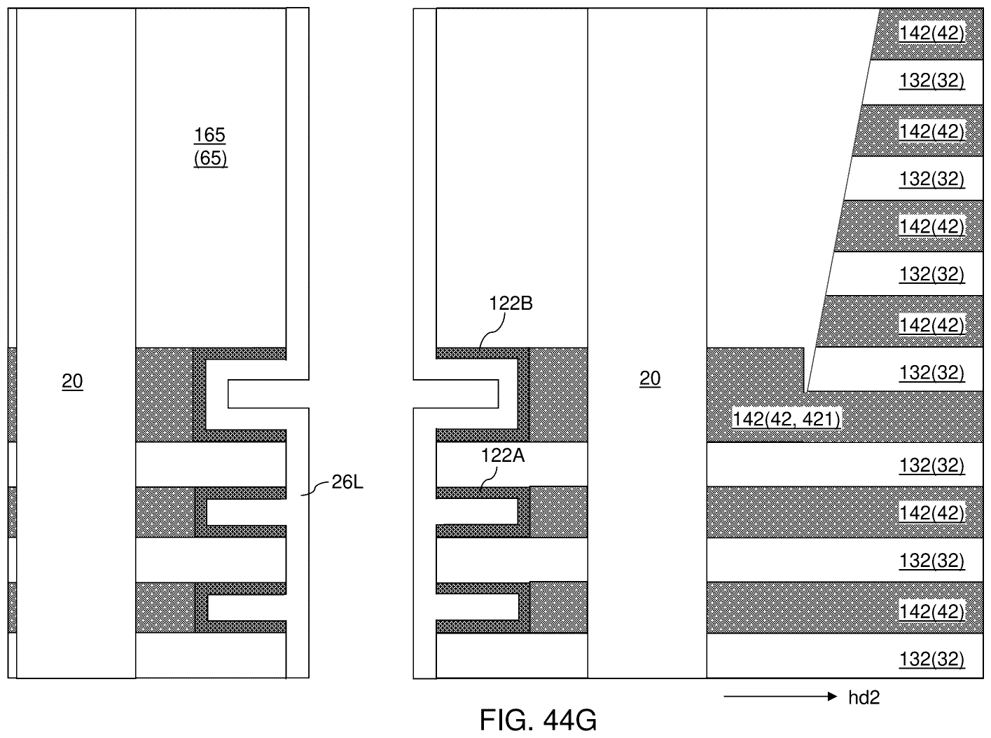

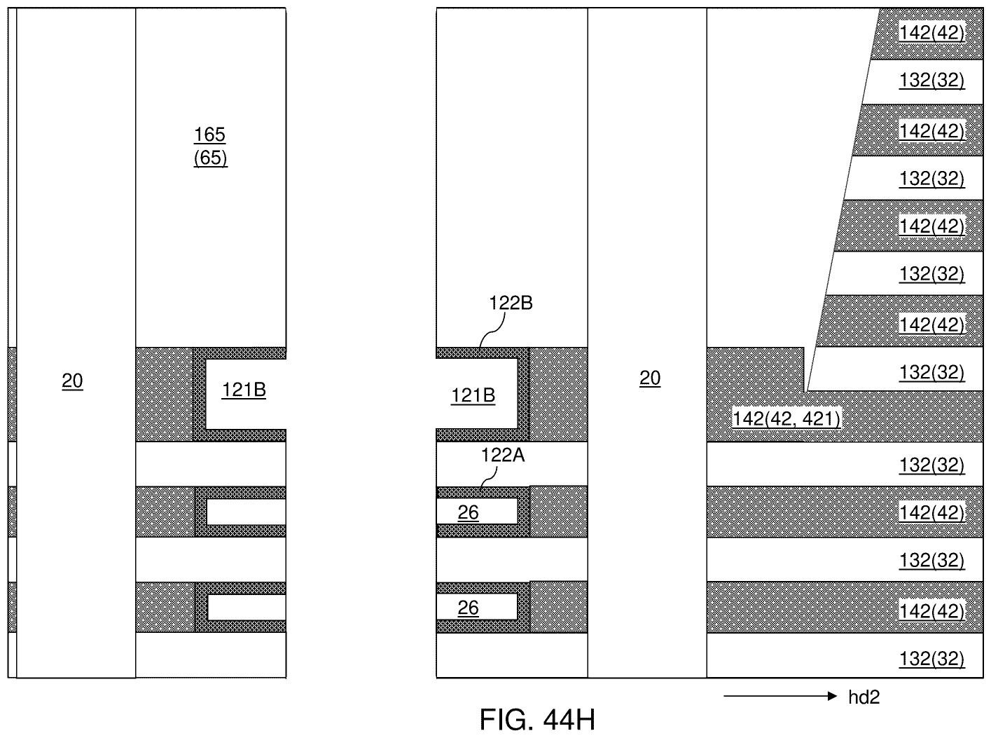

FIGS. 44A-44I are sequential vertical cross-sectional views of a region of a fourth exemplary structure during formation of a sacrificial contact via structure 84 around a contact via cavity 85 according to a fourth embodiment of the present disclosure. In the fourth embodiment, the annular dielectric spacers 26 are formed after formation of the conformal sacrificial material layer 122L. Thus, the order of forming the annular dielectric spacers 26 and the conformal sacrificial material layer 122L in the fourth embodiment is reversed relative to the third embodiment.

Referring to FIG. 44A, the fourth exemplary structure is illustrated after formation of contact via cavities 85. The third exemplary structure can be the same as the second exemplary structure illustrated in FIGS. 31A-31C.

Referring to FIG. 44B, a first isotropic etch process can be performed to isotropically etch proximal portions of the sacrificial material layers 42 around each contact via cavity 85 selectively to the insulating layers 32 and the at least one retro-stepped dielectric material portion 65, as described above with respect to FIG. 41B. For each contact via cavity 85, a first rectangular-vertical-profiled toroidal void 221B can be formed by isotropically etching a proximal portion of the respective first sacrificial material layer 421 selectively to the insulating layers 32. For each contact via cavity 85 that vertically extends through a plurality of sacrificial material layers 42, at least one second rectangular-vertical-profiled toroidal void 221A may be formed in volumes from which material portions of at least one second sacrificial material layer 422 are removed selectively to the insulating layers 32.

Referring to FIG. 44C, the conformal sacrificial material layer 122L can be deposited in the peripheral region of each contact via cavity 85, as described above with respect to FIG. 41F. The conformal sacrificial material layer 122L can be deposited in peripheral regions of each of the rectangular-vertical-profiled toroidal voids (221B, 221A).

Referring to FIG. 44D, optional annular etch mask material portions 123A and 123B may be formed within the unfilled lateral recesses 121A and 121B in the volumes of the respective rectangular-vertical-profiled toroidal voids 221A and 221B, as described above with respect to FIG. 41G. Alternatively, the annular etch mask material portions 123A and 123B may be omitted. The remaining portions of the etch mask material that fill the first rectangular-vertical-profiled toroidal voids 221B are herein referred to as first annular etch mask material portions 123B. The remaining portions of the etch mask material that fill the second rectangular-vertical-profiled toroidal voids 221A are herein referred to as second annular etch mask material portions 123A.

Referring to FIG. 44E, a selective isotropic etch process can be performed to etch unmasked portions of the conformal sacrificial material layer 122L selectively to the materials of the insulating layers 32, the at least one retro-stepped dielectric material portion 65, and the annular etch mask material portions (123B, 123A), as described above with respect to FIG. 41H. Each remaining portion of the conformal sacrificial material layer 122L is herein referred to as a dual-inward-flanged tube (122B, 122A). The dual-inward-flanged tubes (122B, 122A) comprise first dual-inward-flanged tubes 122B that are formed within the volumes of the first rectangular-vertical-profiled toroidal voids 221B, and second dual-inward-flanged tubes 122A that are formed within the volumes of the second rectangular-vertical-profiled toroidal voids 221A. Each dual-inward-flanged tube (122B, 122A) comprises a sacrificial material, and is formed in a respective rectangular-vertical-profiled toroidal void (221B or 221A). Each dual-inward-flanged tube (122B, 122A) comprises a tubular portion, an upper annular plate portion that is adjoined to a top end of an inner sidewall of the tubular portion, and a lower annular plate portion that is adjoined to a bottom end of the inner sidewall of the tubular portion.

Referring to FIG. 44F, each annular etch mask material portions (123B, 123A) can be removed without removing the materials of the dual-inward-flanged tubes (122B, 122A), the insulating layers 32, and the at least one retro-stepped dielectric material portion 65, as described with respect to FIG. 41I. Unfilled lateral recesses 121A and 121B are re-formed in the volumes from which the annular etch mask material portions 123A and 123B are removed.

In an alternative embodiment, formation of the annular etch mask material portions 123A and 123B is omitted, and the steps shown in FIGS. 44D and 44E are not performed. Instead, the conformal sacrificial material layer 122L shown in FIG. 44E is anisotropically etched (e.g., etched using reactive ion etching) to remove the conformal sacrificial material layer 122L from the sidewalls of the contact via cavities without removing the conformal sacrificial material layer 122L from the rectangular-vertical-profiled toroidal voids 221B. The anisotropic etching forms the dual-inward-flanged tubes 122 surrounding the unfilled lateral recesses 221R, as shown in FIG. 41I.

Referring to FIG. 44G, the recess-fill dielectric material layer 26L can be formed by conformally depositing a recess-fill dielectric material, such as silicon oxide, in the unfilled lateral recesses 121A and 121B that are surrounded by the dual-inward-flanged tubes (122B, 122A), as described above with respect to FIG. 41C. In one embodiment, the recess-fill dielectric material layer 26L may comprise a silicate glass (i.e., silicon oxide) material. The thickness of the recess-fill dielectric material layer 26L can be greater than one half of the height of each unfilled lateral recess 121A that is surrounded by a respective one of the second dual-inward-flanged tube 122A, and is less than one half of the height of each unfilled lateral recess 121B that is surrounded by a respective one of the first dual-inward-flanged tube 122B. Thus, each unfilled lateral recess 121A that is laterally surrounded by a respective second dual-inward-flanged tube 122A is completely filled with the recess-fill dielectric material layer 26L, while each unfilled lateral recess 121B that is laterally surrounded by a respective one of the first dual-inward-flanged tube 122B is only partly filled by the recess-fill dielectric material layer 26L.

Referring to FIG. 44H, an isotropic etch process can be performed to isotropically etch the material of the recess-fill dielectric material layer 26L, as described above with respect to FIG. 41D. According to an aspect of the present disclosure, the duration of the second isotropic etch process can be selected to ensure removal of the entirety of each portion of the recess-fill dielectric material layer 26L located within the volumes of the first rectangular-vertical-profiled toroidal void 221B, i.e., to remove the entirety of each portion of the recess-fill dielectric material layer 26L that is laterally surrounded by a respective one of the first dual-inward-flanged tubes 122B. In one embodiment, the duration of the isotropic etch process can be selected such that the recess etch distance of the isotropic etch process for the material of the recess-fill dielectric material layer 26L is in a range from 105% to 150%, such as from 100% to 130%, of the thickness of the recess-fill dielectric material layer 26L. The recess-fill dielectric material layer 26L is entirely removed from each first rectangular-vertical-profiled toroidal void 221B to re-open the first unfilled lateral recess 121B. Each remaining portion of the recess-fill dielectric material layer 26L that is laterally surrounded by a respective one of the second dual-inward-flanged tubes 122A comprises an annular dielectric spacer 26. Each first annular recess region 21A can be filled with a combination of a respective second dual-inward-flanged tube 122A and a respective annular dielectric spacer 26.

Referring to FIG. 44I, a sacrificial via fill material can be deposited in the contact via cavities 85, and excess portions of the sacrificial via fill material can be removed from above the horizontal plane including the top surface of the contact-level dielectric layer 80, as described above with respect to FIG. 41J.

In the fourth exemplary structure, for each sacrificial contact via structure 84 located within a respective contact via cavity 85 and laterally surrounded by a respective first sacrificial material layer 421 and second sacrificial material layers 422, the second sacrificial material layers 422 are laterally offset from a first cylindrical vertical plane CVP1 including an outer sidewall of the lower portion of the sacrificial contact via structure 84 by a first lateral offset distance, and the first sacrificial material layer 421 is laterally offset from the first cylindrical vertical plane CVP1 by a second lateral offset distance that may be the same as the first lateral offset distance. A vertical stack of annular dielectric spacers 26 laterally surrounds the lower portion of the sacrificial contact via structure 84, and the vertical stack is laterally surrounded by the second sacrificial material layers 42.

Subsequently, the processing steps described with reference to FIGS. 20A-21D can be performed to form lateral isolation trenches 79 and lateral recesses 43.

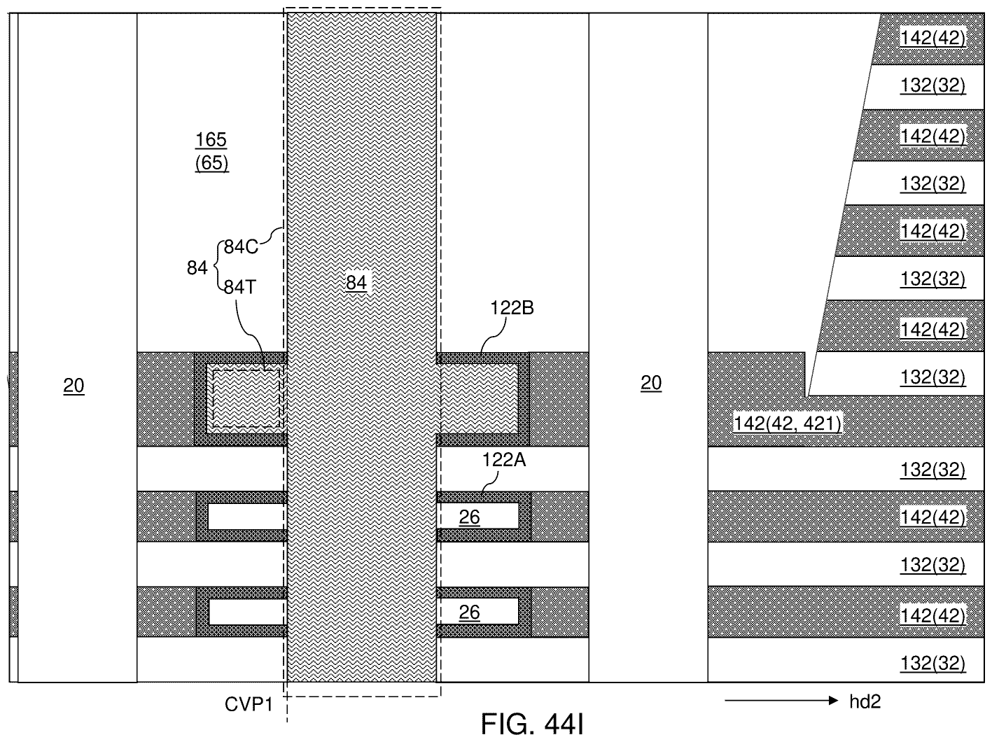

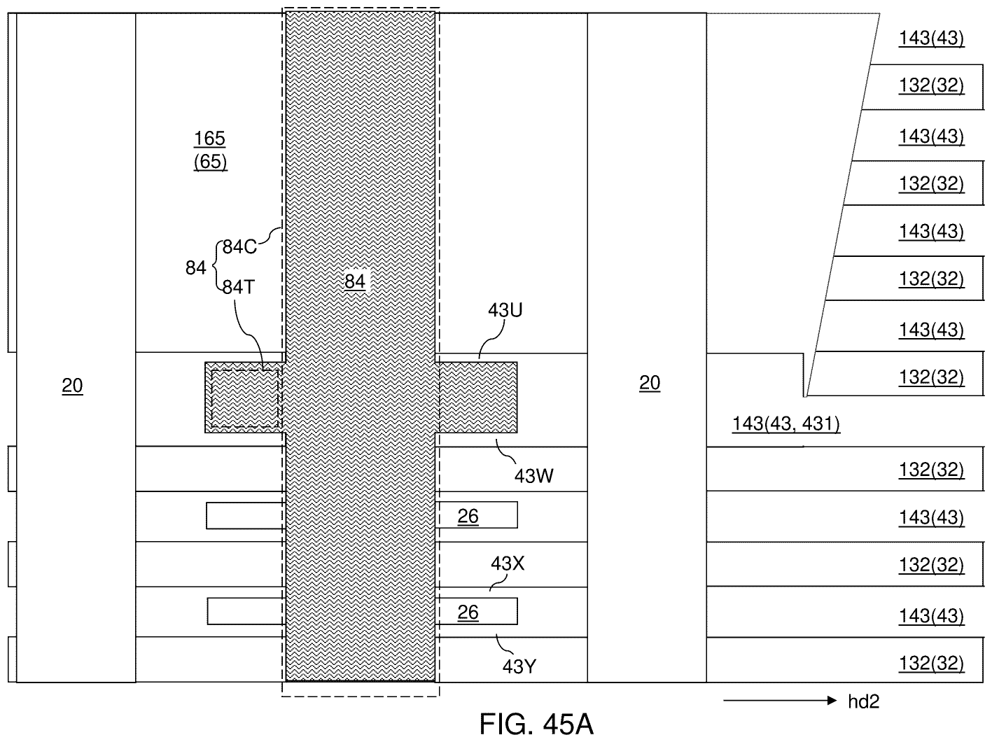

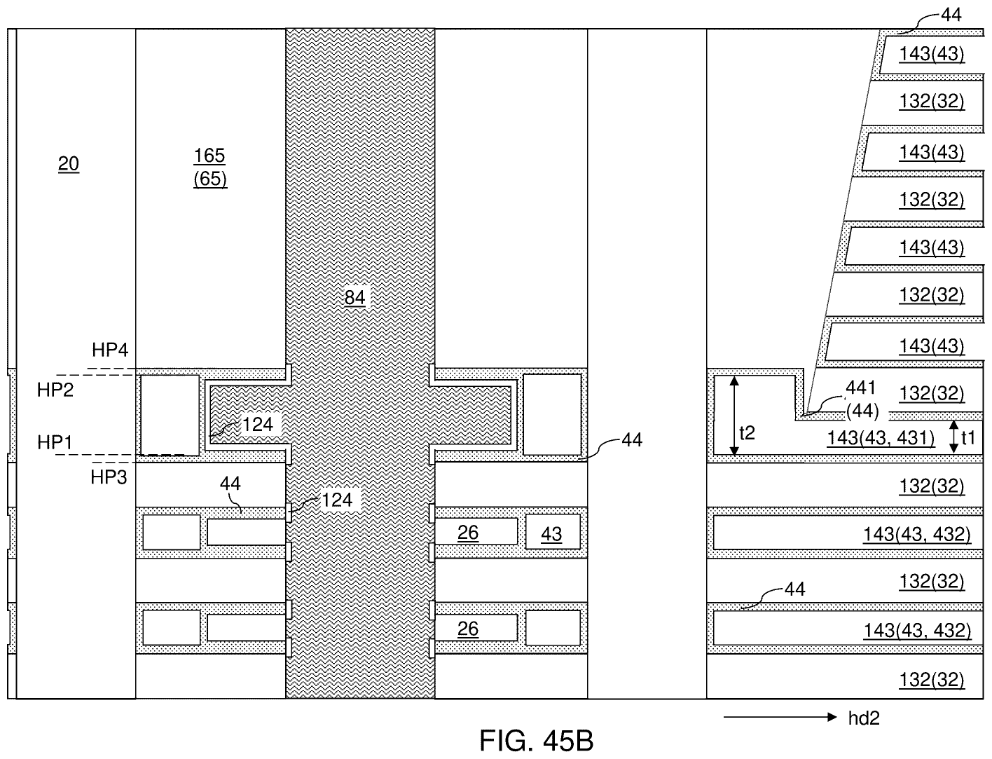

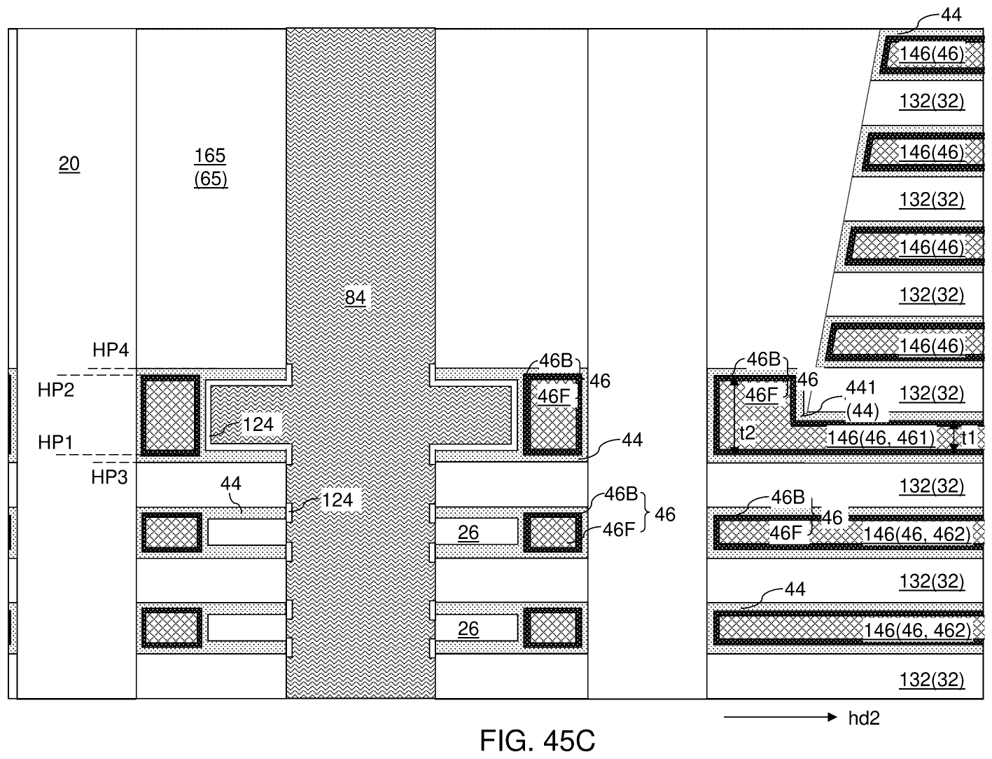

FIGS. 45A-45C are sequential vertical cross-sectional views of a region of the fourth exemplary structure during replacement of the sacrificial material layers 42 with outer blocking dielectric layers 44 and electrically conductive layers 46 according to the fourth embodiment of the present disclosure.

Referring to FIG. 45A, a region around a sacrificial contact via structure 84 is illustrated after formation of the lateral recesses 43, as described above with respect to FIG. 42A. The selective isotropic etch process that removes the sacrificial material layers 42 also removes the dual-inward-flanged tubes (122B, 122A). Thus, the lateral recesses 43 include volumes of voids formed by removal of the sacrificial material layers 42 and volumes of voids formed by removal of the dual-inward-flanged tubes (122B, 122A). An upper annular gap 43U is present between an annular top surface of each toroidal sacrificial material portion 84T and an overlying portion of the at least one retro-stepped dielectric material portion 65. A lower annular gap 43W is present between an annular bottom surface of each toroidal sacrificial material portion 84T and an underlying insulating layer 32. An upper annular gap 43X is present between an annular top surface of each annular dielectric spacer 26 and an overlying insulating layer 32. A lower annular gap 43Y is present between an annular bottom surface of each annular dielectric spacer 26 and an underlying insulating layer 32.

Referring to FIG. 45B, the outer blocking dielectric layer 44 may be conformally deposited in peripheral portions of the lateral recesses 43 and the lateral isolation trenches 79, as described above with respect to FIG. 42B. Optionally, surface portions of the sacrificial contact via structures 84 that are in contact with the outer blocking dielectric layer 44 may be converted into semiconductor oxide liners 124 including a semiconductor oxide material (such as silicon oxide). The entire volume of each annular gap (43U, 43W) overlying or underlying an annular horizontal surface of a toroidal sacrificial material portion 84T can be filled with the outer blocking dielectric layer 44. Likewise, the entire volume of each annular gap (43X, 43Y) overlying or underlying an annular horizontal surface of an annular dielectric spacer 26 can be filled with the outer blocking dielectric layer 44.

Referring to FIG. 45C, the processing steps described with reference to FIG. 42C can be performed to form electrically conductive layers 46. Each of the electrically conductive layers 46 may include the respective metallic barrier liner 46B and the respective metal fill material portion 46F.

Subsequently, the processing steps described with reference to FIGS. 24A-25C may be performed to form lateral isolation trench fill structures 76 and to remove the sacrificial contact via structures 84.

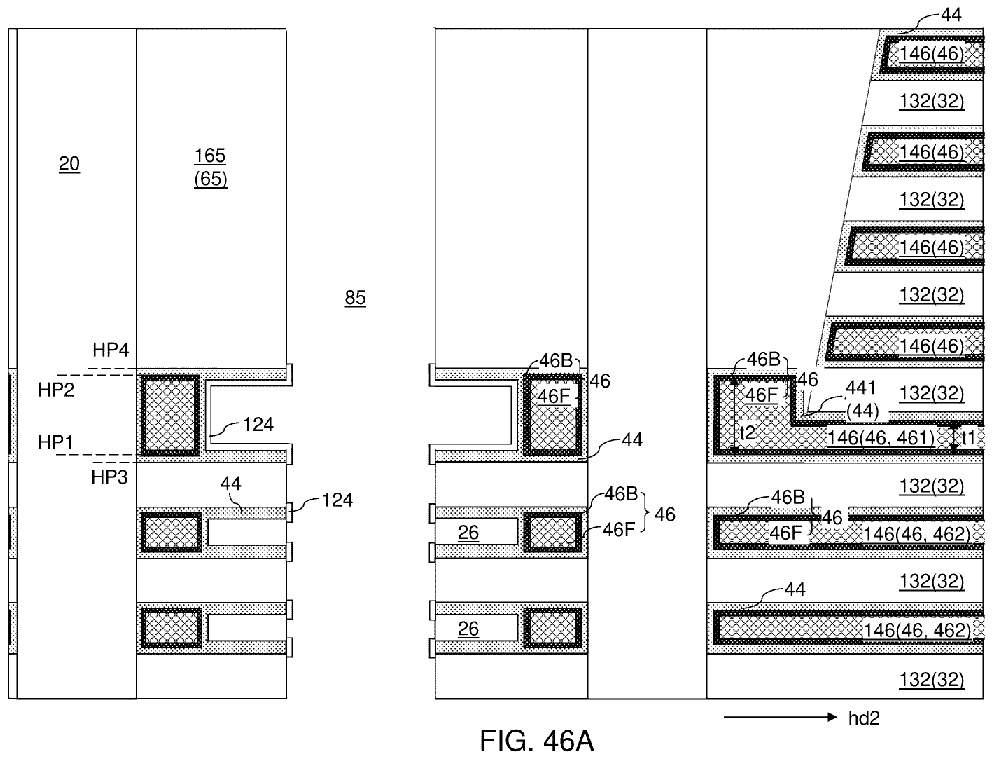

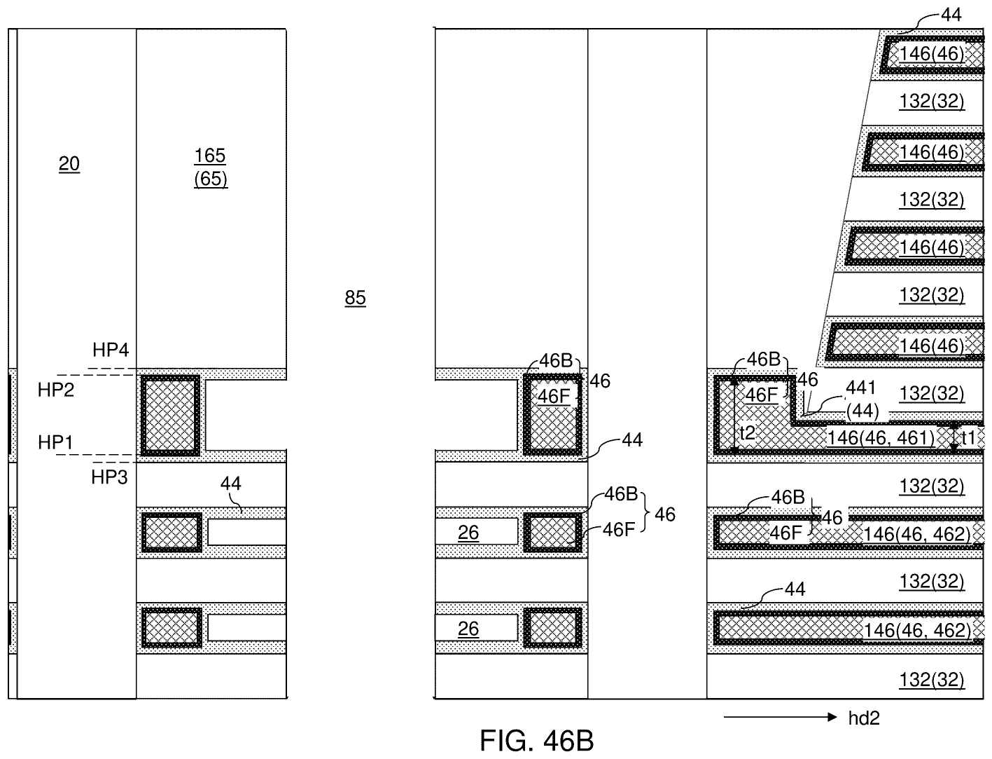

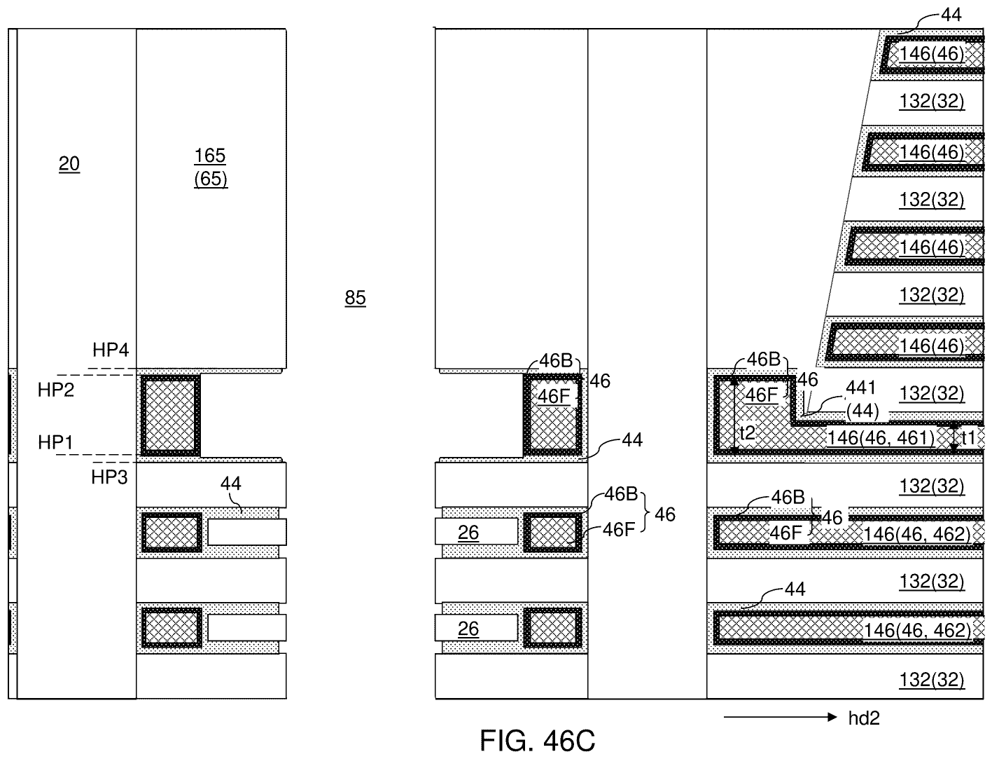

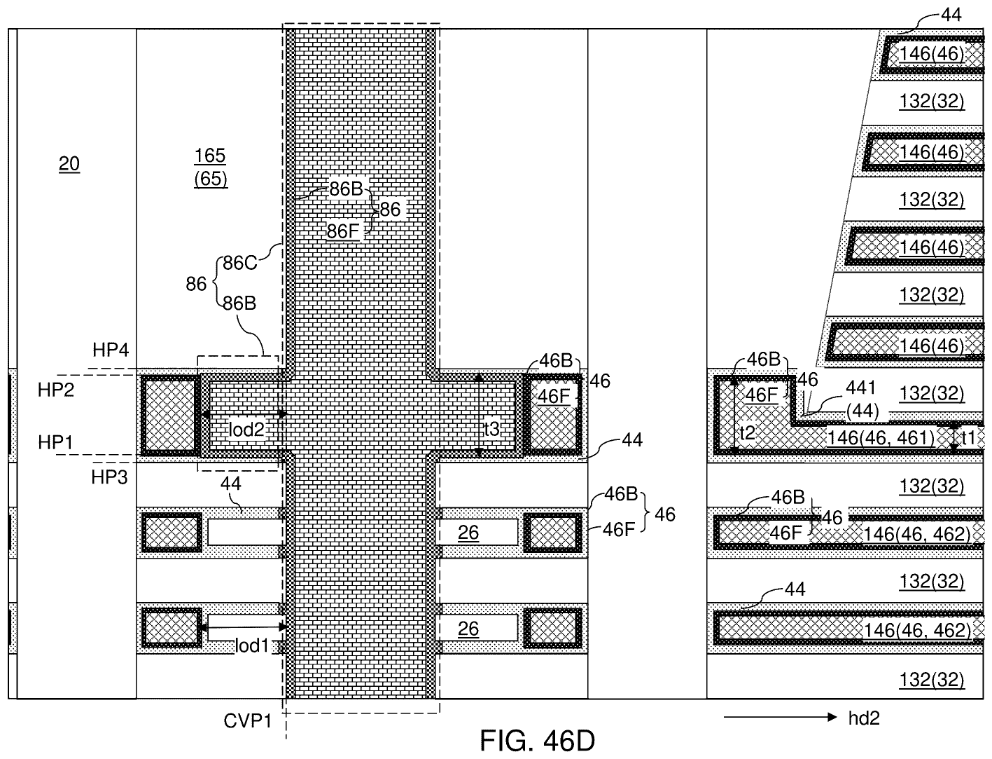

FIGS. 46A-46D are sequential vertical cross-sectional views of a region of the fourth exemplary structure during replacement of a sacrificial contact via structure 84 with a contact via structure 86 according to the fourth embodiment of the present disclosure.

Referring to FIG. 46A, the sacrificial contact via structures 84 can be removed selectively to the contact-level dielectric layer 80, the lateral isolation trench fill structures 76, the at least one retro-stepped dielectric material portion 65, the insulating layers 32, the annular dielectric spacers 26, and the optional semiconductor oxide liners 124 by performing a selective removal process, as described above with respect to FIG. 43A.

Referring to FIG. 46B, in case semiconductor oxide liners 124 are present, the semiconductor oxide liners 124 may be removed by performing an isotropic etch process such as a wet etch process employing dilute hydrofluoric acid.

Referring to FIG. 46C, a selective isotropic etch process to recess physically exposed surface portions of the outer blocking dielectric layers 44, as described above with respect to FIG. 43C. As discussed above, the vertical thickness of the portions of the outer blocking dielectric layer 44 that fill the volumes of the annular gaps (43U, 43W, 43X, 43Y) is greater than the thickness of each outer blocking dielectric layer 44 outside the volumes that fill the annular gaps. The duration of the selective isotropic etch process can be selected such that the etch distance of the selective isotropic etch process for the material of the outer blocking dielectric layers 44 is greater than the lateral thickness of cylindrical portions of the outer blocking dielectric layers 44 that are exposed to the contact via cavities 85, and is less than the vertical thickness of the portions of the outer blocking dielectric layer 44 that fill the volumes of the annular gaps (43U, 43W, 43X, 43Y). Thus, the duration of the selective isotropic etch process can be selected such that cylindrical sidewalls of the thick portions of the electrically conductive layers 46 are physically exposed to the contact via cavities 85, while annular horizontally-extending remaining portions of the outer blocking dielectric layers 44 are located above, and below, a laterally bulging portion of the contact via cavities 85.

Referring to FIG. 46D, at least one second electrically conductive material can be deposited in each of the contact via cavities 85 to form the contact via structure 86 that contacts the respective first electrically conductive layer 461, as described above with respect to FIG. 43D. In one embodiment, the contact via structure 86 may comprise the metallic barrier liner (which is herein referred to as a contact-via metallic barrier liner 86B) and the metal fill material portion (which is herein referred to as a contact-via metal fill material portion 86F) that is laterally surrounded by the contact-via metallic barrier liner 86B.

Each contact via structure 86 comprises a respective cylindrical portion 86C and a respective laterally bulging portion 86B. In one embodiment, the second electrically conductive layers 462 and the first electrically conductive layer 461 may be laterally offset from a first cylindrical vertical plane CVP1 including an outer sidewall of the lower portion of the contact via structure 86 by a same lateral offset distance.

Referring to all drawings of the present disclosure, a device structure is provided, which comprises: at least one alternating stack (32, 46) of respective insulating layers 32 and respective electrically conductive layers 46, wherein each of the at least one alternating stack (32, 46) comprises respective stepped surfaces located in a staircase region; at least one retro-stepped dielectric material portion 65 overlying portions of the at least one alternating stack (32, 46) located in the staircase region; a memory opening 49 vertically extending through each layer within the at least one alternating stack (32, 46); a memory opening fill structure 58 located in the memory opening 49 and comprising a vertical stack of memory elements (e.g., portions of the memory film 50) and a vertical semiconductor channel 60; a contact via structure 86 comprising a laterally bulging portion 86B in contact with a first electrically conductive layer 461 of the electrically conductive layers 46 within the at least one alternating stack (32, 46), an upper portion that vertically extends upward from the laterally bulging portion 86B and through the at least one retro-stepped dielectric material portion 65, and a lower portion that vertically extends through second electrically conductive layers 462 of the electrically conductive layers 46 that underlie the first electrically conductive layer 461; and a vertical stack of annular dielectric spacers 26 laterally surrounding the lower portion of the contact via structure 86, and laterally surrounded by the second electrically conductive layers 462.

In one embodiment, each of the electrically conductive layers 46 is embedded within a respective outer blocking dielectric layer 44 and is vertically spaced from a most proximal one of the insulating layers 32 by a horizontally-extending portion of the respective outer blocking dielectric layer 44. In one embodiment, the first electrically conductive layer 461 is embedded within a first outer blocking dielectric layer 441 of the outer blocking dielectric layers 44; and the laterally bulging portion 86B of the contact via structure 86 comprises an annular horizontal top surface in contact with an annular horizontal bottom surface segment of the first outer blocking dielectric layer 441. In one embodiment, the laterally bulging portion 86B of the contact via structure 86 further comprises an annular horizontal bottom surface in contact with an annular horizontal top surface of the first outer blocking dielectric layer 441.

In one embodiment, a horizontal top surface of the first outer blocking dielectric layer 44 contacts a bottom surface of the at least one retro-stepped dielectric material portion 65. In one embodiment, a sidewall of the upper portion of the contact via structure 86 extends vertically from a periphery of the bottom surface of the at least one retro-stepped dielectric material portion 65 at least to a topmost surface of the at least one retro-stepped dielectric material portion 65 with a straight vertical cross-sectional profile.

In one embodiment, a first portion of the first electrically conductive layer 461 laterally surrounds the memory opening fill structure 58 and has a first thickness t1; and a second portion of the first electrically conductive layer 461 laterally surrounds the laterally bulging portion 86B of the contact via structure 86 and has a second thickness t2 that is greater than the first thickness t1. In one embodiment, the laterally bulging portion 86B of the contact via structure 86 has a third thickness t3 that is greater than the second thickness t2.

In one embodiment, the second portion of the first electrically conductive layer 461 comprises a bottom surface located within a first horizontal plane HP1 and a top surface located within a second horizontal plane HP2; and the laterally bulging portion 86B of the contact via structure 86 comprises an annular horizontal bottom surface that underlies the first horizontal plane HP1, and an annular horizontal top surface that overlies the second horizontal plane HP2. In one embodiment, the first electrically conductive layer 461 is embedded within a first outer blocking dielectric layer 44; the first outer blocking dielectric layer 44 comprises a bottommost surface located within a third horizontal plane HP3 and a topmost surface located within a fourth horizontal plane HP4; the annular horizontal bottom surface of the laterally bulging portion 86B is located above the third horizontal plane HP3; and the annular horizontal top surface of the laterally bulging portion 86B is located below the fourth horizontal plane HP4. In one embodiment, a thickness of a first annular portion of the first outer blocking dielectric layer 44 that overlies and contacts the annular horizontal top surface of the laterally bulging portion 86B is less than a thickness of a horizontally-extending portion of the first outer blocking dielectric layer 44 that overlies and contacts the first electrically conductive layer 461.

In one embodiment, the first electrically conductive layer 461 contacts a cylindrical outer sidewall of the laterally bulging portion 86B of the contact via structure 86. In the third embodiment, the second electrically conductive layers 462 are laterally offset from a first cylindrical vertical plane CVP1 including an outer sidewall of the lower portion of the contact via structure 86 by a first lateral offset distance lod1; and the first electrically conductive layer 461 is laterally offset from the first cylindrical vertical plane CVP1 by a second lateral offset distance lod2 that is greater than the first lateral offset distance lod1. Alternatively, in the fourth embodiment, the second electrically conductive layers 462 and the first electrically conductive layer 461 are laterally offset from a first cylindrical vertical plane CVP1 including an outer sidewall of the lower portion of the contact via structure 86 by a same lateral offset distance.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A device structure, comprising:
at least one alternating stack of respective insulating layers and respective electrically conductive layers, wherein each of the at least one alternating stack comprises respective stepped surfaces located in a staircase region;
at least one retro-stepped dielectric material portion overlying portions of the at least one alternating stack located in the staircase region;
a memory opening vertically extending through each layer within the at least one alternating stack;
a memory opening fill structure located in the memory opening and comprising a vertical stack of memory elements and a vertical semiconductor channel;
a contact via structure comprising a laterally bulging portion in contact with a first electrically conductive layer of the electrically conductive layers within the at least one alternating stack, an upper portion that vertically extends upward from the laterally bulging portion and through the at least one retro-stepped dielectric material portion, and a lower portion that vertically extends through second electrically conductive layers of the electrically conductive layers that underlie the first electrically conductive layer; and
a vertical stack of annular dielectric spacers laterally surrounding the lower portion of the contact via structure, and laterally surrounded by the second electrically conductive layers.

2. The device structure of claim 1, wherein each of the electrically conductive layers is embedded within a respective outer blocking dielectric layer and is vertically spaced from a most proximal one of the insulating layers by a horizontally-extending portion of the respective outer blocking dielectric layer.

3. The device structure of claim 2, wherein:
the first electrically conductive layer is embedded within a first outer blocking dielectric layer of the outer blocking dielectric layers; and
the laterally bulging portion of the contact via structure comprises an annular horizontal top surface in contact with an annular horizontal bottom surface segment of the first outer blocking dielectric layer.

4. The device structure of claim 3, wherein the laterally bulging portion of the contact via structure further comprises an annular horizontal bottom surface in contact with an annular horizontal top surface of the first outer blocking dielectric layer.

5. The device structure of claim 4, wherein a horizontal top surface of the first outer blocking dielectric layer contacts a bottom surface of the at least one retro-stepped dielectric material portion.

6. The device structure of claim 5, wherein a sidewall of the upper portion of the contact via structure extends vertically from a periphery of the bottom surface of the at least one retro-stepped dielectric material portion at least to a topmost surface of the at least one retro-stepped dielectric material portion with a straight vertical cross-sectional profile.

7. The device structure of claim 1, wherein:
a first portion of the first electrically conductive layer laterally surrounds the memory opening fill structure and has a first thickness; and
a second portion of the first electrically conductive layer laterally surrounds the laterally bulging portion of the contact via structure and has a second thickness that is greater than the first thickness.

8. The device structure of claim 7, wherein the laterally bulging portion of the contact via structure has a third thickness that is greater than the second thickness.

9. The device structure of claim 7, wherein:
the second portion of the first electrically conductive layer comprises a bottom surface located within a first horizontal plane and a top surface located within a second horizontal plane; and
the laterally bulging portion of the contact via structure comprises an annular horizontal bottom surface that underlies the first horizontal plane, and an annular horizontal top surface that overlies the second horizontal plane.

10. The device structure of claim 9, wherein:
the first electrically conductive layer is embedded within a first outer blocking dielectric layer;
the first outer blocking dielectric layer comprises a bottommost surface located within a third horizontal plane and a topmost surface located within a fourth horizontal plane;
the annular horizontal bottom surface of the laterally bulging portion is located above the third horizontal plane; and
the annular horizontal top surface of the laterally bulging portion is located below the fourth horizontal plane.

11. The device structure of claim 10, wherein a thickness of a first annular portion of the first outer blocking dielectric layer that overlies and contacts the annular horizontal top surface of the laterally bulging portion is less than a thickness of a horizontally-extending portion of the first outer blocking dielectric layer that overlies and contacts the first electrically conductive layer.

12. The device structure of claim 1, wherein the first electrically conductive layer contacts a cylindrical outer sidewall of the laterally bulging portion of the contact via structure.

13. The device structure of claim 12, wherein:
the second electrically conductive layers are laterally offset from a first cylindrical vertical plane including an outer sidewall of the lower portion of the contact via structure by a first lateral offset distance; and
the first electrically conductive layer is laterally offset from the first cylindrical vertical plane by a second lateral offset distance that is greater than the first lateral offset distance.

14. The device structure of claim 12, wherein the second electrically conductive layers and the first electrically conductive layer are laterally offset from a first cylindrical vertical plane including an outer sidewall of the lower portion of the contact via structure by a same lateral offset distance.

15. The device structure of claim 1, wherein the vertical stack of memory elements comprises portions of a memory film which surrounds the vertical semiconductor channel.

16. A method of forming a device structure, comprising:
forming an alternating stack of insulating layers and sacrificial material layers over a substrate;
forming stepped surfaces by patterning the alternating stack in a staircase region;
forming a retro-stepped dielectric material portion over the stepped surfaces;
forming a contact via cavity through the retro-stepped dielectric material portion and a subset of the sacrificial material layers within the alternating stack, wherein the subset of the sacrificial material layers comprises a first sacrificial material layer which is a topmost sacrificial material layer of the subset of the sacrificial material layers and further comprises second sacrificial material layers that underlie the first sacrificial material layer;
locally expanding the contact via cavity by laterally recessing the first sacrificial material layer around the contact via cavity to form a rectangular-vertical-profiled toroidal void in a volume from which a portion of the first sacrificial material layer is removed;
forming a dual-inward-flanged tube comprising a sacrificial material in the rectangular-vertical-profiled toroidal void;
forming a sacrificial contact via structure in the contact via cavity;
replacing the sacrificial material layers and the dual-inward-flanged tube at least with electrically conductive layers; and
replacing the sacrificial contact via structure with a contact via structure, wherein the contact via structure contacts a cylindrical sidewall of the first electrically conductive layer.

17. The method of claim 16, wherein:
the first electrically conductive layer occupies a fraction of a volume of the first sacrificial material layer; and
the contact via structure is formed directly on a cylindrical sidewall of the first electrically conductive layer.

18. The method of claim 16, wherein the sacrificial material layers and the dual-inward-flanged tube are replaced with the electrically conductive layers and outer blocking dielectric layers each embedding a respective one of the electrically conductive layers.

19. The method of claim 18, wherein:
the dual-inward-flanged tube comprises a tubular portion, an upper annular plate portion that is adjoined to a top end of an inner sidewall of the tubular portion, and a lower annular plate portion that is adjoined to a bottom end of the inner sidewall of the tubular portion;
lateral recesses are formed in volumes from which the sacrificial material layers and the dual-inward-flanged tube are removed; and
the outer blocking dielectric layers are formed by conformally depositing a blocking dielectric material in peripheral regions of the lateral recesses at a thickness that is greater than one half of a thickness of the upper annular plate portion.

20. The method of claim 16, wherein the sacrificial contact via structure comprises:
a cylindrical sacrificial material portion; and
a toroidal sacrificial material portion that is formed within a volume of the rectangular-vertical-profiled toroidal void.
